(19) United States
(12) Patent Application Publication
(10) Pub. No.: US 2025/0380416 A1
(43) Pub. Date: Dec. 11, 2025

(54) THREE-DIMENSIONAL MEMORY DEVICE WITH THROUGH-STACK CONTACT ASSEMBLIES AND METHODS FOR FORMING THE SAME

(71) Applicant: SANDISK TECHNOLOGIES LLC, ADDISON, TX (US)

(72) Inventors: Akira TAKAHASHI, Yokkaichi (JP); Koichi MATSUNO, Fremont, CA (US)

(21) Appl. No.: 18/784,218

(22) Filed: Jul. 25, 2024

Related U.S. Application Data
(60) Provisional application No. 63/656,464, filed on Jun. 5, 2024.

(51) Int. Cl. H10B 43/27; H10B 41/27

(52) U.S. Cl. CPC H10B 43/27; H10B 41/27

(57) ABSTRACT

A device structure includes an alternating stack of insulating layers and electrically conductive layers. The alternating stack includes a staircase region. A retro-stepped dielectric material portion overlies the alternating stack in the staircase region. A contact assembly includes a layer contact via structure and a finned support assembly. The layer contact via structure vertically extends through the retro-stepped dielectric material portion and includes a contoured bottom surface that includes an annular surface segment that contacts an annular top surface segment of a first electrically conductive layer of the electrically conductive layers. The finned support assembly contacts central surface segments of the contoured bottom surface of the layer contact via structure.

### FIELD

The present disclosure relates generally to the field of semiconductor devices, and particularly to a three-dimensional memory device including through-stack contact assemblies and methods for forming the same.

### BACKGROUND

A three-dimensional memory device including three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an embodiment of the present disclosure, a device structure comprises: an alternating stack of insulating layers and electrically conductive layers, wherein the alternating stack comprises a staircase region; a retro-stepped dielectric material portion overlying the alternating stack in the staircase region; and a contact assembly comprising a layer contact via structure and a finned support assembly, wherein: a first electrically conductive layer of the electrically conductive layers comprises a first portion having a first thickness in a region in which each layer in the alternating stack is present, has a second portion having a second thickness that is greater than the first thickness around the contact assembly, and has a third portion having a third thickness and that is laterally surrounded by the second portion; and the layer contact via structure vertically extends through the retro-stepped dielectric material portion and comprises a contoured bottom surface that includes an annular planar surface segment that contacts an annular top surface segment of the third portion of the first electrically conductive layer.

According to another aspect of the present disclosure, a method of forming a device structure is provided, which comprises: forming an alternating stack of insulating layers and sacrificial material layers over a substrate; forming stepped surfaces by patterning the alternating stack in a staircase region; thickening physically-exposed portions of the sacrificial material layers in the staircase region; forming a retro-stepped dielectric material portion overlying the stepped surfaces; forming a contact via cavity through the retro-stepped dielectric material portion and the alternating stack; thinning a thickened portion of one of the sacrificial material layers around the contact via cavity; forming a combination of a finned support assembly and a sacrificial contact via structure in the contact via cavity; replacing the sacrificial material layers with electrically conductive layers, wherein a first electrically conductive layer that replaces said one of the sacrificial material layers comprises a first portion located outside the staircase region and having a first thickness, a second portion located around the layer contact via structure and having a second thickness that is greater than the first thickness, and a third portion that replaces a thinned segment of said one of the sacrificial material layers and has a third thickness that is less than the second thickness; and replacing the sacrificial contact via structure with a layer contact via structure that directly contacts and annular surface segment of the third portion of the first electrically conductive layer.

According to yet another aspect of the present disclosure, a device structure comprises: an alternating stack of insulating layers and electrically conductive layers, wherein the alternating stack comprises a staircase region; a retro-stepped dielectric material portion overlying the alternating stack in the staircase region; and a contact assembly comprising a layer contact via structure, a finned support assembly, and a doped silicate glass portion interposed between the finned support assembly and the layer contact via structure, wherein: the layer contact via structure vertically extends through the retro-stepped dielectric material portion and comprises a contoured bottom surface that includes an annular surface segment that contacts an annular top surface segment of a first electrically conductive layer of the electrically conductive layers.

According to another aspect of the present disclosure, a method of forming a device structure comprises: forming an alternating stack of insulating layers and sacrificial material layers over a substrate; forming stepped surfaces by patterning the alternating stack; forming a retro-stepped dielectric material portion overlying the stepped surfaces; forming a contact via cavity through the retro-stepped dielectric material portion and the alternating stack; forming a combination of a finned support assembly, a doped silicate glass portion overlying the finned support assembly, and a sacrificial contact via structure in the contact via cavity; replacing the sacrificial material layers with electrically conductive layers; and replacing the sacrificial contact via structure with a layer contact via structure that directly contacts an annular surface segment of a first electrically conductive layer of the electrically conductive layers.

According to still another aspect of the present disclosure, device structure comprises: an alternating stack of insulating layers and electrically conductive layers, wherein the alternating stack comprises a staircase region; a retro-stepped dielectric material portion overlying the alternating stack in the staircase region; and a contact assembly comprising a layer contact via structure and a finned support assembly, wherein the layer contact via structure vertically extends through the retro-stepped dielectric material portion and comprises a contoured bottom surface that includes an annular horizontal surface segment that contacts an annular top surface segment of a first electrically conductive layer of the electrically conductive layers, the finned support assembly contacts at least one central surface segment of the contoured bottom surface; and the finned support assembly comprises a tubular semiconductor liner having an outer cylindrical segment that contacts a surface segment of the contoured bottom surface of the layer contact via structure.

According to a further aspect of the present disclosure, a device structure comprises: an alternating stack of insulating layers and electrically conductive layers, wherein the alternating stack comprises a staircase region; a retro-stepped dielectric material portion overlying the alternating stack in the staircase region; and a contact assembly comprising a layer contact via structure and a finned support assembly, wherein the layer contact via structure vertically extends through the retro-stepped dielectric material portion and comprises a contoured bottom surface that includes an annular surface segment that contacts an annular top surface segment of a first electrically conductive layer of the electrically conductive layers, and the finned support assembly contacts central surface segments of the contoured bottom surface, wherein the finned support assembly comprises a cylindrical dielectric pillar, a spacer liner that laterally surrounds the cylindrical dielectric pillar, and a finned dielectric pillar that laterally surrounds the spacer liner and includes a tubular dielectric portion in contact with the spacer liner and a plurality of dielectric fins that laterally protrude from the tubular dielectric portion.

According to further another aspect of the present disclosure, a method of forming a device structure comprises: forming an alternating stack of insulating layers and sacrificial material layers over a substrate; forming stepped surfaces in a staircase region by patterning the alternating stack; forming a retro-stepped dielectric material portion overlying the stepped surfaces; forming a contact via cavity through the retro-stepped dielectric material portion and the alternating stack; forming a combination of a finned support assembly and a sacrificial contact via structure in the contact via cavity, wherein the finned support assembly comprises a cylindrical dielectric pillar, a spacer liner that laterally surrounds the cylindrical dielectric pillar, and a finned dielectric pillar that laterally surrounds the spacer liner and includes a tubular dielectric portion in contact with the spacer liner and a plurality of dielectric fins that laterally protrude from the tubular dielectric portion; replacing the sacrificial material layers with electrically conductive layers; and replacing the sacrificial contact via structure with a layer contact via structure that directly contacts an annular surface segment of a first electrically conductive layer of the electrically conductive layers.

### BRIEF DESCRIPTION OF THE DRAWINGS

FIG. 1A is a plan view of a configuration of an exemplary semiconductor die including multiple three-dimensional memory array regions according to an embodiment of the present disclosure. FIG. 1B is a schematic see-through top-down view of region M1 of FIG. 1A.

FIG. 1C is a schematic vertical cross-sectional view of a region of the exemplary semiconductor die along the vertical plane C-C′ of FIG. 1B. The vertical plane E-E′ is the cut plane of the schematic vertical cross-sectional view of FIG. 1E. FIG. 1D is a schematic vertical cross-sectional view of a region of the exemplary semiconductor die along the vertical plane D-D′ of FIG. 1B. FIG. 1E is a schematic vertical cross-sectional view of a region of the exemplary semiconductor die along the vertical plane E-E′ of FIG. 1B. The vertical plane C-C′ is the cut plane of the schematic vertical cross-sectional view of FIG. 1C.

FIG. 2A is a schematic vertical cross-sectional view of a first exemplary structure for forming a semiconductor die after formation of a vertically alternating sequence of first-tier continuous insulating layers and first-tier continuous sacrificial material layers, and a first-tier stepped cavity according to a first embodiment of the present disclosure. FIG. 2B is a schematic vertical cross-sectional view of the first exemplary structure along the vertical plane B-B′ of FIG. 2A. The vertical plane A-A′ is the cut plane of the vertical cross-sectional view of FIG. 2A. FIG. 2C is a magnified view of a region of the first exemplary structure around a bottom corner of a first-tier stepped cavity in FIG. 2B.

FIGS. 3A-3C are sequential vertical cross-sectional views of a region of the first exemplary structure during thickening of physically-exposed portions of the first-tier sacrificial material layers and formation of a layer stack including a first-tier silicon barrier layer and a first-tier silicon nitride buffer layer according to the first embodiment of the present disclosure. FIG. 3D is a top-down view a region of the first exemplary structure after patterning the first-tier silicon nitride buffer layer according to the first embodiment of the present disclosure.

FIG. 4A is a schematic vertical cross-sectional view of the first exemplary structure after formation of a first-tier retro-stepped dielectric material portion according to the first embodiment of the present disclosure. FIG. 4B is a schematic vertical cross-sectional view of the first exemplary structure along the vertical plane B-B′ of FIG. 4A. The vertical plane A-A′ is the cut plane of the vertical cross-sectional view of FIG. 4A. FIG. 4C is a magnified view of a region of the first exemplary structure around a bottom corner of a first-tier stepped cavity in FIG. 4B.

FIG. 5A is a schematic vertical cross-sectional view of the first exemplary structure after formation of various first-tier openings and various first-tier sacrificial opening fill structures according to the first embodiment of the present disclosure. FIG. 5B is a schematic vertical cross-sectional view of the first exemplary structure along the vertical plane B-B′ of FIG. 5A. The vertical plane A-A′ is the cut plane of the vertical cross-sectional view of FIG. 5A.

FIG. 6A is a schematic vertical cross-sectional view of the first exemplary structure after formation of a vertically alternating sequence of second-tier continuous insulating layers and second-tier continuous sacrificial material layers, a second-tier stepped cavity, a layer stack including a second-tier silicon oxide buffer layer and a second-tier silicon nitride buffer layer, and a second-tier retro-stepped dielectric material portion according to the first embodiment of the present disclosure. FIG. 6B is a schematic vertical cross-sectional view of the first exemplary structure along the vertical plane B-B′ of FIG. 6A. The vertical plane A-A′ is the cut plane of the vertical cross-sectional view of FIG. 6A. FIG. 6C is a see-through top-down view a region of the first exemplary structure of FIGS. 6A and 6B in which the second-tier retro-stepped dielectric material portion is omitted from the view to illustrate the lateral extent of the second-tier silicon nitride buffer layer according to the first embodiment of the present disclosure.

FIG. 7A is a schematic vertical cross-sectional view of the first exemplary structure after formation of various second-tier openings and various second-tier sacrificial opening fill structures according to the first embodiment of the present disclosure. FIG. 7B is a schematic vertical cross-sectional view of the first exemplary structure along the vertical plane B-B′ of FIG. 7A. The vertical plane A-A′ is the cut plane of the vertical cross-sectional view of FIG. 7A.

FIG. 8A is a schematic vertical cross-sectional view of the first exemplary structure after formation of a vertically alternating sequence of third-tier continuous insulating layers and third-tier continuous sacrificial material layers, a third-tier stepped cavity, a layer stack including a third-tier silicon oxide buffer layer and a third-tier silicon nitride buffer layer, and a third-tier retro-stepped dielectric material portion according to the first embodiment of the present disclosure. FIG. 8B is a schematic vertical cross-sectional view of the first exemplary structure along the vertical plane B-B′ of FIG. 8A. The vertical plane A-A′ is the cut plane of the vertical cross-sectional view of FIG. 8A.

FIG. 9A is a schematic vertical cross-sectional view of the first exemplary structure after formation of various third-tier openings and various third-tier sacrificial opening fill structures according to the first embodiment of the present disclosure. FIG. 9B is a schematic vertical cross-sectional view of the first exemplary structure along the vertical plane B-B′ of FIG. 9A. The vertical plane A-A′ is the cut plane of the vertical cross-sectional view of FIG. 9A.

FIG. 10A is a schematic vertical cross-sectional view of the first exemplary structure after replacement sacrificial support opening fill structures with support pillar structures according to the first embodiment of the present disclosure. FIG. 10B is a schematic vertical cross-sectional view of the first exemplary structure along the vertical plane B-B′ of FIG. 10A. The vertical plane A-A′ is the cut plane of the vertical cross-sectional view of FIG. 10A.

FIG. 11A is a schematic vertical cross-sectional view of the first exemplary structure after formation of contact via cavities according to the first embodiment of the present disclosure. FIG. 11B is a schematic vertical cross-sectional view of the first exemplary structure along the vertical plane B-B′ of FIG. 11A. The vertical plane A-A′ is the cut plane of the vertical cross-sectional view of FIG. 11A. FIG. 11C is a magnified view of a region of the first exemplary structure around a portion of a contact via cavity adjacent to a first-tier silicon nitride buffer layer in FIG. 11B.

FIGS. 12A-12J are sequential vertical cross-sectional views of a bottom corner of region of the first exemplary structure around a portion of a contact via cavity adjacent to a first-tier silicon nitride buffer layer during formation of a finned support assembly and a sacrificial contact via structure according to the first embodiment of the present disclosure.

FIG. 13A is a schematic vertical cross-sectional view of the first exemplary structure after formation of stacks of a finned support assembly and a sacrificial contact via structure according to the first embodiment of the present disclosure. FIG. 13B is a schematic vertical cross-sectional view of the first exemplary structure along the vertical plane B-B′ of FIG. 13A. The vertical plane A-A′ is the cut plane of the vertical cross-sectional view of FIG. 13A.

FIG. 14 is a schematic vertical cross-sectional view of the first exemplary structure after formation of memory openings according to the first embodiment of the present disclosure.

FIGS. 15A-15F illustrate sequential vertical cross-sectional views of a memory opening during formation of a memory opening fill structure according to the first embodiment of the present disclosure.

FIG. 16A is a schematic vertical cross-sectional view of the first exemplary structure after formation of memory opening fill structures according to the first embodiment of the present disclosure. FIG. 16B is a schematic vertical cross-sectional view of the first exemplary structure along the vertical plane B-B′ of FIG. 16A. The vertical plane A-A′ is the cut plane of the vertical cross-sectional view of FIG. 16A.

FIG. 17A is a schematic vertical cross-sectional view of the first exemplary structure after formation of a contact-level dielectric layer and lateral isolation trenches according to the first embodiment of the present disclosure. FIG. 17B is a schematic vertical cross-sectional view of the first exemplary structure along the vertical plane B-B′ of FIG. 17A. The vertical plane A-A′ is the cut plane of the vertical cross-sectional view of FIG. 17A.

FIG. 18A is a schematic vertical cross-sectional view of the first exemplary structure after formation of laterally-extending cavities according to the first embodiment of the present disclosure. FIG. 18B is a schematic vertical cross-sectional view of the first exemplary structure along the vertical plane B-B′ of FIG. 18A. The vertical plane A-A′ is the cut plane of the vertical cross-sectional view of FIG. 18A. FIG. 18C is a magnified view of a region of the first exemplary structure around an interface between a finned support assembly and a sacrificial contact via structure in FIG. 18B.

FIG. 19A is a schematic vertical cross-sectional view of the first exemplary structure after formation of electrically conductive layers according to the first embodiment of the present disclosure. FIG. 19B is a schematic vertical cross-sectional view of the first exemplary structure along the vertical plane B-B′ of FIG. 19A. The vertical plane A-A′ is the cut plane of the vertical cross-sectional view of FIG. 19A. FIG. 19C is a magnified view of a region of the first exemplary structure around an interface between a finned support assembly and a sacrificial contact via structure in FIG. 19B.

FIG. 20A is a schematic vertical cross-sectional view of the first exemplary structure after formation of lateral isolation trench fill structures and connection via cavities according to the first embodiment of the present disclosure. FIG. 20B is a schematic vertical cross-sectional view of the first exemplary structure along the vertical plane B-B′ of FIG. 20A. The vertical plane A-A′ is the cut plane of the vertical cross-sectional view of FIG. 20A.

FIG. 21A is a schematic vertical cross-sectional view of the first exemplary structure after removal of the sacrificial contact via structures according to the first embodiment of the present disclosure. FIG. 21B is a schematic vertical cross-sectional view of the first exemplary structure along the vertical plane B-B′ of FIG. 21A. The vertical plane A-A′ is the cut plane of the vertical cross-sectional view of FIG. 21A. FIG. 21C is a magnified view of a region of the first exemplary structure around an upper portion of a finned support assembly in FIG. 21B.

Referring to FIG. 22 is a magnified view of a region of the first exemplary structure around an interface between a finned support assembly and a contact via cavity after removing proximal portions of the outer blocking dielectric layers around the contact via cavity according to the first embodiment of the present disclosure.

FIG. 23A is a schematic vertical cross-sectional view of the first exemplary structure after formation of layer contact via structures according to the first embodiment of the present disclosure. FIG. 23B is a schematic vertical cross-sectional view of the first exemplary structure along the vertical plane B-B′ of FIG. 23A. The vertical plane A-A′ is the cut plane of the vertical cross-sectional view of FIG. 23A. FIG. 23C is a magnified view of a region of the first exemplary structure around an interface between a finned support assembly and a sacrificial contact via structure in FIG. 23B.

FIGS. 24A-24H are sequential vertical cross-sectional views of a region of a first alternative embodiment of the first exemplary structure during formation of a combination of a finned support assembly and a layer contact via structure according to the first embodiment of the present disclosure.

FIGS. 25A-25F are sequential vertical cross-sectional views of a region of a second alternative embodiment of the first exemplary structure during formation of a combination of a finned support assembly and a layer contact via structure according to the first embodiment of the present disclosure.

FIG. 26 is a vertical cross-sectional view of the first exemplary structure after formation of memory-side dielectric material layers, memory-side metal interconnect structures, and memory-side bonding pads according to the first embodiment of the present disclosure.

FIG. 27 is a vertical cross-sectional view of the first exemplary structure after bonding a logic die to a memory die according to the first embodiment of the present disclosure.

FIG. 28 is a vertical cross-sectional view of the first exemplary structure after detaching a carrier substrate and formation of source structures, backside dielectric material layers, and backside bonding pads according to the first embodiment of the present disclosure.

FIG. 29 is a magnified vertical cross-sectional view of a region around a bottom corner of a first-tier retro-stepped dielectric material portion in a second exemplary structure according to a second embodiment of the present disclosure.

FIGS. 30A-30O are sequential vertical cross-sectional views of a region of a first configuration of the second exemplary structure during formation of a combination of a finned support assembly and a layer contact via structure according to the second embodiment of the present disclosure.

FIGS. 31A-31M are sequential vertical cross-sectional views of a region of a second configuration of the second exemplary structure during formation of a combination of a finned support assembly and a layer contact via structure according to the second embodiment of the present disclosure.

FIGS. 32A-32M are sequential vertical cross-sectional views of a region of a third configuration of the second exemplary structure during formation of a combination of a finned support assembly and a layer contact via structure according to the second embodiment of the present disclosure.

FIGS. 33A-33M are sequential vertical cross-sectional views of a region of a first configuration of a third exemplary structure during formation of a combination of a finned support assembly and a layer contact via structure according to a third embodiment of the present disclosure.

FIGS. 34A-34C are sequential vertical cross-sectional views of a region of a second configuration of the third exemplary structure during formation of a combination of a finned support assembly and a layer contact via structure according to the third embodiment of the present disclosure.

### DETAILED DESCRIPTION

As discussed above, an embodiments of the present disclosure are directed to a three-dimensional memory device including through-stack contact assemblies and methods for forming the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements. The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconducting material” refers to a material having electrical conductivity in the range from 1.0×10⁵ S/m to 1.0×10⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

A monolithic three-dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and vertically stacking the memory levels, as described in U.S. Pat. No. 5,915,167 titled “Three-dimensional Structure Memory.” The substrates may be thinned or removed from the memory levels before bonding, but as the memory levels are initially formed over separate substrates, such memories are not true monolithic three-dimensional memory arrays. The substrate may include integrated circuits fabricated thereon, such as driver circuits for a memory device.

The various three-dimensional memory devices of the present disclosure include a monolithic three-dimensional NAND string memory device, and may be fabricated using the various embodiments described herein. The monolithic three-dimensional NAND string is located in a monolithic, three-dimensional array of NAND strings located over the substrate. At least one memory cell in the first device level of the three-dimensional array of NAND strings is located over another memory cell in the second device level of the three-dimensional array of NAND strings.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

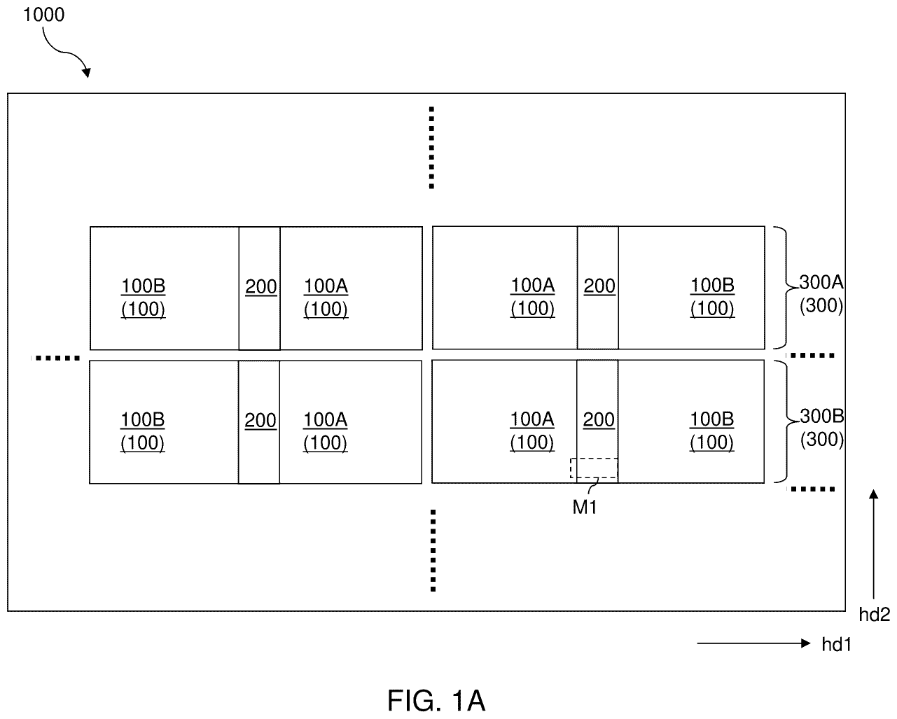

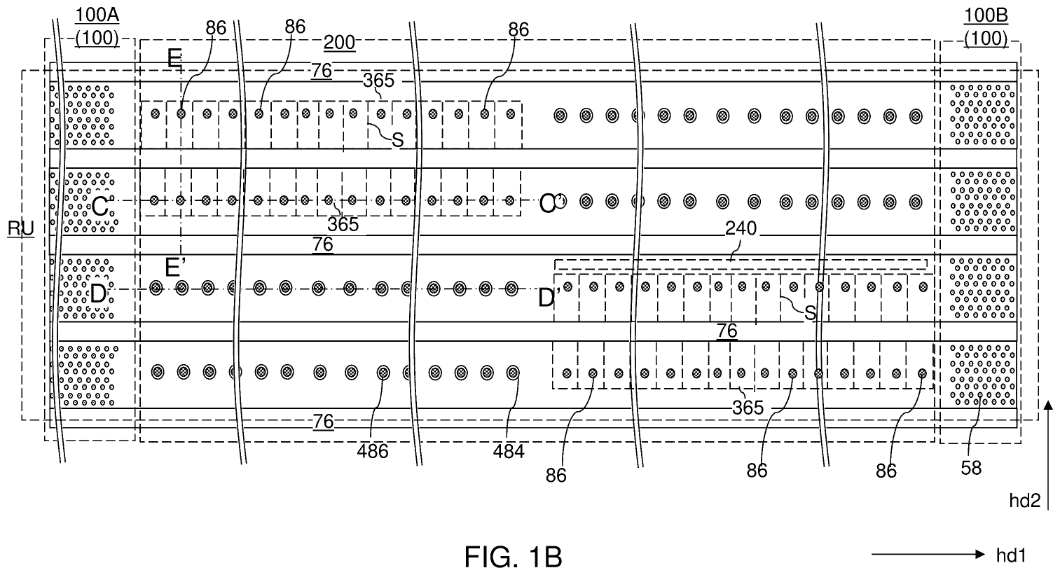

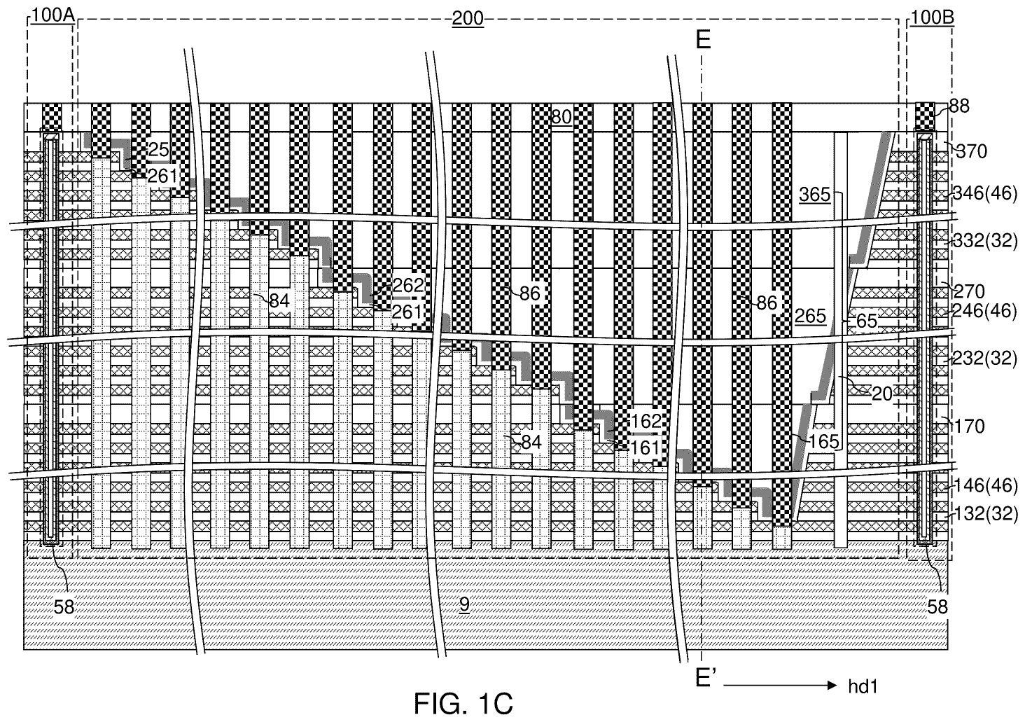

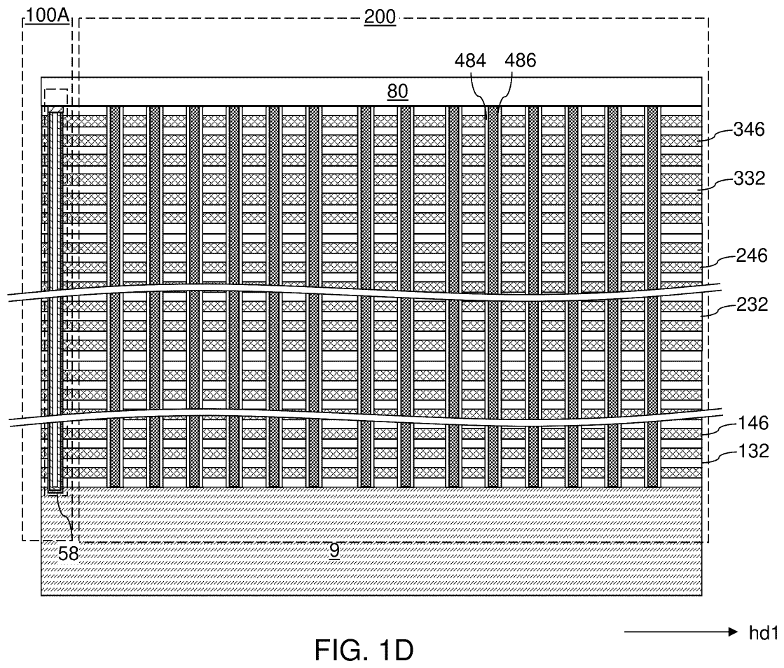

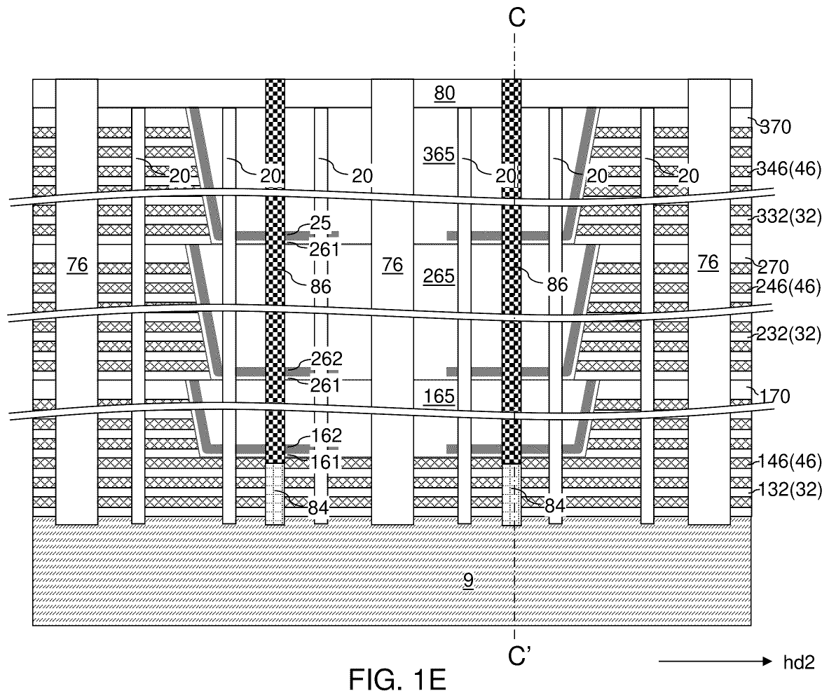

Referring to FIGS. 1A-1E, an exemplary semiconductor die 1000 according to an embodiment of the present disclosure is illustrated. The exemplary semiconductor die 1000 comprises a substrate 9, which may be a semiconductor substrate and/or a carrier substrate. For example, the substrate 9 may comprise a commercially available silicon wafer. If the substrate 9 comprises a carrier substrate, the substrate 9 may comprise any material that may be removed selective the materials of overlying materials which are subsequently formed. The exemplary semiconductor die 1000 is illustrated after a set of processing steps that forms various contact via structures (86, 88), which include layer contact via structures 86 and drain contact via structures 88. The exemplary semiconductor die 1000 illustrates an exemplary layout and configuration of the various device structures of the present disclosure that are subsequently described. However, the layout and the configuration of the exemplary semiconductor die 1000 in FIGS. 1A-1E are only illustrative, and do not limit the general layout and/or configurations of embodiments of the present disclosure.

The exemplary semiconductor die 1000 includes multiple three-dimensional memory array regions and multiple inter-array regions. The exemplary semiconductor die 1000 can include multiple planes 300 (e.g., 300A, 300B), each of which includes two memory array regions 100, such as a first memory array region 100A and a second memory array region 100B that are laterally spaced apart by a respective inter-array region 200. Generally, a semiconductor die 1000 may include a single plane 300 or multiple planes. The total number of planes in the semiconductor die 1000 may be selected based on performance requirements on the semiconductor die 1000. A pair of memory array regions 100 in a plane 300 may be laterally spaced apart along a first horizontal direction hd1 (which may be the word line direction). A second horizontal direction hd2 (which may be the bit line direction) can be perpendicular to the first horizontal direction hd1.

The size of the first memory array region 100A may be the same as, or may differ from, the size of the second memory array region 100B within a given plane. In one embodiment, each of the first memory array region 100A and the second memory array region 100B may have a respective rectangular area having a same width along the second horizontal direction hd2. In one embodiment, the inter-array region 200 within each plane 300 can be located off-center of the respective plane 300 along the first horizontal direction hd1 (i.e., the inter-array region 200 is located closer to one end than to another end of the respective plane 300). For example, the inter-array region 200 in the left plane 300A may be shifted toward the left edge of the die 1000, while the inter-array region 200 in the right plane 300B may be shifted toward the right edge of the die 1000. Alternatively, the inter-array region 200 within each plane 300 can be centered in the respective plane 300 along the first horizontal direction hd1 (i.e., the inter-array region 200 is located the same distance from both ends of the respective plane 300).

Each memory array region 100 includes first-tier alternating stacks of first-tier insulating layers 132 and first-tier electrically conductive layers 146 (which function as first word lines), optional second-tier alternating stacks of second-tier insulating layers 232 and second-tier electrically conductive layers 246 (which function as second word lines), and optional third-tier alternating stacks of third-tier insulating layers 332 and third-tier electrically conductive layers 346 (which function as third word lines). Each second-tier alternating stack (232, 246) overlies a respective first-tier alternating stack (132, 146), and each third-tier alternating stack (332, 346), if present, overlies a respective second-tier alternating stack (232, 246). Each combination of a first-tier alternating stack (132, 146), an overlying second-tier alternating stack (232, 246), and an optional overlying third-tier alternating stack (332, 346) may be laterally spaced apart from neighboring combinations of a respective first-tier alternating stack (132, 146), an overlying respective second-tier alternating stack (232, 246), and an overlying optional third-tier alternating stack (332, 346) by lateral isolation trench fill structures 76 that laterally extend along the first horizontal direction hd1 (which may be a word line direction). The first-tier insulating layers 132, the second-tier insulating layers 232, and the third-tier insulating layers 332 are collectively referred to as insulating layers 32. The first-tier electrically conductive layers 146, the second-tier electrically conductive layers 246, and the third-tier electrically conductive layers 346 are collectively referred to as electrically conductive layers 46.

As used herein, a “first-tier level” refers to the tier level that is most proximal to a substrate, a “second-tier level” refers to the tier level that is most proximal to the substrate among tier levels that overlie the first-tier level, and a “third-tier level” refers to the tier level that is most proximal to the substrate among tier levels that overlie the second-tier level, etc. A “first-tier” element refers to an element that is located within the first-tier level; a “second-tier” element refers to an element that is located within the second-tier level; a “third-tier” element refers to an element that is located within the second-tier level; etc. Individual tier levels within a structure including multiple tier levels may be labeled as a first tier level, a second tier level, a third tier level, etc. In this case, the first tier level may be any of the multiple tier levels, the second tier level may be a tier level that is different from the first tier level, etc.

A first-tier alternating stack of first-tier insulating layers 132 and first-tier electrically conductive layers 146 is located over the substrate 9 between each neighboring pair of lateral isolation trench fill structures 76. A first-tier retro-stepped dielectric material portion 165 overlies, and contacts, first stepped surfaces of the first-tier alternating stack (132, 146). A second-tier alternating stack of second-tier insulating layers 232 and second-tier electrically conductive layers 246 overlies the first-tier alternating stack (132, 146), and overlies a horizontal plane including a planar top surface of the first-tier retro-stepped dielectric material portion 165 between each neighboring pair of lateral isolation trench fill structures 76. A second-tier retro-stepped dielectric material portion 265 overlies, and contacts, second stepped surfaces of the second-tier alternating stack (232, 246). A third-tier alternating stack of third-tier insulating layers 332 and third-tier electrically conductive layers 346, if present, overlies the second-tier alternating stack (232, 246), and overlies a horizontal plane including a planar top surface of the second-tier retro-stepped dielectric material portion 265 between each neighboring pair of lateral isolation trench fill structures 76. A third-tier retro-stepped dielectric material portion 365 overlies, and contacts, third stepped surfaces of the third-tier alternating stack (332, 346), if present. Vertical steps S of the first stepped surfaces and the second stepped surfaces laterally extend along the second horizontal direction hd2 (which may be a bit line direction). The first-tier retro-stepped dielectric material portion 165, the second-tier retro-stepped dielectric material portion 265, and the third-tier retro-stepped dielectric material portion 365 are collectively referred to as retro-stepped dielectric material portions 65.

Memory opening fill structures 58 can be located within each memory array region 100 (which includes a first memory array region 100A and a second memory array region 100B) between each neighboring pair of lateral isolation trench fill structures 76. The memory opening fill structures 58 can be located within memory openings that vertically extend through each layer within the first-tier alternating stack (132, 146), the second-tier alternating stack (232, 246), and the optional third-tier alternating stack (332, 346), if present, that are located between a respective neighboring pair of lateral isolation trench fill structures 76.

In one embodiment, each of the memory opening fill structures 58 comprises a vertical stack of memory elements (e.g., portions of a memory film or vertically separated, discrete memory elements) located at levels of the electrically conductive layers 46 and a vertical semiconductor channel 60 that is electrically connected to a respective overlying metal interconnect structure (such as a bit line). In one embodiment, the inter-array region 200 is free of any memory stack structure that is electrically contacted by any metal interconnect structure (such as a bit line).

Each memory opening fill structure 58 includes a respective memory stack structure, which includes a respective memory film and a respective vertical semiconductor channel. The memory openings and the memory opening fill structures 58 are formed in region in which each layer of a first-tier alternating stack and each layer of the second-tier alternating stack are present. For each area within which a continuous combination of a first-tier alternating stack (132, 146), a second-tier alternating stack (232, 246), and an optional third-tier alternating stack (332, 346) continuously laterally extends, first memory stack structures can be located within a respective first memory array region 100A and second memory stack structures can be located within a respective second memory array region 100B. The second memory array region 100B can be connected to the first memory array region 100A through a respective inter-array region 200, in which a first-tier retro-stepped dielectric material portion 165, a second-tier retro-stepped dielectric material portion 265, and an optional third-tier retro-stepped dielectric material portion 365 are located.

A first-tier retro-stepped dielectric material portion 165 can be located between each neighboring pair of lateral isolation trench fill structures 76. Each first-tier retro-stepped dielectric material portion 165 overlies first stepped surfaces of a respective first-tier alternating stack (132, 146). Each first-tier retro-stepped dielectric material portion 165 can have a sidewall that laterally extends along the first horizontal direction hd1 and contacts a respective lateral isolation trench fill structure 76. The first stepped surfaces comprise vertical steps of the first-tier alternating stack (132, 146) that are laterally spaced apart along the first horizontal direction hd1 and vertically offset from each other.

A second-tier retro-stepped dielectric material portion 265 can be located between each neighboring pair of lateral isolation trench fill structures 76. Each second-tier retro-stepped dielectric material portion 265 overlies second stepped surfaces of a respective second-tier alternating stack (232, 246). Each second-tier retro-stepped dielectric material portion 265 can have a sidewall that laterally extends along the second horizontal direction hd1 and contacts a respective lateral isolation trench fill structure 76. The second stepped surfaces comprise vertical steps of the second-tier alternating stack (232, 246) that are laterally spaced apart along the first horizontal direction hd1 and vertically offset from each other. In one embodiment, each second-tier retro-stepped dielectric material portion 265 overlies, and contacts, a respective one of the first-tier retro-stepped dielectric material portions 165.

A third-tier retro-stepped dielectric material portion 365 can be located between each neighboring pair of lateral isolation trench fill structures 76. Each third-tier retro-stepped dielectric material portion 365 overlies third stepped surfaces of a respective third-tier alternating stack (332, 346). Each third-tier retro-stepped dielectric material portion 365 can have a sidewall that laterally extends along the second horizontal direction hd2 and contacts a respective lateral isolation trench fill structure 76. The third stepped surfaces comprise vertical steps of the third-tier alternating stack (332, 346) that are laterally spaced apart along the second horizontal direction hd2 and vertically offset from each other. In one embodiment, each third-tier retro-stepped dielectric material portion 365 overlies, and contacts, a respective one of the second-tier retro-stepped dielectric material portions 265.

Lateral isolation trenches can laterally extend along the first horizontal direction hd1. Each lateral isolation trench can be filled with a lateral isolation trench fill structure 76, which may include a combination of a backside contact via structure and an insulating spacer that laterally surround the backside contact via structure. Alternatively, each lateral isolation trench fill structure 76 may consist of an insulating fill structure. Each vertical stack of a first-tier alternating stack (132, 146), a second-tier alternating stack (232, 246), and an optional third-tier alternating stack (332, 346) can be located between a neighboring pair of lateral isolation trench fill structure 76.

For each vertical stack of a first-tier alternating stack (132, 146), a second-tier alternating stack (232, 246), and an optional third-tier alternating stack (332, 346), a respective first lateral isolation trench fill structure 761 laterally extends along the first horizontal direction hd1 (e.g., word line direction), and may, or may not, contact first sidewalls of the first-tier alternating stack (132, 146), first sidewalls of the second-tier alternating stack (232, 246), and first sidewalls of the third-tier alternating stack (332, 346), if present; and a second lateral isolation trench fill structure 762 laterally extends along the first horizontal direction hd1, and may, or may not, second sidewalls of the first-tier alternating stack (132, 146), second sidewalls of the second-tier alternating stack (232, 246), and second sidewalls of the third-tier alternating stack (332, 346), if present, as illustrated in FIG. 1E. The first lateral isolation trench fill structure 761 and the second lateral isolation trench fill structure 762 are neighboring pairs of lateral isolation trench fill structures 76. Generally, at least one of the first lateral isolation trench fill structure 761 and the second lateral isolation trench fill structure 762 is in direct contact with each layer within the first-tier alternating stack (132, 146); at least one of the first lateral isolation trench fill structure 761 and the second lateral isolation trench fill structure 762 is in direct contact with each layer within the second-tier alternating stack (232, 246); and at least one of the first lateral isolation trench fill structure 761 and the second lateral isolation trench fill structure 762 is in direct contact with each layer within the third-tier alternating stack (332, 346) in case the third-tier alternating stack (332, 346) is present.

According to various embodiments, various configurations of the exemplary structure are provided in which one or both of the first lateral isolation trench fill structure 761 and the second lateral isolation trench fill structure 762 is/are in direct contact with each layer within the first-tier alternating stack (132, 146). Furthermore, one or both of the first lateral isolation trench fill structure 761 and the second lateral isolation trench fill structure 762 is/are in direct contact with each layer within the second-tier alternating stack (232, 246). Furthermore, one or both of the first lateral isolation trench fill structure 761 and the second lateral isolation trench fill structure 762 is/are in direct contact with each layer within the third-tier alternating stack (332, 346) (if present). While FIGS. 1A-1E illustrate a configuration in which a first lateral isolation trench fill structure 761 is not in direct contact with the first-tier alternating stack (132, 146), the second-tier alternating stack (232, 246), or the third-tier alternating stack (332, 346), and a second lateral isolation trench fill structure 762 is in direct contact with each layer within the first-tier alternating stack (132, 146), with each layer within the second-tier alternating stack (232, 246), and with each layer within the third-tier alternating stack (332, 346), embodiments are expressly contemplated herein in which different combinations in which the first lateral isolation trench fill structure 761 and the second lateral isolation trench fill structure 762 contact or do not contact each of the first-tier alternating stack (132, 146), the second-tier alternating stack (232, 246), and the third-tier alternating stack (332, 346).

In one embodiment, first contact via structures 86A vertically extend through a second-tier retro-stepped dielectric material portion 265 and a first-tier retro-stepped dielectric material portion 165, and contact a respective one of the first-tier electrically conductive layers 146. Second contact via structures 86B vertically extend through a second-tier retro-stepped dielectric material portion 265 and contact a respective one of the second-tier electrically conductive layers 246.

The inter-array region 200 includes strips of the first-tier insulating layers 132, the first-tier electrically conductive layers 146, the second-tier insulating layers 232, the second-tier electrically conductive layers 246, the third-tier insulating layers 332, and the third-tier electrically conductive layers 346 located between each laterally neighboring pair of lateral isolation trench fill structures 76. Such strips are located in a respective strip-shaped connection regions 240 (i.e., bridge regions) of the inter-array regions 200, which are located adjacent to a respective first-tier retro-stepped dielectric material portion 165, a respective second-tier retro-stepped dielectric material portion 265, or a respective third-tier retro-stepped dielectric material portions 365. The strips have a narrower width along the second horizontal direction hd2 than portions of the alternating stacks (132, 146, 232, 246, 332, 346) located in the memory array regions 100, and portions of the strips located in the remaining portions of the inter-array regions 200 outside of the respective strip-shaped connection regions 240.

For each vertical stack of a first-tier alternating stack (132, 146), a second-tier alternating stack (232, 246), and an optional third-tier alternating stack (332, 346), first memory opening fill structures 58 can be located within a first memory array region 100A in which each layer of the first-tier alternating stack (132, 1446), the second-tier alternating stack (232, 246), and the optional third-tier alternating stack (332, 346) is present. Further, second memory opening fill structures 58 can be located within a second memory array region 100B that is laterally offset along the first horizontal direction hd1 from the first memory array region 100A by the first-tier retro-stepped dielectric material portion 165, the second-tier retro-stepped dielectric material portion 265, and the optional third-tier retro-stepped dielectric material portion 365. Each layer of the first-tier alternating stack (132, 146), the second-tier alternating stack (232, 246), and the optional third-tier alternating stack (332, 346) is present within the second memory array region 100B. Each of the electrically conductive layers 46 within the vertical stack may continuously extend from the first memory array region 100A to the second memory array region 100B through a strip-shaped connection region 240 (which is also referred to as a bridge region). Each strip-shaped connection region 240 is located within an inter-array region 200, and may be located between the lateral isolation trench fill structure 76 and the first-tier retro-stepped dielectric material portion 165 at the level of the first-tier alternating stack (132, 146), or between a lateral isolation trench fill structures 76 and the second-tier retro-stepped dielectric material portion 265 at the level of the second-tier alternating stack (232, 246), or between a lateral isolation trench fill structures 76 and the third-tier retro-stepped dielectric material portion 365 at the level of the third-tier alternating stack (332, 346).

Staircases including first stepped surfaces of a first-tier alternating stack (132, 146), optionally second stepped surfaces of a second-tier alternating stack (232, 246), and optionally third stepped surfaces of a third-tier alternating stack (332, 346) can ascend (i.e., rise) from the substrate along the first horizontal direction hd1, or along the opposite direction of the first horizontal direction hd1. Each region including the staircases is herein referred to as a staircase region. In one embodiment, the direction of rise of the staircases can change for every other pair of vertical stacks of a respective first-tier alternating stack (132, 146), a respective second-tier alternating stack (232, 246), and a respective third-tier alternating stack (332, 346). In other words, the direction of rise is staggered in adjacent alternating stacks that are separated along the second horizontal direction. For example, upon sequentially numbering each vertical stack of a respective first-tier alternating stack (132, 146), a respective second-tier alternating stack (232, 246), and a respective third-tier alternating stack (332, 346) with positive integers N starting with 1, each (4N+1)-th combination and each (4N+2)-th vertical stack {(132, 146), (232, 246), (332, 246)} can have stairs that rise along the first horizontal direction hd1, and each (4N+3)-th combination and each (4N+4)-th vertical stack {(132, 146), (232, 246), (332, 246)} can have stairs that rise along the opposite direction of the first horizontal direction hd1. In this embodiment, a vertical distance between the first stepped surfaces and the substrate increases along the first horizontal direction hd1, a vertical distance between the second stepped surfaces and the substrate increases along the first horizontal direction hd1, a vertical distance between the additional first stepped surfaces and the substrate decreases along the first horizontal direction hd1, and a vertical distance between the additional second stepped surfaces and the substrate decreases along the first horizontal direction hd1.

In an alternative embodiment, the direction of rise of the staircases does not change for every other pair of combinations of a respective first-tier alternating stack (132, 146), a respective second-tier alternating stack (232, 246), and a respective third-tier alternating stack (332, 246). In other words, the direction of rise is the same (i.e., non-staggered) in adjacent alternating stacks that are separated along the second horizontal direction.

Laterally-isolated vertical interconnection structures (484, 486) can be formed through the inter-array region 200. Each laterally-isolated vertical interconnection structure (484, 486) can include a through-memory-level conductive via structure 486 and a tubular insulating spacer 484 that laterally surrounds the conductive via structure 486. The laterally-isolated vertical interconnection structures (484, 486) vertically extend through the strip portions of the first-tier alternating stack (132, 146), the second-tier alternating stack (232, 246), and the third-tier alternating stack (332, 346), and can contact the substrate 9.

Drain contact via structures 88 can contact an upper portion of a respective memory opening fill structure 58 (such as a drain region within the respective memory opening fill structure 58). Bit lines (not illustrated) can laterally extend along the second horizontal direction hd2, and can contact top surfaces of a respective subset of the drain contact via structures. Additional metal interconnect structures embedded in overlying dielectric material layers (not shown) may be employed to provide electrical connection among the various nodes of the three-dimensional memory device located in the semiconductor die 1000.

Each lateral isolation trench fill structure 76 includes an insulating material portion. In one embodiment, each insulating material portion may comprise an insulating spacer that laterally surrounds a layer contact via structure such as a backside contact via structure (not expressly shown). In another embodiment, each insulating material portion may comprise a dielectric wall structure which takes up the entire volume of the respective lateral isolation trench fill structure 76. In one embodiment, each sidewall of the first alternating stacks (132, 146) can be contacted by a sidewall of an insulating material portion of a respective one of the lateral isolation trench fill structures 76.

According to various embodiments of the present disclosure, the various retro-stepped dielectric material portions (165, 265, 365) may be formed in various configurations, and may or may not contact a neighboring lateral isolation trench fill structure 76. In one embodiment, upon sequentially numbering the lateral isolation trench fill structures 76 along the second horizontal direction (e.g., bit line direction) hd2 with positive integers, each odd-numbered lateral isolation trench fill structure 76 may contact a respective pair of first-tier retro-stepped dielectric material potions 165, and each even-numbered lateral isolation trench fill structure 76 does not contact any of the first-tier retro-stepped dielectric material portions 165. Alternatively, the lateral isolation trench fill structures 76 may not contact any of the first-tier retro-stepped dielectric material portions 165, and the first-tier retro-stepped dielectric material portions 165 may be laterally spaced from each neighboring pair of lateral isolation trench fill structures 76. For each configuration for the first-tier retro-stepped dielectric material portions 165, each odd-numbered lateral isolation trench fill structure 76 may contacts a respective pair of second-tier retro-stepped dielectric material potions 265, and each even-numbered lateral isolation trench fill structure 76 does not contact any of the second-tier retro-stepped dielectric material portions 265. Alternatively, each even-numbered lateral isolation trench fill structure 76 may contact a respective pair of second-tier retro-stepped dielectric material potions 265, and each odd-numbered lateral isolation trench fill structure 76 does not contact any of the second-tier retro-stepped dielectric material portions 265. Yet alternatively, the lateral isolation trench fill structures 76 may not contact any of the second-tier retro-stepped dielectric material portions 265, and the second-tier retro-stepped dielectric material portions 265 may be laterally spaced from each neighboring pair of lateral isolation trench fill structures 76. For each configuration for the first-tier retro-stepped dielectric material portions 165 and for each configuration for the second-tier retro-stepped dielectric material portions 265, each odd-numbered lateral isolation trench fill structure 76 may contact a respective pair of third-tier retro-stepped dielectric material potions 365, and each even-numbered lateral isolation trench fill structure 76 does not contact any of the third-tier retro-stepped dielectric material portions 365. Alternatively, each even-numbered lateral isolation trench fill structure 76 may contact a respective pair of third-tier retro-stepped dielectric material potions 365, and each odd-numbered lateral isolation trench fill structure 76 does not contact any of the third-tier retro-stepped dielectric material portions 365. Yet alternatively, the lateral isolation trench fill structures 76 may not contact any of the third-tier retro-stepped dielectric material portions 365, and the third-tier retro-stepped dielectric material portions 365 may be laterally spaced from each neighboring pair of lateral isolation trench fill structures 76.

In one embodiment, each plane 300 within the exemplary semiconductor die 1000 includes a three-dimensional memory device, which includes alternating stacks of insulating layers 32 and electrically conductive layers 46. Each of the alternating stacks {(132, 146), (232, 246), (332, 346)} laterally extends along a first horizontal direction hd1 through a first memory array region 100A and a second memory array region 100B that are laterally spaced apart by an inter-array region 200. Each of the alternating stacks {(132, 146), (232, 246), (332, 346)} includes a set of stepped surfaces (i.e., a staircase) in the inter-array region 200. Each plane 300 within the exemplary semiconductor die 1000 includes retro-stepped dielectric material portions (165, 265, 365) overlying a respective set of stepped surfaces of the alternating stacks {(132, 146), (232, 246), (332, 346)}. Each plane 300 within the exemplary semiconductor die 1000 includes clusters of memory stack structures located within memory opening fill structures 58. Each of the memory stack structures vertically extends through a respective one of the alternating stacks {(132, 146), (232, 246), (332, 346)} and is located within the first memory array region 100A or the second memory array region 100B. Each memory stack structure can include a respective vertical semiconductor channel and a vertical stack of memory elements (e.g., a memory film) located at levels of the electrically conductive layers 46.

The three-dimensional memory device can comprise through-stack contact assemblies (84, 86), which are also referred to contact assemblies (84, 86). Each contact assembly (84, 86) vertically extends through at least one retro-stepped dielectric material portion 65 and at least one alternating stack (32, 46) of insulating layers 32 and electrically conductive layers 46. Each contact assembly (84, 86) vertically extends at least from a horizontal plane including the topmost surface of the retro-stepped dielectric material portions 65 to a horizontal plane including the bottommost surface of the at least one alternating stack (32, 46). Each contact assembly (84, 86) comprises a vertical stack of a finned support assembly 84 and a layer contact via structure 86, which contacts an annular top surface segment of a respective one of the electrically conductive layers 46, which will be described in detail in subsequent sections.

Each of the retro-stepped dielectric material portions 65 comprises a respective stepped bottom surface. Each region of the alternating stacks (32, 46) that underlies a respective retro-stepped dielectric material portion 65 constitutes a staircase region. A strip-shaped connection region 240 including each layer within an alternating stack (32, 46) is provided adjacent to each staircase region, and is herein referred to as a bridge region. Each strip-shaped connection region 240 laterally extends along the first horizontal direction hd1, and provides electrically conductive paths between a respective portion located in the first memory array region 100A and a respective portion located in the second memory array region 100B for each electrically conductive layer 46. The strip region has a lesser width (i.e., narrower width along the second horizontal direction hd2) than the portions of the electrically conductive layer 46 located in the first memory array region 100A or in the second memory array region 100B. The portions of the electrically conductive layer 46 located in the first memory array region 100A or in the second memory array region 100B have a width along the second horizontal direction hd2 that is the same as a lateral distance between a neighboring pair of lateral isolation trench fill structures 76.

In contrast, each strip portion of the electrically conductive layer 46 in the strip-shaped connection region 240 has a width along the second horizontal direction hd2 that is the same as the difference between the lateral distance between a neighboring pair of lateral isolation trench fill structures 76 and the width of an adjoining retro-stepped dielectric material portion (165 or 265) along the second horizontal direction hd2. Each electrical connection between a layer contact via structure 86 and a most proximal portion of the second memory array region 100B includes a narrow strip portion of an electrically conductive layer 46 in the strip-shaped connection region 240, while electrical connection between the layer contact via structure 86 and a most proximal portion of the first memory array region 100A does not include any narrow strip portion of the electrically conductive layer 46 because the first memory array region 100A is not separated from the layer contact via structures 86 by the strip-shaped connection region 240.

In one embodiment, the alternating stacks {(132, 146), (232, 246), (332, 346)} are laterally spaced apart along the second horizontal direction hd2 by line trenches (such as lateral isolation trenches) that laterally extend along the first horizontal direction hd1. The line trenches are filled with lateral isolation trench fill structures 76 having dielectric surfaces (such as surfaces of insulating spacers or dielectric wall structures) that contact sidewalls of the alternating stacks {(132, 146), (232, 246), (332, 346)}. In one embodiment, upon sequentially numbering the lateral isolation trench fill structures 76 with positive integers along the second horizontal direction hd2, odd-numbered lateral isolation trench fill structures may contact a respective pair of retro-stepped dielectric material portions (165, 265, 365) (which are located on either side of a respective odd-numbered lateral isolation trench fill structure 76), and even-numbered lateral isolation trench fill structures do not contact any retro-stepped dielectric material portion (165, 265, 365), or even-numbered lateral isolation trench fill structures may contact a respective pair of retro-stepped dielectric material portions (165, 265, 365) and odd-numbered lateral isolation trench fill structures do not contact any retro-stepped dielectric material portion (165, 265, 365).

In one embodiment, strip widths of the first-tier electrically conductive layers 146 decrease with a respective vertical distance from the substrate 9. Strip widths of the second-tier electrically conductive layers 246 decrease with a respective vertical distance from the substrate 9. Strip widths of the third-tier electrically conductive layers 346 decrease with a respective vertical distance from the substrate 9. A bottommost second electrically conductive layer 246 within the second-tier alternating stack (232, 246) has a greater strip width than a topmost first electrically conductive layer 146 within the first-tier alternating stack (132, 146). A bottommost third electrically conductive layer 346 within the third-tier alternating stack (332, 346) has a greater strip width than a topmost second electrically conductive layer 246 within the second-tier alternating stack (232, 246).

According to an aspect of the present disclosure shown in FIG. 1E, a set of a first-tier retro-stepped dielectric material portion 165, a second-tier retro-stepped dielectric material portion 265, and a third-tier retro-stepped dielectric material portion 365 can be formed between a neighboring pair of lateral isolation trench fill structures 76, which are herein referred to as a first lateral isolation trench fill structure 761 and a second lateral isolation trench fill structure 762. The widths of each strip of an electrically conductive layer 46 along the second horizontal direction in the strip-shaped connection region 240 is herein referred to as a strip width or a bridge width. Generally, embedding of the retro-stepped dielectric material portions (165, 265, 365) in alternating stacks of insulating layers 32 and electrically conductive layers 46 may induce cracking due to voids formed in the retro-stepped dielectric material portions (165, 265, 365) and/or due to incline of the alternating stacks into the lateral isolation trenches due to unbalanced electrically conductive layer material filling.

In some embodiments, the various tier structures may be constructed with a mirror symmetry with respective to a vertical plane extending along the first horizontal direction through a lateral isolation trench fill structure 76 (such as a first lateral isolation trench fill structure 761). According to an aspect of the present disclosure, conformal fill of the dielectric material in retro-stepped trenches during formation of the first-tier retro-stepped dielectric material portions 165 may be facilitated by increasing the width of the retro-stepped trenches along the second horizontal direction hd2, which accompanies an increase in the first width D1 of each first-tier retro-stepped dielectric material portion 165. This reduces cracks and tilting while forming symmetric structures around each lateral isolation trench that is located between pairs of a respective stack of retro-stepped dielectric material portions (165, 265, 365).

While the illustrated configuration of the exemplary structure illustrated in FIGS. 1A-1E includes three tier levels, embodiments are expressly contemplated herein in which one tier level, two tier levels, or four or more tier levels are used in an alternative configuration.

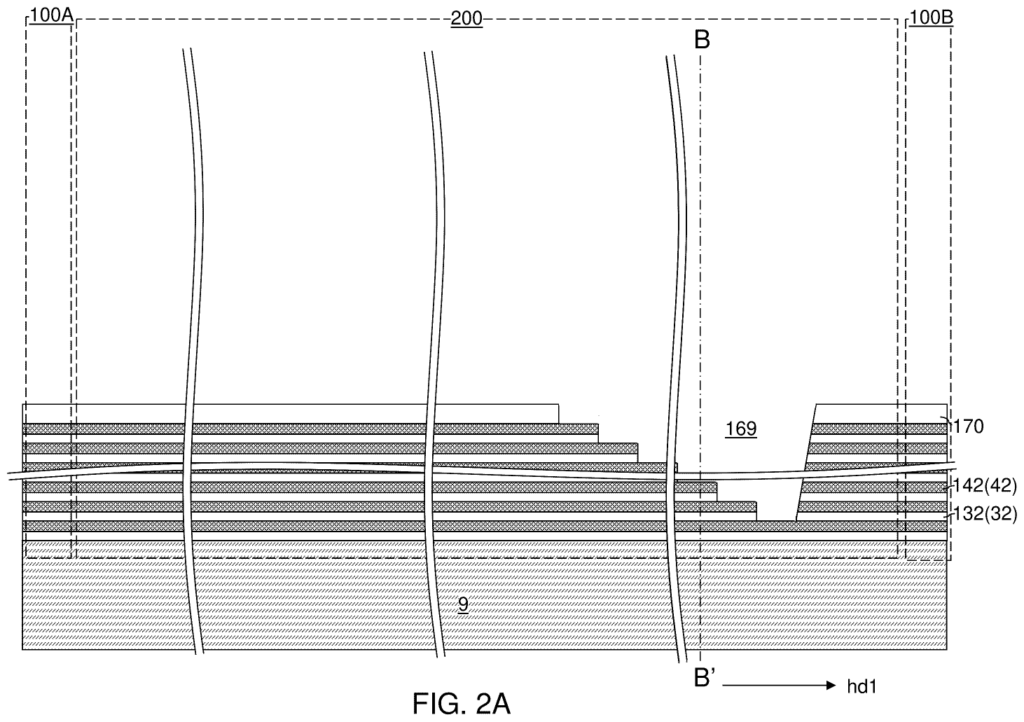

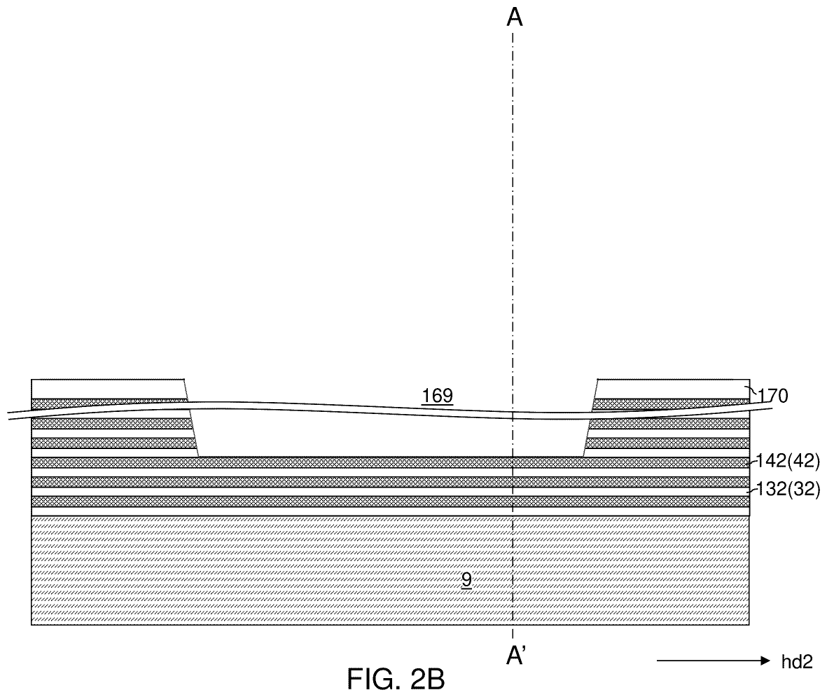

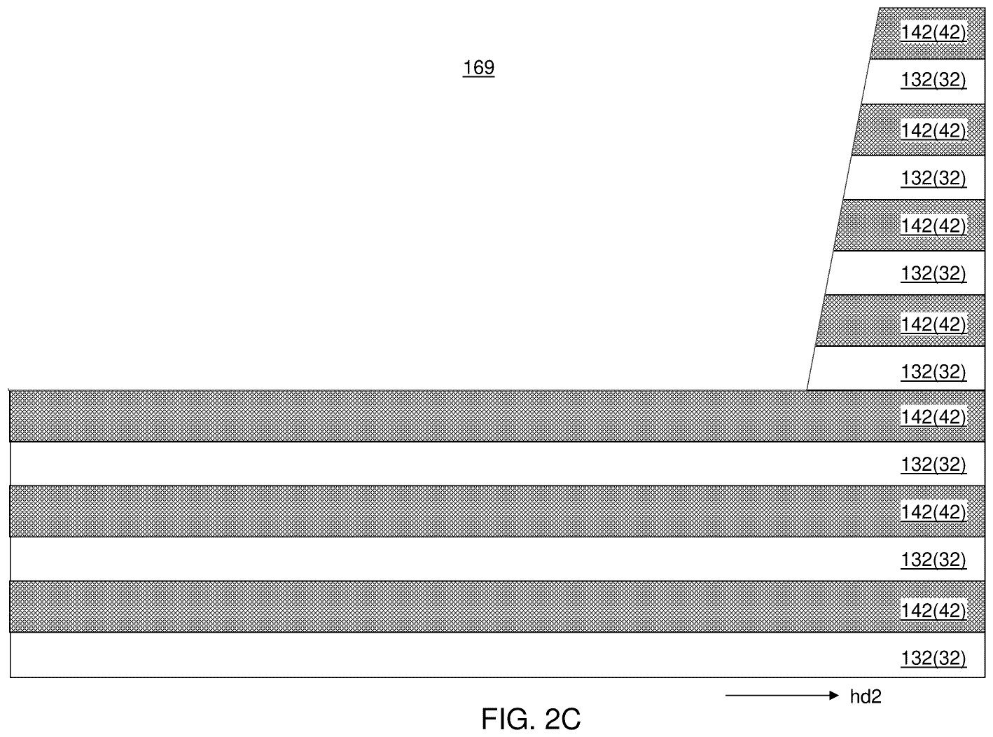

Referring to FIGS. 2A-2C, a first exemplary structure according to a first embodiment of the present disclosure is illustrated, which can be employed to form a semiconductor die such as the semiconductor die 1000 illustrated in FIGS. 1A-1E.

A first vertically alternating sequence of first-tier insulating layers 132 and first-tier sacrificial material layers 142 can be formed over a substrate 9. As used herein, a vertically alternating sequence refers to a sequence of multiple instances of a first element and multiple instances of a second element that is arranged such that an instance of a second element is located between each vertically neighboring pair of instances of the first element, and an instance of a first element is located between each vertically neighboring pair of instances of the second element.

The first-tier insulating layers 132 can be composed of the first material, and the first-tier sacrificial material layers 142 can be composed of the second material, which is different from the first material. Each of the first-tier insulating layers 132 is an insulating layer that continuously extends over the entire area of the substrate 8, and may have a uniform thickness throughout. Each of the first-tier sacrificial material layers 142 includes is a sacrificial material layer that includes a dielectric material and continuously extends over the entire area of the substrate 8, and may have a uniform thickness throughout. Insulating materials that may be used for the first-tier insulating layers 132 include, but are not limited to silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the first-tier insulating layers 132 may be silicon oxide.

The second material of the first-tier sacrificial material layers 142 is a dielectric material, which is a sacrificial material that may be removed selective to the first material of the first-tier insulating layers 132. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The thickness of each first-tier insulating layer 132 may be in a range from 12 nm to 50 nm, such as from 15 nm to 30 nm, although lesser and greater thicknesses may also be employed. The thickness of each first-tier sacrificial material layer 142 may be in a range from 15 nm to 50 nm, such as from 20 nm to 30 nm, although lesser and greater thicknesses may also be employed. The second material of the first-tier sacrificial material layers 142 may be subsequently replaced with electrically conductive electrodes which may function, for example, as control gate electrodes of a vertical NAND device. In one embodiment, the first-tier sacrificial material layers 142 may be material layers that comprise silicon nitride.

Generally, a vertically alternating sequence of unit layer stacks over a substrate. Each of the unit layer stacks comprises a first insulating layer (such as a first insulating layer 132) and a first spacer material layer (such as a first-tier sacrificial material layer 142). Generally, the first spacer material layers are formed as, or are subsequently replaced with, first-tier electrically conductive layers. While the present disclosure is described employing an embodiment in which the first spacer material layers are formed as first-tier sacrificial material layers 142 that are subsequently replaced with first-tier electrically conductive layers, embodiments are expressly contemplated herein in which the first spacer material layers are formed as first-tier electrically conductive layers. In such embodiments, steps for replacing the material of the first spacer material layers with an electrically conductive material can be omitted.

A first-tier insulating cap layer 170 can be formed over the first vertically alternating sequence (132, 142). The first-tier insulating cap layer 170 comprises an insulating material, which may be the same material as the material of the first-tier insulating layers 132. First stepped surfaces can be formed within the staircase regions of the inter-array region 200 by patterning the first-tier insulating cap layer 170 and the first vertically alternating sequence (132, 142). For example, a combination of a sacrificial hard mask layer and a trimming mask layer may be employed to form the first stepped surfaces. In one embodiment, a row of multiple first staircase regions can be formed within each area that corresponds to a combination of the area of a laterally-neighboring pair of first-tier retro-stepped dielectric material portions 165 and an intervening area. In this case, the multiple first staircase regions can be subsequently vertically offset by different depths by subsequently performing area recess etch processes.

In an illustrative example, 2^{M} sets of first stepped surfaces can be formed within a combination of the area of a laterally-neighboring pair of first-tier retro-stepped dielectric material portions 165 and an intervening area. M can be an integer in a range from 1 to 8. Each set of first stepped staircases may include P steps such that sidewalls of P first continuous spacer material layers are physically exposed with lateral offsets. P may be an integer from 2 to 64. M area recess etch processes can be performed such that each area recess etch process vertically recesses P times 2ⁱ sets of a first insulating layer 132 and a first-tier sacrificial material layer 142, in which i is a different integer from 0 to (M−1). A total of up to 2^{M}×P stepped surfaces can be formed for the first vertically alternating sequence of the first-tier insulating layers 132 and the first-tier sacrificial material layers 142. The total number of the stepped surfaces within each continuous cavity overlying the first stepped surfaces can be the same as the total number of the first-tier sacrificial material layers 142 in the first vertically alternating sequence (132, 142).

A first-tier stepped cavity 169 can be formed over each contiguous set of stepped surfaces of the first vertically alternating sequence (132, 142). The lateral extents of the first-tier sacrificial material layers 142 vary with a vertical distance from the substrate 9. Generally, an alternating stack (32, 42) of insulating layers 32 and sacrificial material layers 42 may be formed over a substrate 9, and stepped surfaces can be formed by patterning the alternating stack (32, 42) such that lateral extents of the sacrificial material layers 42 vary with a vertical distance from the substrate 9 in a staircase region.

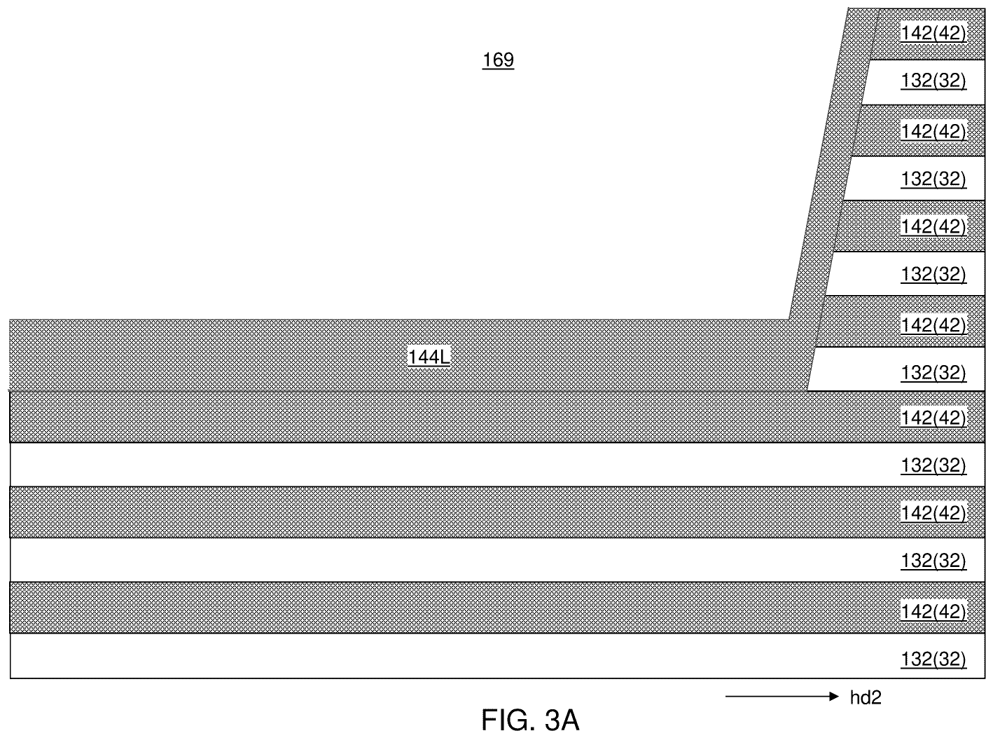

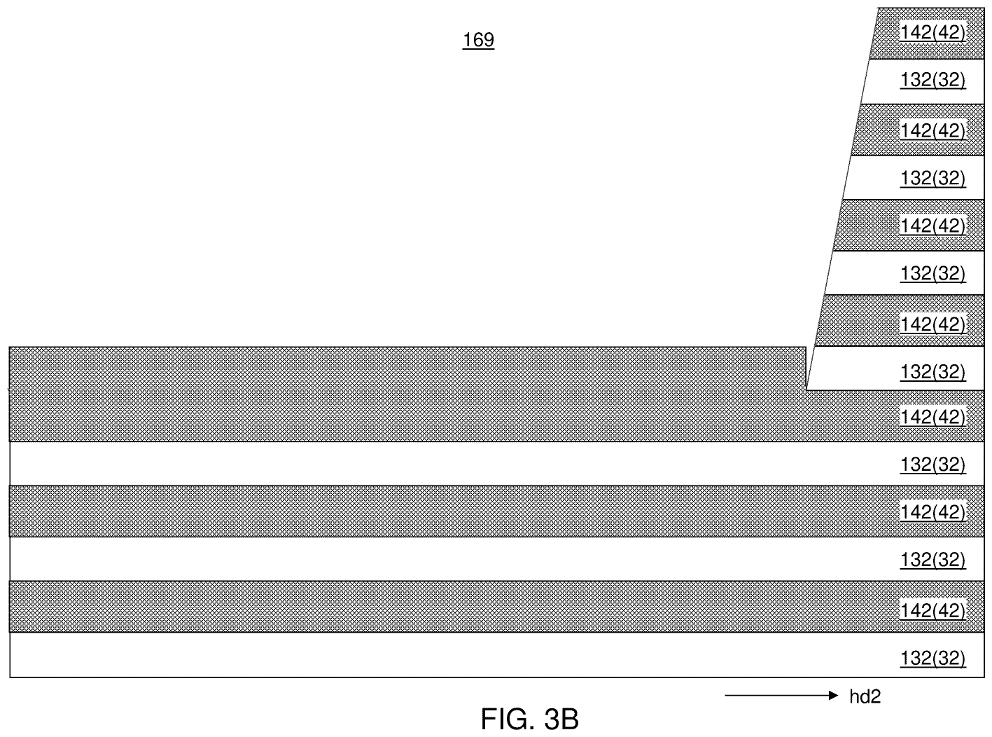

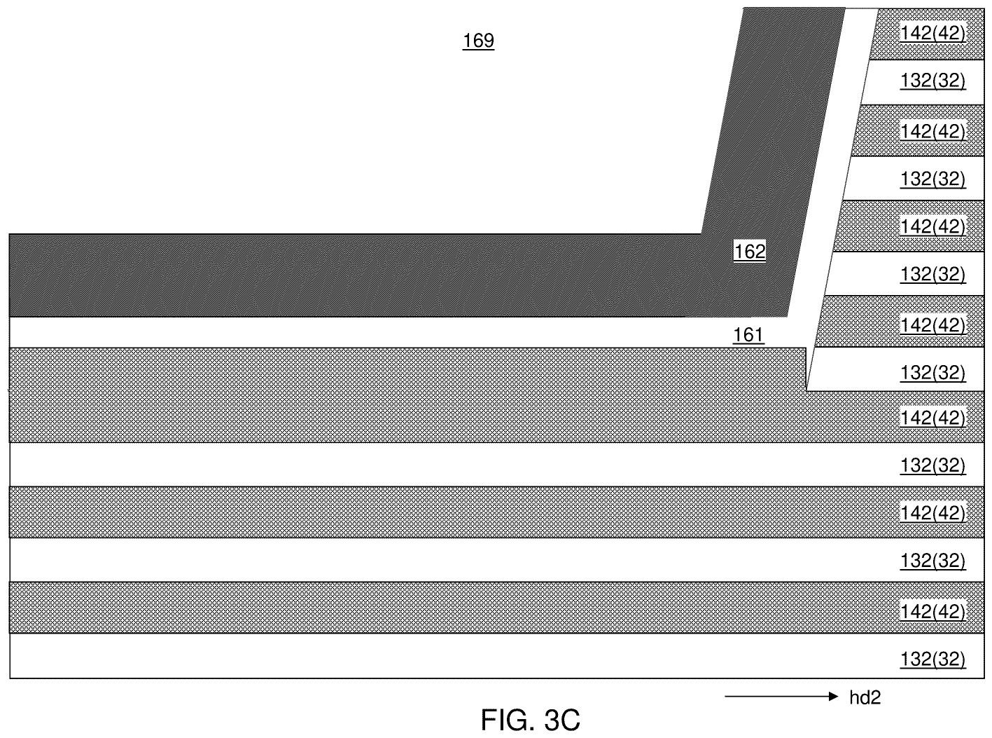

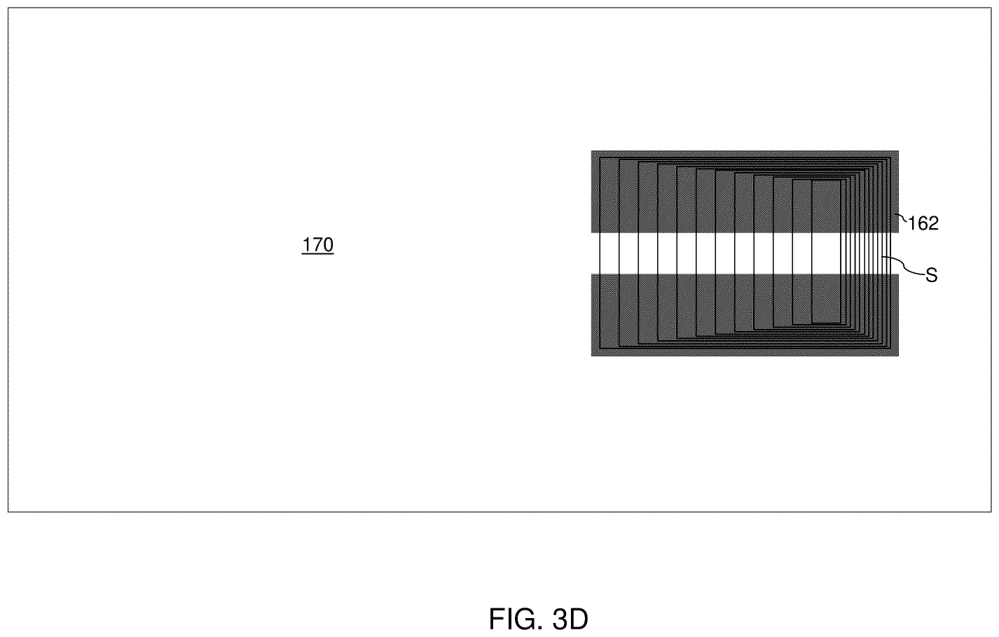

Referring to FIG. 3A, an anisotropic material deposition process can be performed to anisotropically deposit a same material as the material of the first-tier sacrificial material layers 142 to form a non-conformal sacrificial material layer 144L. In one embodiment, the first-tier sacrificial material layers 142 comprise silicon nitride, and the anisotropic material deposition process may deposit a silicon nitride material anisotropically. The non-conformal sacrificial material layer 144L is deposited by a non-conformal deposition process such as a plasma-enhanced chemical vapor deposition (PECVD) process. Preferably, the deposition of the sacrificial material of the non-conformal sacrificial material layer 144L is highly anisotropic such that the thickness of each horizontally-extending portion of the non-conformal sacrificial material layer 144L is greater than (e.g., at least twice) the thickness of non-horizontally-extending portions of the non-conformal sacrificial material layer 144L. In one embodiment the thickness of the horizontally-extending portions of the non-conformal sacrificial material layer 144L may be in a range from 50% to 300% of the thickness of each first-tier sacrificial material layer 142.

Referring to FIG. 3B, an isotropic etch process can be performed to isotropically recess the non-conformal sacrificial material layer 144L. The duration of the isotropic etch process can be selected such that the non-horizontally-extending portions of the non-conformal sacrificial material layer 144L are removed by the isotropic etch process. Remaining horizontally-extending portions of the non-conformal sacrificial material layer 144L overlying a top surface segment of a respective one of the first-tier sacrificial material layers 142 can be incorporated into the respective one of the first-tier sacrificial material layers 142.

Thus, physically-exposed portions of the sacrificial material layers 42 (such as the first-tier sacrificial material layers 142) in the staircase region can be thickened such that the thickened portions of the sacrificial material layers 142 has a thickness in a range form 125% to 250%, such as from 150% to 200%, of the unthickened portion of the first-tier sacrificial material layers 142 (which is the same as the original thickness of each first-tier sacrificial material layers 142). While an embodiment is described in which physically exposed portions of the first-tier sacrificial material layers 142 are locally thickened by anisotropic deposition and isotropic etch-back of a sacrificial material, the physically exposed portions of the first-tier sacrificial material layers 142 may be locally thickened by alternative methods that can selectively increase the thickness of physically exposed portions of the first-tier sacrificial material layers 142.

Referring to FIG. 3C, a layer stack including a first-tier silicon oxide buffer layer 161 and a first-tier silicon nitride buffer layer 162 can be over the stepped surfaces of the first vertically alternating sequence (132, 242). The first-tier silicon oxide buffer layer 161 can be deposited by a first conformal deposition process, and the first-tier silicon nitride buffer layer 162 can be deposited by a second conformal deposition process. The thickness of the first-tier silicon oxide buffer layer 161 may be in a range from 25% to 100% of the thickness of a first-tier insulating layers 132, and the thickness of the first-tier silicon nitride buffer layer 162 may be in a range from 50% to 200% of the thickness of a first-tier insulating layer 132. For example, the first-tier silicon oxide buffer layer 161 may have a thickness in a range from 10 nm to 50 nm, and the first-tier silicon nitride buffer layer 162 may have a thickness in a range from 20 nm to 100 nm, although lesser and greater thicknesses may also be employed for each.

Referring to FIG. 3D, the first-tier silicon nitride buffer layer 162 and optionally the first-tier silicon oxide buffer layer 161 can be patterned, for example, by forming a patterned photoresist layer over the first-tier silicon nitride buffer layer 162, and by transferring the pattern in the patterned photoresist layer through the first-tier silicon nitride buffer layer 162 and optionally through the first-tier silicon oxide buffer layer 161. Generally, the first-tier silicon nitride buffer layer 162 can be patterned so that the first-tier silicon nitride buffer layer 162 is present only within the area of the first-tier stepped cavity 169. Further, the first-tier silicon nitride buffer layer 162 can be patterned so that the first-tier silicon nitride buffer layer 162 is not present within areas of lateral isolation trenches to be subsequently formed.

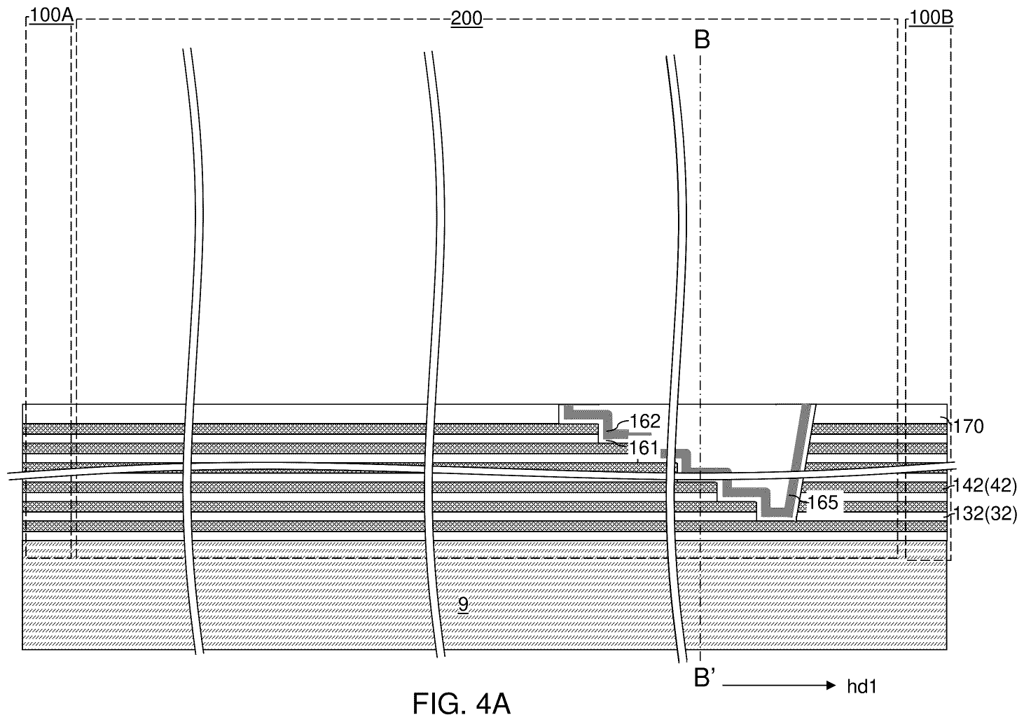

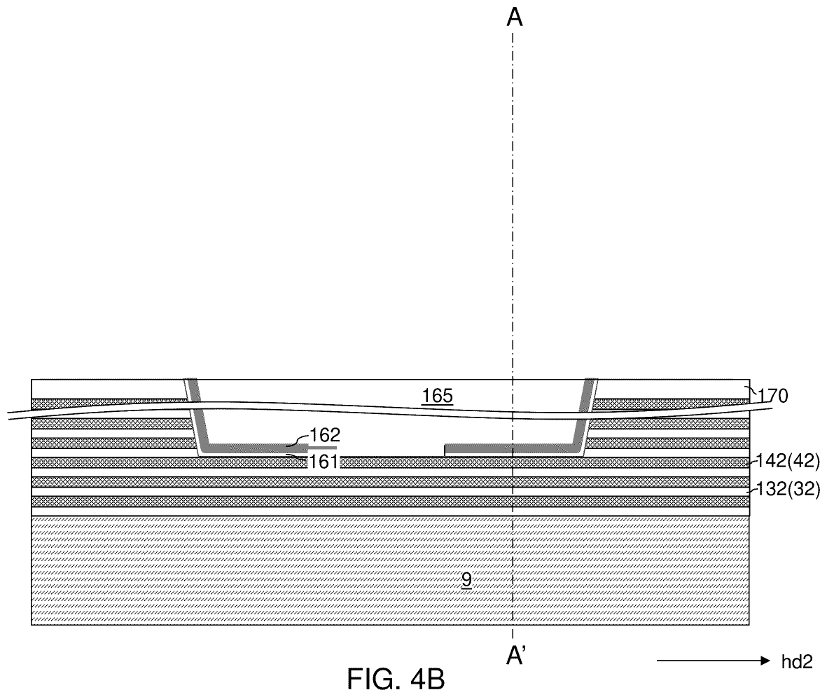

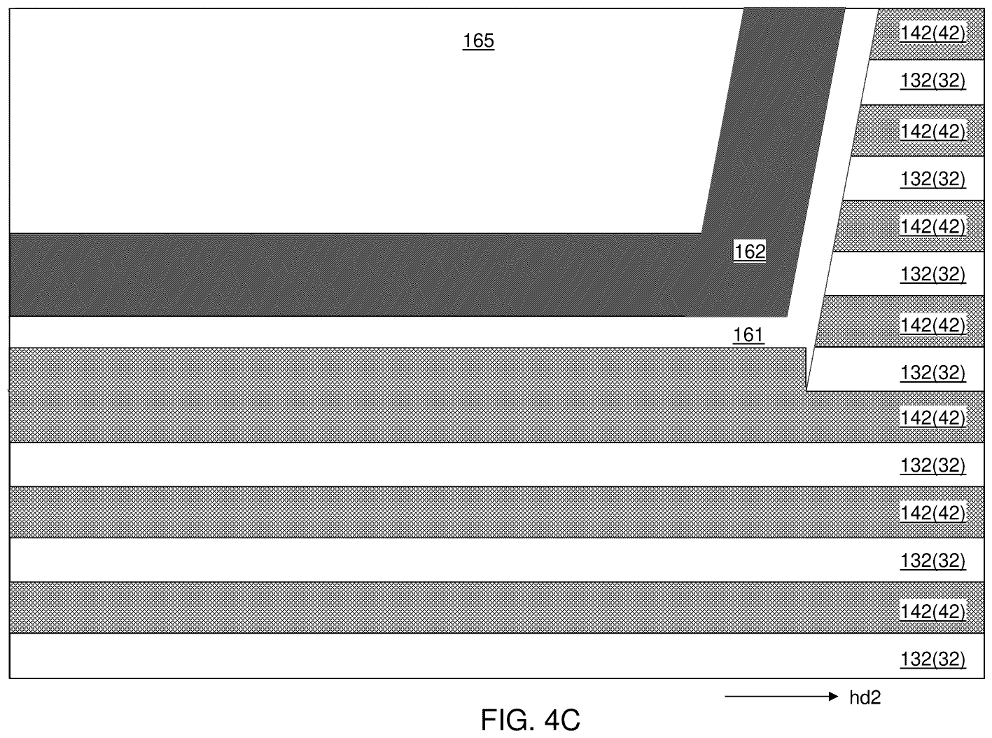

Referring to FIGS. 4A-4C, a first dielectric fill material (such as undoped silicate glass (i.e., silicon oxide) or a doped silicate glass) can be deposited in each first-tier stepped cavity 169. The first dielectric fill material can be planarized to remove excess portions of the first dielectric fill material from above the horizontal plane including the topmost surface of the first vertically alternating sequence (132, 142). Each remaining portion of the first dielectric fill material that fills a respective first-tier stepped cavity 169 constitutes a first-tier retro-stepped dielectric material portion 165. Generally, the first-tier retro-stepped dielectric material portions 165 can be formed in inter-array regions 200 located between a respective first memory array region 100A and a respective second memory array region 100B that are laterally spaced apart along the first horizontal direction hd1. The planar top surface of each first-tier retro-stepped dielectric material portion 165 can be located within a horizontal plane including the top surface of the first-tier insulating cap layer 170.

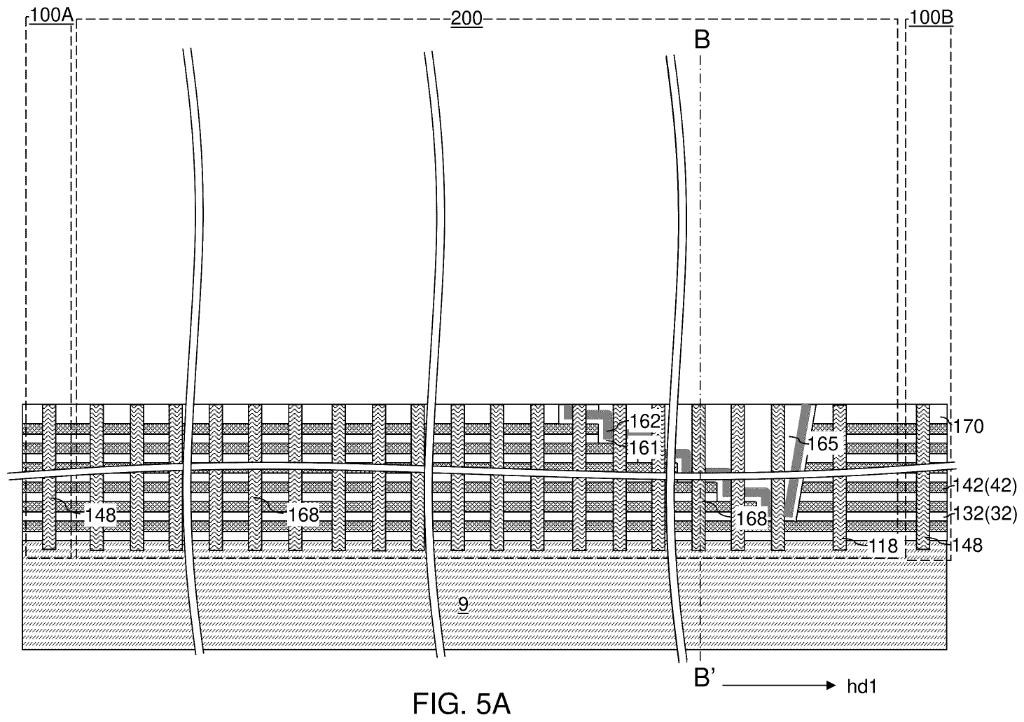

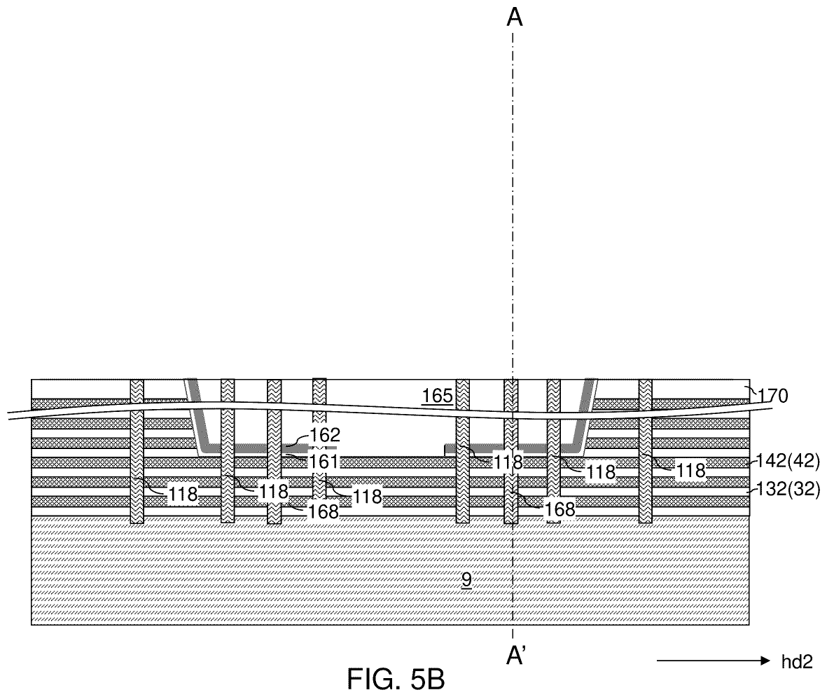

Referring to FIGS. 5A and 5B, various first-tier openings may be formed through the first vertically alternating sequence (132, 142) and into the substrate 9. A photoresist layer (not shown) may be applied over the first vertically alternating sequence (132, 142), and may be lithographically patterned to form various openings therethrough. The pattern of openings in the photoresist layer may be transferred through the first vertically alternating sequence (132, 142) and into the substrate 9 by a first anisotropic etch process to form the various first-tier openings concurrently, i.e., during the first isotropic etch process. The various first-tier openings may include first-tier memory openings formed in the memory array regions 100 and first-tier support openings formed in the inter-array regions 200, and first-tier contact openings formed in the staircase regions (which are located within the inter-array regions 200). Each cluster of first-tier memory openings may be formed as a two-dimensional array of first-tier memory openings. The first-tier support openings are openings that are formed in the inter-array region 200, and are subsequently employed to form support pillar structures. Each first-tier contact opening is formed in a respective area in which a respective contact assembly (84, 86) is to be subsequently formed. A subset of the first-tier support openings may be formed through a respective horizontally-extending surface segment of the first stepped surfaces. A subset of the first-tier contact openings is formed through a respective horizontally-extending surface segment of the first stepped surfaces.

Sacrificial first-tier opening fill structures (148, 118, 168) may be formed in the various first-tier openings. For example, a sacrificial first-tier fill material is deposited concurrently deposited in each of the first-tier openings. The sacrificial first-tier fill material includes a material that may be subsequently removed selective to the materials of the first-tier insulating layers 132 and the first-tier sacrificial material layers 142. In one embodiment, the sacrificial first-tier fill material may include a semiconductor material such as silicon (e.g., a-Si or polysilicon), a silicon-germanium alloy, germanium, a III-V compound semiconductor material, or a combination thereof. Optionally, a thin etch stop liner (such as a silicon oxide layer or a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In another embodiment, the sacrificial first-tier fill material may include a silicon oxide material having a higher etch rate than the materials of the first-tier insulating layers 132. For example, the sacrificial first-tier fill material may include borosilicate glass or porous or non-porous organosilicate glass having an etch rate that is at least 100 times higher than the etch rate of densified TEOS oxide (i.e., a silicon oxide material formed by decomposition of tetraethylorthosilicate glass in a chemical vapor deposition process and subsequently densified in an anneal process) in a 100:1 dilute hydrofluoric acid. In this case, a thin etch stop liner (such as a silicon nitride layer having a thickness in a range from 1 nm to 3 nm) may be used prior to depositing the sacrificial first-tier fill material. The sacrificial first-tier fill material may be formed by a non-conformal deposition or a conformal deposition method.

In yet another embodiment, the sacrificial first-tier fill material may include carbon-containing material (such as amorphous carbon or diamond-like carbon) that may be subsequently removed by ashing, or a silicon-based polymer that may be subsequently removed selective to the materials of the first vertically alternating sequence (132, 142).

Portions of the deposited sacrificial first-tier fill material may be removed from above the topmost layer of the first vertically alternating sequence (132, 142), such as from above the first-tier insulating cap layer 170. For example, the sacrificial first-tier fill material may be recessed to a top surface of the first-tier insulating cap layer 170 using a planarization process. The planarization process may include a recess etch, chemical mechanical planarization (CMP), or a combination thereof. The top surface of the first-tier insulating cap layer 170 may be used as an etch stop layer or a planarization stop layer.

Remaining portions of the sacrificial first-tier fill material comprise sacrificial first-tier opening fill structures (148, 118, 168). Specifically, each remaining portion of the sacrificial first-tier fill material in a first-tier memory opening constitutes a sacrificial first-tier memory opening fill structure 148. Each remaining portion of the sacrificial first-tier fill material in a first-tier support opening constitutes a sacrificial first-tier support opening fill structure 118. Each remaining portion of the sacrificial first-tier fill material in a first-tier contact opening constitutes a sacrificial first-tier contact opening fill structure 168. The various sacrificial first-tier opening fill structures (148, 118, 168) are concurrently formed, i.e., during a same set of processes including the deposition process that deposits the sacrificial first-tier fill material and the planarization process that removes the first-tier deposition process from above the first vertically alternating sequence (132, 142) (such as from above the top surface of the first-tier insulating cap layer 170). The top surfaces of the sacrificial first-tier opening fill structures (148, 118, 168) may be coplanar with the top surface of the first-tier insulating cap layer 170. Each of the sacrificial first-tier opening fill structures (148, 118, 168) may, or may not, include cavities therein. The set of all structures located between the bottommost surface of the first vertically alternating sequence (132, 142) and the topmost surface of the first vertically alternating sequence (132, 142) or embedded within the first vertically alternating sequence (132, 142) constitutes a first-tier structure.

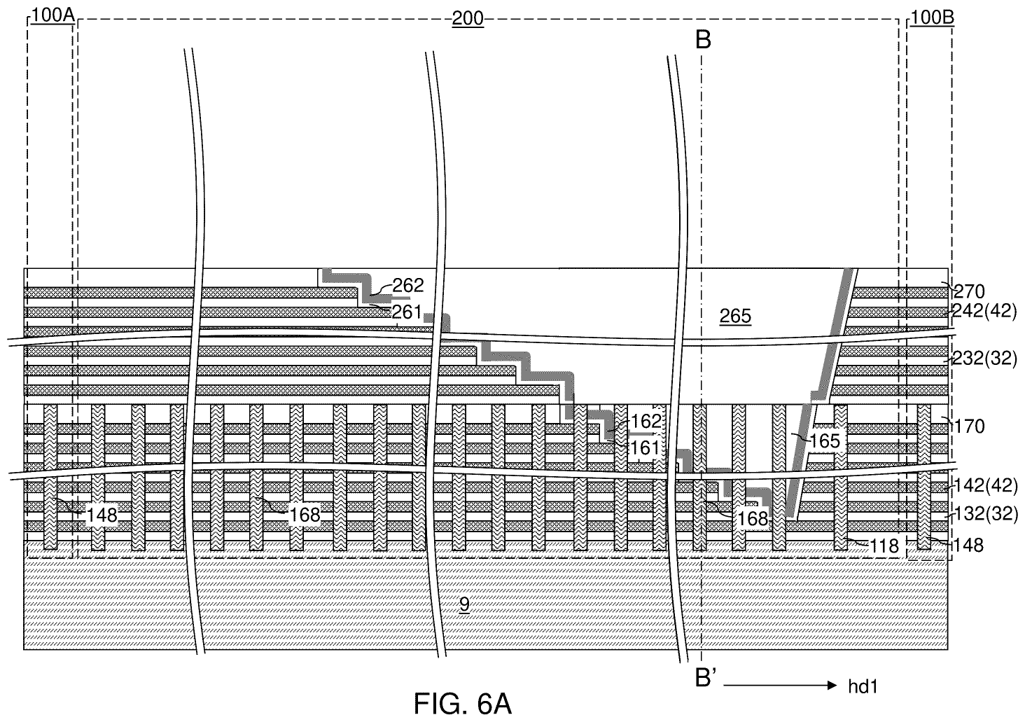

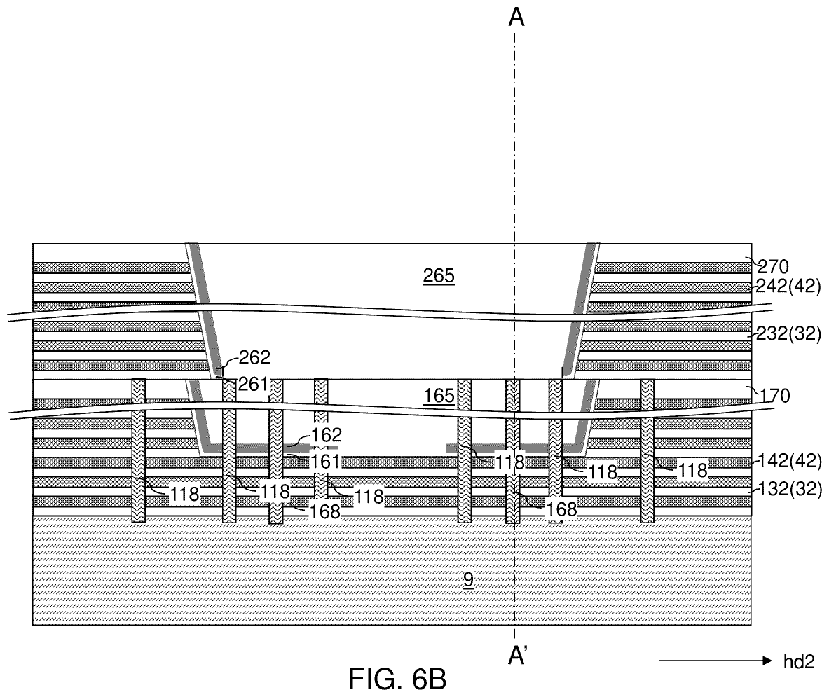

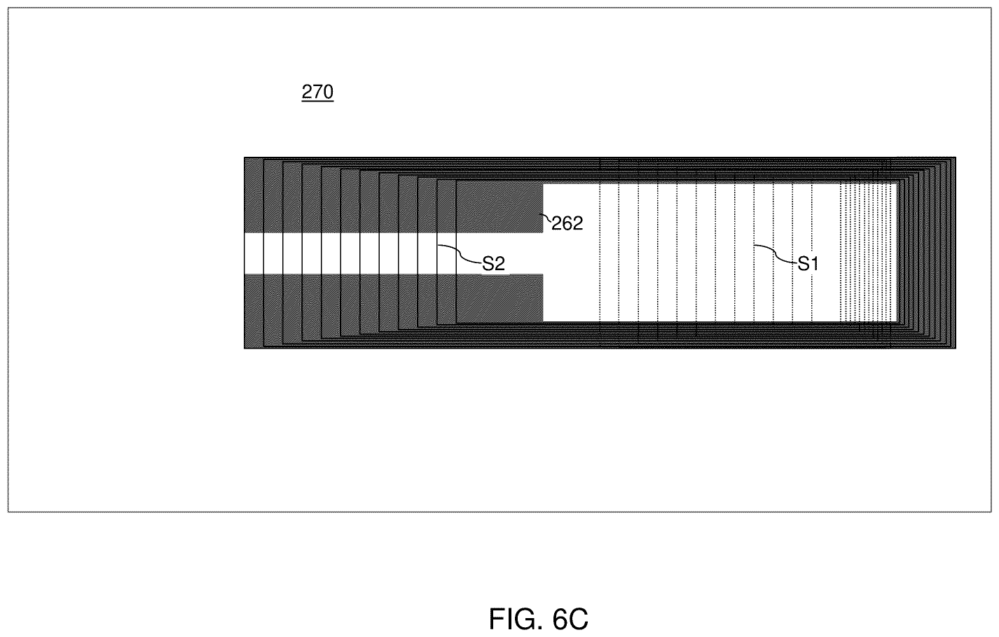

Referring to FIGS. 6A-6C, a second vertically alternating sequence of second-tier insulating layers 232 and second-tier sacrificial material layers 242 can be formed. Each of the second-tier insulating layers 232 is an insulating layer 32 that continuously extends over the entire area of the substrate 8, and may have a uniform thickness throughout. Each of the second-tier sacrificial material layers 242 is a sacrificial material layer 42 that includes a dielectric material and continuously extends over the entire area of the substrate 8, and may have a uniform thickness throughout. The second-tier insulating layers 232 can have the same material composition and the same thickness as the first-tier insulating layers 132. The second-tier sacrificial material layers 242 can have the same material composition and the same thickness as the first-tier sacrificial material layers 142. A second-tier insulating cap layer 270 can be formed over the second vertically alternating sequence (232, 242).

Second stepped surfaces can be formed within the staircase regions of the inter-array region 200 which will be filled with the second-tier retro-stepped dielectric material portions 265. For example, a combination of a sacrificial hard mask layer and a trimming mask layer may be employed to form the second stepped surfaces. Generally, the processing steps described with reference to FIGS. 2A-2C can be performed to form second-tier stepped cavities, under which a respective set of second stepped surfaces of the second vertically alternating sequence (232, 242) are exposed. Each set of second stepped surfaces may be laterally offset relative to an adjacent and underling set of first stepped surfaces of the first vertically alternating sequence (132, 142) along the first horizontal direction hd1.

In an illustrative example, 2N sets of second stepped surfaces can be formed within a combination of the area of a laterally-neighboring pair of second-tier retro-stepped dielectric material portions 265 and an intervening area. N can be an integer in a range from 2 to 8. Each set of second stepped staircases may include P steps such that sidewalls of Q second continuous spacer material layers are physically exposed with lateral offsets. Q may be an integer from 2 to 64. M area recess etch processes can be performed such that each area recess etch process vertically recesses Q times 2^{j} sets of a second insulating layer 232 and a second-tier sacrificial material layer 242, in which j is a different integer from 0 to (N−1). A total of up to 2^{N}×Q stepped surfaces can be formed for the second vertically alternating sequence of the second-tier insulating layers 232 and the second-tier sacrificial material layers 242. The total number of the stepped surfaces within each continuous cavity overlying the second stepped surfaces can be the same as the total number of the second-tier sacrificial material layers 242 in the second vertically alternating sequence (132, 242).

The processing steps described with reference to FIGS. 3A-3C can be performed with suitable modifications to form a layer stack of a second-tier silicon oxide buffer layer 261 and a second-tier silicon nitride buffer layer 262. The second-tier silicon nitride buffer layer 262 can be patterned as illustrated in FIG. 6C, which is a top-down view of a region of the first exemplary structure prior to formation of a second-tier retro-stepped dielectric material portion 265. Generally, the second-tier silicon nitride buffer layer 262 can be patterned to cover portions of the second-tier stepped surfaces without covering the first-tier stepped surfaces. The second-tier silicon nitride buffer layer 262 can be patterned so that the second-tier silicon nitride buffer layer 262 is not present within areas of lateral isolation trenches to be subsequently formed. A second dielectric fill material (such as undoped silicate glass (i.e., silicon oxide) or a doped silicate glass) can be deposited in each second-tier stepped cavity. The second dielectric fill material can be planarized to remove excess portions of the second dielectric fill material from above the horizontal plane including the topmost surface of the second vertically alternating sequence (232, 242). Each remaining portion of the second dielectric fill material that fills a respective second continuous retro-stepped cavity constitutes a second-tier retro-stepped dielectric material portion 265.

Generally, a second-tier structure is formed, which comprises a second vertically alternating sequence of second-tier insulating layers 232 and second-tier sacrificial material layers 242 and second-tier retro-stepped dielectric material portions 265 overlying second stepped surfaces of the second vertically alternating sequence that are located in the inter-array regions 200.

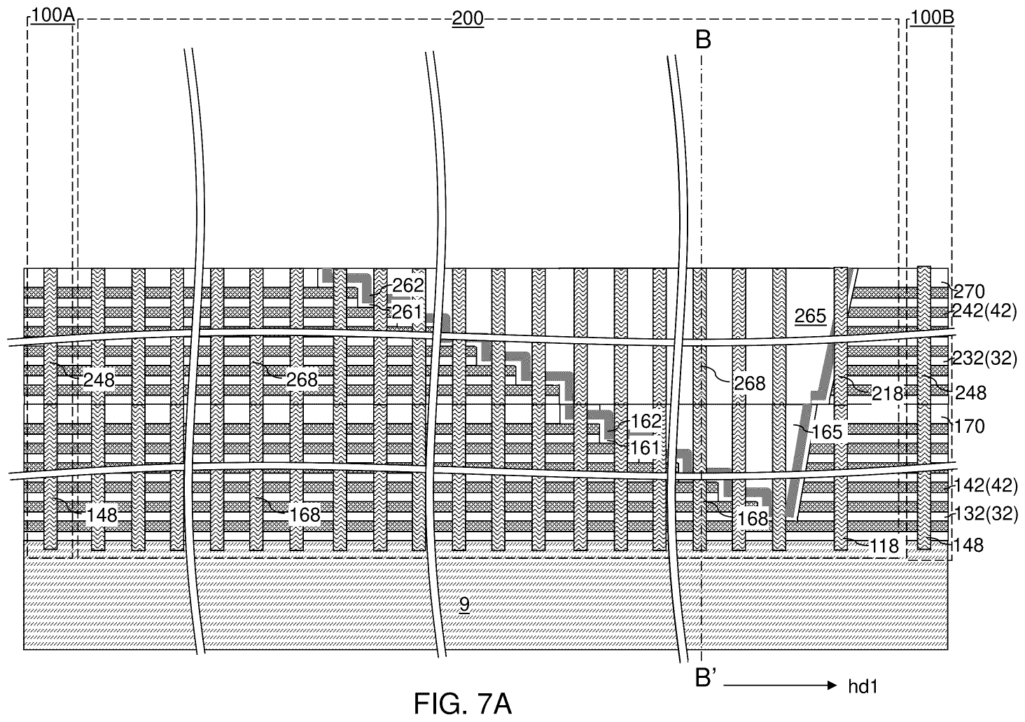

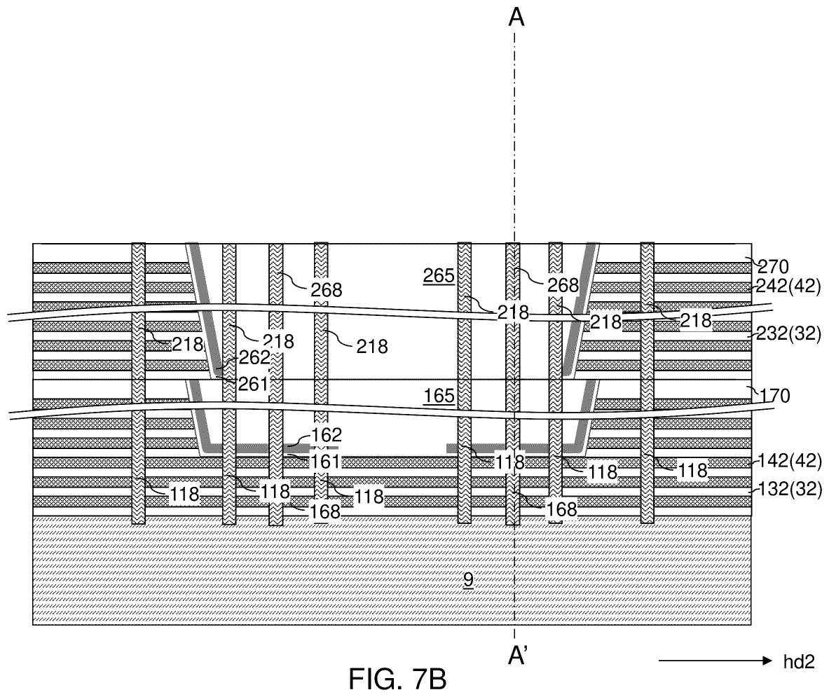

Referring to FIGS. 7A and 7B, various second-tier openings may be formed through the second vertically alternating sequence (232, 242) and over the sacrificial first-tier opening fill structures (148, 118, 168). A photoresist layer (not shown) may be applied over the second vertically alternating sequence (232, 242), and may be lithographically patterned to form various openings therethrough. The pattern of openings in the photoresist layer may be transferred through the second vertically alternating sequence (232, 242) to form the various second-tier openings concurrently, i.e., during the second isotropic etch process.

The various second-tier openings may include second-tier memory openings formed in the memory array regions 100, second-tier support openings formed in the inter-array region 200, and second-tier contact openings formed in the staircase region which is located within the inter-array region 200. Each second-tier opening may be formed within the area of a respective one of the sacrificial first-tier opening fill structures (148, 118, 168). Thus, a top surface of a sacrificial first-tier opening fill structure can be physically exposed at the bottom of each second-tier opening. Specifically, each second-tier memory openings can be formed directly over a respective sacrificial first-tier memory opening fill structure 148, each second-tier support opening can be formed directly over a respective sacrificial first-tier support opening fill structure 118, and each second-tier contact opening can be formed directly over a respective sacrificial first-tier contact opening fill structure 168. Each cluster of second-tier memory openings may be formed as a two-dimensional array of second-tier memory openings. The second-tier support openings are openings that are formed in the inter-array region 200, and are subsequently employed to form support pillar structures. A subset of the second-tier support openings may be formed through a respective horizontally-extending surface segment of the second stepped surfaces. A subset of the second-tier contact openings may be formed through a respective horizontally-extending surface segment of the second stepped surfaces.

Sacrificial second-tier opening fill structures may be formed in the various second-tier openings. For example, a sacrificial first-tier fill material is deposited concurrently deposited in each of the second-tier openings. The sacrificial second-tier fill material can include any material that may be employed for the sacrificial first-tier fill material. Portions of the deposited sacrificial second-tier fill material may be removed from above the topmost layer of the second vertically alternating sequence (232, 242). Remaining portions of the sacrificial second-tier fill material comprise sacrificial second-tier opening fill structures (248, 218, 268). Specifically, each remaining portion of the sacrificial second-tier fill material in a second-tier memory opening constitutes a sacrificial second-tier memory opening fill structure 248. Each remaining portion of the sacrificial second-tier fill material in a second-tier support opening constitutes a sacrificial second-tier support opening fill structure 218. Each remaining portion of the sacrificial second-tier fill material in a second-tier contact opening constitutes a sacrificial second-tier contact opening fill structure 268. The top surfaces of the sacrificial second-tier opening fill structures (248, 218, 268) may be coplanar with the top surface of the second-tier insulating cap layer 270. Each of the sacrificial second-tier opening fill structures may, or may not, include cavities therein. The set of all structures located between the bottommost surface of the second vertically alternating sequence (232, 242) and the topmost surface of the second vertically alternating sequence (232, 242) or embedded within the second vertically alternating sequence (232, 242) constitutes a second-tier structure.

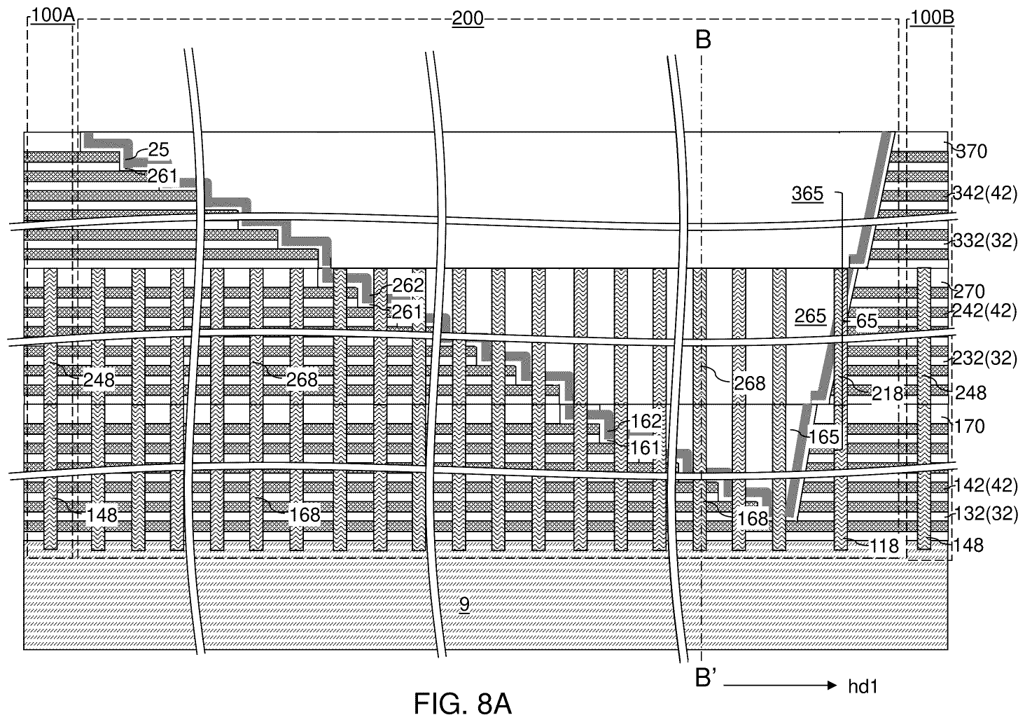

Referring to FIGS. 8A and 8B, a third vertically alternating sequence of third-tier insulating layers 332 and third-tier sacrificial material layers 342 can be formed. Each of the third-tier insulating layers 332 is an insulating layer 32 that continuously extends over the entire area of the substrate 8, and may have a uniform thickness throughout. Each of the third-tier sacrificial material layers 342 is a sacrificial material layer 42 that includes a dielectric material and continuously extends over the entire area of the substrate 8, and may have a uniform thickness throughout. The third-tier insulating layers 332 can have the same material composition and the same thickness as the first-tier insulating layers 132. The third-tier sacrificial material layers 342 can have the same material composition and the same thickness as the first-tier sacrificial material layers 142. A third-tier insulating cap layer 370 can be formed over the third vertically alternating sequence (332, 342).

Third stepped surfaces can be formed within the staircase regions of the inter-array region 200 which will be filled with the third-tier retro-stepped dielectric material portions 365. For example, a combination of a sacrificial hard mask layer and a trimming mask layer may be employed to form the third stepped surfaces. Generally, the processing steps described with reference to FIGS. 2A-2C can be performed to form third-tier stepped cavities, under which a respective set of third stepped surfaces of the third vertically alternating sequence (332, 342) are exposed. Each set of third stepped surfaces may be laterally offset relative to an adjacent and underling set of second stepped surfaces of the second vertically alternating sequence (232, 242) and relative to an adjacent and underlying set of first stepped surfaces of the first vertically alternating sequence (132, 142) along the first horizontal direction hd1.

The processing steps described with reference to FIGS. 3A-3C can be performed with suitable modifications to form a layer stack of a third-tier silicon oxide buffer layer 361 and a third-tier silicon nitride buffer layer 362. The third-tier silicon nitride buffer layer 362 can be patterned to cover portions of the third-tier stepped surfaces without covering the second-tier stepped surfaces or the first-tier stepped surfaces. Further, the third-tier silicon nitride buffer layer 362 can be patterned so that the third-tier silicon nitride buffer layer 362 is not present within areas of lateral isolation trenches to be subsequently formed. A third dielectric fill material (such as undoped silicate glass (i.e., silicon oxide) or a doped silicate glass) can be deposited in each third-tier stepped cavity. The third dielectric fill material can be planarized to remove excess portions of the second dielectric fill material from above the horizontal plane including the topmost surface of the third-tier insulating cap layer 370. Each remaining portion of the second dielectric fill material that fills a respective second continuous retro-stepped cavity constitutes a second-tier retro-stepped dielectric material portion 265.

A third dielectric fill material (such as undoped silicate glass (i.e., silicon oxide) or a doped silicate glass) can be deposited in each third continuous retro-stepped cavity. The third dielectric fill material can be planarized to remove excess portions of the third dielectric fill material from above the horizontal plane including the topmost surface of the third vertically alternating sequence (332, 342). Each remaining portion of the third dielectric fill material that fills a respective third continuous retro-stepped cavity constitutes a third-tier retro-stepped dielectric material portion 365.

Generally, a third-tier structure is formed, which comprises a third vertically alternating sequence of third-tier insulating layers 332 and third-tier sacrificial material layers 342 and third-tier retro-stepped dielectric material portions 365 overlying third stepped surfaces of the third vertically alternating sequence that are located in the inter-array regions 200.

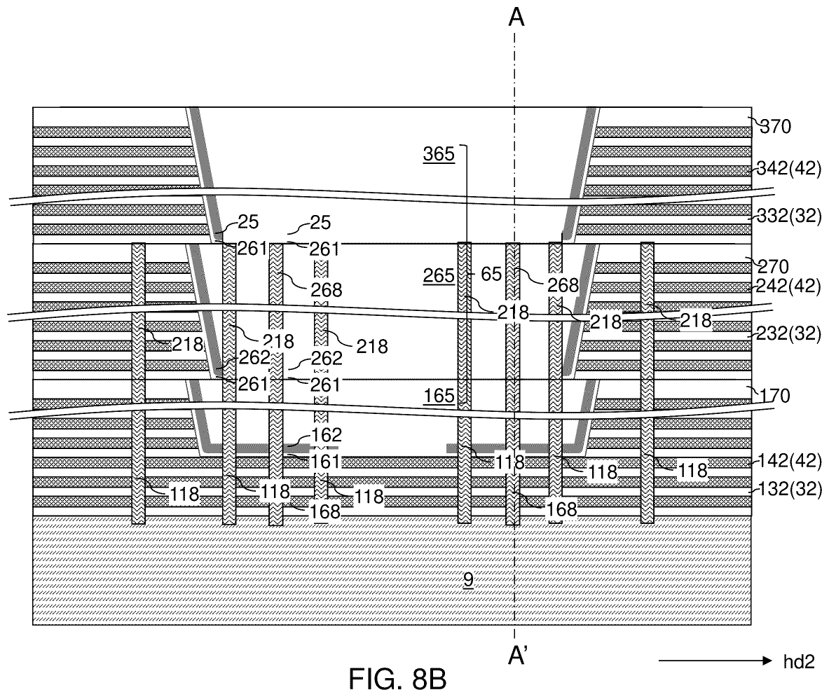

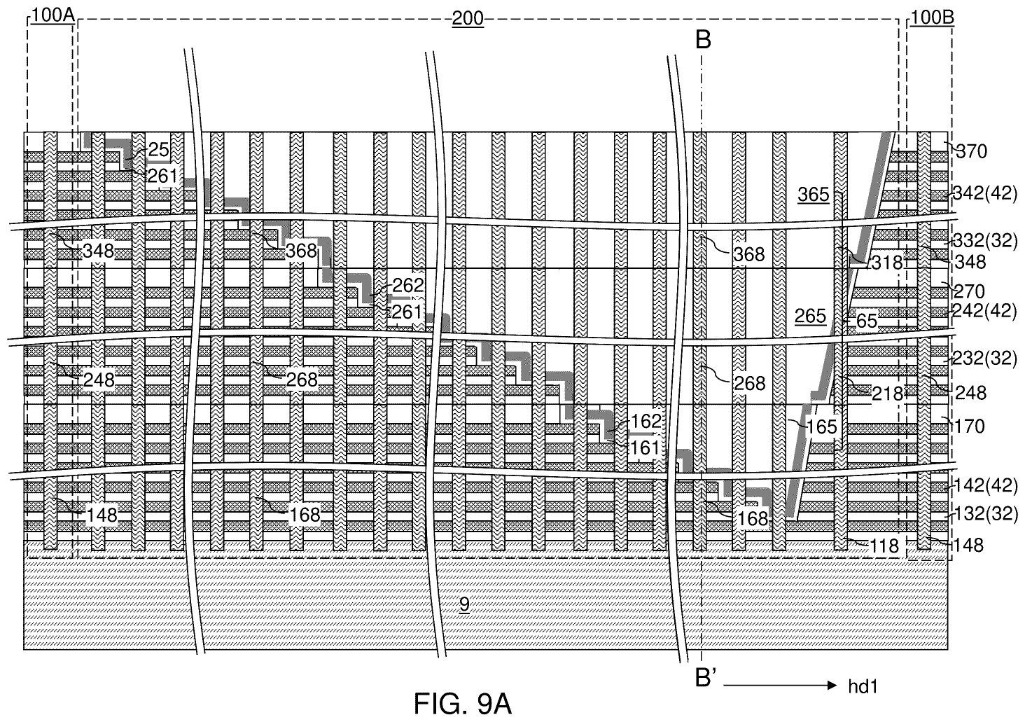

Referring to FIGS. 9A and 9B, various third-tier openings may be formed through the third vertically alternating sequence (332, 342) and over the sacrificial second-tier opening fill structures (248, 218, 268). A photoresist layer (not shown) may be applied over the third vertically alternating sequence (332, 342), and may be lithographically patterned to form various openings therethrough. The pattern of openings in the photoresist layer may be transferred through the third vertically alternating sequence (332, 342) to form the various third-tier openings concurrently, i.e., during the third isotropic etch process.

The various third-tier openings may include third-tier memory openings formed in the memory array regions 100, third-tier support openings formed in the inter-array region 200, and third-tier contact openings formed in the staircase region which is located within the inter-array region 200. Each third-tier opening may be formed within the area of a respective one of the sacrificial second-tier opening fill structures (248, 218, 268). Thus, a top surface of a sacrificial second-tier opening fill structure can be physically exposed at the bottom of each third-tier opening. Specifically, each third-tier memory openings can be formed directly over a respective sacrificial second-tier memory opening fill structure 248, each third-tier support opening can be formed directly over a respective sacrificial second-tier support opening fill structure 218, and each third-tier contact opening can be formed directly over a respective sacrificial second-tier contact opening fill structure 268. Each cluster of third-tier memory openings may be formed as a two-dimensional array of third-tier memory openings. The third-tier support openings are openings that are formed in the inter-array region 200, and are subsequently employed to form support pillar structures. A subset of the third-tier support openings may be formed through a respective horizontally-extending surface segment of the third stepped surfaces. A subset of the third-tier contact openings may be formed through a respective horizontally-extending surface segment of the third stepped surfaces.

Sacrificial third-tier opening fill structures may be formed in the various third-tier openings. For example, a sacrificial second-tier fill material is deposited concurrently deposited in each of the third-tier openings. The sacrificial third-tier fill material can include any material that may be employed for the sacrificial second-tier fill material. Portions of the deposited sacrificial third-tier fill material may be removed from above the topmost layer of the third vertically alternating sequence (332, 342). Remaining portions of the sacrificial third-tier fill material comprise sacrificial third-tier opening fill structures (348, 318, 368). Specifically, each remaining portion of the sacrificial third-tier fill material in a third-tier memory opening constitutes a sacrificial third-tier memory opening fill structure 348. Each remaining portion of the sacrificial third-tier fill material in a third-tier support opening constitutes a sacrificial third-tier support opening fill structure 318. Each remaining portion of the sacrificial third-tier fill material in a third-tier contact opening constitutes a sacrificial third-tier contact opening fill structure 368. The top surfaces of the sacrificial third-tier opening fill structures (348, 318, 368) may be coplanar with the top surface of the third-tier insulating cap layer 370. Each of the sacrificial third-tier opening fill structures may, or may not, include cavities therein. The set of all structures located between the bottommost surface of the third vertically alternating sequence (332, 342) and the topmost surface of the third vertically alternating sequence (332, 342) or embedded within the third vertically alternating sequence (332, 342) constitutes a third-tier structure.

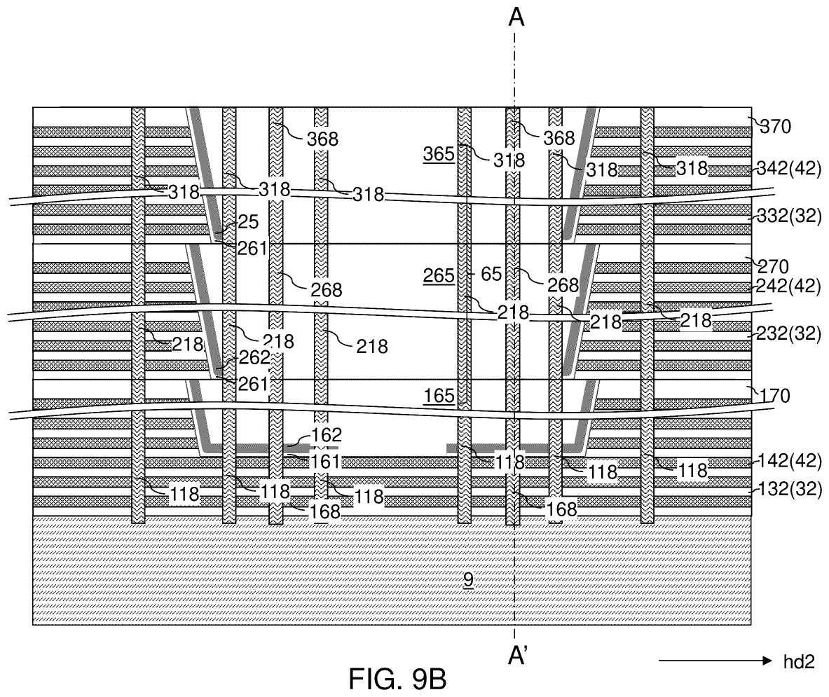

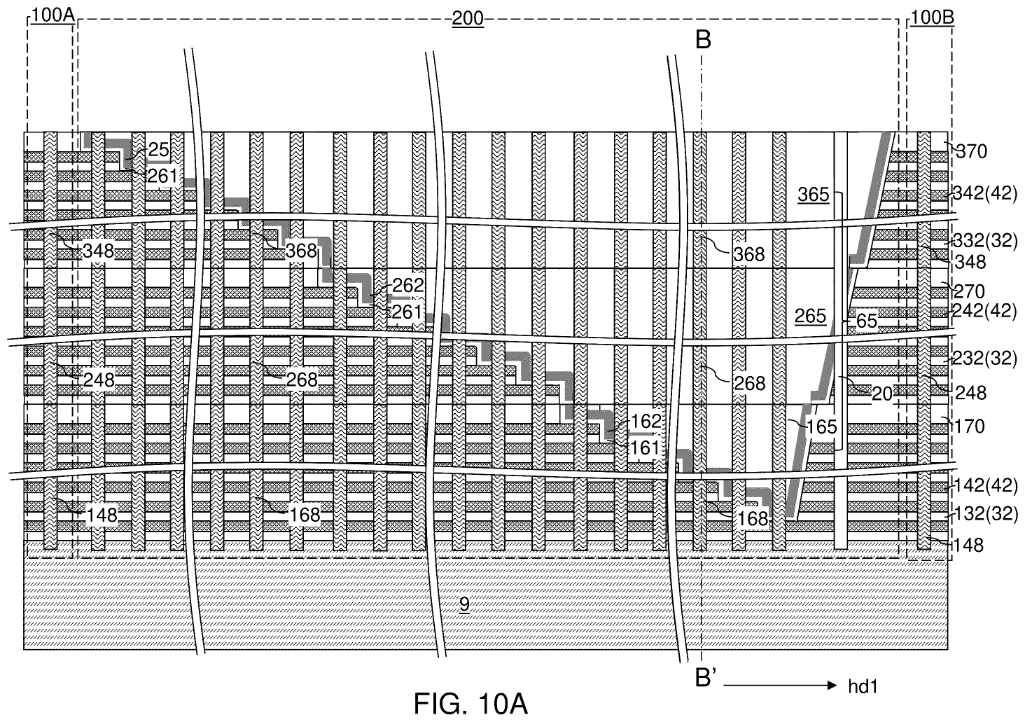

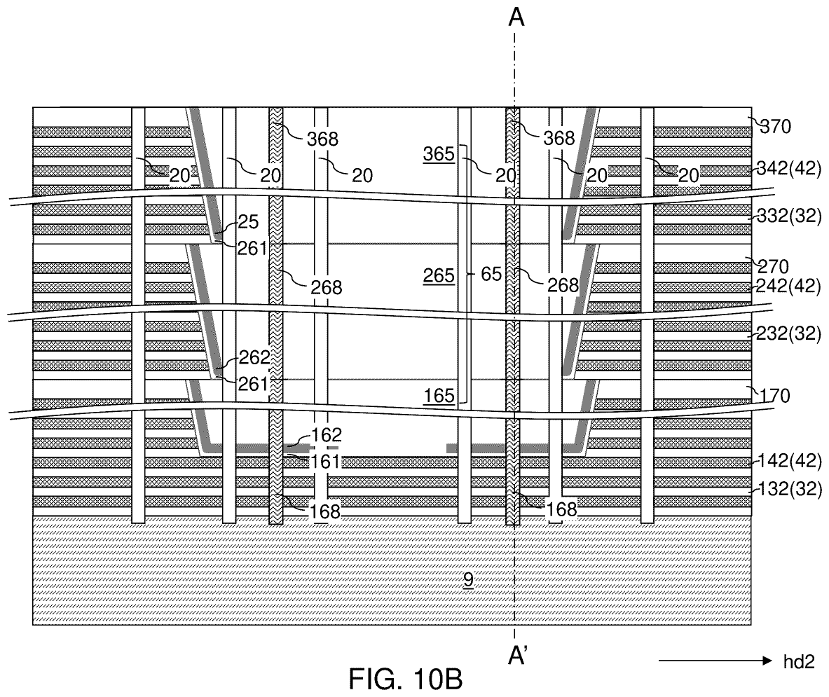

Referring to FIGS. 10A and 10B, a photoresist layer (not shown) can be applied over the third-tier structure, and can be lithographically patterned to form openings over the areas of the sacrificial third-tier support opening fill structures 318. The sacrificial fill materials of the sacrificial third-tier support opening fill structures 318, the sacrificial second-tier support opening fill structures 218, and the sacrificial first-tier support opening fill structures 118 can be removed selective to the materials of the retro-stepped dielectric material portions 65, the insulating layers 32, and the sacrificial material layers 42. Support pillar cavities can be formed in the volumes from which the materials of the sacrificial third-tier support opening fill structures 318, the sacrificial second-tier support opening fill structures 218, and the sacrificial first-tier support opening fill structures 118 are removed. The photoresist layer can be subsequently removed, for example, by ashing.

A dielectric fill material can be deposited in the support pillar cavities by performing a conformal deposition process. The dielectric fill material comprises a dielectric material that is different from the material of the sacrificial material layers 42. For example, the dielectric fill material may comprise undoped silicate glass or a doped silicate glass. Excess portions of the dielectric fill material can be removed from above the horizontal plane including the top surface of the topmost retro-stepped dielectric material portions 65 (such as the third-tier retro-stepped dielectric material portion 365). Each remaining portion of the dielectric fill material that fills a respective support pillar cavity constitutes a support pillar structure 20. The support pillar structures 20 can be formed in the inter-array region 200, and may vertically extend from the substrate 9 to a horizontal plane including the topmost surfaces of the retro-stepped dielectric material portions 65 and the third-tier insulating cap layer 370.

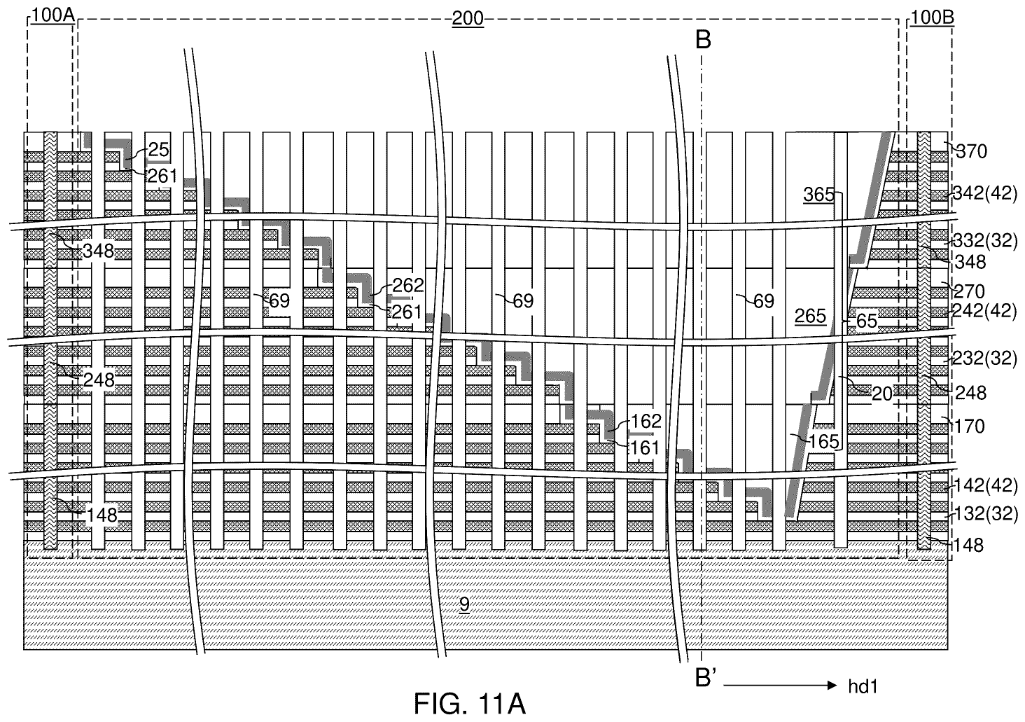

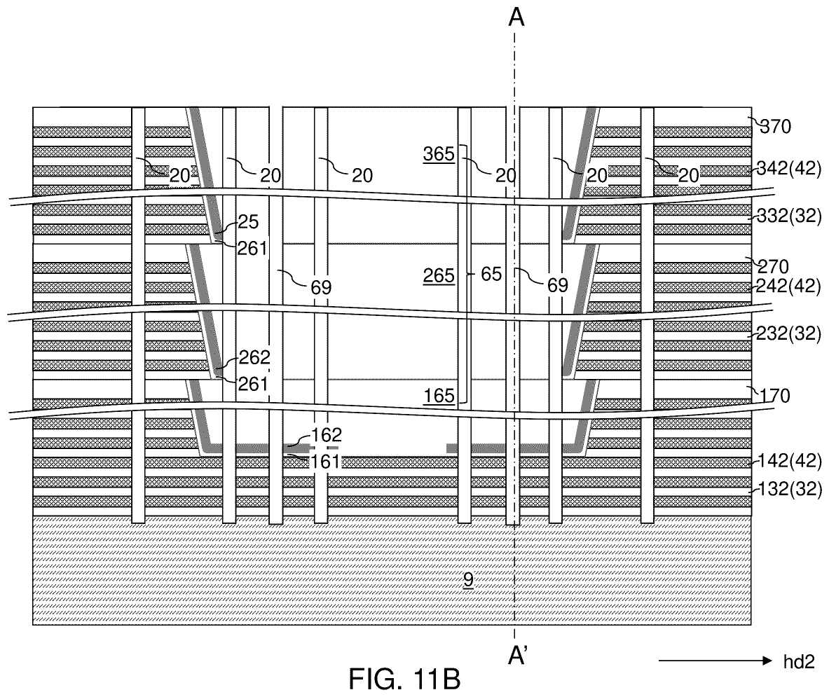

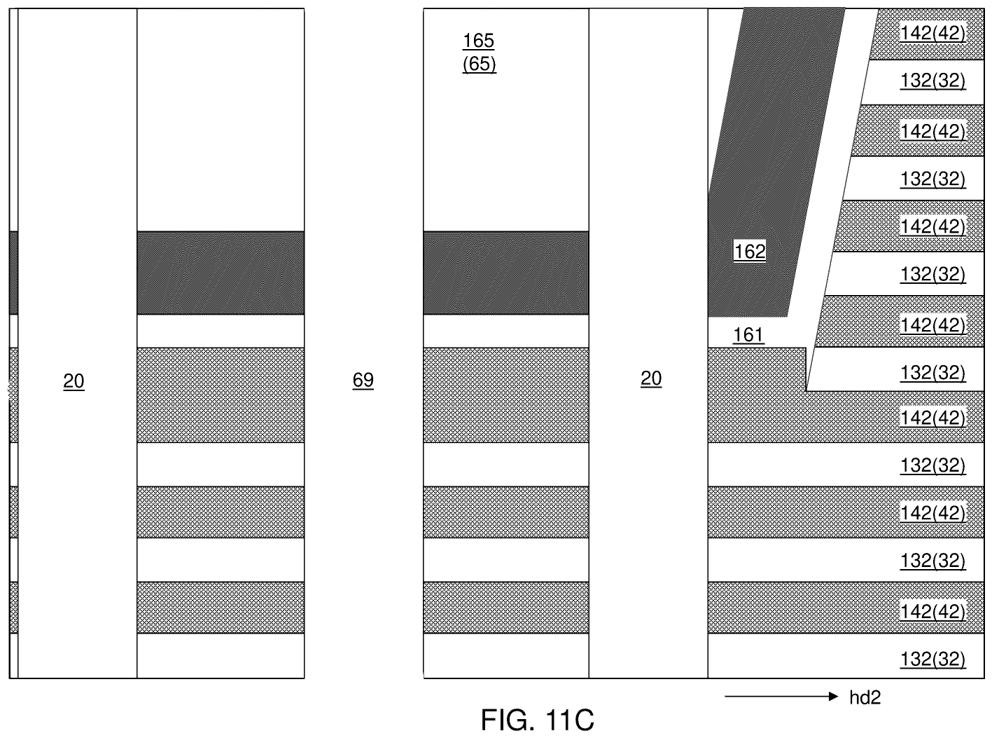

Referring to FIGS. 11A-11C, a photoresist layer (not shown) can be applied over the third-tier structure, and can be lithographically patterned to cover the memory array regions 100 without covering the inter-array regions 200. The sacrificial fill materials of the sacrificial third-tier contact opening fill structures 368, the sacrificial second-tier contact opening fill structures 268, and the sacrificial first-tier contact opening fill structures 168 can be removed selective to the materials of the retro-stepped dielectric material portions 65, the insulating layers 32, the sacrificial material layers 42, and the support pillar structures 20. Contact via cavities 69 are formed in the volumes from which the materials of the sacrificial third-tier contact opening fill structures 368, the sacrificial second-tier contact opening fill structures 268, and the sacrificial first-tier contact opening fill structures 168 are removed. Each contact via cavity 69 vertically extends from the horizontal plane including the planar top surfaces of the third-tier retro-stepped dielectric material portion 365 to the substrate 9. In one embodiment, each of the contact via cavities 69 may vertically extend through a horizontally extending portion of a layer stack including a respective silicon oxide buffer layer (161, 261, or 361) and a respective silicon nitride buffer layer (162, 262, 362). Each contact via cavity 69 may vertically extend through at least one insulating layer 32 and at least one sacrificial material layer 42 of an alternating stack of insulating layers 32 and sacrificial material layers 42.

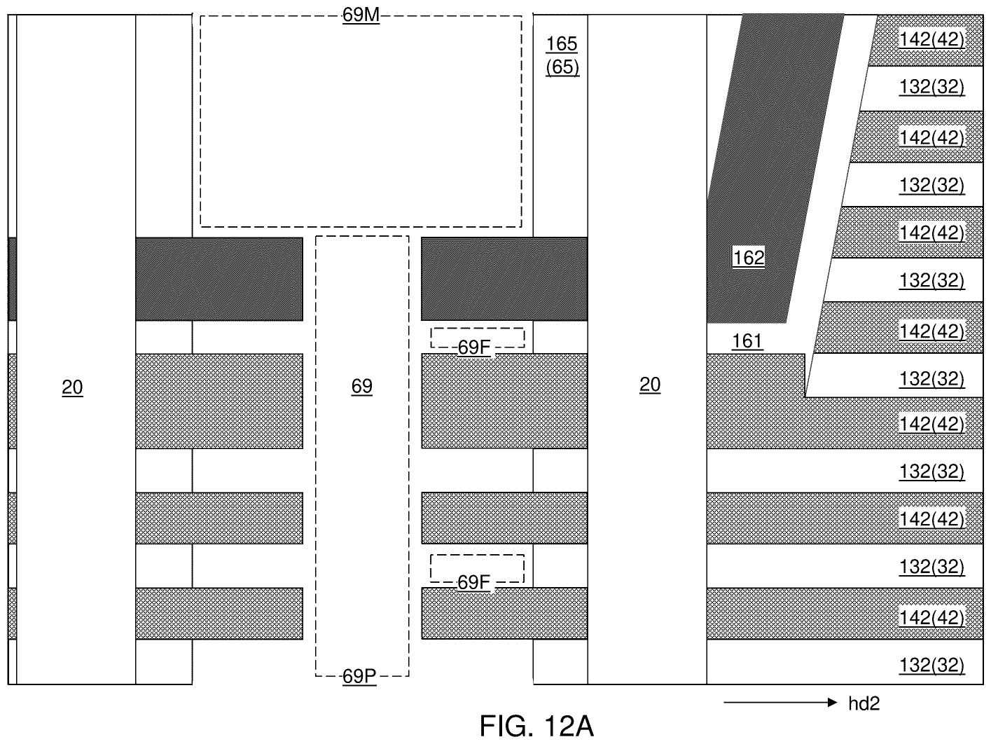

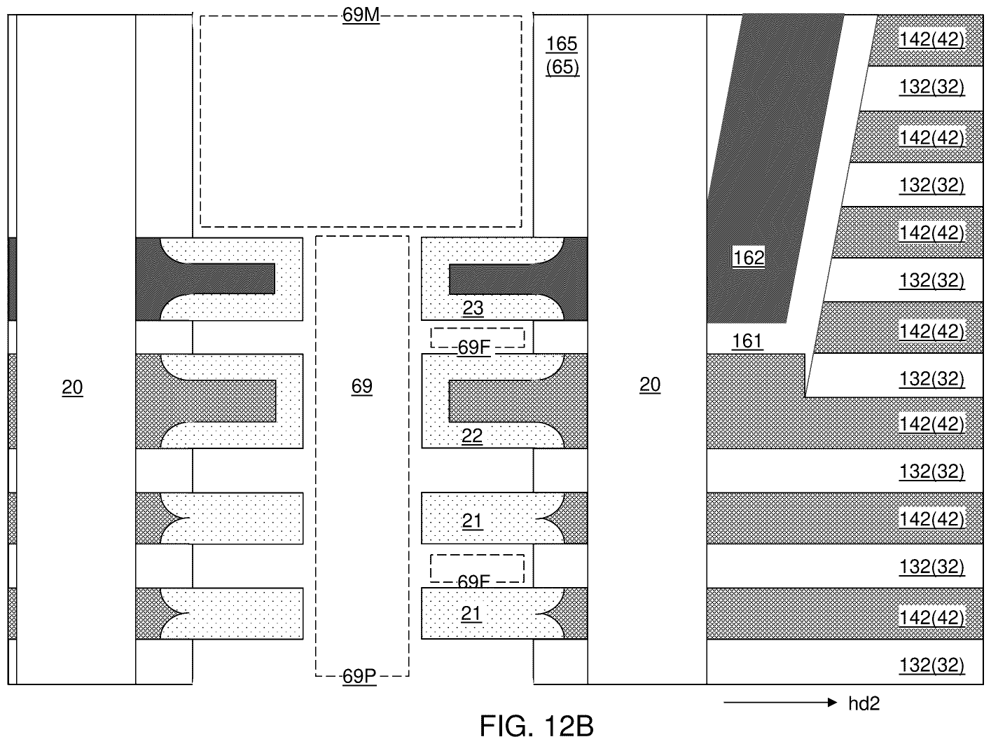

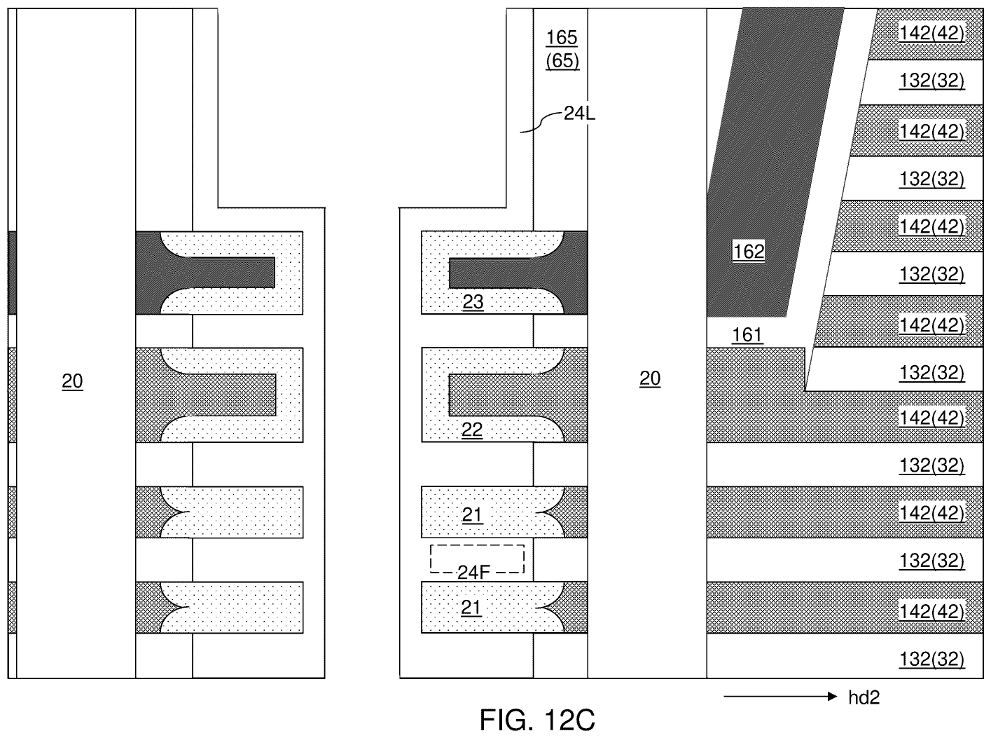

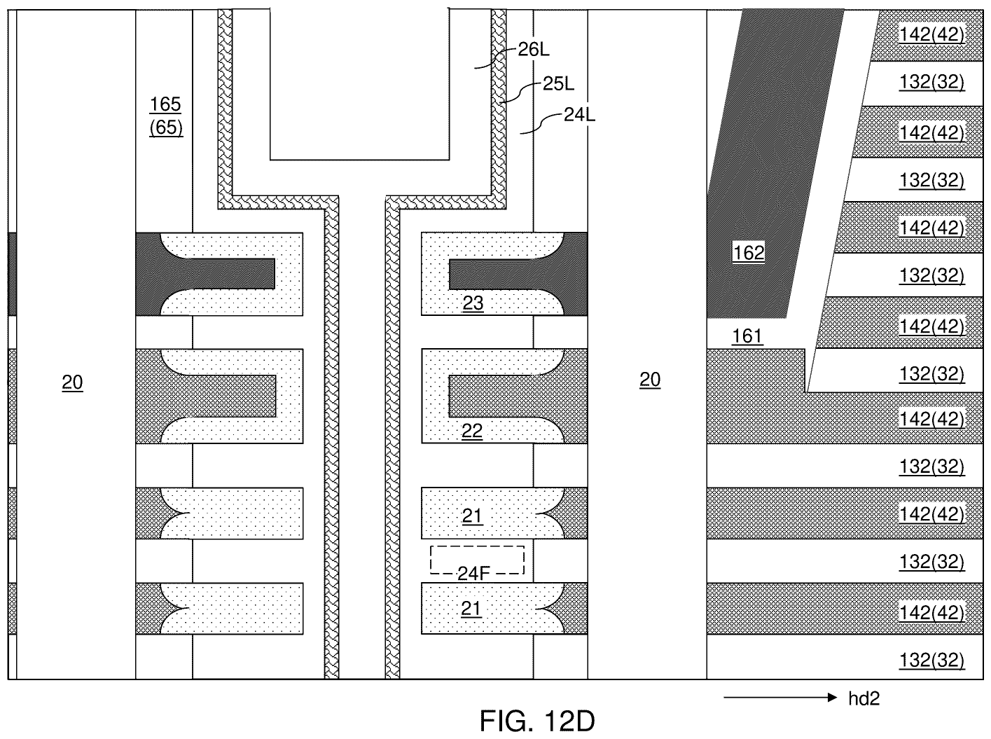

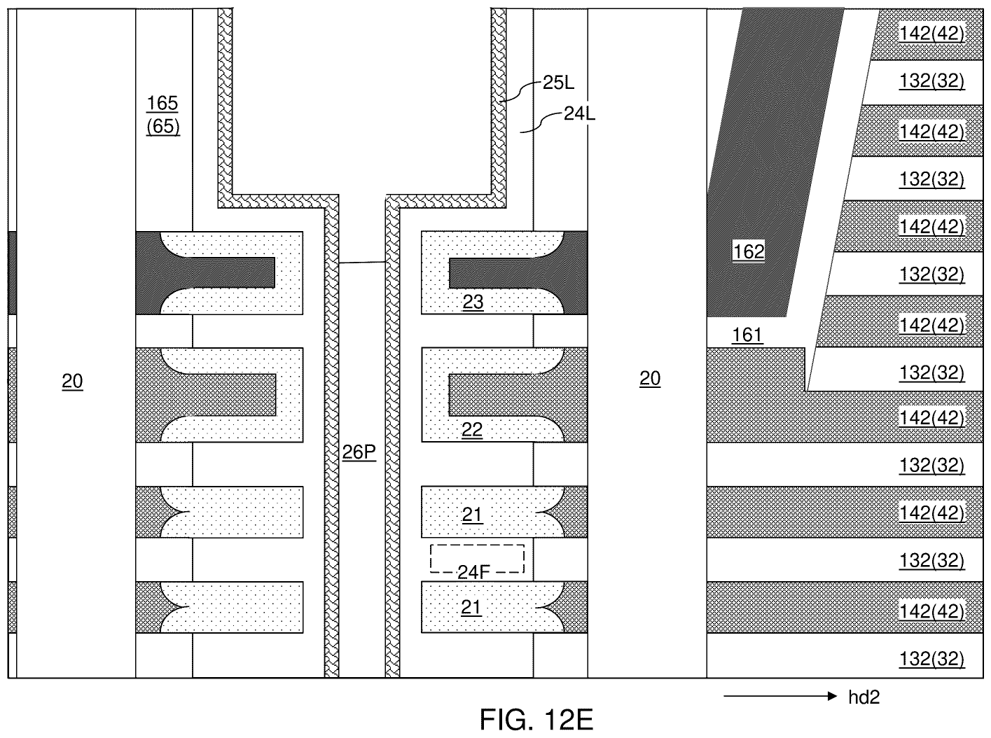

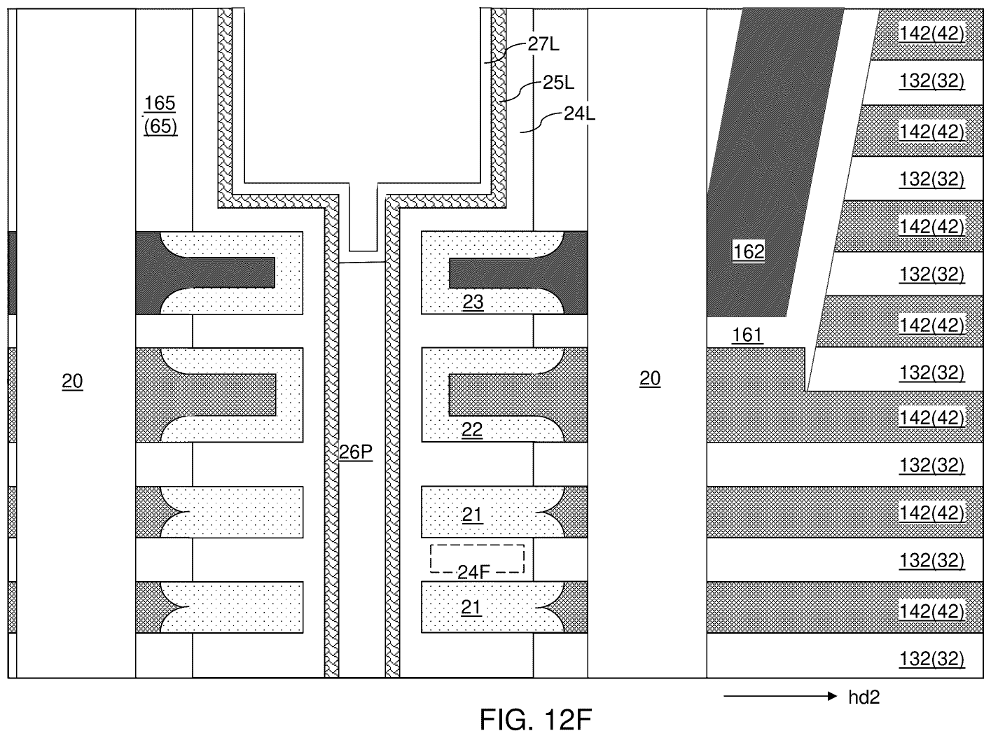

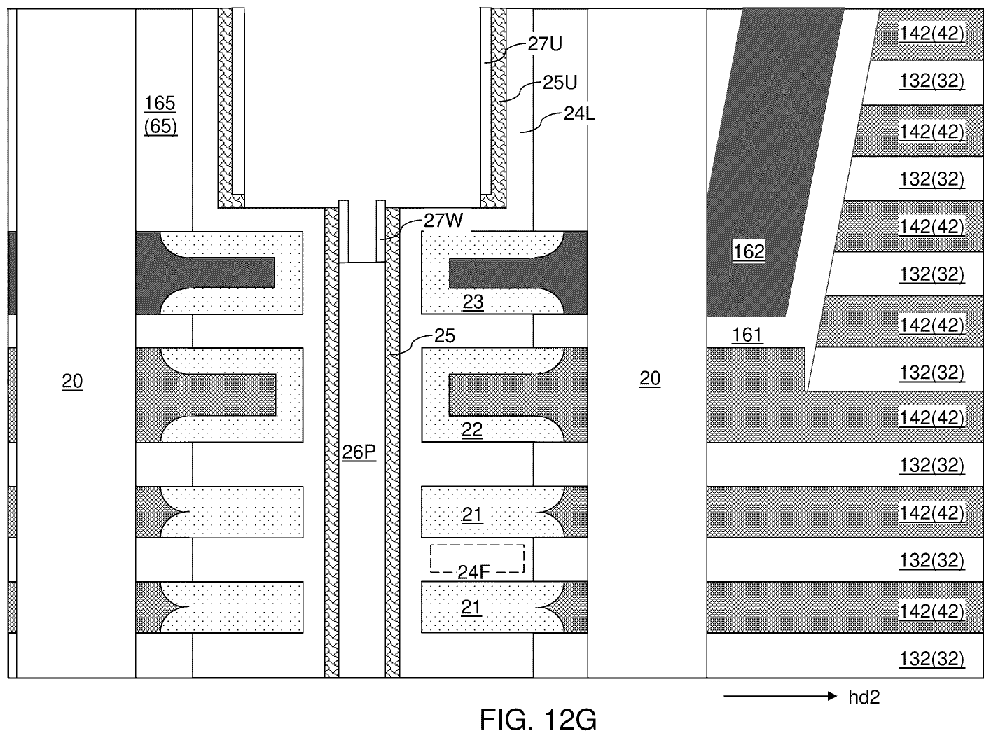

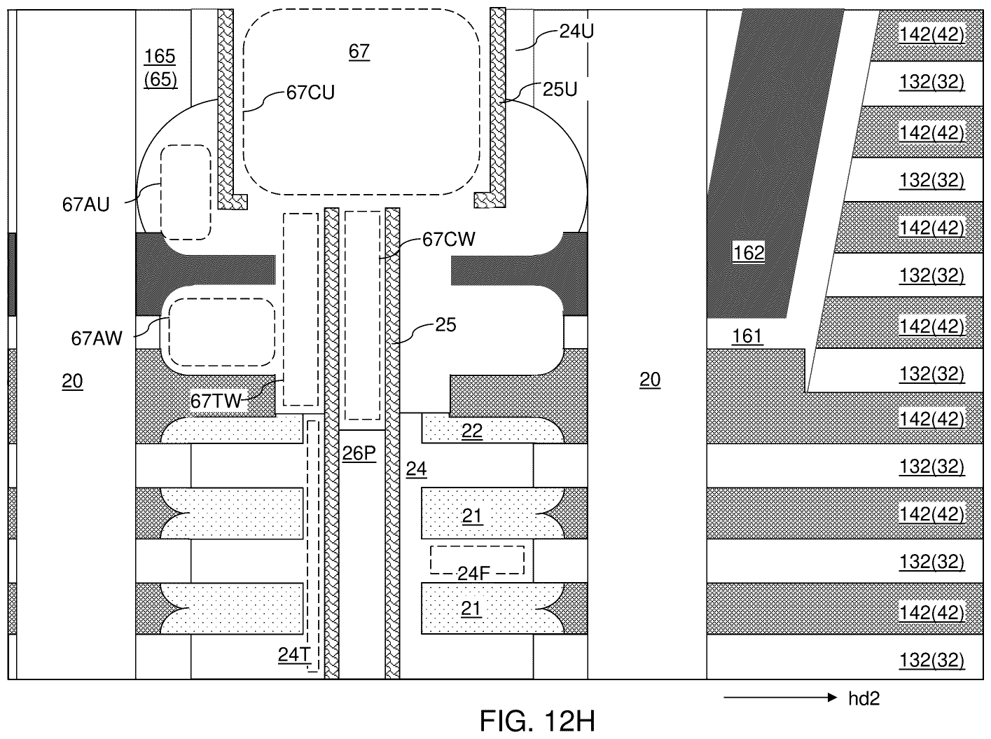

FIGS. 12A-12J are sequential vertical cross-sectional views of a bottom corner of region of the first exemplary structure around a portion of a contact via cavity adjacent to a first-tier silicon nitride buffer layer (162, 262, or 362) during formation of a finned support assembly 84 and a sacrificial contact via structure 68 according to the first embodiment of the present disclosure.

Referring to FIG. 12A, a first selective isotropic etch process can be performed to laterally recess surface portions of the insulating layers 32, the silicon oxide buffer layers (161, 261, 361), and the retro-stepped dielectric material portions 65 around each contact via cavity 69. In an illustrative example, the insulating layers 32, the silicon oxide buffer layers (161, 261, 361), and the retro-stepped dielectric material portions 65 may comprise a respective silicon oxide material (such as undoped silicate glass or a doped silicate glass), and the sacrificial material layers 42 may comprise silicon nitride. In this case, the first selective isotropic etch process may comprise a wet etch process employing dilute hydrofluoric acid. Annular fin cavities 69F are formed in volumes from which portions of the insulating layers 32 are removed during the first selective isotropic etch process. Further, the first selective isotropic etch process can isotropically recess a silicon oxide buffer layer (161, 261, or 361) around each contact via cavity 69. Each contact via cavity 69 can be laterally expanded above a respective silicon nitride buffer layer (162, 262, 362) due to removal of tubular portions of the retro-stepped dielectric material portions 65. The duration of the first selective isotropic etch process can be selected such that the lateral recess distance of the first selective isotropic etch process for the insulating layers 32 is in a range from 100% to 600%, such as from 150% to 400%, of the thickness of each insulating layer 32.

After the first selective isotropic etch process, each contact via cavity 69 may comprise a main cavity portion 69M that is laterally surrounded by at least one retro-stepped dielectric material portion 65, having a respective cylindrical shape, and vertically extending from the horizontal plane including the top surface of the topmost retro-stepped dielectric material portion (such as a third-tier retro-stepped dielectric material portion 365) to a respective annular top surface segment of a silicon nitride buffer layer (162, 262, or 362). Further, each contact via cavity 69 may comprise a pillar cavity portion 69P having a shape of a cylinder and vertically extending from the horizontal plane including the respective annular top surface segment of the silicon nitride buffer layer 162 to the substrate 9. In addition, each contact via cavity 69 may comprise at least one annular fin cavity 69F located at each level of the insulating layers 32 that laterally surrounds the pillar cavity portion 69P, and an additional annular fin cavity 69F that is formed at the level of a silicon oxide buffer layer (161, 261, or 361).

Referring to FIG. 12B, an oxidation process can be performed to convert surface portions of the sacrificial material layers 42 and the silicon nitride buffer layers (162, 262, 362) that are proximal to the contact via cavities 69 into oxidized dielectric material portions. For example, if the sacrificial material layers 42 comprise silicon nitride, the oxidation process can convert surface portions of the sacrificial material layers 42 that are proximal to the contact via cavities 69 into silicon oxide or silicon oxynitride portions having a respective vertically-extending perforation (i.e., an opening) therethrough. A such, each silicon oxide or oxynitride portion that is derived from the sacrificial material layers 42 and the silicon nitride buffer layer (162, 262, 362) is herein referred to as a perforated dielectric portion (21, 22, 23). As used herein, silicon oxynitride refers to any dielectric compound including silicon, nitrogen, and oxygen. If the perforated dielectric portions are oxidized completely, then they comprise silicon oxide. If they are partially oxidized, then they comprise silicon oxynitride, and a nitrogen concentration gradient may be present at least in one portion of each perforated dielectric portion 21 such as an interfacial portion that is proximal to the unoxidized remaining portion of a respective sacrificial material layer 42. In this case, the atomic concentration of nitrogen atoms may decrease within each perforated dielectric portion (21, 22, 23) with a distance from a proximal sacrificial material layer 42 or a silicon nitride buffer layer (162, 262, 362) to which the perforated dielectric portion (21, 22, 23) is adjoined.

The perforated dielectric portions (21, 22, 23) may comprise first-type perforated dielectric portions 21 that are formed by oxidizing portions of the sacrificial material layers 42 that are not thickened, second-type perforated dielectric portions 22 that are formed by oxidizing thickened portions of the sacrificial material layers 42, and third-type perforated dielectric portions 23 that are formed by oxidizing the silicon nitride buffer layers (162, 262, 362). In one embodiment, the oxidation thickness (i.e., the thickness by which the oxidation process proceeds in the sacrificial material layers 42) is less than one half of the thickness of the thickened portions of the sacrificial material layers 42, and is less than one half of the thickness of the silicon nitride buffer layer 162. In this case, each of the second-type perforated dielectric portions 22 and the third-type perforated dielectric portions 23 may be a coupled-flange-shaped silicon oxide or oxynitride portion having a respective shape of a couple flange, i.e., a pair of flanges that are coupled to each other by a connecting cylindrical tube having a lesser lateral extent than each of the flanges.

Surface portions of underlying sacrificial material layers 42 may be oxidized to form additional silicon oxide or oxynitride portions, which are perforated dielectric portions 21 having a respective vertically-extending perforation (i.e., an opening) therethrough. In one embodiment, the oxidation thickness may be greater than one half of the initial thickness (i.e., the thickness of prior to local thickening) of each sacrificial material layer 42. In this case, each of the perforated dielectric portions 21 may have a configuration of an annular plate. Due to the isotropic nature of conversion of the silicon nitride material of the sacrificial material layers 42 to the perforated dielectric portions 21, each perforated dielectric portion 21 may have a pair of convex annular surface segments that are adjoined to each other. The pair of convex annular surface segments may contact a pair of concave annular surface segments of a respective sacrificial material layer 42. As used herein, a convex surface of an element refers to a surface of the element that has a convex cross-sectional profile (i.e., a profile having an outward-protruding curved cross-sectional profile) such that each center of curvature of the surface is located on the side of the element with respect to the surface itself. In contrast, a concave surface of an element refers to a surface of the element that has a concave cross-sectional profile (i.e., a profile having an inward-recessed curved cross-sectional profile) such that each center of curvature of the surface is located on the opposite side (i.e., outside) of the element with respect to the surface. The radius of curvature of the convex annular surface segments may be in a range from 50% of the thickness of each sacrificial material layer 42 to 100% of the thickness of each sacrificial material layer 42.

In summary, surface portions of the sacrificial material layers 42 can be oxidized into perforated dielectric portions (21, 22) by performing an oxidation process after formation of the annular fin cavities 69F. The oxidation process thins segments of the thickened portions of the sacrificial material layers 42 that are proximal to the contact via cavities 69. A segment of each thickened portion of the sacrificial material layers 42 may be thinned underneath a respective annular fin cavity 69F that underlies a silicon nitride buffer layer (162, 262, or 362).

Referring to FIG. 12C, a dielectric material, such as undoped silicate glass or a doped silicate glass, can be conformally deposited in peripheral regions of the contact via cavities 69 to form a dielectric material layer 24L. The dielectric material layer 24L may be deposited by a conformal deposition process, such as a chemical vapor deposition process. The thickness of the dielectric material layer 24L can be greater than one half of the height of each annular fin cavity 69F located at levels of the insulating layers 32 (which is the same as the thickness of each insulating layer 32). The thickness of the dielectric material layer 24L is less than the lateral dimension (such as a diameter) of the pillar cavity portion 69P of each contact via cavity 69. The dielectric material layer 24L can fill the volumes of the annular fin cavities 69F, and thus, a dielectric fin 24F having a shape of an annular plate can be formed within each annular fin cavity 69F.

Referring to FIG. 12D, a semiconductor liner layer 25L can be deposited by a conformal deposition process, such as a chemical vapor deposition process. The semiconductor liner layer 25L comprises a semiconductor material, such as amorphous silicon, polysilicon, or a compound semiconductor material. The thickness of the semiconductor liner layer 25L may be in a range from 5 nm to 60 nm, such as from 10 nm to 40 nm, although lesser and greater thicknesses may also be employed. The semiconductor liner layer 25L may comprise an intrinsic semiconductor material, and/or is not intentionally doped with electrical dopants (such as p-type dopants or n-type dopants). As such, the atomic concentration of electrical dopants in the semiconductor liner layer 25L may be in a range from 1.0×10¹⁰/cm³ to 1.0×10¹⁶/cm³, such as from 1.0×10¹²/cm³ to 1.0×10¹⁵/cm³.

A dielectric fill material, such as undoped silicate glass or a doped silicate glass, can be conformally deposited to form a dielectric fill material layer 26L, which fills remaining volumes of the pillar cavity portions 69P of the contact via cavities 69. Thus, the volumes of the annular fin cavities 69F and the pillar cavity portions 69P of the contact via cavities 69 can be filled with a combination of the dielectric material layer 24L, the semiconductor liner layer 25L, and the dielectric fill material layer 26L.

Referring to FIG. 12E, a second selective isotropic etch process can be performed to isotropically recess the material of the dielectric fill material layer 26L selective to the material of the semiconductor liner layer 25L. For example, a wet etch process employing dilute hydrofluoric acid can be performed to isotropically recess portions of the dielectric fill material layer 26L that overlies the silicon nitride buffer layer (162, 262, 362). The duration of the second selective isotropic etch process can be selected such that surface segments of the semiconductor liner layer 25L are physically exposed above each annular interface between an annular bottom surface segment of the dielectric material layer 24L and an annular top surface segment of an underlying third-type perforated dielectric portion 23. Each remaining pillar-shaped dielectric material portion that is laterally surrounded by a tubular bottom portion of the semiconductor liner layer 25L comprises a cylindrical dielectric pillar 26P. Each cylindrical dielectric pillar 26P may have a cylindrical shape, and may have a respective top surface located at the level of a most proximal horizontally-extending portion of a silicon nitride buffer layer (162, 262, 362).

Referring to FIG. 12F, a silicon oxide liner 27L may be conformally deposited over the cylindrical inner surface and an annular horizontal surface of the semiconductor liner layer 25L. The thickness of the silicon oxide liner 27L may be in a range from 3 nm to 30 nm, although lesser and greater thicknesses may also be employed.

Referring to FIG. 12G, an anisotropic etch process (e.g., a reactive ion etch process) can be performed to remove horizontally-extending portions of the silicon oxide liner 27L and the semiconductor liner layer 25L. A first etch step of the anisotropic etch process can remove horizontally-extending portions of the silicon oxide liner 27L. An upper silicon oxide liner 27U can be formed on the cylindrical inner surface of an upper cylindrical portion of the semiconductor liner layer 25L, and a lower silicon oxide liner 27W can be formed on an upper cylindrical inner surface segment of a lower cylindrical portion of the semiconductor liner layer 25L. A second etch step of the anisotropic etch process can remove horizontally-extending portions of the semiconductor liner layer 25L. Remaining portions of the semiconductor liner layer 25L include a tubular semiconductor liner 25 (which is also referred to as a lower tubular semiconductor liner) that laterally surrounds the cylindrical dielectric pillar 26P, and an additional tubular semiconductor liner 25U (which is also referred to as an upper tubular semiconductor liner). The lower silicon oxide liner 27W contacts an upper cylindrical surface segment of the inner cylindrical sidewall of the tubular semiconductor liner 25. The upper silicon oxide liner 27U contacts an inner cylindrical sidewall of the additional tubular semiconductor liner 25U.

Referring to FIG. 12H, an isotropic etch process can be performed to isotropically etch silicon oxide materials of the upper silicon oxide liner 27U, the lower silicon oxide liner 27W, the cylindrical dielectric pillar 26P, the dielectric material layer 24L, the third-type perforated dielectric portion 23, the second-type perforated dielectric portion 22, and the retro-stepped dielectric material portion 65 selective to the materials of the silicon nitride buffer layer (162, 262, 362) and the sacrificial material layers 42. For example, the isotropic etch process may comprise a wet etch process employing dilute hydrofluoric acid as an etchant. The upper silicon oxide liner 27U and the lower silicon oxide liner 27W can be completely removed by the isotropic etch process. The top surface of the cylindrical dielectric pillar 26P can be vertically recessed by the isotropic etch process. The dielectric material layer 24L can be divided into an upper tubular dielectric liner 24U that laterally surrounds the additional tubular semiconductor liner 25U (i.e., an upper tubular semiconductor liner), and a finned dielectric pillar 24 which comprises a tubular dielectric portion 24T and a plurality of dielectric fins 24F that laterally protrudes from the tubular dielectric portion 24T. The third-type perforated dielectric portion 23 can be completely removed by the isotropic etch process. An upper portion of the second-type perforated dielectric portion 22 can be removed, while a lower portion the second-type perforated dielectric portion 22 may remain underneath a thinned annular portion of a sacrificial material layer 42.

A layer contact via cavity 67 is formed around each opening through a silicon nitride buffer layer (162, 262, 362). Each layer contact via cavity 67 may comprise an upper cylindrical cavity portion 67CU that is laterally surrounded by the additional tubular semiconductor liner 25U (i.e., an upper tubular semiconductor liner), a lower cylindrical cavity portion 67CW that is laterally surrounded by an upper segment of the tubular semiconductor liner 25, a tubular cavity portion 67TW that laterally surrounds the upper segment of the tubular semiconductor liner 25, a lower annular cavity portion 67AW that is located between a thinned annular portion of the silicon nitride buffer layer (162, 262, or 362) and a thinned annular portion of a sacrificial material layer 42, and an upper annular cavity portion 67AU that is located between the thinned annular portion of the silicon nitride buffer layer (162, 262, 362) and a contoured bottom surface segment of the retro-stepped dielectric material portion 65.

Referring to FIG. 12I, an optional oxidation process can be performed to convert an upper portion of the tubular semiconductor liner 25 into a tubular semiconductor oxide liner 28W, and to convert the additional tubular semiconductor liner 25U into an upper tubular semiconductor oxide liner 28U. For example, the tubular semiconductor oxide liner 28W and the upper tubular semiconductor oxide liner 28U may comprise silicon oxide.

The assembly of all material portions that replaces materials of the insulating layers 32 and the sacrificial material layers 42 and underlies an opening in a silicon nitride buffer layer (162, 262, 362) is herein referred to as a finned support assembly 84. The finned support assembly 84 comprises a cylindrical dielectric pillar 26P, a tubular semiconductor liner 25 that laterally surrounds the cylindrical dielectric pillar 26P, a tubular semiconductor oxide liner 28W adjoined to an annular top end of the tubular semiconductor liner 25, a finned dielectric pillar 24 laterally surrounding the tubular semiconductor liner 25 and comprising a tubular dielectric portion 24T and a plurality of dielectric fins 24F that laterally protrude from the tubular dielectric portion 24T, and perforated dielectric portions (21, 22).

Referring to FIG. 12J, a sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material, such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Each sacrificial contact via structure 68 may comprise an upper cylindrical sacrificial material portion 68CU that is laterally surrounded by the upper tubular semiconductor oxide liner 28U, a lower cylindrical sacrificial material portion 68CW that is laterally surrounded by the tubular semiconductor oxide liner 28W, a tubular sacrificial material portion 68TW that laterally surrounds the tubular semiconductor oxide liner 28W, a lower annular sacrificial material portion 68AW that is located between a thinned annular portion of the silicon nitride buffer layer (162, 262, or 362) and a thinned annular portion of a sacrificial material layer 42, and an upper annular sacrificial material portion 68AU that is located between the thinned annular portion of the silicon nitride buffer layer (162, 262, 362) and a contoured bottom surface segment of the retro-stepped dielectric material portion 65.

Referring to FIGS. 13A and 13B, the first exemplary structure is illustrated after formation of in-process contact assemblies 66 within the contact via cavities 69. Each in-process contact assembly 66 comprises a stack of a finned support assembly 84 and a sacrificial contact via structure 68.

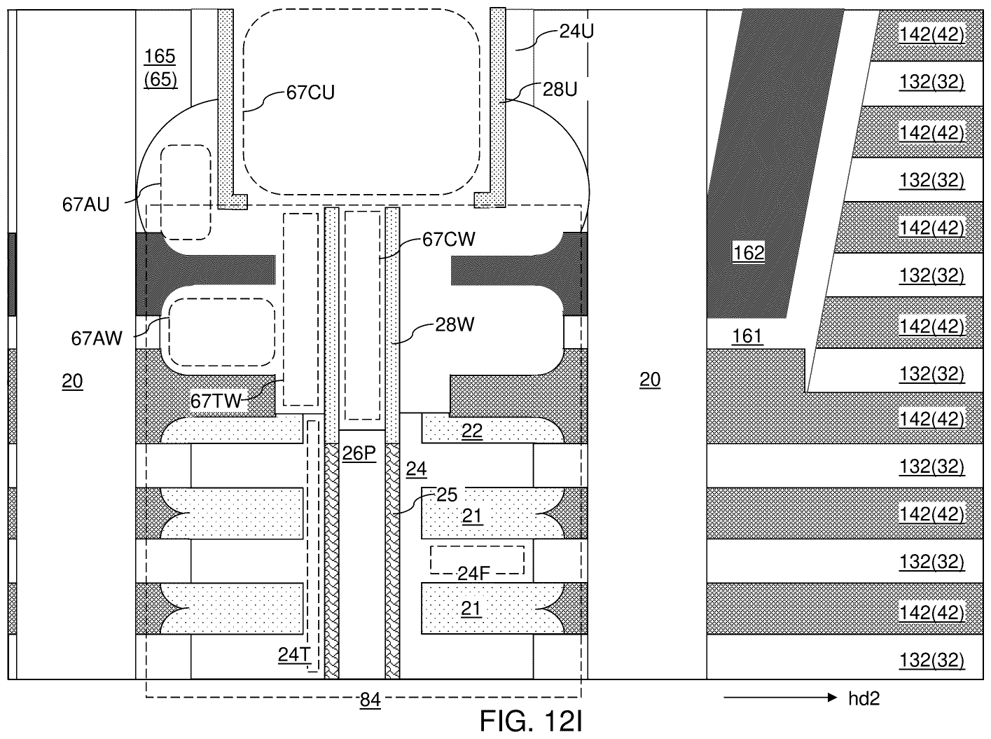

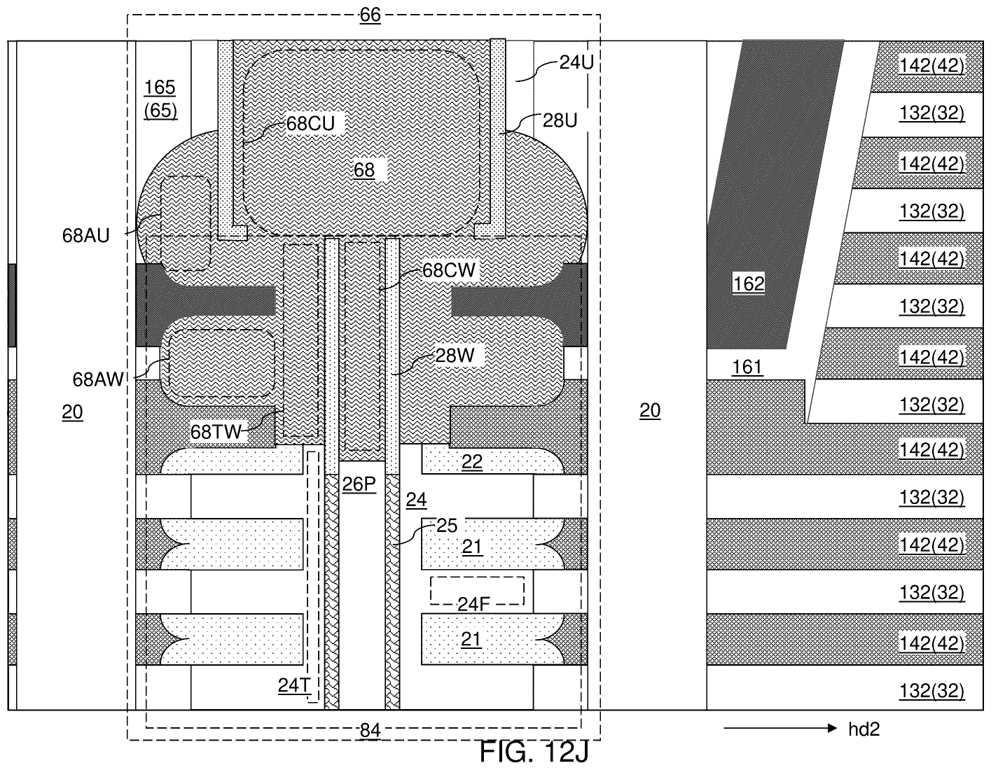

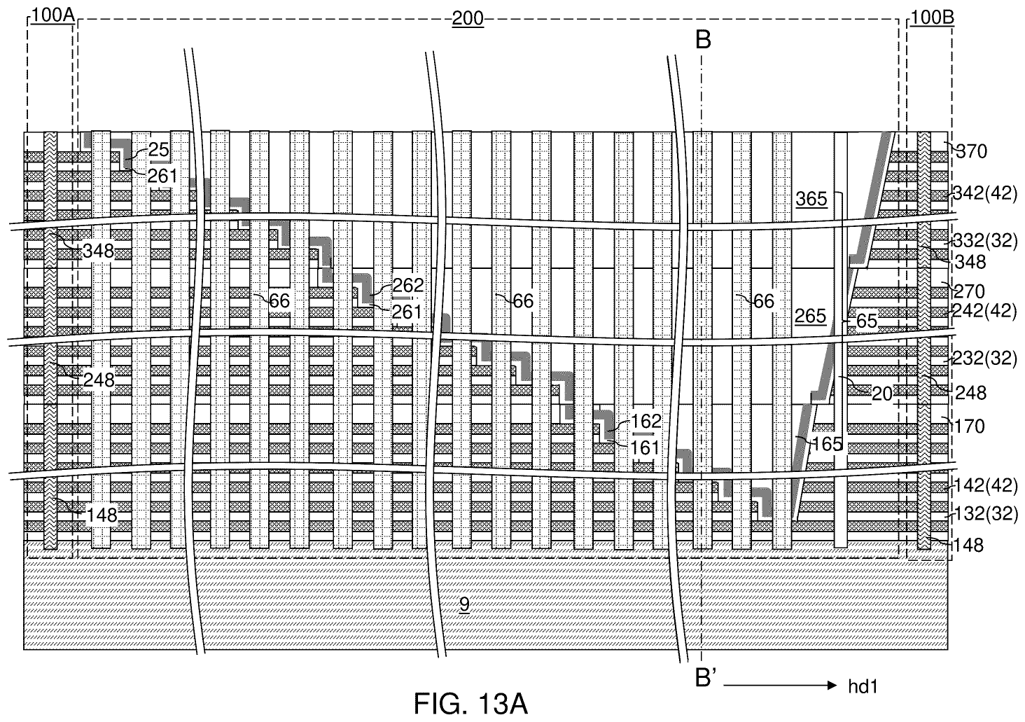

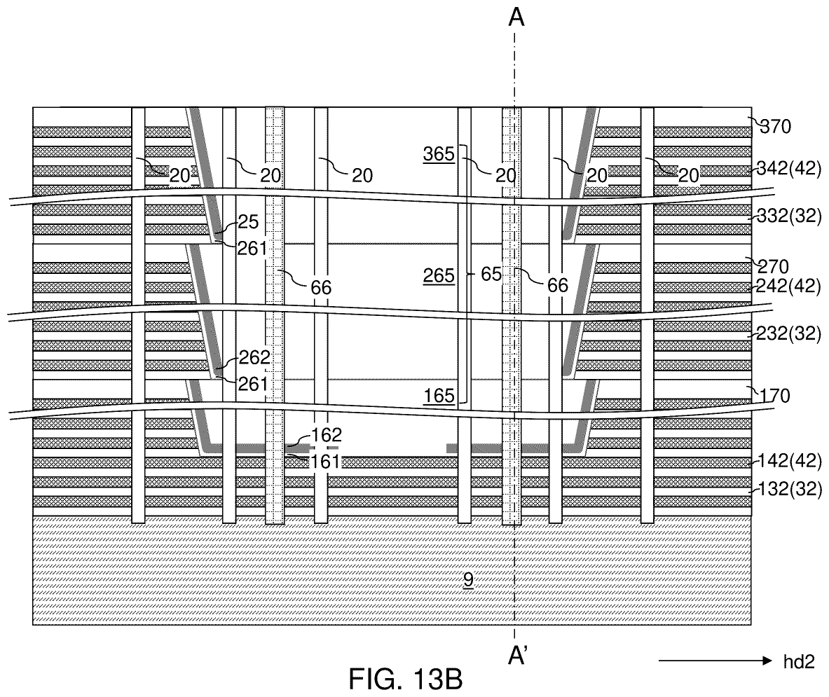

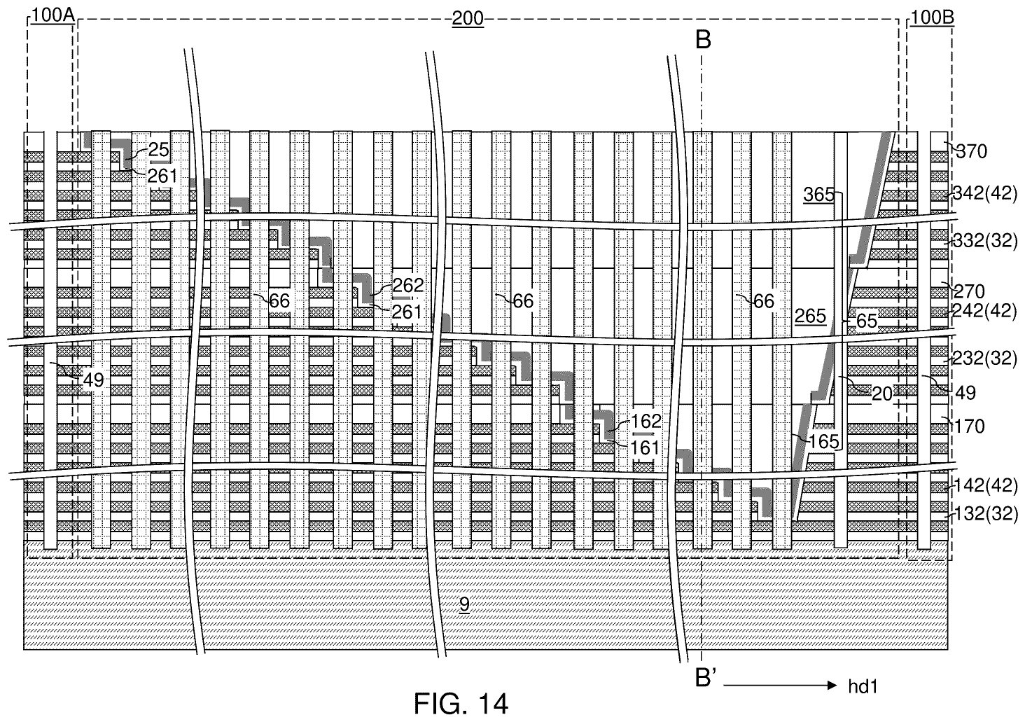

Referring to FIG. 14, a photoresist layer (not shown) can be applied over the third-tier structure, and can be lithographically patterned to cover the inter-array regions 200 without covering the memory array regions 100. The sacrificial fill materials of the sacrificial memory opening fill structures (148, 248, 348) can be removed selective to the materials of the insulating layers 32, the sacrificial material layers 42, and the substrate 9. Memory openings 49 are formed in the voids from which the sacrificial fill materials of the sacrificial memory opening fill structures (148, 248, 348) are removed.

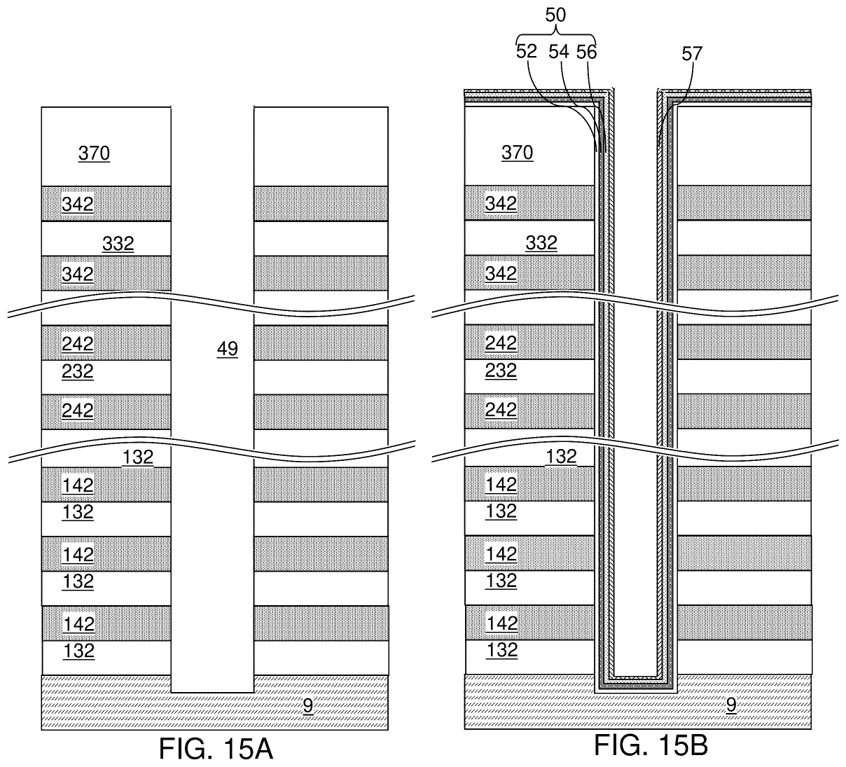

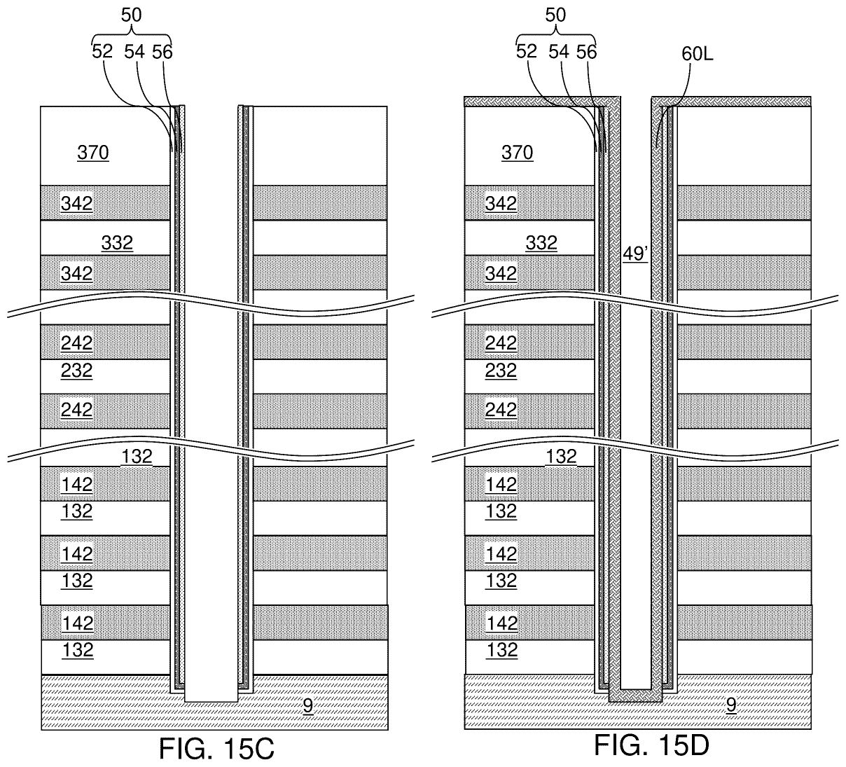

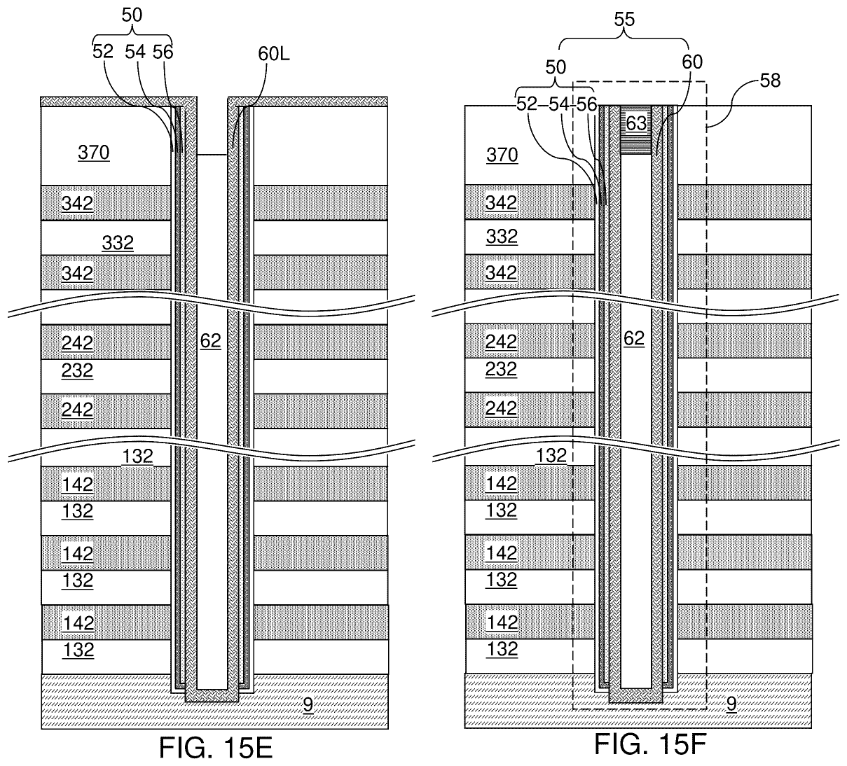

FIGS. 15A-15F illustrate sequential vertical cross-sectional views of a memory opening during formation of a memory opening fill structure according to the first embodiment of the present disclosure.

Referring to FIG. 15A, a memory opening 49 in the first exemplary structure of FIG. 14 is illustrated.

Referring to FIG. 15B, a stack of layers including a blocking dielectric layer 52, a memory material layer 54, a dielectric liner 56, and an optional sacrificial cover layer 57 may be sequentially deposited in the inter-tier memory openings 49. The blocking dielectric layer 52 may include a single dielectric material layer or a stack of a plurality of dielectric material layers. In one embodiment, the blocking dielectric layer may include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the blocking dielectric layer 52 may include a dielectric metal oxide having a dielectric constant greater than 7.9, i.e., having a dielectric constant greater than the dielectric constant of silicon nitride. The thickness of the dielectric metal oxide layer may be in a range from 1 nm to 20 nm, although lesser and greater thicknesses may also be used. The dielectric metal oxide layer may subsequently function as a dielectric material portion that blocks leakage of stored electrical charges to control gate electrodes. In one embodiment, the blocking dielectric layer 52 includes aluminum oxide. Alternatively or additionally, the blocking dielectric layer 52 may include a dielectric semiconductor compound such as silicon oxide, silicon oxynitride, silicon nitride, or a combination thereof.

Subsequently, the memory material layer 54 may be formed. Generally, the memory material layer 54 may comprise any memory material known in the art. In one embodiment, the memory material layer 54 may be a continuous layer or patterned discrete portions of a charge trapping material including a dielectric charge trapping material, which may be, for example, silicon nitride. Alternatively, the memory material layer 54 may include a continuous layer or patterned discrete portions of a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 may have vertically coincident sidewalls, and the memory material layer 54 may be formed as a single continuous layer. Alternatively, the sacrificial material layers 42 may be laterally recessed with respect to the sidewalls of the insulating layers 32, and a combination of a deposition process and an anisotropic etch process may be used to form the memory material layer 54 as a plurality of memory material portions that are vertically spaced apart. The thickness of the memory material layer 54 may be in a range from 2 nm to 20 nm, although lesser and greater thicknesses may also be used.

The dielectric liner 56 includes a dielectric material. In one embodiment, the dielectric liner 56 may comprise a tunneling dielectric layer through which charge tunneling may be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric liner 56 may include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 may include a stack of a first silicon oxide layer, a silicon oxynitride layer, and a second silicon oxide layer, which is commonly known as an ONO stack. In one embodiment, the dielectric liner 56 may include a silicon oxide layer that is substantially free of carbon or a silicon oxynitride layer that is substantially free of carbon. The thickness of the dielectric liner 56 may be in a range from 2 nm to 20 nm, although lesser and greater thicknesses may also be used. The stack of the blocking dielectric layer 52, the memory material layer 54, and the dielectric liner 56 constitutes a memory film 50 that stores memory bits.

The sacrificial cover layer 57 may comprise a sacrificial material that may be subsequently removed selective to the material of the dielectric liner 56. For example, the sacrificial cover layer may comprise a semiconductor material (e.g., amorphous silicon), silicon oxide, or a carbon-based material (such as amorphous carbon or diamond-like carbon). The thickness of the sacrificial cover layer may be in a range from 1 nm to 10 nm, although lesser and greater thicknesses may also be employed.

Referring to FIG. 15C, an anisotropic etch process may be performed to remove horizontal portions of the sacrificial cover layer 57, the dielectric liner 56, the memory material layer 54, and the blocking dielectric layer 52. Remaining cylindrical portions of the sacrificial cover layer 57 may be removed selective to the material of the dielectric liner 56 during the anisotropic etch process, or by an isotropic etch process (such as a wet etch process) or by ashing. Alternatively, if the sacrificial cover layer 57 comprises a semiconductor material (e.g., amorphous silicon), then it may be retained.

Referring to FIG. 15D, a semiconductor channel material layer 60L can be deposited by a conformal deposition process. The semiconductor channel material layer 60L includes a p-doped semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer 60L may have a uniform doping. In one embodiment, the semiconductor channel material layer 60L has a p-type doping in which p-type dopants (such as boron atoms) are present at an atomic concentration in a range from 1.0×10¹²/cm³ to 1.0×10¹⁸/cm³, such as from 1.0×10¹⁴/cm³ to 1.0×10¹⁷/cm³. In one embodiment, the semiconductor channel material layer 60L includes, and/or consists essentially of, boron-doped amorphous silicon or boron-doped polysilicon. In another embodiment, the semiconductor channel material layer 60L has an n-type doping in which n-type dopants (such as phosphor atoms or arsenic atoms) are present at an atomic concentration in a range from 1.0×10¹²/cm³ to 1.0×10¹⁸/cm³, such as from 1.0×10¹⁴/cm³ to 1.0×10¹⁷/cm³. The semiconductor channel material layer 60L may be formed by a conformal deposition method such as low pressure chemical vapor deposition (LPCVD). The thickness of the semiconductor channel material layer 60L may be in a range from 2 nm to 10 nm, although lesser and greater thicknesses may also be used. A cavity 49′ is formed in the volume of each inter-tier memory opening 49 that is not filled with the deposited material layers (52, 54, 56, 60L).

Referring to FIG. 15E, in case the cavity 49′ in each memory opening is not completely filled by the semiconductor channel material layer 60L, a dielectric core layer may be deposited in the cavity 49′ to fill any remaining portion of the cavity 49′ within each memory opening. The dielectric core layer includes a dielectric material such as silicon oxide or organosilicate glass. The dielectric core layer may be deposited by a conformal deposition method such as low pressure chemical vapor deposition (LPCVD), or by a self-planarizing deposition process such as spin coating. The horizontal portion of the dielectric core layer overlying the top second insulating layer 232 may be removed, for example, by a recess etch. The recess etch continues until top surfaces of the remaining portions of the dielectric core layer are recessed to a height between the top and bottom surfaces of the second-tier insulating cap layer 270. Each remaining portion of the dielectric core layer constitutes a dielectric core 62.

Referring to FIG. 15F, a doped semiconductor material having a doping of a second conductivity type may be deposited in cavities overlying the dielectric cores 62. The second conductivity type is the opposite of the first conductivity type. For example, if the first conductivity type is p-type, the second conductivity type is n-type, and vice versa. Portions of the deposited doped semiconductor material, the semiconductor channel material layer 60L, the dielectric liner 56, the memory material layer 54, and the blocking dielectric layer 52 that overlie the horizontal plane including the top surface of the second-tier insulating cap layer 270 may be removed by a planarization process such as a chemical mechanical planarization (CMP) process.

Each remaining portion of the doped semiconductor material of the second conductivity type constitutes a drain region 63. The dopant concentration in the drain regions 63 may be in a range from 5.0×10¹⁸/cm³ to 2.0×10²¹/cm³, although lesser and greater dopant concentrations may also be used. The doped semiconductor material may be, for example, doped polysilicon.

Each remaining portion of the semiconductor channel material layer 60L constitutes a vertical semiconductor channel 60 through which electrical current may flow when a vertical NAND device including the vertical semiconductor channel 60 is turned on. A dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which may store electrical charges with a macroscopic retention time. In some embodiments, a blocking dielectric layer 52 may not be present in the memory film 50 at this step, and a blocking dielectric layer may be subsequently formed after formation of lateral recesses. As used herein, a macroscopic retention time refers to a retention time suitable for operation of a memory device as a permanent memory device such as a retention time in excess of 24 hours.

Each combination of a memory film 50 and a vertical semiconductor channel 60 (which is a vertical semiconductor channel) within an inter-tier memory opening 49 constitutes a memory stack structure 55. The memory stack structure 55 is a combination of a vertical semiconductor channel 60, a dielectric liner 56, a plurality of memory elements comprising portions of the memory material layer 54, and an optional blocking dielectric layer 52. The memory stack structures 55 can be formed through memory array regions 100 of the first and second vertically alternating sequences in which all layers of the first and second vertically alternating sequences are present. Each combination of a memory stack structure 55, a dielectric core 62, and a drain region 63 within an inter-tier memory opening 49 constitutes a memory opening fill structure 58. Generally, memory opening fill structures 58 are formed within the memory openings 49. Each of the memory opening fill structures 58 comprises a respective memory film 50 and a respective vertical semiconductor channel 60.

In one embodiment, each of the memory stack structures 55 comprises vertical NAND string including the respective vertical stack of memory elements (comprising portions of a memory material layer 54 located at levels of the sacrificial material layers 42) and a vertical semiconductor channel 60 that vertically extend through the sacrificial material layers 42 adjacent to the respective vertical stack of memory elements.

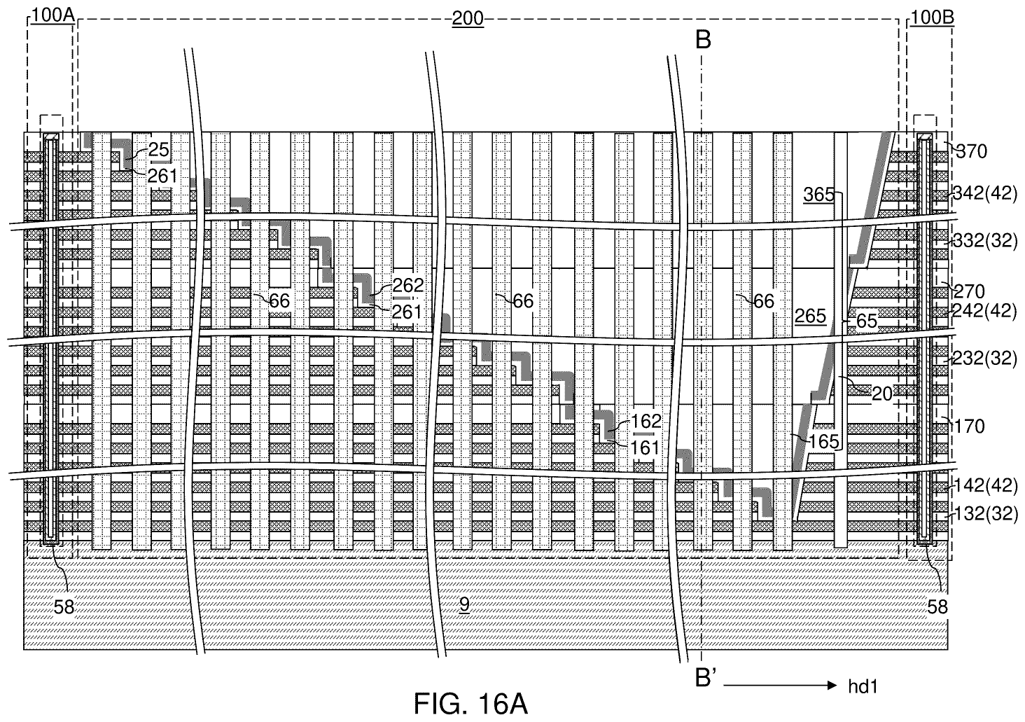

Referring to FIGS. 16A and 16B, the first exemplary structure is illustrated after the processing steps of FIG. 15F, i.e., after formation of the memory opening fill structures 58 in the memory openings 49. In one embodiment, support pillar structures (not shown) may be formed in the support openings. Generally, each of the memory opening fill structures 58 comprises a respective vertical stack of memory elements located at levels of the electrically conductive layers 46 within the plurality of tier structures, and further comprises a respective vertical semiconductor channel 60 that vertically extends through the plurality of tier structures.

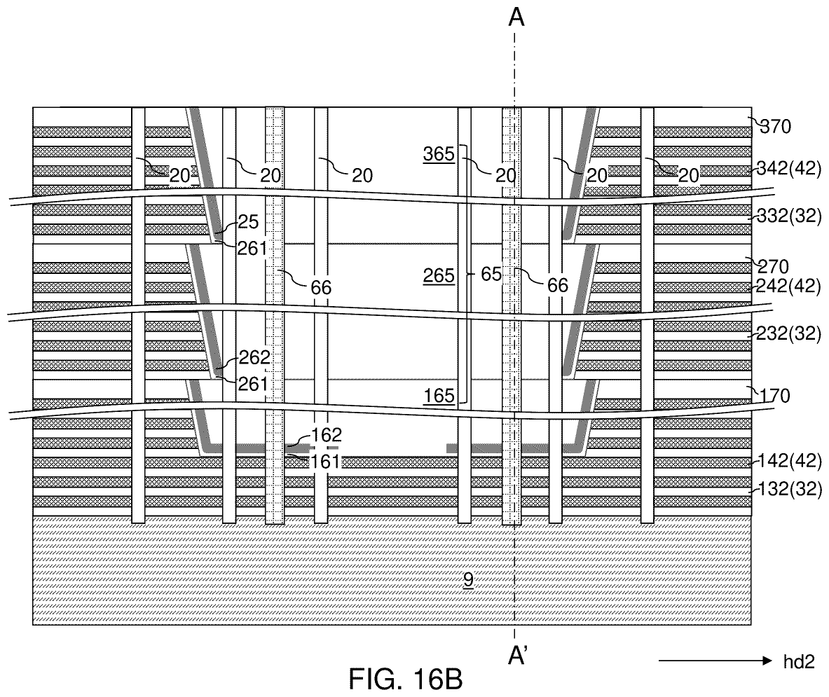

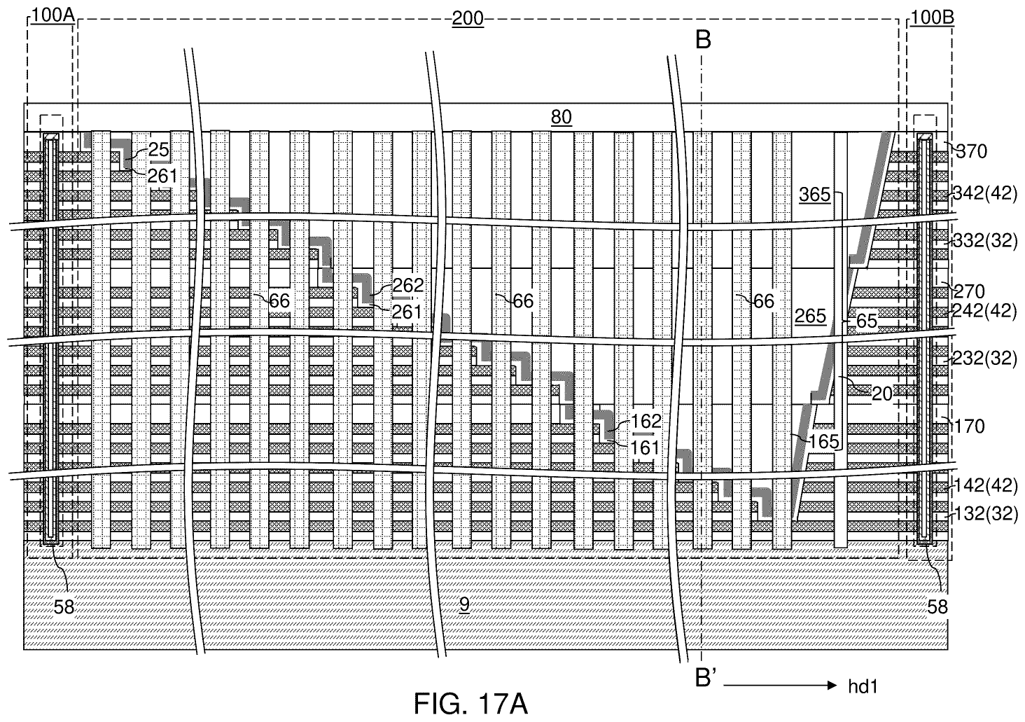

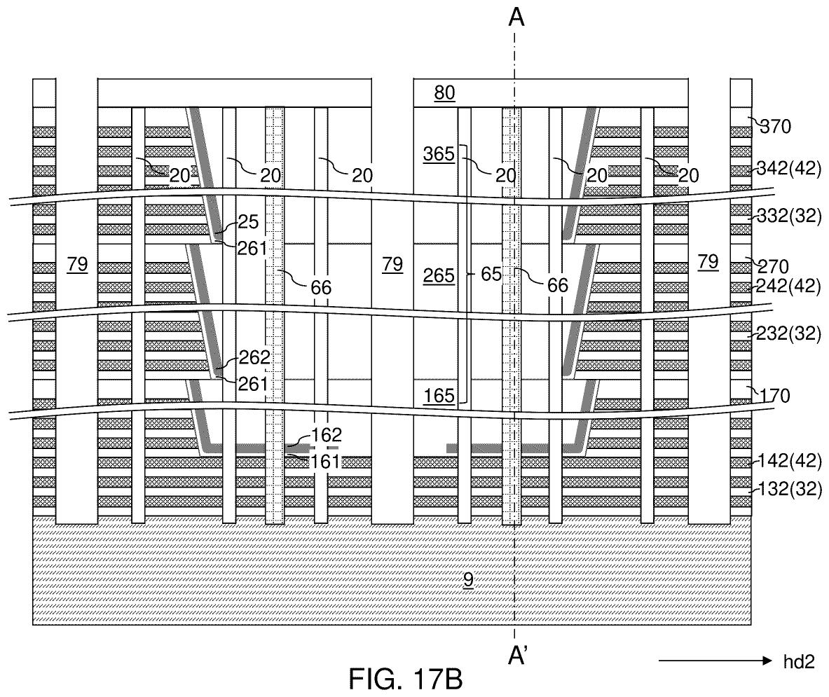

Referring to FIGS. 17A and 17B, a contact-level dielectric layer 80 can be deposited over the third-tier insulating cap layer 370 and the third-tier retro-stepped dielectric material portions 365. The contact-level dielectric layer 80 comprises a dielectric material such as silicon oxide, and may have a thickness in a range from 100 nm to 800 nm, although lesser and greater thicknesses may also be employed.

A photoresist layer can be applied over the contact-level dielectric layer 80, and can be lithographically patterned to form elongated openings that laterally extend along the first horizontal direction hd1. The elongated openings can be formed in areas in which the memory opening fill structure 58, the support pillar structures 20, and the in-process contact assemblies 66 are not present. An anisotropic etch process can be performed to transfer the pattern of the elongated openings through the contact-level dielectric layer 80 and the vertically alternating sequences (32, 42) of the insulating layers 32 and the sacrificial material layers 42.

Lateral isolation trenches 79 can be formed in the voids formed by removal of the material portions of the contact-level dielectric layer 80 and the vertically alternating sequences. Each of the vertically alternating sequences is divided into a respective set of alternating stacks {(132, 142), (232, 242), (332, 342)} of insulating layers 32 and sacrificial material layers 42 that are laterally spaced apart along a second horizontal direction hd2. For example, the first vertically alternating sequence is divided into first-tier alternating stacks of first-tier insulating layers 132 and first-tier sacrificial material layers 142, the second vertically alternating sequence is divided into second-tier alternating stacks of second-tier insulating layers 232 and second-tier sacrificial material layers 242, and the third vertically alternating sequence is divided into third-tier alternating stacks of third-tier insulating layers 332 and third-tier sacrificial material layers 342. The locations of the lateral isolation trenches 79 may be the same as the locations of the lateral isolation trench fill structures 76 illustrated in FIGS. 1A-1E.

The lateral isolation trenches 79 may comprise first lateral isolation trenches 79 that cut through the retro-stepped dielectric material portion (165, 265, 365) and second lateral isolation trenches 79 that do not cut through the retro-stepped dielectric material portion (165, 265, 365). In one embodiment, each first lateral isolation trench 79 divides each retro-stepped dielectric material portion (165, 265, 365) into a respective pair of retro-stepped dielectric material portions (such as first-tier retro-stepped dielectric material portions 265, second-tier retro-stepped dielectric material portions 265 and/or third-tier retro-stepped dielectric material portions 365). Generally, a plurality of tier structures that are vertically stacked can be formed over a substrate 9. Each tier structure within the plurality of tier structures comprises a respective set of alternating stacks of insulating layers 32 and sacrificial material layers 42.

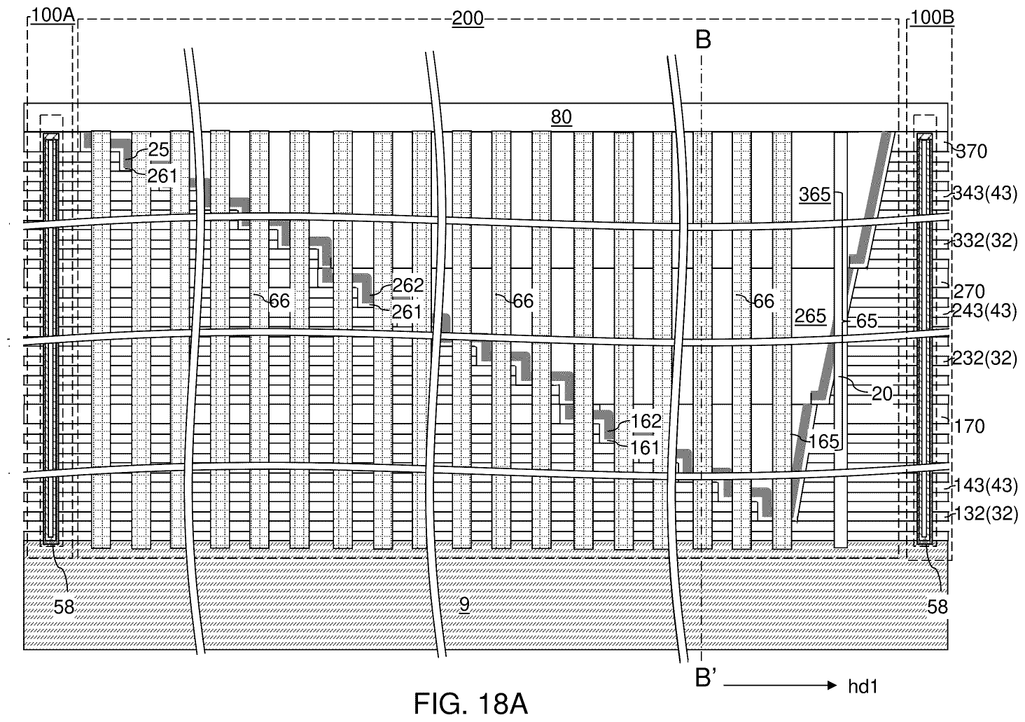

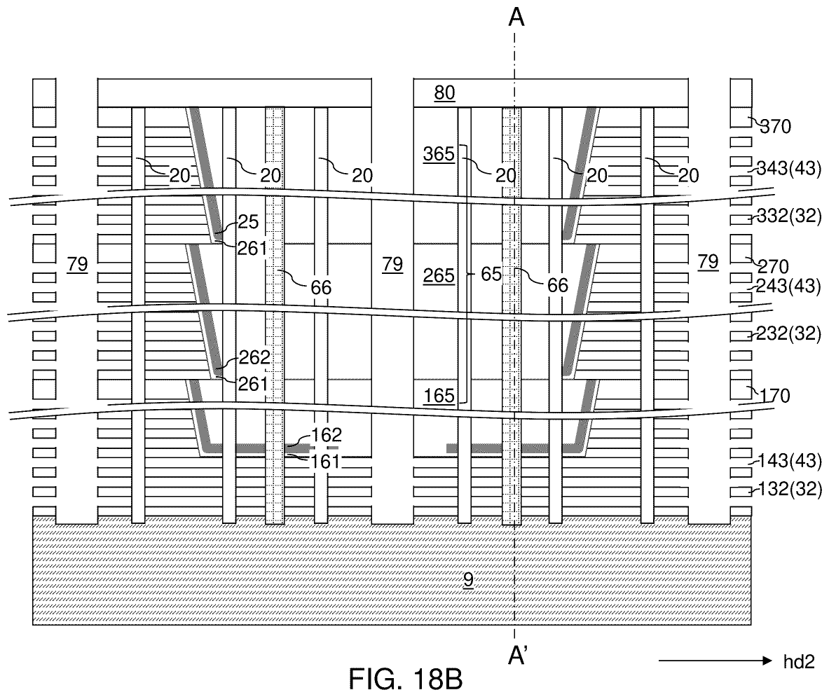

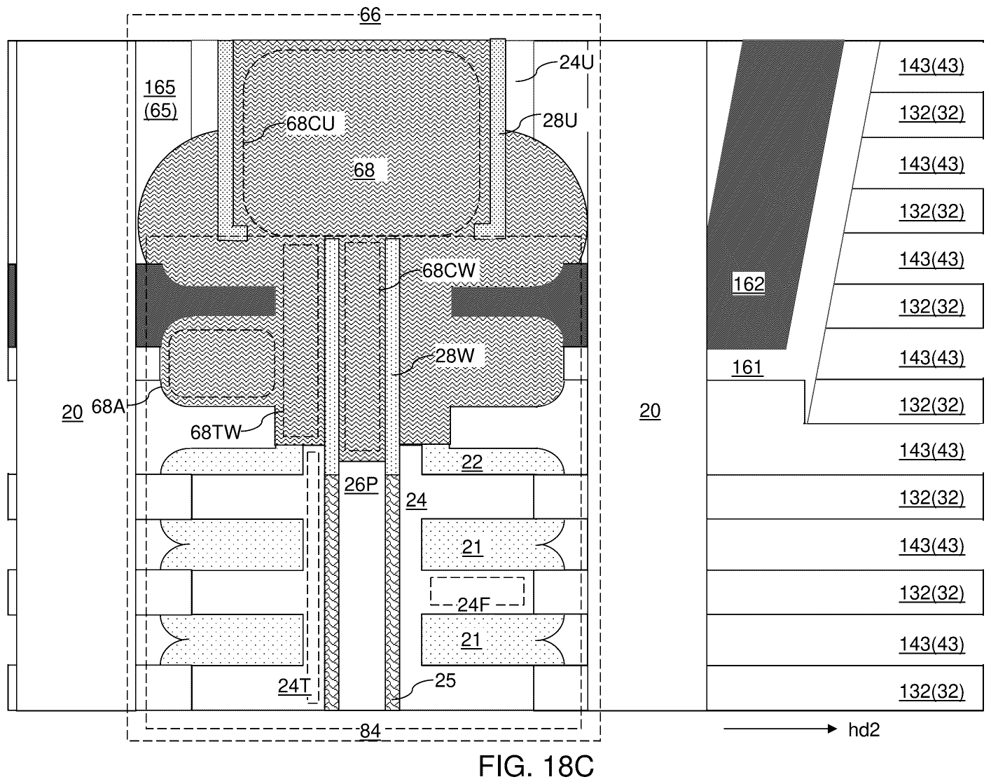

Referring to FIGS. 18A-18C, the sacrificial material layers 42 may be isotropically etched selective to the insulating layers 32 and the retro-stepped dielectric material portions 65 by supplying an isotropic etchant into the lateral isolation trenches 79. Specifically, the sacrificial material layers 42 may be isotropically etched selective to the insulating layers 32, the retro-stepped dielectric material portions (165, 265, 365), and the substrate 9 by supplying an isotropic etchant into the lateral isolation trenches 79. In one embodiment, an etchant that selectively etches the materials of the sacrificial material layers 42 with respect to the materials of the insulating layers 32, the retro-stepped dielectric material portions (165, 265, 365), and the material of the outermost layer of the memory films 50 may be introduced into the lateral isolation trenches, for example, using an isotropic etch process.

The isotropic etch process may be a wet etch process using a wet etch solution, or may be a gas phase (dry) etch process in which the etchant is introduced in a vapor phase into the lateral isolation trench. For example, if the sacrificial material layers 42 comprise silicon nitride, and if the insulating layers 32, the retro-stepped dielectric material portions (165, 265, 365), and the outermost layer of the memory films 50 comprise silicon oxide materials, the etch process may comprise a wet etch tank employing hot phosphoric acid, which etches silicon nitride selective to silicon oxide, silicon, and various other materials used in the art.

Lateral recesses 43 are formed in volumes from which the sacrificial material layers 42 are removed. The lateral recesses 43 include first lateral recesses 143 that are formed in volumes from which the first-tier sacrificial material layers 142 are removed, second lateral recesses 243 that are formed in volumes from which the second-tier sacrificial material layers 242 are removed, and third lateral recesses 343 that are formed in volumes from which the third-tier sacrificial material layers 342 are removed. Each of the lateral recesses 43 may be a laterally extending cavity having a lateral dimension that is greater than the vertical extent of the cavity. In other words, the lateral dimension of each of the lateral recesses 43 may be greater than the height of the respective lateral recess. A plurality of lateral recesses 43 may be formed in the volumes from which the material of the sacrificial material layers 42 is removed. Each of the lateral recesses 43 may extend substantially parallel to the top surface of the substrate 9. A lateral recess 43 may be vertically bounded by a top surface of an underlying insulating layer 32 and a bottom surface of an overlying insulating layer 32.

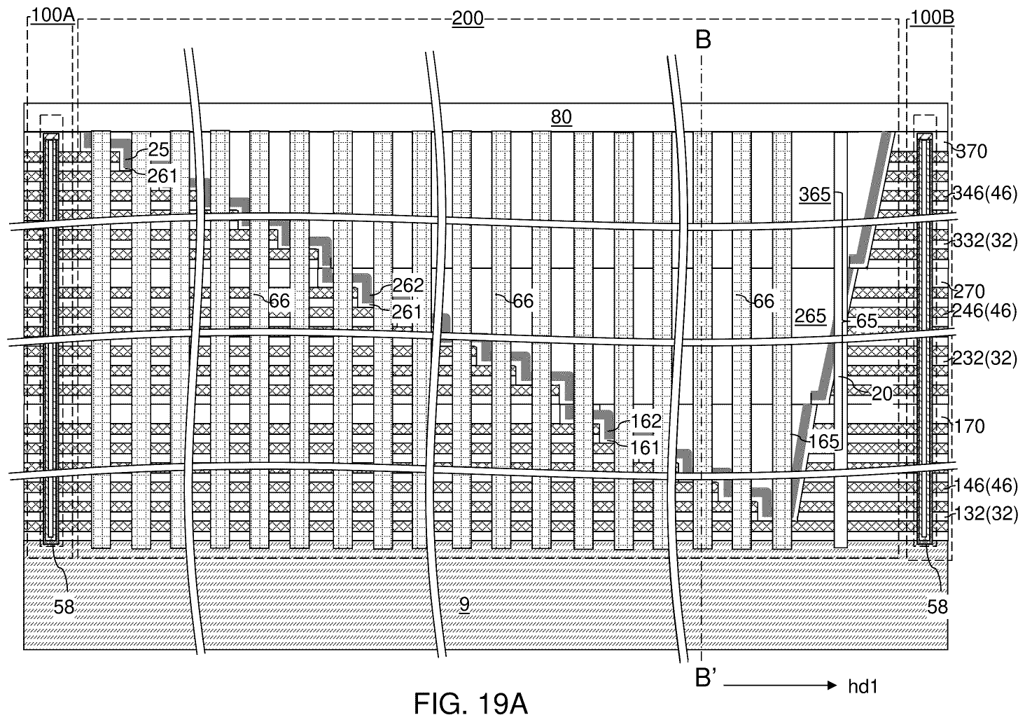

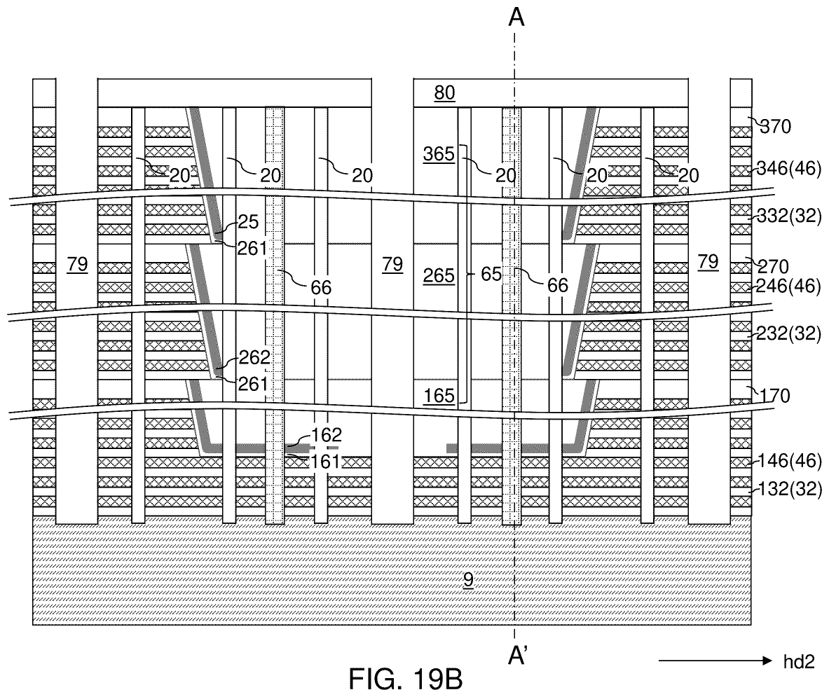

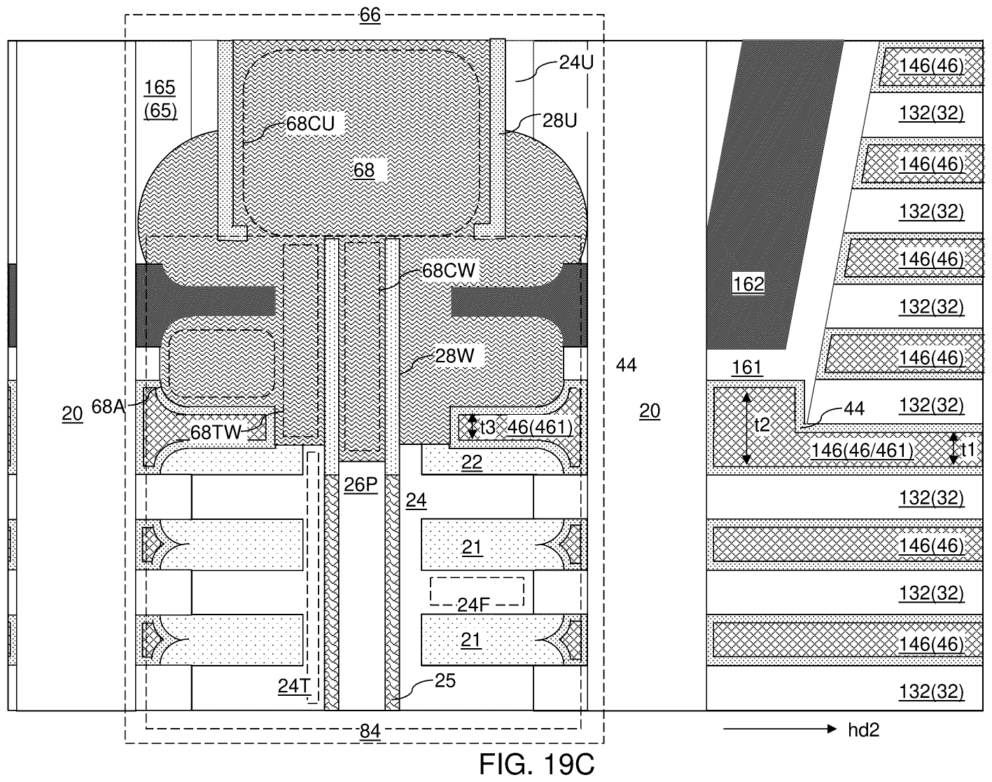

Referring to FIGS. 19A-19C, an optional outer blocking dielectric layer 44 may be optionally deposited in the lateral recesses 43 and the lateral isolation trenches 79. The outer blocking dielectric layer 44 includes a dielectric material such as a dielectric metal oxide (e.g., aluminum oxide), silicon oxide, or a combination thereof.

Electrically conductive layers 46 may be deposited in remaining volumes of the lateral recesses 43 by performing a conformal deposition process in which a precursor gas for a conductive material of the electrically conductive layers 46 is supplied into the lateral recesses 43 through the lateral isolation trenches 79. At least one conductive material may be deposited in the plurality of lateral recesses 43, on the sidewalls of the lateral isolation trenches, and over the topmost tier structure. The at least one conductive material may be deposited by a conformal deposition method, which may be, for example, chemical vapor deposition (CVD), atomic layer deposition (ALD), electroless plating, electroplating, or a combination thereof. The at least one conductive material may include an elemental metal, an intermetallic alloy of at least two elemental metals, a conductive nitride of at least one elemental metal, a conductive metal oxide, a conductive doped semiconductor material, a conductive metal-semiconductor alloy such as a metal silicide, alloys thereof, and combinations or stacks thereof.

In one embodiment, the at least one conductive material may include at least one metallic material, i.e., an electrically conductive material that includes at least one metallic element. Non-limiting exemplary metallic materials that may be deposited in the lateral recesses 43 include tungsten, tungsten nitride, titanium, titanium nitride, tantalum, tantalum nitride, cobalt, and ruthenium. For example, the at least one conductive material may include a conductive metallic nitride liner that includes a conductive metallic nitride material such as TiN, TaN, WN, or a combination thereof, and a conductive fill material such as W, Co, Ru, Mo, Cu, or combinations thereof. In one embodiment, the at least one conductive material for filling the lateral recesses 43 may be a combination of titanium nitride layer and a tungsten fill material.

Electrically conductive layers 46 may be formed in the lateral recesses 43 by deposition of the at least one conductive material. A plurality of first-tier electrically conductive layers 146 may be formed in the plurality of first lateral recesses 143, a plurality of second-tier electrically conductive layers 246 may be formed in the plurality of second lateral recesses 243, a plurality of third-tier electrically conductive layers 346 may be formed in the plurality of third lateral recesses 343, and a continuous metallic material layer (not shown) may be formed on the sidewalls of each lateral isolation trench and over the topmost tier structure. Each of the electrically conductive layers 46 may include a respective conductive metallic nitride liner and a respective conductive fill material. Thus, the sacrificial material layers 42 may be replaced with the electrically conductive layers 46, respectively. Specifically, each first-tier sacrificial material layer 142 may be replaced with an optional portion of the outer blocking dielectric layer and a first electrically conductive layer 146, each second-tier sacrificial material layer 242 may be replaced with an optional portion of the outer blocking dielectric layer and a second electrically conductive layer 246, and each third-tier sacrificial material layer 342 may be replaced with an optional portion of the outer blocking dielectric layer and a third electrically conductive layer 346. A backside cavity is present in the portion of each lateral isolation trench 79 that is not filled with the continuous metallic material layer.

The continuous metallic material layer is formed at peripheral regions of the lateral isolation trenches 79 and over the plurality of tier structures during formation of the electrically conductive layers 46. Residual conductive material of the continuous metallic material layer may be removed from inside the lateral isolation trenches 79 and from above the plurality of tier structures. Specifically, the deposited metallic material of the continuous metallic material layer may be etched back from the sidewalls of each lateral isolation trench and from above the topmost tier structure, for example, by an anisotropic or isotropic etch. Each remaining portion of the deposited metallic material in the first lateral recesses constitutes a first electrically conductive layer 146. Each remaining portion of the deposited metallic material in the second lateral recesses constitutes a second electrically conductive layer 246. Each remaining portion of the deposited metallic material in the third lateral recesses constitutes a third electrically conductive layer 346. Sidewalls of the electrically conductive layers 46 may be physically exposed to a respective lateral isolation trench 79.

Each electrically conductive layer 46 may be a conductive sheet including openings therein. A first subset of the openings through each electrically conductive layer 46 may be filled with memory opening fill structures 58. A second subset of the openings through each electrically conductive layer 46 may be filled with the support pillar structures 20.

A subset of the electrically conductive layers 46 may comprise word lines for the memory elements. The memory-level assembly is located over the substrate 9. The memory-level assembly includes at least one alternating stack (132, 146, 232, 246, 332, 346) and memory stack structures 55 vertically extending through the at least one alternating stack (132, 146, 232, 246, 332, 346). Each of the memory stack structures 55 comprises a vertical stack of memory elements located at each level of the electrically conductive layers 46.

Generally, the sacrificial material layers 42 are replaced with the electrically conductive layers 46, and an alternating stack (32, 46) of insulating layers 32 and electrically conductive layers 46 is provided. The alternating stack (32, 46) comprises a staircase region in which lateral extents of the electrically conductive layer 46 vary with a vertical distance from a horizontal plane including a bottommost surface of the alternating stack (32, 46). A retro-stepped dielectric material portion 65 having a planar top surface overlies the alternating stack (32, 46) in the staircase region. For each in-process contact assembly 66, a first electrically conductive layer 461 is provided which replaces a respective sacrificial material layers 42. The first electrically conductive layer 461 comprises a first portion located outside the staircase region and having a first thickness t1, a second portion located around the in-process contact assembly 66 and having a second thickness t2 that is greater than the first thickness t1, and a third portion that replaces a thinned segment of the respective sacrificial material layers 42 and has a third thickness t3 that is less than the second thickness t2.

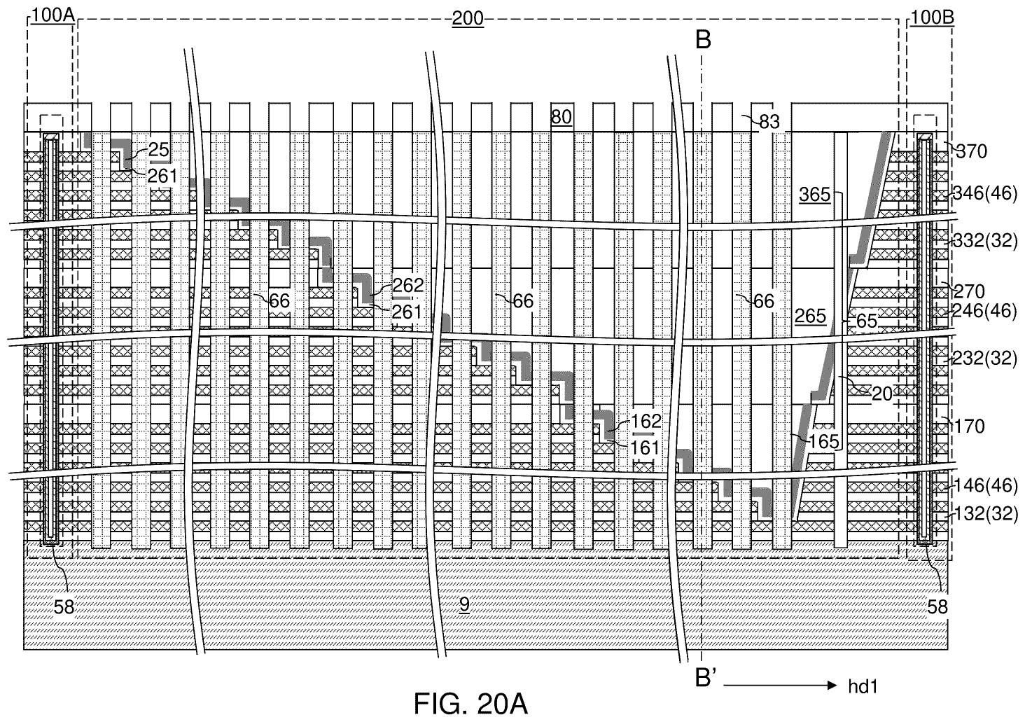

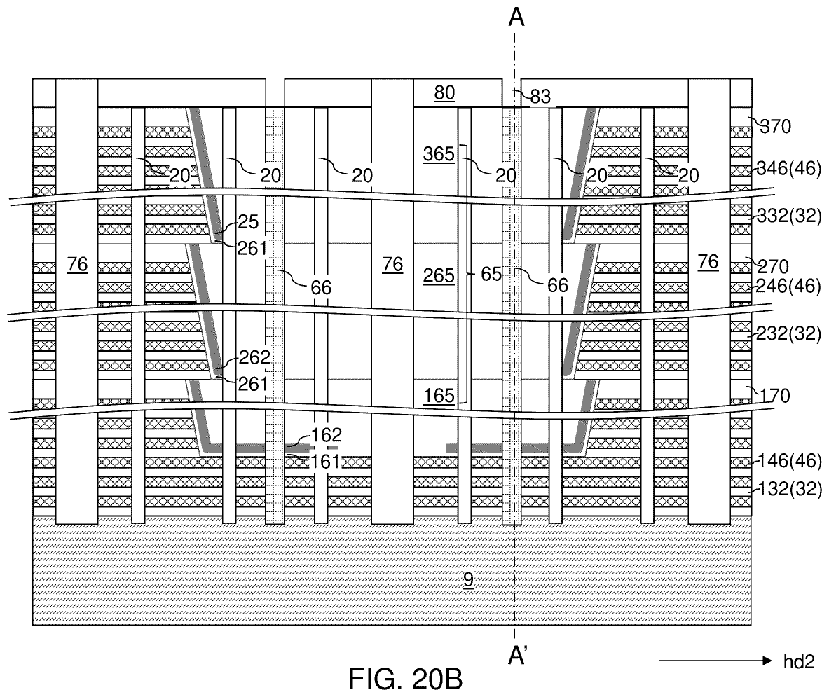

Referring to FIGS. 20A and 20B, a lateral isolation trench fill structure 76 can be formed in each lateral isolation trench 79. In one embodiment, an insulating liner layer including a dielectric material (such as silicon oxide) can be conformally deposited at a periphery of each lateral isolation trench, and can be anisotropically etched to form an insulating spacer within each lateral isolation trench. At least one conductive material can be deposited in remaining volumes of the lateral isolation trenches, and excess portions of the at least one conductive material can be removed from above the topmost tier structure by a planarization process. Each contiguous combination of an insulating spacer and a backside contact via structure that fills a lateral isolation trench constitutes a lateral isolation trench fill structure 76.

Alternatively, at least one dielectric material, such as silicon oxide, may be conformally deposited in the lateral isolation trenches 79 by a conformal deposition process. Each portion of the deposited dielectric material that fills a lateral isolation trench 79 constitutes a lateral isolation trench fill structure 76. In this case, each lateral isolation trench fill structure 76 may fill the entire volume of a lateral isolation trench 79 and may consist essentially of at least one dielectric material.

A photoresist layer (not shown) can be applied over the contact-level dielectric layer 80, and can be lithographically patterned to form discrete openings over the areas of the in-process contact assemblies 66. An anisotropic etch process can be performed to form openings through the contact-level dielectric layer 80 underneath each opening in the photoresist layer. Connection via cavities 83 can be formed through the contact-level dielectric layer 80. A top surface of an in-process contact assembly 66 can be physically exposed underneath each connection via cavity 83. The photoresist layer can be subsequently removed, for example, by ashing.

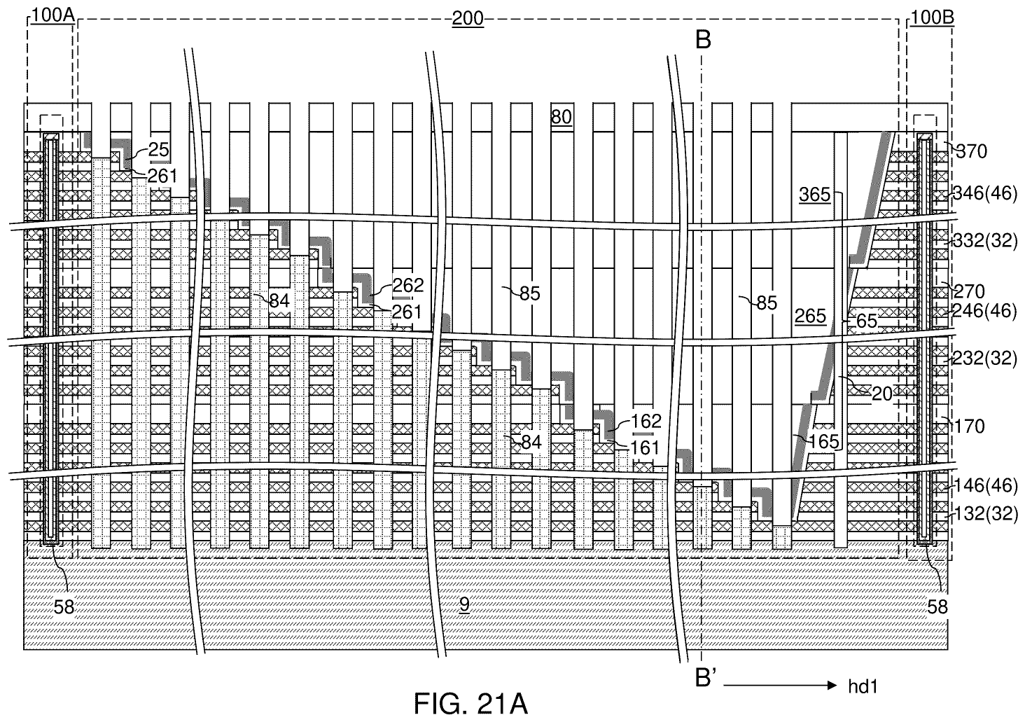

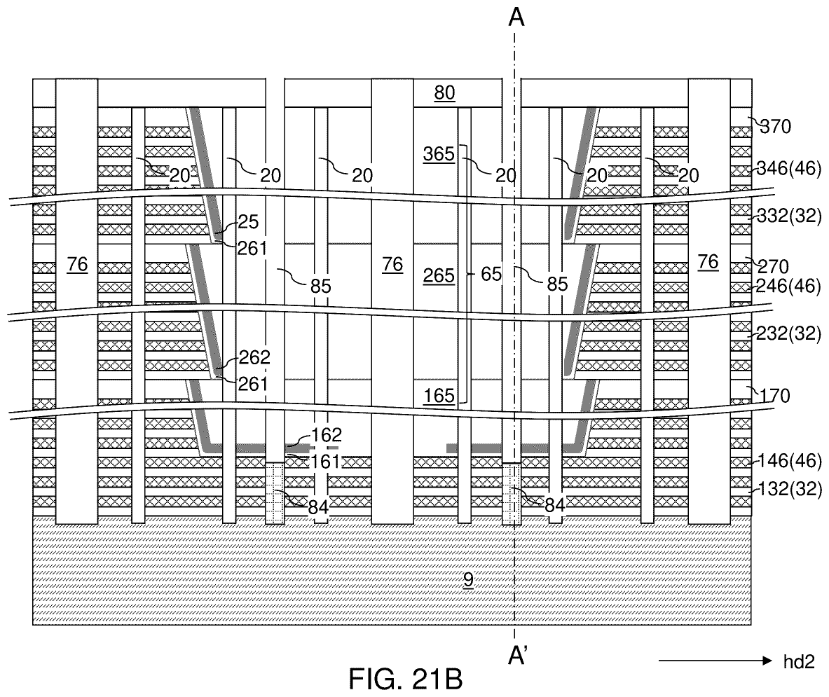

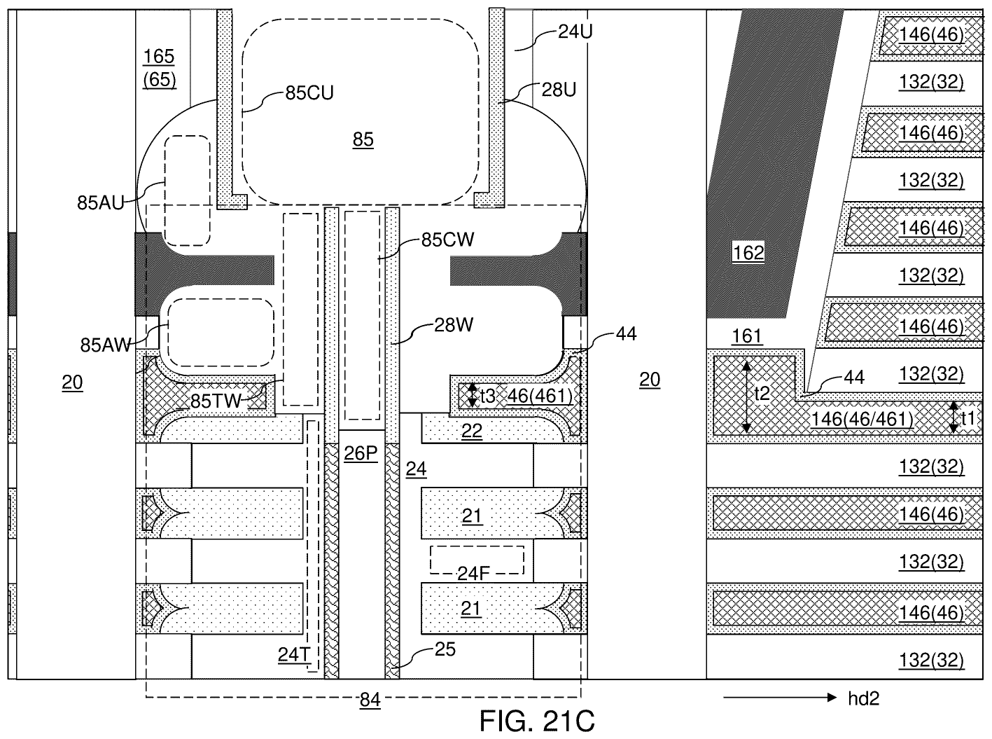

Referring to FIGS. 21A-21C, the sacrificial contact via structures 68 can be removed selective to the materials of the finned support assembly 84, the silicon nitride buffer layers (162, 262, 362), and the various silicon oxide material portions around the sacrificial contact via structures 68 by performing a selective etch process. For example, if the sacrificial contact via structures 68 comprise a semiconductor material, such as polysilicon or amorphous silicon, the selective etch process may comprise a wet etch process employing hot trimethyl-2 hydroxyethyl ammonium hydroxide (“hot TMY”) or tetramethyl ammonium hydroxide (TMAH).

A void is formed within the volume of each layer contact via cavity 85. Each layer contact via cavity 85 may comprise an upper cylindrical cavity portion 85CU that is laterally surrounded by the upper tubular semiconductor oxide liner 28U, a lower cylindrical cavity portion 85CW that is laterally surrounded by the tubular semiconductor oxide liner 28W, a tubular cavity portion 85TW that laterally surrounds the tubular semiconductor oxide liner 28W, a lower annular cavity portion 85AW that is located between a thinned annular portion of the silicon nitride buffer layer (162, 262, or 362) and the third portion of an electrically conductive layer 46 having the third thickness t3, and an upper annular cavity portion 85AU that is located between the thinned annular portion of the silicon nitride buffer layer (162, 262, 362) and a contoured bottom surface segment of the retro-stepped dielectric material portion 65.

Referring to FIG. 22, an isotropic etch process, such as a wet etch process, can be performed to remove physically exposed surface portions of the outer blocking dielectric layers 44. An annular planar top surface segment 46P, a cylindrical sidewall surface segment 46S, and an annular convex surface segment 46C of an electrically conductive layer 46 can be physically exposed underneath each layer contact via cavity 85.

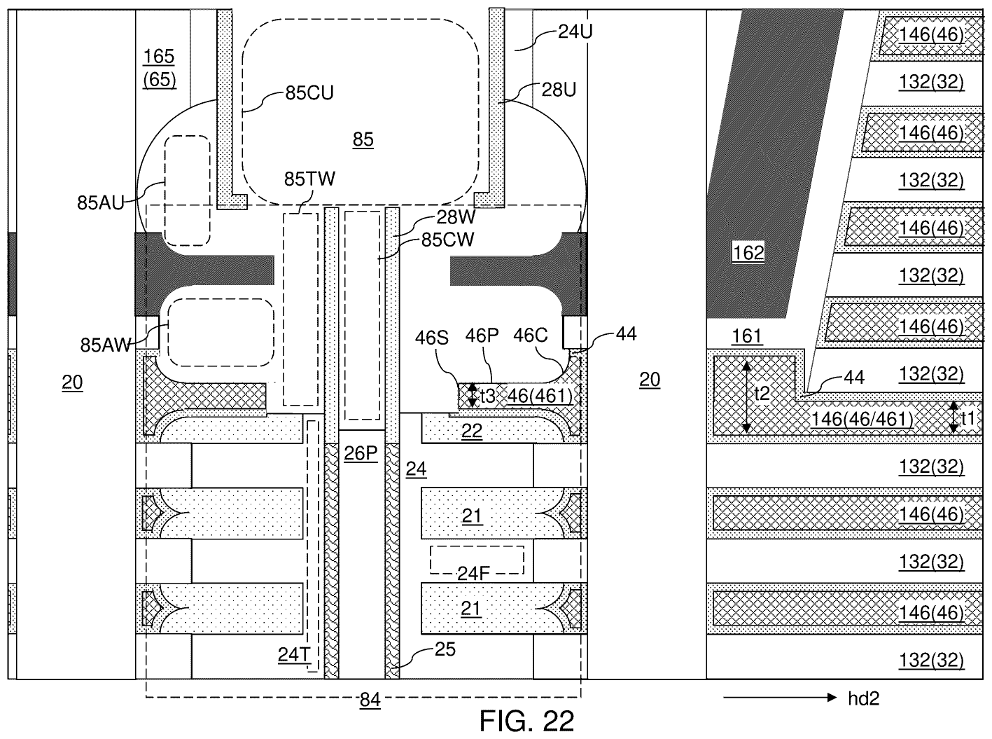

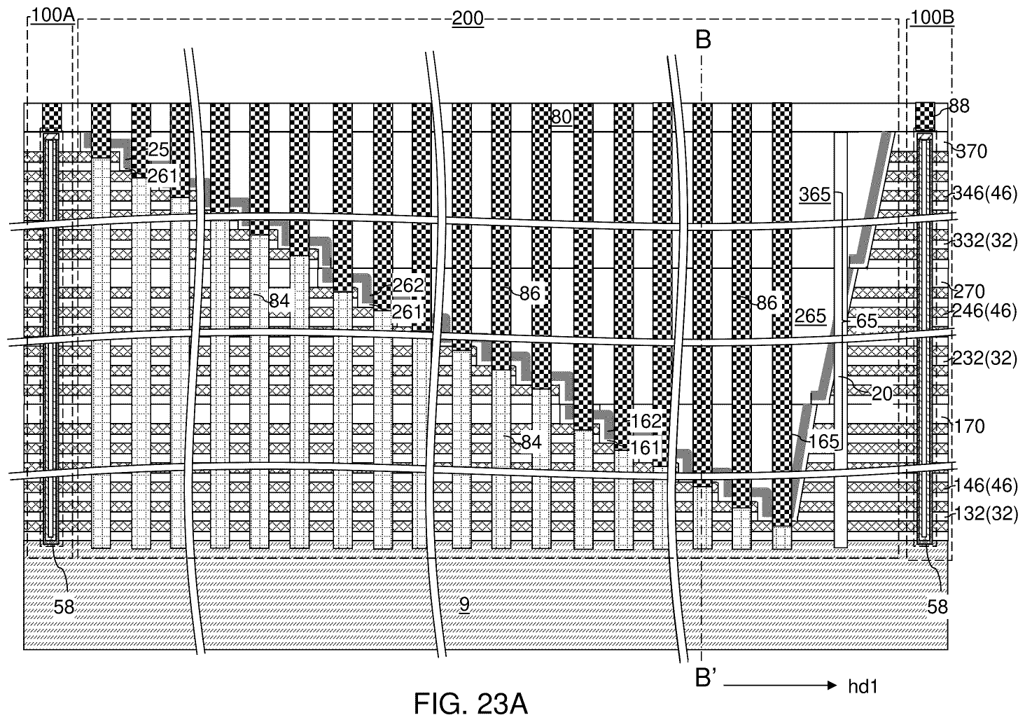

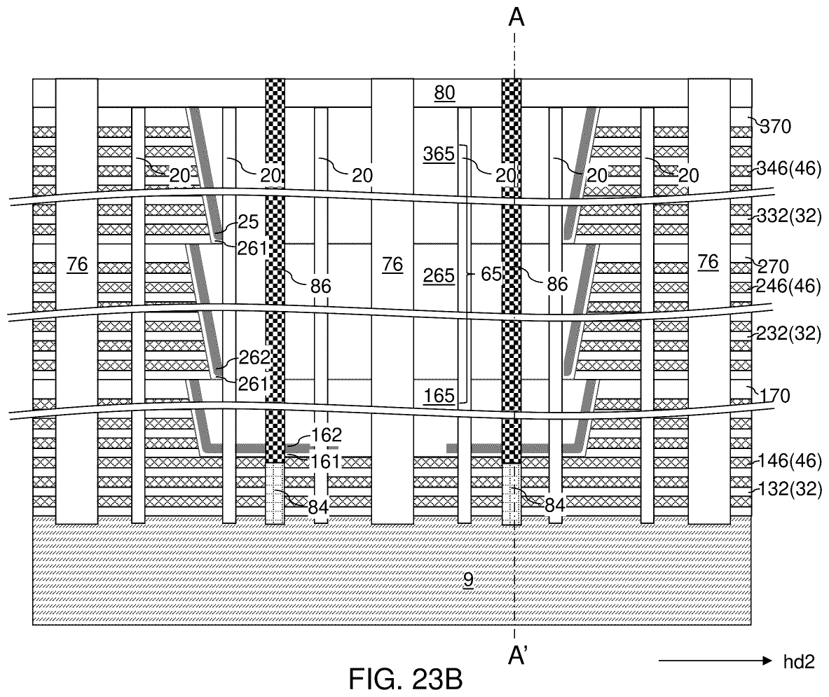

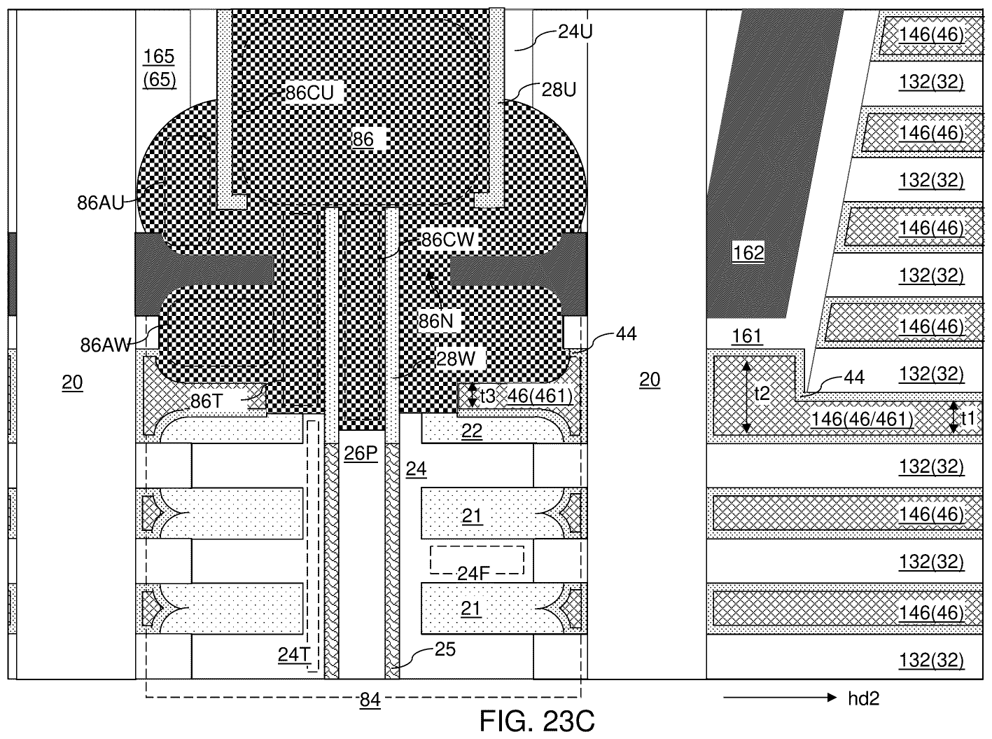

Referring to FIGS. 23A-23C, at least one electrically conductive material, such as at least one metallic material, can be deposited in the layer contact via cavities 85. The at least one metallic material may comprise a combination of a metallic barrier liner material (such as TiN, TaN, WN, and/or MoN) and a metal fill material (such as W, Ru, Mo, Co, Cu, etc.). Excess portions of the at least one metallic material can be removed from above the horizontal plane including the top surface of the contact-level dielectric layer 80. Each remaining portion of the at least one metallic material that fills a respective layer contact via cavity 85 constitutes a layer contact via structure 86.

Each layer contact via structure 86 may comprise an upper cylindrical portion 86CU that is laterally surrounded by the upper tubular semiconductor oxide liner 28U, a lower cylindrical portion 86CW that is laterally surrounded by the tubular semiconductor oxide liner 28W, a tubular portion 86T that laterally surrounds the tubular semiconductor oxide liner 28W, a lower annular portion 86AW that is located between a thinned annular portion of the silicon nitride buffer layer (162, 262, or 362) and the third portion of an electrically conductive layer 46 having the third thickness t3, and an upper annular portion 86AU that is located between the thinned annular portion of the silicon nitride buffer layer (162, 262, 362) and a contoured bottom surface segment of the retro-stepped dielectric material portion 65.

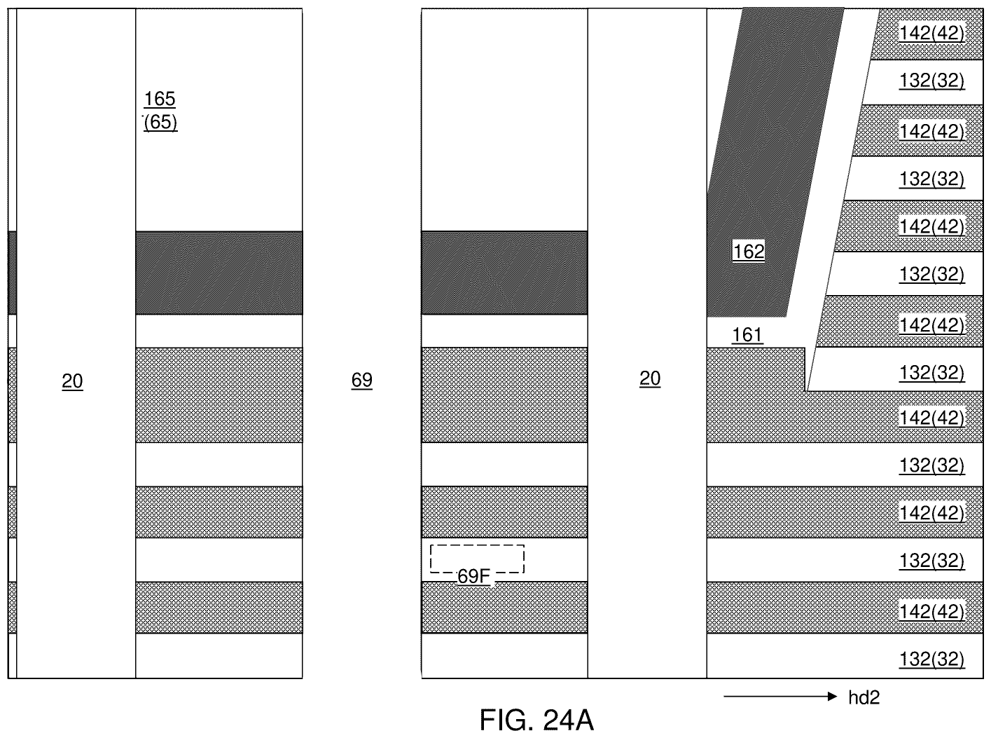

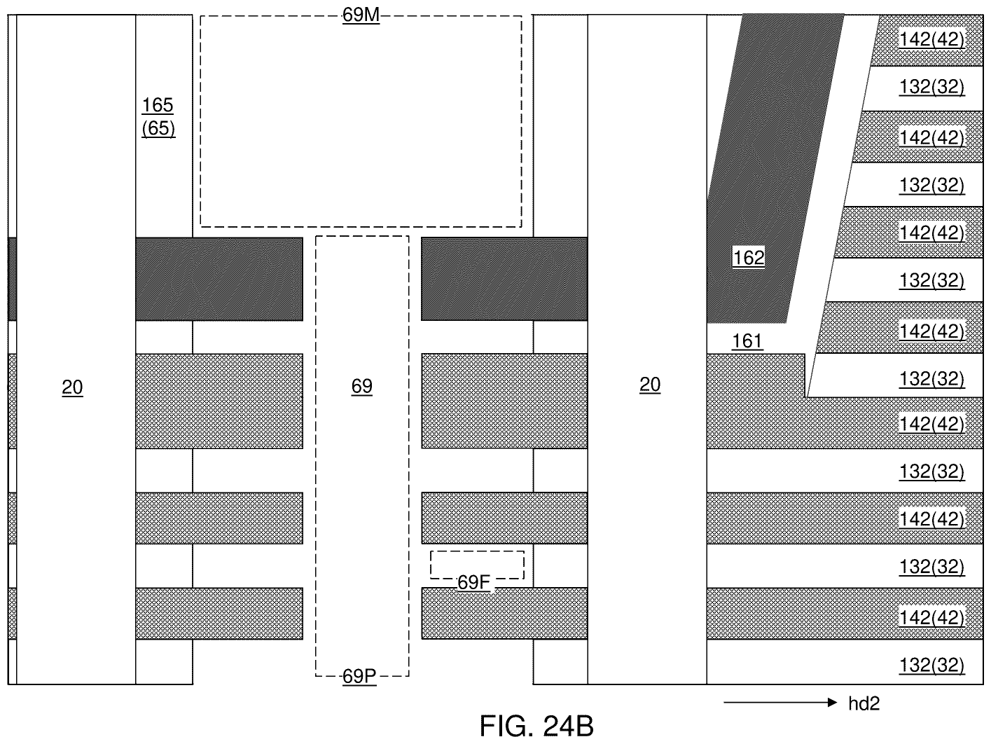

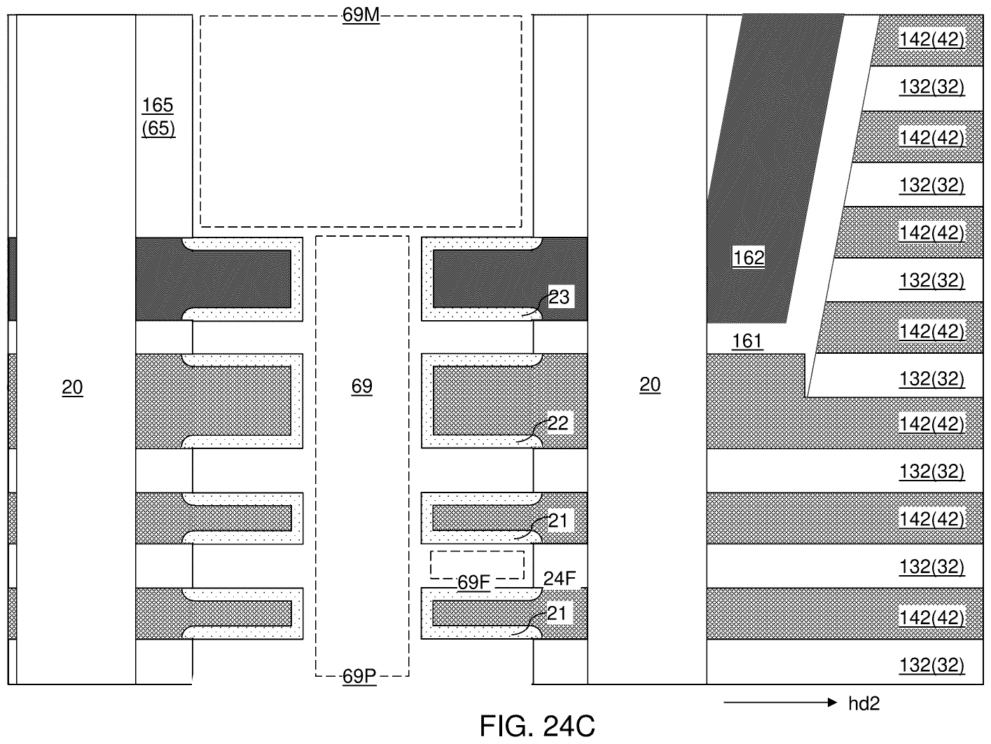

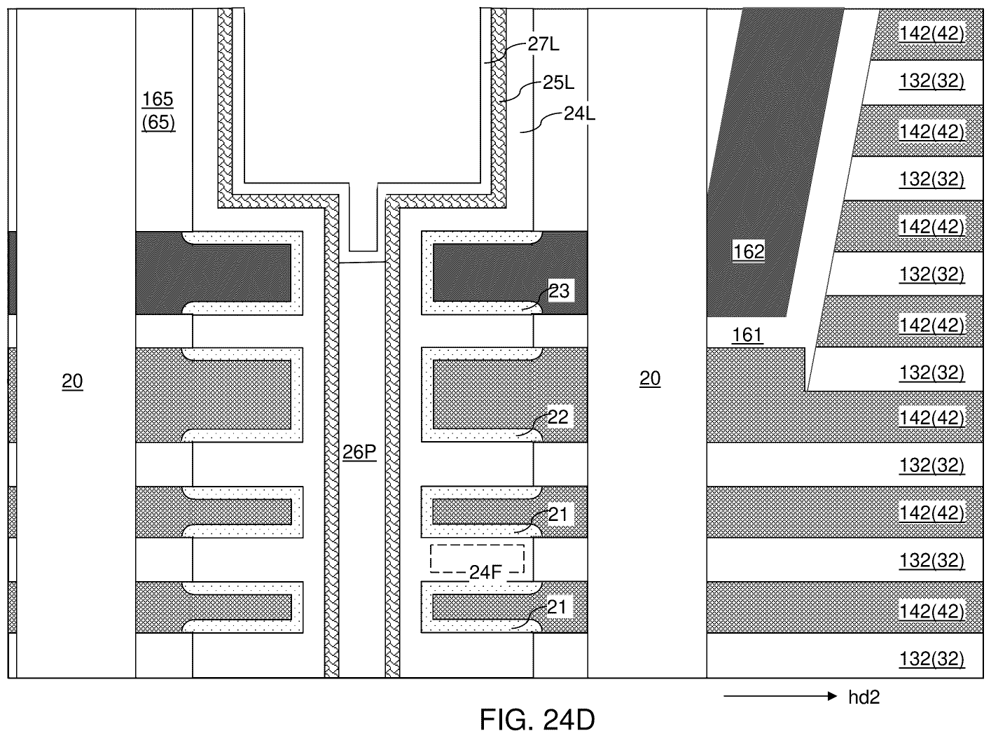

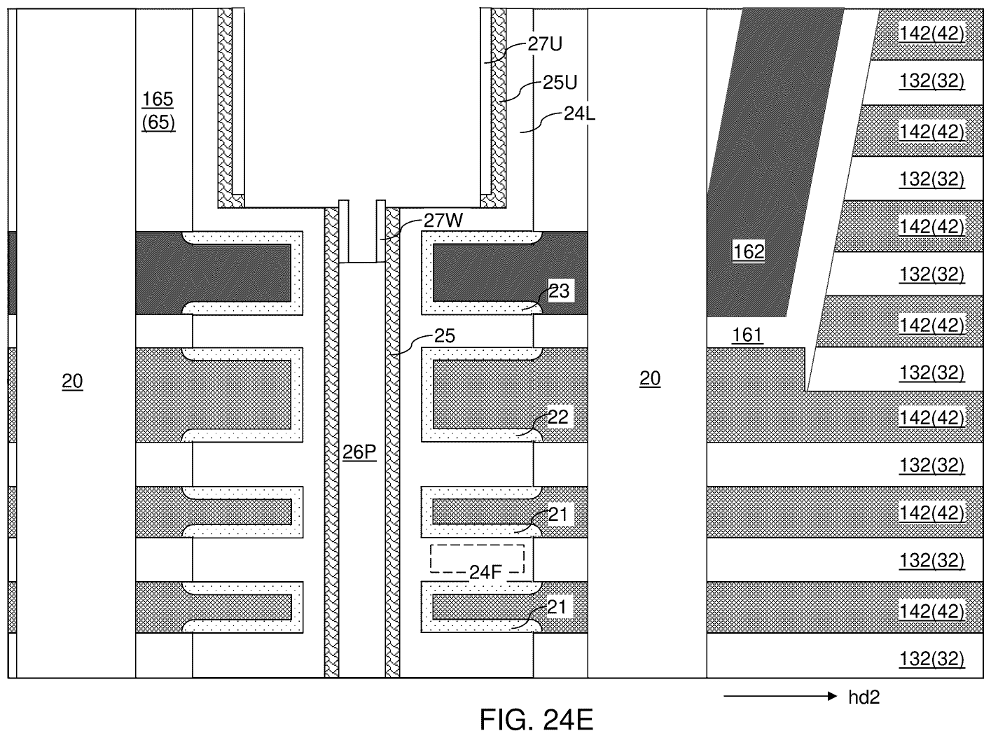

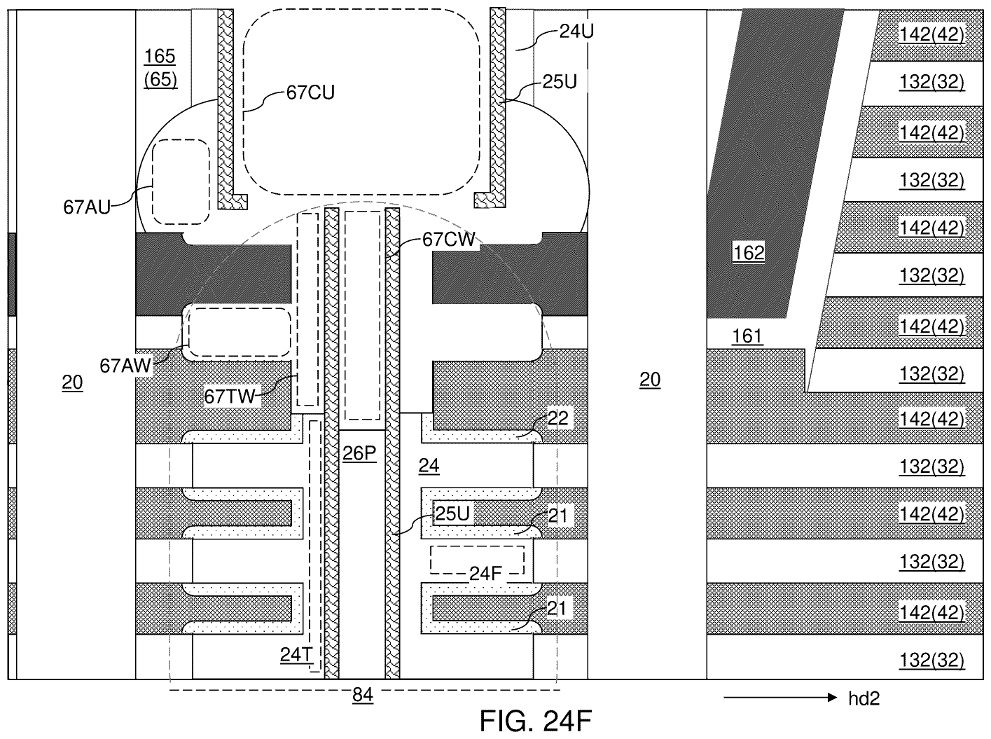

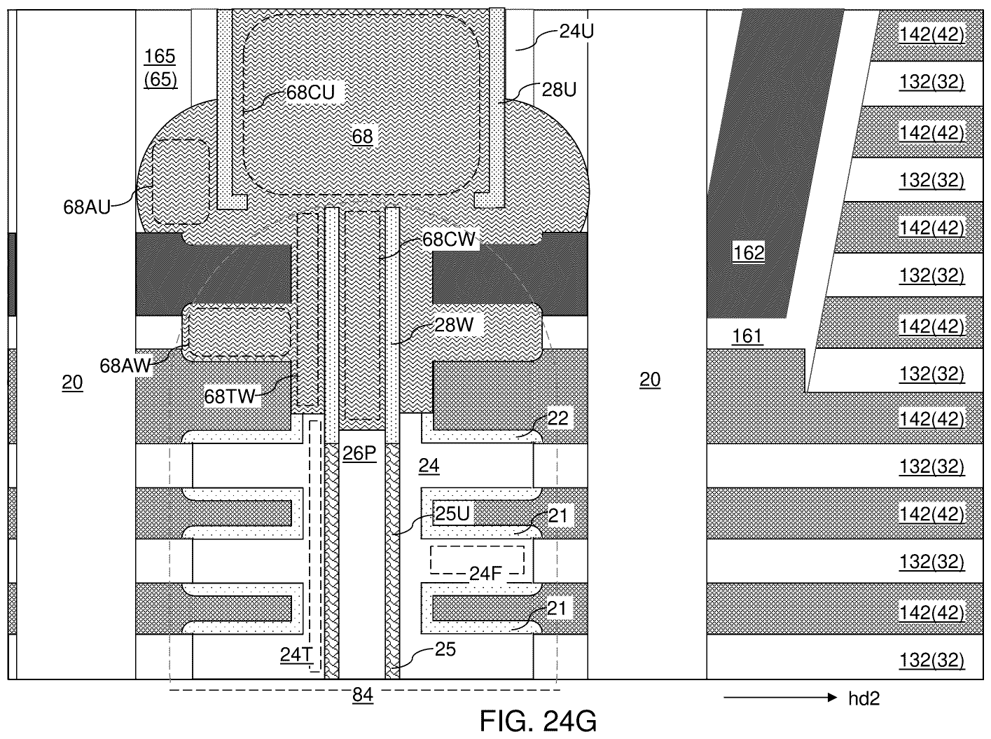

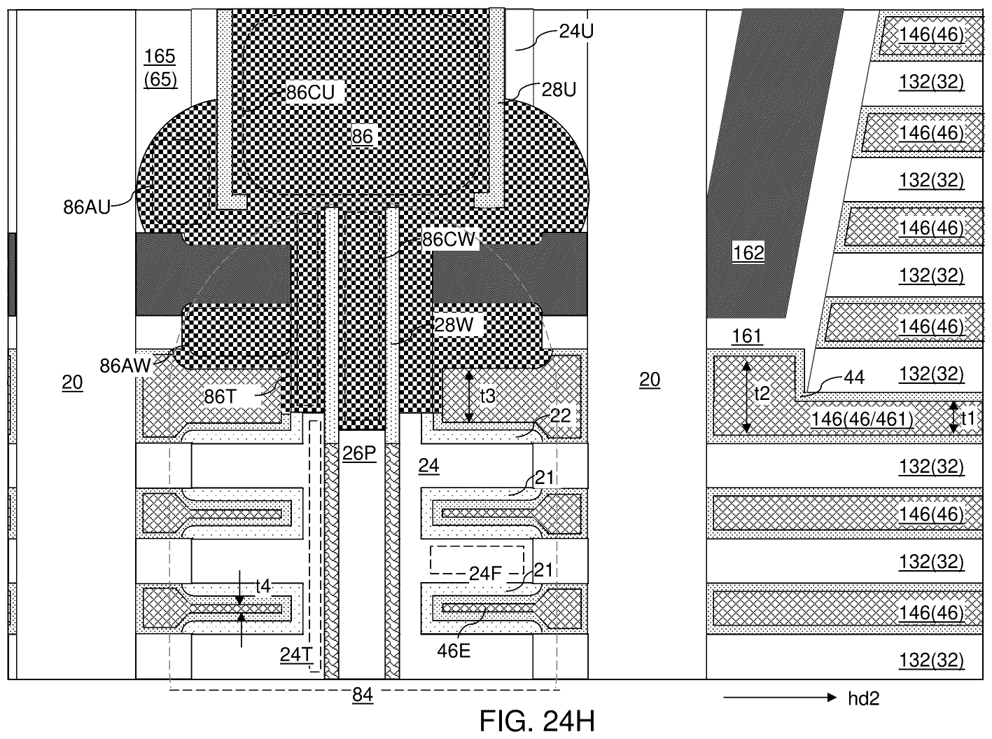

FIGS. 24A-24H are sequential vertical cross-sectional views of a region of a first alternative embodiment of the first exemplary structure during formation of a combination of a finned support assembly 84 and a layer contact via structure 86 according to the first embodiment of the present disclosure.

Referring to FIG. 24A, the first alternative embodiment of the first exemplary structure is illustrated at the processing steps of FIGS. 11A-11C. The first alternative embodiment of the first exemplary structure at this processing step may be the same as the first exemplary structure illustrated in FIGS. 11A-11C.

Referring to FIG. 24B, the first alternative embodiment of the first exemplary structure is illustrated at the processing steps of FIG. 12A. The first alternative embodiment of the first exemplary structure at this processing step may be the same as the first exemplary structure illustrated in FIG. 12A.

Referring to FIG. 24C, an oxidation process can be performed to convert surface portions of the sacrificial material layers 42 and the silicon nitride buffer layers (162, 262, 362) that are proximal to the contact via cavities 69 into oxidized dielectric material portions. For example, if the sacrificial material layers 42 comprise silicon nitride, the oxidation process can convert surface portions of the sacrificial material layers 42 that are proximal to the contact via cavities 69 into silicon oxide or oxynitride portions having a respective vertically-extending perforation (i.e., an opening) therethrough. A such, each silicon oxide or oxynitride portion that is derived from the sacrificial material layers 42 and the silicon nitride buffer layer (162, 262, 362) is herein referred to as a perforated dielectric portion (21, 22, 23). If the perforated dielectric portion comprises silicon oxynitride, then nitrogen concentration gradient may be present at least in one portion of each perforated dielectric portion 21, such as an interfacial portion that is proximal to the unoxidized remaining portion of a respective sacrificial material layer 42. In this case, the atomic concentration of nitrogen atoms may decrease within each perforated dielectric portion (21, 22, 23) with a distance from a proximal sacrificial material layer 42 or a silicon nitride buffer layer (162, 262, 362) to which the perforated dielectric portion (21, 22, 23) is adjoined.

The perforated dielectric portions (21, 22, 23) may comprise first-type perforated dielectric portions 21 that are formed by oxidizing portions of the sacrificial material layers 42 that are not thickened, second-type perforated dielectric portions 22 that are formed by oxidizing thickened portions of the sacrificial material layers 42, and third-type perforated dielectric portions 23 that are formed by oxidizing the silicon nitride buffer layers (162, 262, 362). In one embodiment, the oxidation thickness (i.e., the thickness by which the oxidation process proceeds in the sacrificial material layers 42) is less than one half of the initial thickness (i.e., the thickness prior to local thickening) of the sacrificial material layers 42, and is less than one half of the thickness of the silicon nitride buffer layer 162. In this case, each of the first-type perforated dielectric portions 21, the second-type perforated dielectric portions 22, and the third-type perforated dielectric portions 23 may be a coupled-flange-shaped silicon oxide or oxynitride portion having a respective shape of a couple flange, i.e., a pair of flanges that are coupled to each other by a connecting cylindrical tube having a lesser lateral extent than each of the flanges.

In summary, surface portions of the sacrificial material layers 42 can be oxidized into perforated dielectric portions (21, 22) by performing an oxidation process after formation of the annular fin cavities 69F. The oxidation process thins segments of the thickened portions of the sacrificial material layers 42 that are proximal to the contact via cavities 69. A segment of each thickened portion of the sacrificial material layers 42 may be thinned underneath a respective annular fin cavity 69F that underlies a silicon nitride buffer layer (162, 262, or 362).

Referring to FIG. 24D, the processing steps described with reference to FIGS. 12C, 12D, 12E, and 12F can be performed. Specifically, a dielectric material, such as undoped silicate glass or a doped silicate glass, can be conformally deposited in peripheral regions of the contact via cavities 69 to form a dielectric material layer 24L. A semiconductor liner layer 25L can be deposited by a conformal deposition process such as a chemical vapor deposition process. A dielectric fill material such as undoped silicate glass or a doped silicate glass can be conformally deposited to form a dielectric fill material layer 26L, which fills remaining volumes of the pillar cavity portions 69P of the contact via cavities 69. A second selective isotropic etch process can be performed to isotropically recess the material of the dielectric fill material layer 26L selective to the material of the semiconductor liner layer 25L. Each remaining pillar-shaped dielectric material portion that is laterally surrounded by a tubular bottom portion of the semiconductor liner layer 25L comprises a cylindrical dielectric pillar 26P. Each cylindrical dielectric pillar 26P may have a cylindrical shape, and may have a respective top surface located at the level of a most proximal horizontally-extending portion of a silicon nitride buffer layer (162, 262, 362). A silicon oxide liner 27L may be conformally deposited over the cylindrical inner surface and an annular horizontal surface of the semiconductor liner layer 25L.

Referring to FIG. 24E, the processing steps described with reference to FIG. 12G can be performed. Specifically, an anisotropic etch process can be performed to remove horizontally-extending portions of the silicon oxide liner 27L and the semiconductor liner layer 25L. A first etch step of the anisotropic etch process can remove horizontally-extending portions of the silicon oxide liner 27L. An upper silicon oxide liner 27U can be formed on the cylindrical inner surface of an upper cylindrical portion of the semiconductor liner layer 25L, and a lower silicon oxide liner 27W can be formed on an upper cylindrical inner surface segment of a lower cylindrical portion of the semiconductor liner layer 25L. A second etch step of the anisotropic etch process can remove horizontally-extending portions of the semiconductor liner layer 25L. Remaining portions of the semiconductor liner layer 25L include a tubular semiconductor liner 25 (which is also referred to as a lower tubular semiconductor liner) that laterally surrounds the cylindrical dielectric pillar 26P, and an additional tubular semiconductor liner 25U (which is also referred to as an upper tubular semiconductor liner). The lower silicon oxide liner 27W contacts an upper cylindrical surface segment of the inner cylindrical sidewall of the tubular semiconductor liner 25. The upper silicon oxide liner 27U contacts an inner cylindrical sidewall of the additional tubular semiconductor liner 25U.

Referring to FIG. 24F, the processing steps described with reference to FIG. 12H can be performed. Specifically, an isotropic etch process can be performed to isotropically etch silicon oxide materials of the upper silicon oxide liner 27U, the lower silicon oxide liner 27W, the cylindrical dielectric pillar 26P, the dielectric material layer 24L, the third-type perforated dielectric portion 23, the second-type perforated dielectric portion 22, and the retro-stepped dielectric material portion 65 selective to the materials of the silicon nitride buffer layer (162, 262, 362) and the sacrificial material layers 42. For example, the isotropic etch process may comprise a wet etch process employing dilute hydrofluoric acid as an etchant. The upper silicon oxide liner 27U and the lower silicon oxide liner 27W can be completely removed by the isotropic etch process. The top surface of the cylindrical dielectric pillar 26P can be vertically recessed by the isotropic etch process. The dielectric material layer 24L can be divided into an upper tubular dielectric liner 24U that laterally surrounds the additional tubular semiconductor liner 25U (i.e., an upper tubular semiconductor liner), and a finned dielectric pillar 24 which comprises a tubular dielectric portion 24T and a plurality of dielectric fins 24F that laterally protrudes from the tubular dielectric portion 24T. The third-type perforated dielectric portion 23 can be completely removed by the isotropic etch process. An upper portion of the second-type perforated dielectric portion 22 can be removed, while a lower portion the second-type perforated dielectric portion 22 may remain underneath a thinned annular portion of a sacrificial material layer 42.

A layer contact via cavity 67 is formed around each opening through a silicon nitride buffer layer (162, 262, 362). Each layer contact via cavity 67 may comprise an upper cylindrical cavity portion 67CU that is laterally surrounded by the additional tubular semiconductor liner 25U (i.e., an upper tubular semiconductor liner), a lower cylindrical cavity portion 67CW that is laterally surrounded by an upper segment of the tubular semiconductor liner 25, a tubular cavity portion 67TW that laterally surrounds the upper segment of the tubular semiconductor liner 25, a lower annular cavity portion 67AW that is located between a thinned annular portion of the silicon nitride buffer layer (162, 262, or 362) and a thinned annular portion of a sacrificial material layer 42, and an upper annular cavity portion 67AU that is located between the thinned annular portion of the silicon nitride buffer layer (162, 262, 362) and a contoured bottom surface segment of the retro-stepped dielectric material portion 65.

Referring to FIG. 24G, the processing steps described with reference to FIGS. 12I and 12J can be performed. Specificially, an oxidation process can be performed to convert an upper portion of the tubular semiconductor liner 25 into a tubular semiconductor oxide liner 28W, and to convert the additional tubular semiconductor liner 25U into an upper tubular semiconductor oxide liner 28U. For example, the tubular semiconductor oxide liner 28W and the upper tubular semiconductor oxide liner 28U may comprise silicon oxide.

The assembly of all material portions that replaces materials of the insulating layers 32 and the sacrificial material layers 42 and underlies an opening in a silicon nitride buffer layer (162, 262, 362) is herein referred to as a finned support assembly 84. The finned support assembly comprises a cylindrical dielectric pillar 26P, a tubular semiconductor liner 25 that laterally surrounds the cylindrical dielectric pillar 26P, a tubular semiconductor oxide liner 28W adjoined to an annular top end of the tubular semiconductor liner 25, a finned dielectric pillar 24 laterally surrounding the tubular semiconductor liner 25 and comprising a tubular dielectric portion 24T and a plurality of dielectric fins 24F that laterally protrudes from the tubular dielectric portion 24T, and perforated dielectric portions (21, 22).

A sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Each sacrificial contact via structure 68 may comprise an upper cylindrical sacrificial material portion 68CU that is laterally surrounded by the upper tubular semiconductor oxide liner 28U, a lower cylindrical sacrificial material portion 68CW that is laterally surrounded by the tubular semiconductor oxide liner 28W, a tubular sacrificial material portion 68TW that laterally surrounds the tubular semiconductor oxide liner 28W, a lower annular sacrificial material portion 68AW that is located between a thinned annular portion of the silicon nitride buffer layer (162, 262, or 362) and a thinned annular portion of a sacrificial material layer 42, and an upper annular sacrificial material portion 68AU that is located between the thinned annular portion of the silicon nitride buffer layer (162, 262, 362) and a contoured bottom surface segment of the retro-stepped dielectric material portion 65.

Referring to FIG. 24H, the processing steps described with reference to FIGS. 14-23C can be performed to replace the sacrificial material layers 42 with electrically conductive layers 46, and to replace the sacrificial contact via structures 68 with layer contact via structures 86. In this alternative embodiment, the electrically conductive layers 46 include additional extension portions 46E which extend into and are surrounded on three sides by the first-type perforated dielectric portions 21. The extension portions 46E have a thickness t4 which is less than the thicknesses t1, t2 and t3.

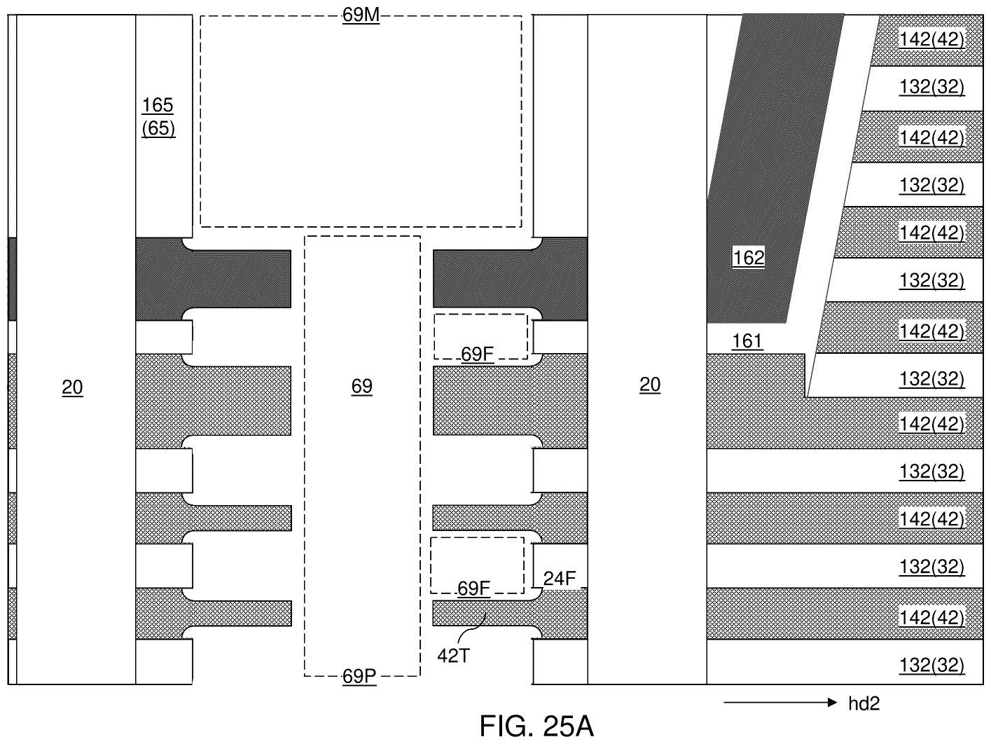

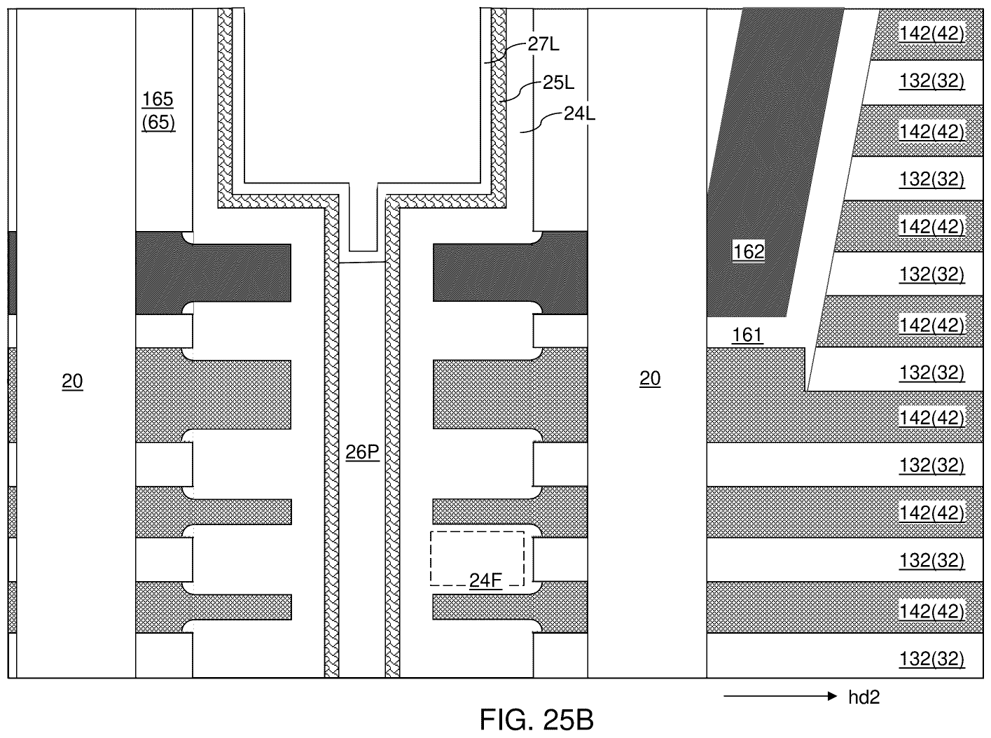

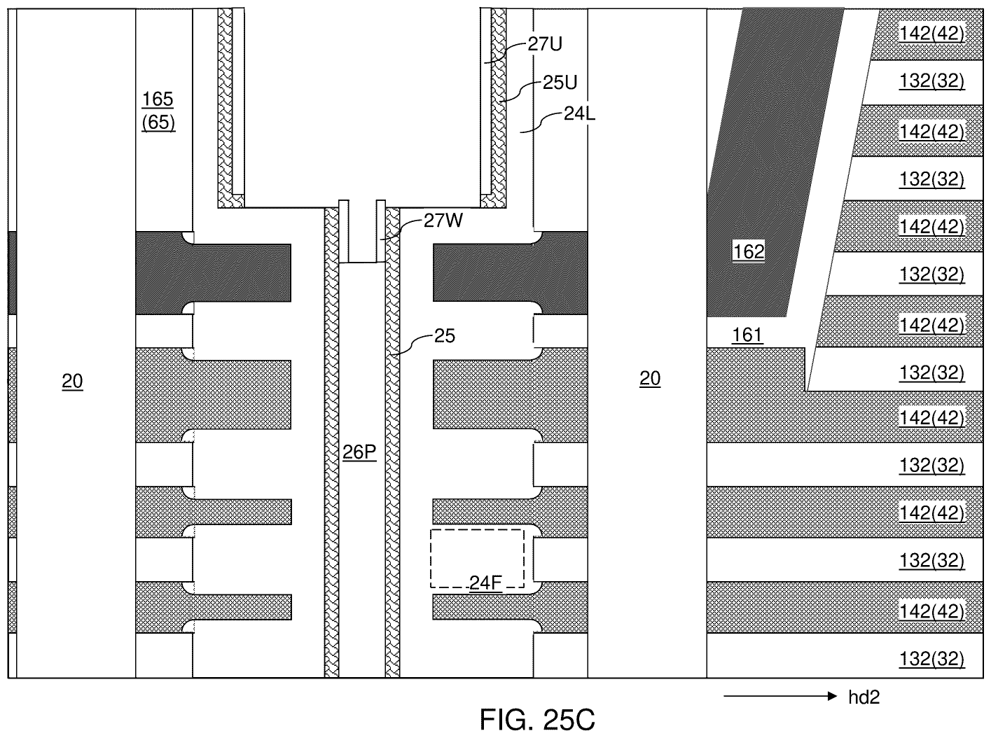

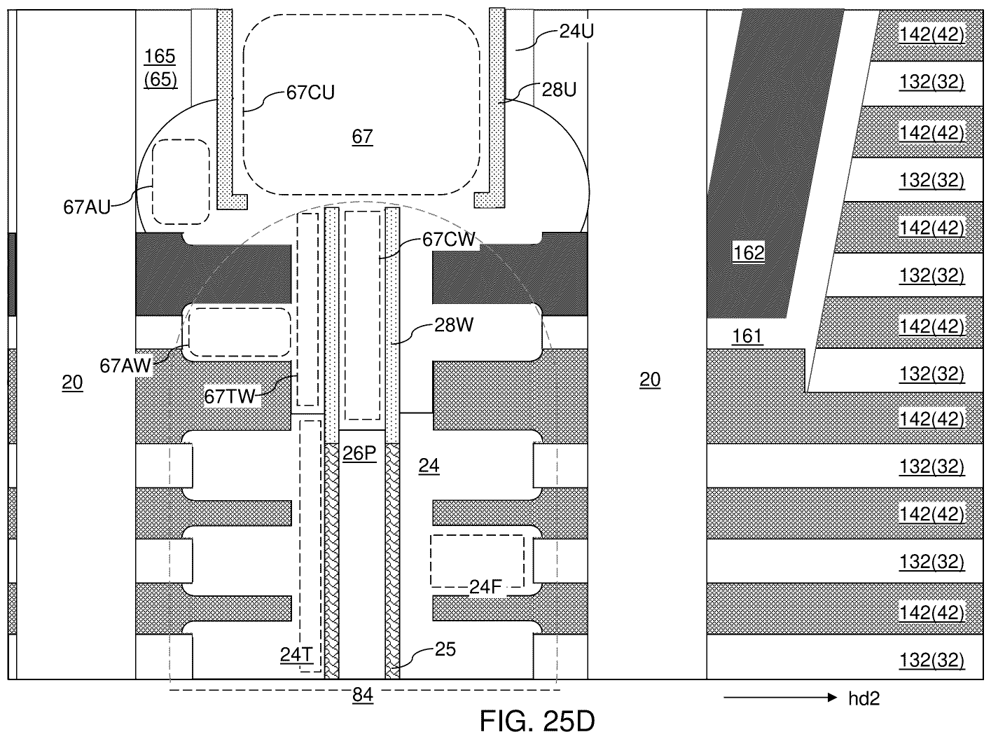

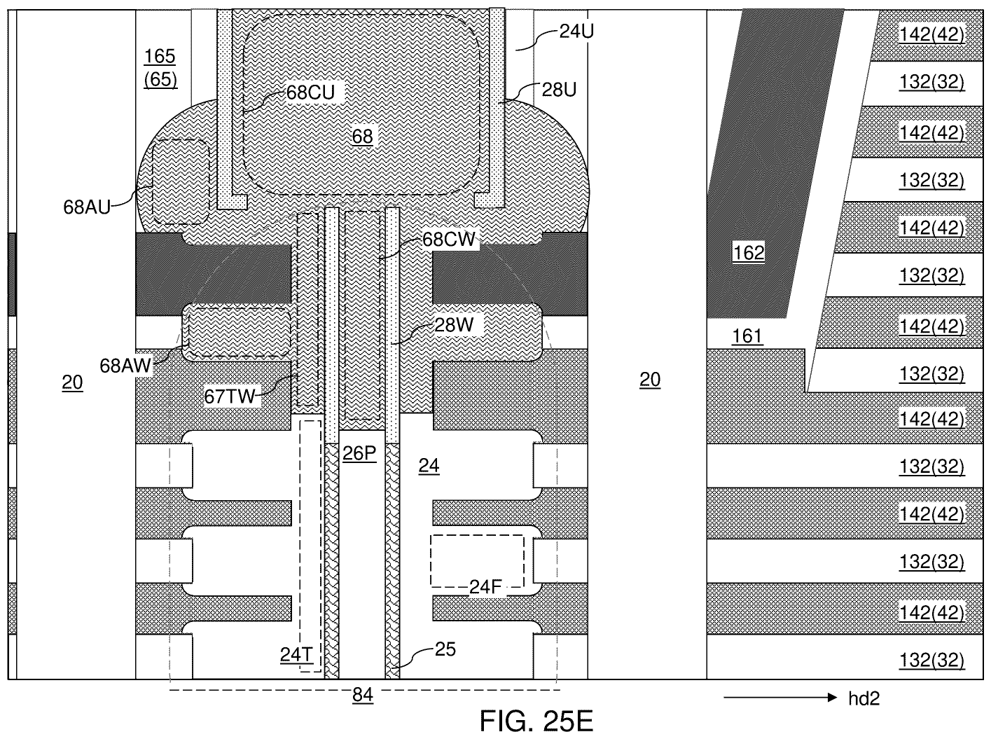

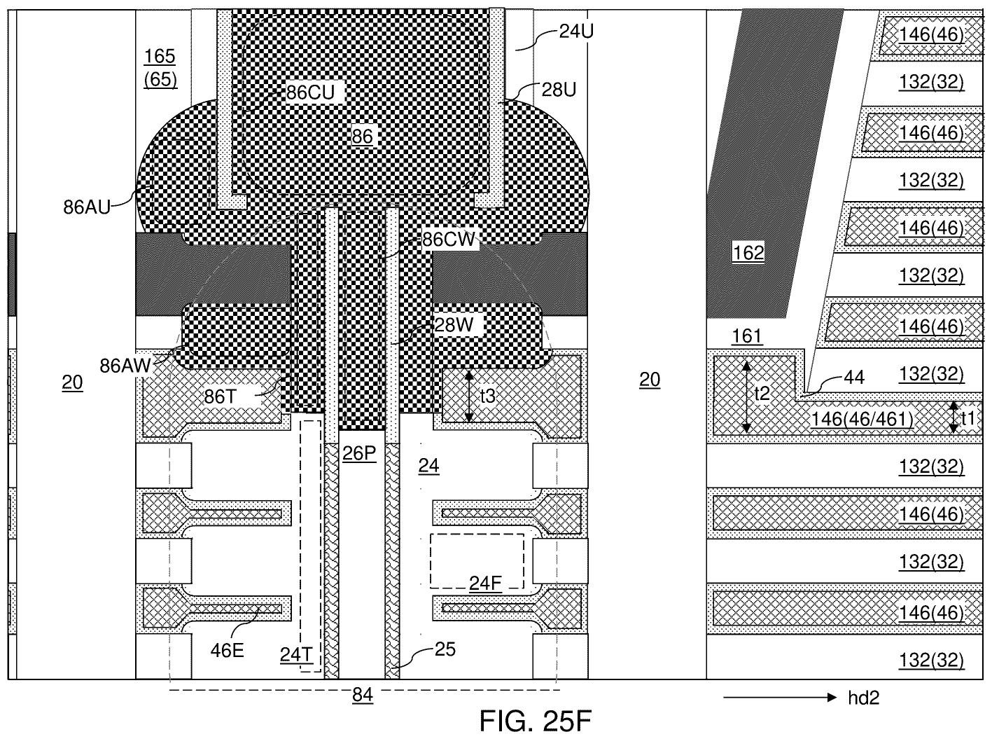

FIGS. 25A-25F are sequential vertical cross-sectional views of a region of a second alternative embodiment of the first exemplary structure during formation of a combination of a finned support assembly 84 and a layer contact via structure 86 according to the first embodiment of the present disclosure.

Referring to FIG. 25A, the second alternative embodiment of the first exemplary structure is illustrated, which can be derived from the first exemplary structure after the processing steps in FIG. 12A by performing a second selective isotropic etch process that isotropically etches the materials of the sacrificial material layers 42 and the silicon nitride buffer layers (162, 262, 362) selective to the materials of the insulating layers 32 and the retro-stepped dielectric material portions 65. For example, if the sacrificial material layers 42 comprise silicon nitride, the second selective isotropic etch process may comprise a wet etch process employing hot phosphoric acid. The duration of the second selective isotropic etch process may be selected such that the etch distance of the second selective isotropic etch process is less than one half of the initial thickness (i.e., the thickness prior to local thickening) of the sacrificial material layers 42, and is less than one half of the thickness of the silicon nitride buffer layer 162. Each of the sacrificial material layers 42 and the silicon nitride buffer layer (162, 262, 362) around a contact via cavity 69 may have a respective thinned annular portion 42T. A segment of each thickened portion of the sacrificial material layers 42 may be thinned underneath a respective annular fin cavity 69F that underlies a silicon nitride buffer layer (162, 262, or 362).

Referring to FIG. 25B, the processing steps described with reference to FIGS. 12C, 12D, 12E, and 12F can be performed. Specifically, a dielectric material such as undoped silicate glass or a doped silicate glass can be conformally deposited in peripheral regions of the contact via cavities 69 to form a dielectric material layer 24L. A semiconductor liner layer 25L can be deposited by a conformal deposition process such as a chemical vapor deposition process. A dielectric fill material such as undoped silicate glass or a doped silicate glass can be conformally deposited to form a dielectric fill material layer 26L, which fills remaining volumes of the pillar cavity portions 69P of the contact via cavities 69. A second selective isotropic etch process can be performed to isotropically recess the material of the dielectric fill material layer 26L selective to the material of the semiconductor liner layer 25L. Each remaining pillar-shaped dielectric material portion that is laterally surrounded by a tubular bottom portion of the semiconductor liner layer 25L comprises a cylindrical dielectric pillar 26P. Each cylindrical dielectric pillar 26P may have a cylindrical shape, and may have a respective top surface located at the level of a most proximal horizontally-extending portion of a silicon nitride buffer layer (162, 262, 362). A silicon oxide liner 27L may be conformally deposited over the cylindrical inner surface and an annular horizontal surface of the semiconductor liner layer 25L.

Referring to FIG. 25C, the processing steps described with reference to FIG. 12G can be performed. Specifically, an anisotropic etch process can be performed to remove horizontally-extending portions of the silicon oxide liner 27L and the semiconductor liner layer 25L. A first etch step of the anisotropic etch process can remove horizontally-extending portions of the silicon oxide liner 27L. An upper silicon oxide liner 27U can be formed on the cylindrical inner surface of an upper cylindrical portion of the semiconductor liner layer 25L, and a lower silicon oxide liner 27W can be formed on an upper cylindrical inner surface segment of a lower cylindrical portion of the semiconductor liner layer 25L. A second etch step of the anisotropic etch process can remove horizontally-extending portions of the semiconductor liner layer 25L. Remaining portions of the semiconductor liner layer 25L include a tubular semiconductor liner 25 (which is also referred to as a lower tubular semiconductor liner) that laterally surrounds the cylindrical dielectric pillar 26P, and an additional tubular semiconductor liner 25U (which is also referred to as an upper tubular semiconductor liner). The lower silicon oxide liner 27W contacts an upper cylindrical surface segment of the inner cylindrical sidewall of the tubular semiconductor liner 25. The upper silicon oxide liner 27U contacts an inner cylindrical sidewall of the additional tubular semiconductor liner 25U.

Referring to FIG. 25D, the processing steps described with reference to FIG. 12H can be performed. Specifically, an isotropic etch process can be performed to isotropically etch silicon oxide materials of the upper silicon oxide liner 27U, the lower silicon oxide liner 27W, the cylindrical dielectric pillar 26P, the dielectric material layer 24L, the third-type perforated dielectric portion 23, the second-type perforated dielectric portion 22, and the retro-stepped dielectric material portion 65 selective to the materials of the silicon nitride buffer layer (162, 262, 362) and the sacrificial material layers 42. For example, the isotropic etch process may comprise a wet etch process employing dilute hydrofluoric acid as an etchant. The upper silicon oxide liner 27U and the lower silicon oxide liner 27W can be completely removed by the isotropic etch process. The top surface of the cylindrical dielectric pillar 26P can be vertically recessed by the isotropic etch process. The dielectric material layer 24L can be divided into an upper tubular dielectric liner 24U that laterally surrounds the additional tubular semiconductor liner 25U (i.e., an upper tubular semiconductor liner), and a finned dielectric pillar 24 which comprises a tubular dielectric portion 24T and a plurality of dielectric fins 24F that laterally protrudes from the tubular dielectric portion 24T. The third-type perforated dielectric portion 23 can be completely removed by the isotropic etch process. An upper portion of the second-type perforated dielectric portion 22 can be removed, while a lower portion the second-type perforated dielectric portion 22 may remain underneath a thinned annular portion of a sacrificial material layer 42.

A layer contact via cavity 67 is formed around each opening through a silicon nitride buffer layer (162, 262, 362). Each layer contact via cavity 67 may comprise an upper cylindrical cavity portion 67CU that is laterally surrounded by the additional tubular semiconductor liner 25U (i.e., an upper tubular semiconductor liner), a lower cylindrical cavity portion 67CW that is laterally surrounded by an upper segment of the tubular semiconductor liner 25, a tubular cavity portion 67TW that laterally surrounds the upper segment of the tubular semiconductor liner 25, a lower annular cavity portion 67AW that is located between a thinned annular portion of the silicon nitride buffer layer (162, 262, or 362) and a thinned annular portion of a sacrificial material layer 42, and an upper annular cavity portion 67AU that is located between the thinned annular portion of the silicon nitride buffer layer (162, 262, 362) and a contoured bottom surface segment of the retro-stepped dielectric material portion 65.

Referring to FIG. 25E, the processing steps described with reference to FIGS. 12I and 12J can be performed. Specificially, an oxidation process can be performed to convert an upper portion of the tubular semiconductor liner 25 into a tubular semiconductor oxide liner 28W, and to convert the additional tubular semiconductor liner 25U into an upper tubular semiconductor oxide liner 28U. For example, the tubular semiconductor oxide liner 28W and the upper tubular semiconductor oxide liner 28U may comprise silicon oxide.

The assembly of all material portions that replaces materials of the insulating layers 32 and the sacrificial material layers 42 and underlies an opening in a silicon nitride buffer layer (162, 262, 362) is herein referred to as a finned support assembly 84. The finned support assembly comprises a cylindrical dielectric pillar 26P, a tubular semiconductor liner 25 that laterally surrounds the cylindrical dielectric pillar 26P, a tubular semiconductor oxide liner 28W adjoined to an annular top end of the tubular semiconductor liner 25, a finned dielectric pillar 24 laterally surrounding the tubular semiconductor liner 25 and comprising a tubular dielectric portion 24T and a plurality of dielectric fins 24F that laterally protrudes from the tubular dielectric portion 24T, and perforated dielectric portions (21, 22).

A sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Each sacrificial contact via structure 68 may comprise an upper cylindrical sacrificial material portion 68CU that is laterally surrounded by the upper tubular semiconductor oxide liner 28U, a lower cylindrical sacrificial material portion 68CW that is laterally surrounded by the tubular semiconductor oxide liner 28W, a tubular sacrificial material portion 68TW that laterally surrounds the tubular semiconductor oxide liner 28W, a lower annular sacrificial material portion 68AW that is located between a thinned annular portion of the silicon nitride buffer layer (162, 262, or 362) and a thinned annular portion of a sacrificial material layer 42, and an upper annular sacrificial material portion 68AU that is located between the thinned annular portion of the silicon nitride buffer layer (162, 262, 362) and a contoured bottom surface segment of the retro-stepped dielectric material portion 65.

Referring to FIG. 25F, the processing steps described with reference to FIGS. 14-23C can be performed to replace the sacrificial material layers 42 with electrically conductive layers 46, and to replace the sacrificial contact via structures 68 with layer contact via structures 86. In this alternative embodiment, the first-type perforated dielectric portions 21 are omitted. The electrically conductive layers 46 include additional extension portions 46E which extend into and are surrounded on three sides by the finned dielectric pillar 24. The extension portions 46E have a thickness t4 which is less than the thicknesses t1, t2 and t3.

Referring collectively to FIGS. 23A-23C, 24H, and 25F, and according to a first embodiment of the present disclosure, a device structure comprises: an alternating stack (32, 46) of insulating layers 32 and electrically conductive layers 46, wherein the alternating stack (32, 46) comprises a staircase region; a retro-stepped dielectric material portion 65 overlying the alternating stack (32, 46) in the staircase region; and a contact assembly (84, 86) comprising a layer contact via structure 86 and a finned support assembly 84, wherein: a first electrically conductive layer 461 among the electrically conductive layers 46 comprises a first portion having a first thickness t1 in a region in which each layer in the alternating stack (32, 46) is present, has a second portion having a second thickness t2 that is greater than the first thickness t1 around the contact assembly (84, 86), and has a third portion having a third thickness t3 and that is laterally surrounded by the second portion; and the layer contact via structure 86 vertically extends through the retro-stepped dielectric material portion 65 and comprises a contoured bottom surface that includes an annular planar surface segment that contacts an annular top surface segment 46P of the third portion of the first electrically conductive layer 461.

In one embodiment, the contoured bottom surface of the layer contact via structure 86 comprises a cylindrical sidewall surface segment that contacts a cylindrical sidewall surface segment 46S of an opening through the third portion of the first electrically conductive layer 461. In one embodiment, the annular planar surface segment 46P of the layer contact via structure 86 is located below a horizontal plane including a top surface of the second portion of the electrically conductive layer 46. In one embodiment, a bottom surface of the first portion of the first electrically conductive layer 461 and a bottom surface of the second portion of the first electrically conductive layer 461 are located within a horizontal plane that underlies a horizontal plane including an annular bottom surface of the third portion of the first electrically conductive layer 461. In one embodiment, an outer periphery of the annular top surface segment 46P of the third portion of the first electrically conductive layer 461 is adjoined to an inner periphery of a planar top surface of the second portion of the first electrically conductive layer 461 by a contoured annular surface segment 46C of the first electrically conductive layer 461 having a concave vertical cross-sectional shape.

In one embodiment, the device structure further comprises an outer blocking dielectric layer 44 laterally surrounding the first electrically conductive layer 461, wherein an annular bottom surface segment of the third portion of the first electrically conductive layer 461 contacts the outer blocking dielectric layer 44. In one embodiment, a cylindrical sidewall surface segment of the layer contact via structure 86 contacts a cylindrical sidewall surface segment of an opening in the outer blocking dielectric layer 44 above the annular top surface segment of the third portion of the first electrically conductive layer 461; and an annular surface segment of the outer blocking dielectric layer 44 contacts an annular surface segment of the contoured bottom surface of the layer contact via structure 86.

In one embodiment, the device structure comprises a layer stack including a silicon oxide buffer layer (161, 261, or 361) and a silicon nitride buffer layer (162, 262, or 362) and interposed between the alternating stack (32, 46) and the retro-stepped dielectric material portion 65 in the staircase region, wherein: the layer contact via structure 86 vertically extends through the layer stack; and the layer contact via structure 86 comprises a neck portion 86N at a level of the silicon nitride buffer layer (162, 262, or 362). The neck portion 86N is narrower than and is located vertically between the overlying portion 86AU and the underlying portion 86AW of the layer contact via structure 86. In one embodiment, a vertical extent of a cylindrical sidewall of the neck portion 86N is less than a thickness of a horizontally-extending portion of the silicon nitride buffer layer (162, 262, or 362) through which the layer contact via structure 86 vertically extends.

In one embodiment, the finned support assembly 84 comprises a finned dielectric pillar 24 comprising a tubular dielectric portion 24T and a plurality of dielectric fins 24F that laterally protrude from the tubular dielectric portion 24T. In one embodiment, the layer contact via structure 86 comprises a tubular portion 86T having an outer cylindrical surface segment that contacts a cylindrical surface segment of the third portion of the first electrically conductive layer 461, and having an annular bottom surface segment contacting an annular top surface segment of the tubular dielectric portion 24T. In one embodiment, an inner periphery of the bottom surface segment of the tubular portion 86T of the layer contact via structure 86 coincides within an inner periphery of the annular top surface segment of the tubular dielectric portion 24T.

In one embodiment, the finned support assembly 84 further comprises a tubular semiconductor liner 25 contacting an inner cylindrical sidewall of the tubular portion 86T of the layer contact via structure 86 and contacting an inner cylindrical sidewall of the tubular dielectric portion 24T of the finned dielectric pillar 24. In one embodiment, the finned support assembly 84 further comprises cylindrical dielectric pillar 26P having a cylindrical sidewall that contacts a cylindrical surface segment of an inner sidewall of the tubular semiconductor liner 25; and the layer contact via structure further 86 comprises a lower cylindrical portion 86CW laterally surrounded by an upper portion of the tubular semiconductor liner 25. In one embodiment, the finned support assembly 84 comprises discrete perforated dielectric portions (21, 22) interposed between vertically neighboring pairs of dielectric fins 24F of the plurality of dielectric fins 24F.

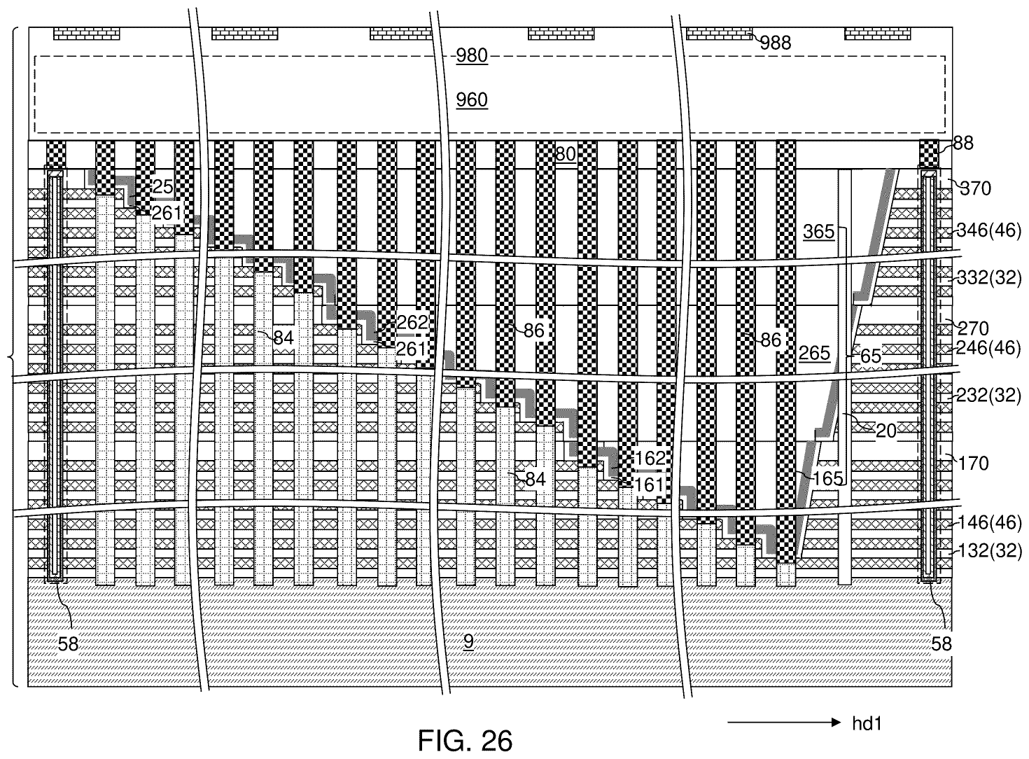

Referring to FIG. 26, additional dielectric material layers can be formed over the contact-level dielectric layer 80. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The dielectric material layers that are formed above the contact-level dielectric layer 80 are herein collectively referred to as memory-side dielectric material layers 960. The additional metal interconnect structures are collectively referred to as memory-side dielectric material layers 960. The memory-side dielectric material layers 960 comprise a bit-line-level dielectric material layer embedding bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In summary, the memory die 900 comprises a memory array (32, 46, 58), memory-side metal interconnect structures 980, and memory-side bonding pads 988 embedded within memory-side dielectric material layers 960. The memory array may comprise a three-dimensional memory array including an alternating stack of insulating layers 32 and electrically conductive layers 46, and further comprises a two-dimensional array of NAND strings (e.g., memory opening fill structures 58) vertically extending through the alternating stack (32, 46). In one embodiment, the electrically conductive layers 46 comprise word lines and select gate electrodes of the two-dimensional array of NAND strings. In one embodiment, the memory-side metal interconnect structures 980 comprise bit lines for the two-dimensional array of NAND strings.

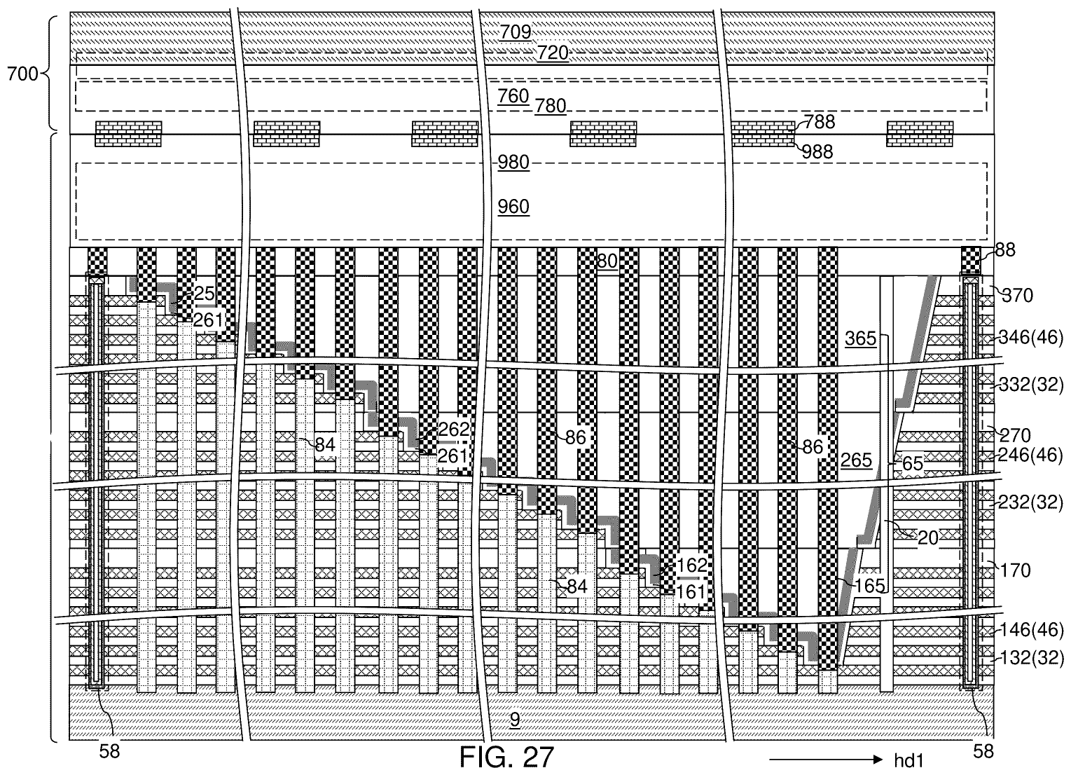

Referring to FIG. 27, a logic die 700 can be provided. The logic die 700 includes a logic-side substrate 709, a peripheral circuit 720 located on the logic-side substrate 709 and comprising logic-side semiconductor devices (such as field effect transistors), logic-side metal interconnect structures 780 embedded within logic-side dielectric material layers 760, and logic-side bonding pads 778. The peripheral circuit 720 can be configured to control operation of the memory array within the memory die 900. Specifically, the peripheral circuit 720 can be configured to drive various electrical components within the memory array including, but not limited to, the electrically conductive layers 46, the drain regions 63, and a source contact structure to be subsequently formed. The peripheral circuit 720 can be configured to control operation of the vertical stack of memory elements in the memory array in the memory die 900. Particularly, the peripheral circuit 720 comprises word line driver transistors configured to drive the word lines in the memory die 900.

The logic die 700 can be attached to the memory die 900, for example, by bonding the logic-side bonding pads 788 to the memory-side bonding pads 988 at a bonding interface. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

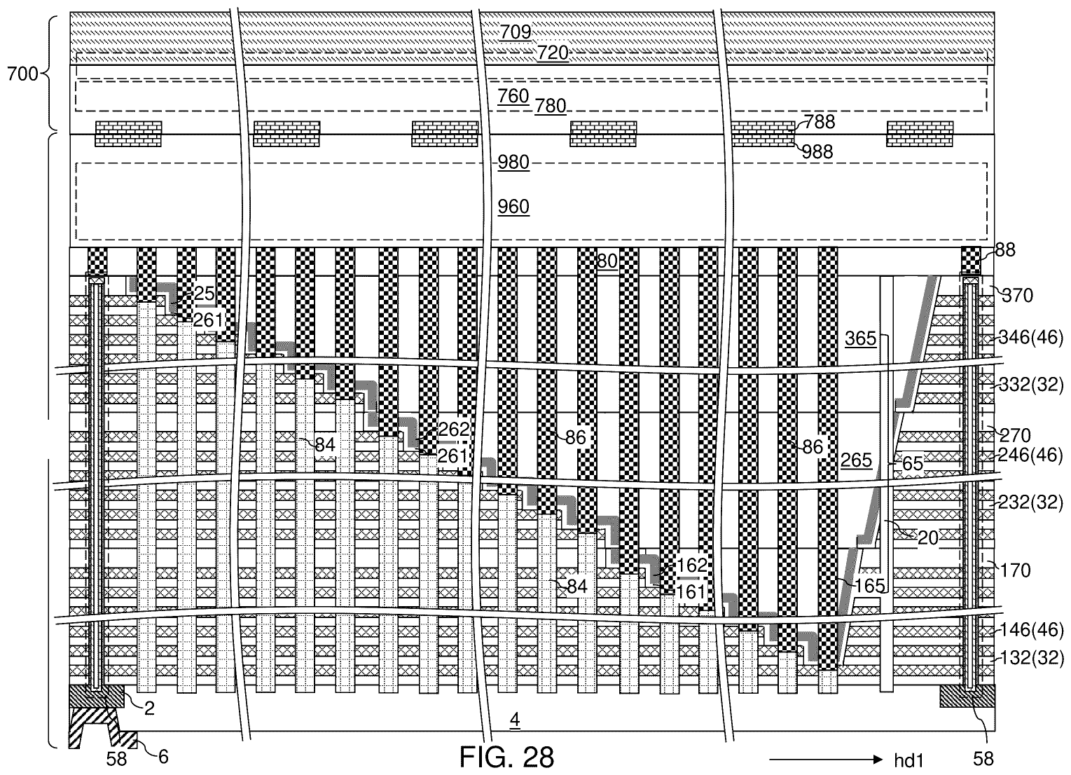

Referring to FIG. 28, the substrate 9 can be removed, for example, by grinding, polishing, cleaving, an isotropic etch process, an anisotropic etch process, and/or a combination thereof. In one embodiment, at least a terminal step of at least one removal process that is employed to remove the substrate 9 may comprise a selective wet etch process that etches the material of the substrate 9 (such as a semiconductor material of the substrate 9) selective to dielectric materials of the memory films 50. In an illustrative example, if the substrate 9 comprises a semiconductor material, the terminal step of the at least one removal process may comprise a wet etch process using hot trimethyl-2 hydroxyethyl ammonium hydroxide (“hot TMY”) or tetramethyl ammonium hydroxide (TMAH). The entirety of the substrate 9 can be removed by the selective wet etch process. Backside end surfaces of the support pillar structures 20 can be physically exposed upon removal of the substrate 9.

An end portion of each memory opening fill structure 58 can be removed. In one embodiment, an end portion of each memory film 50 may be removed by performing a sequence of wet etch processes. A horizontal end portion of each vertical semiconductor channel 60 may be physically exposed. In one embodiment, the sequence of wet etch processes may be selective to the material of the vertical semiconductor channels 60.

At least one source structure 2 (e.g., a source region and/or source line) can be formed in contact vertical semiconductor channels 60. The at least one source structure 2 may comprise a heavily doped semiconductor material and/or a metallic material (e.g., a metal and/or an electrically conductive metal nitride or silicide). A backside dielectric layer 4 and backside contact structures 6 can be subsequently formed.

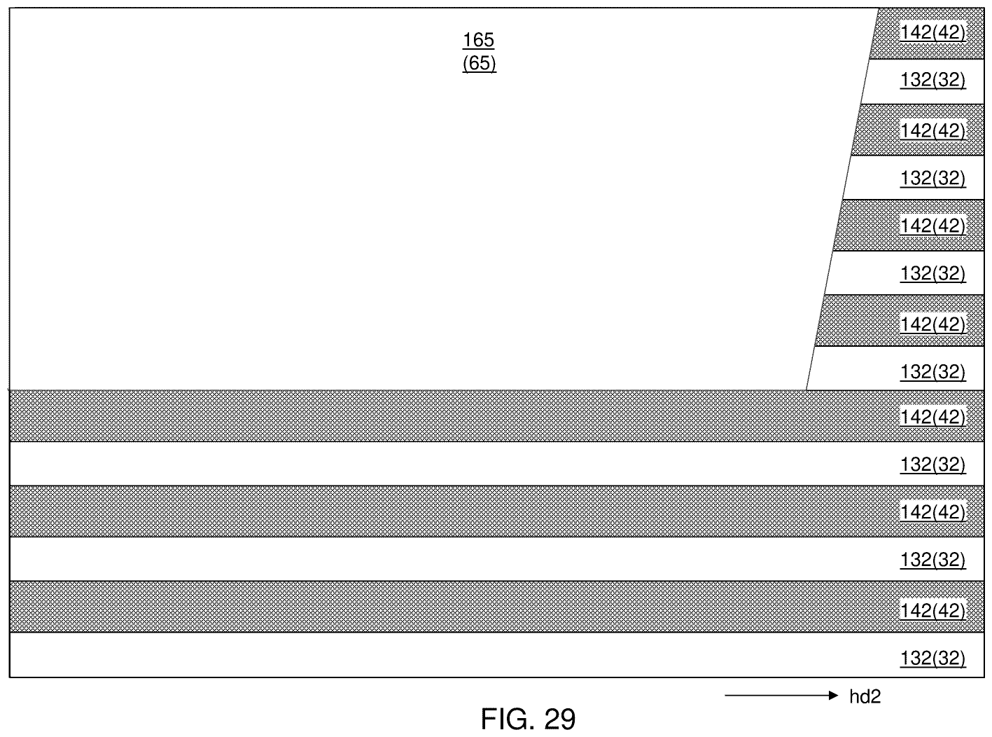

Referring to FIG. 29, a region of a second exemplary structure is illustrated after formation of the first-tier retro-stepped dielectric material portion 165. The second exemplary structure can be derived from the first exemplary structure by omitting all processing steps for locally thickening the sacrificial material layers 42 and optionally omitting formation of silicon oxide buffer layers (161, 261, 361) and silicon nitride buffer layers (162, 262, 362). Thus, the processing steps described with reference to FIGS. 3A-3D and corresponding processing steps during formation of a second-tier structure and a third-tier structure can be omitted during formation of the first configuration of the second exemplary structure. Except for the above modifications, the processing steps described with reference to FIGS. 2A and 2B, 4A-10B can be performed to provide the second exemplary structure.

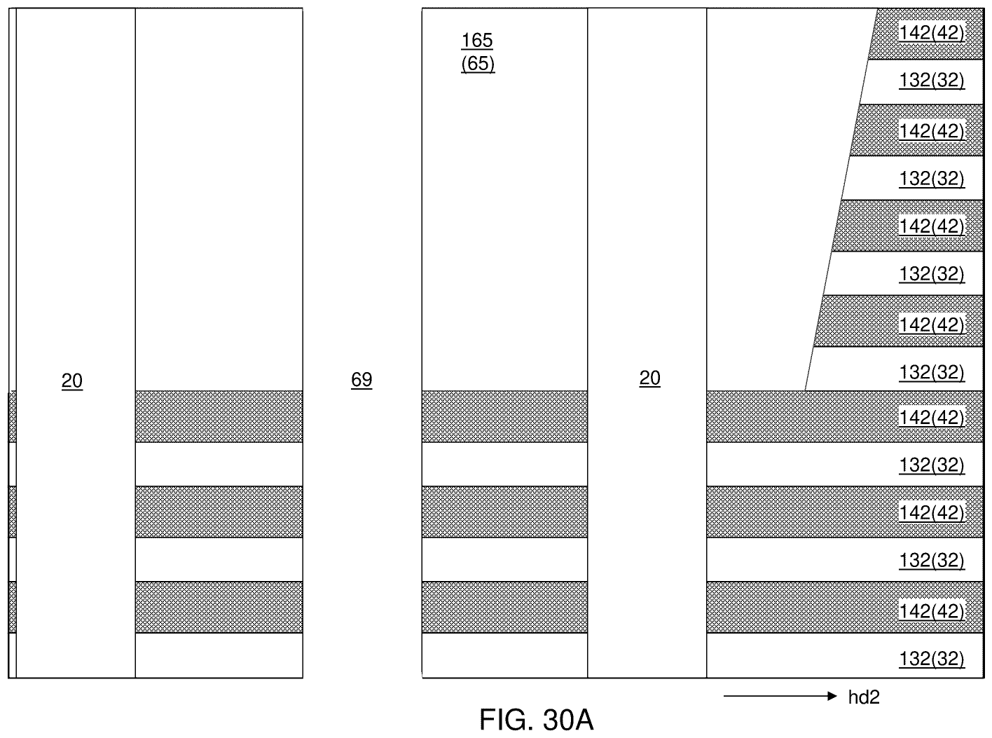

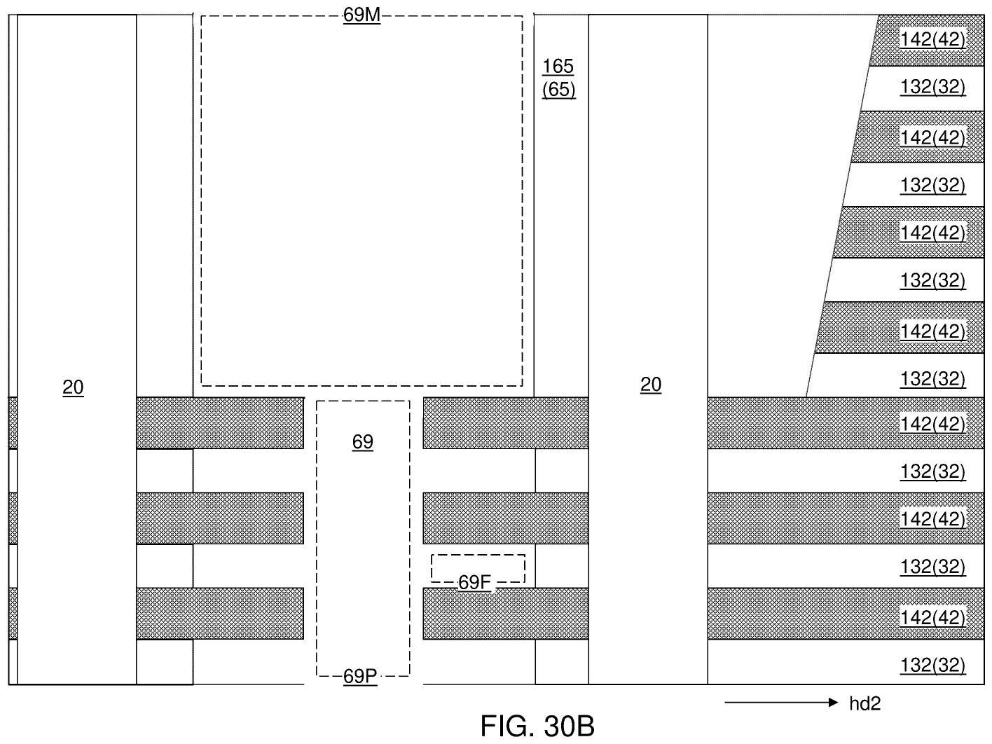

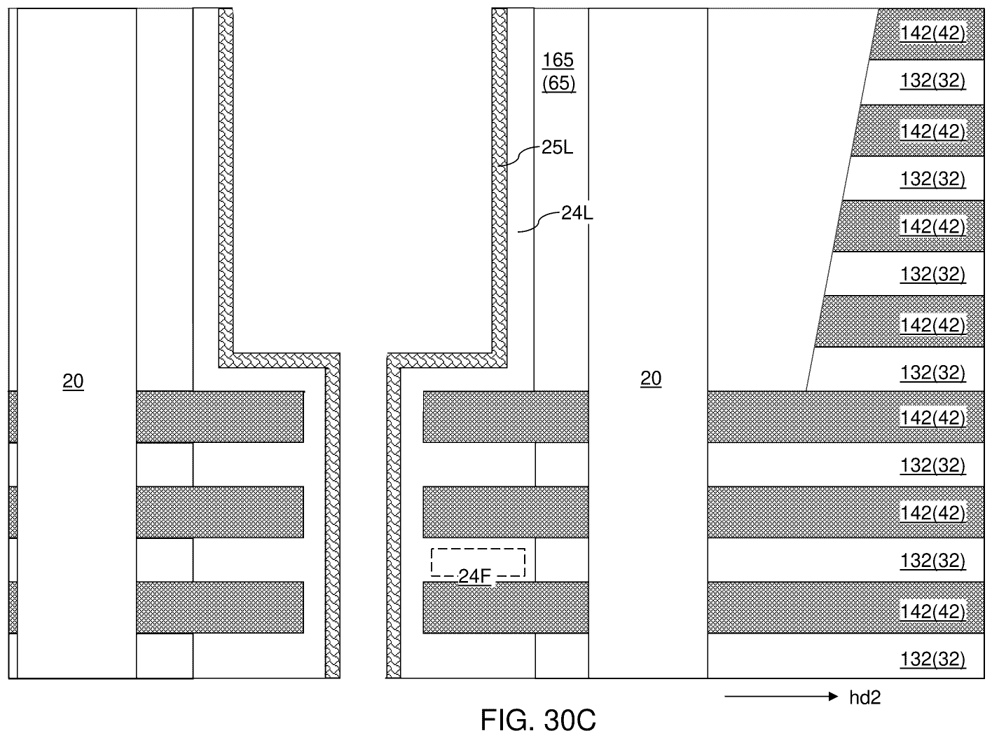

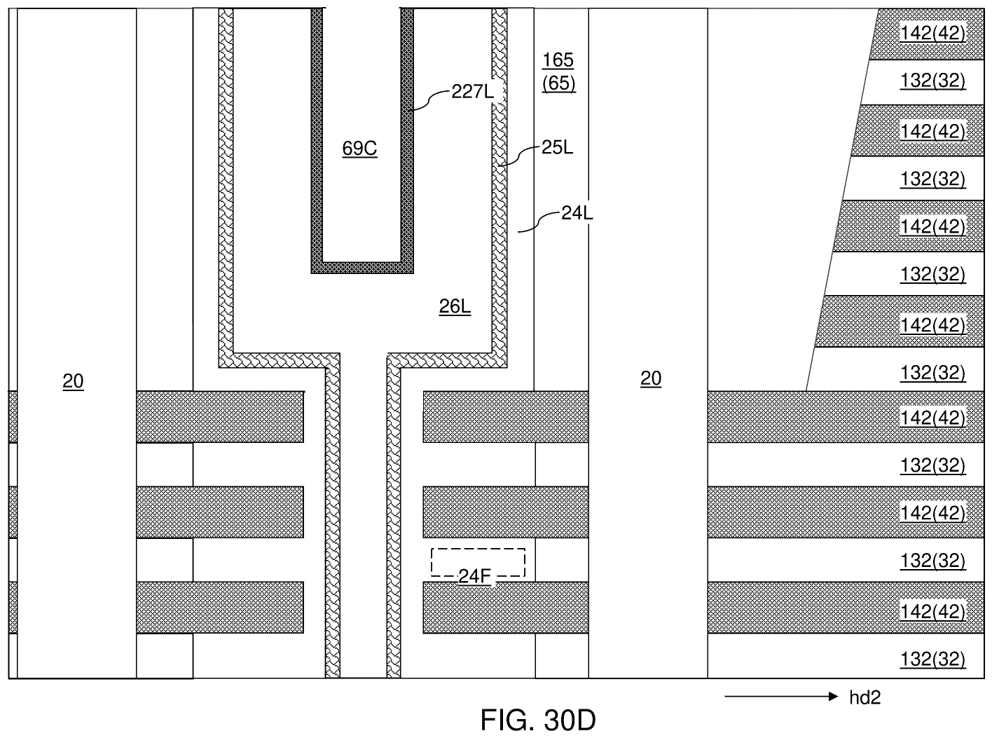

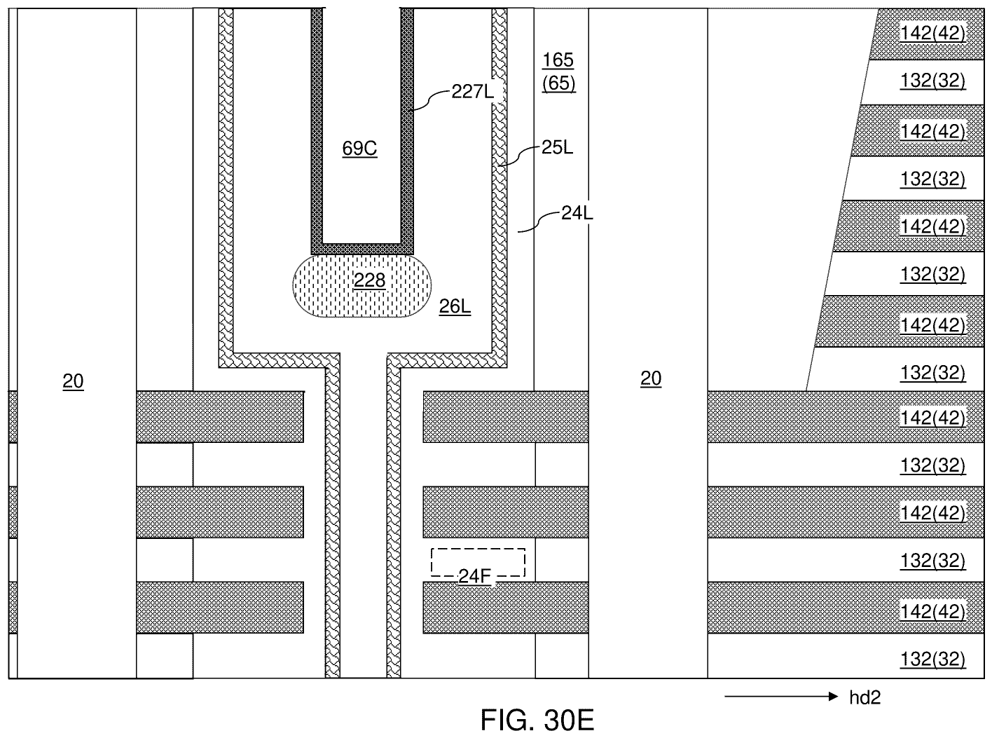

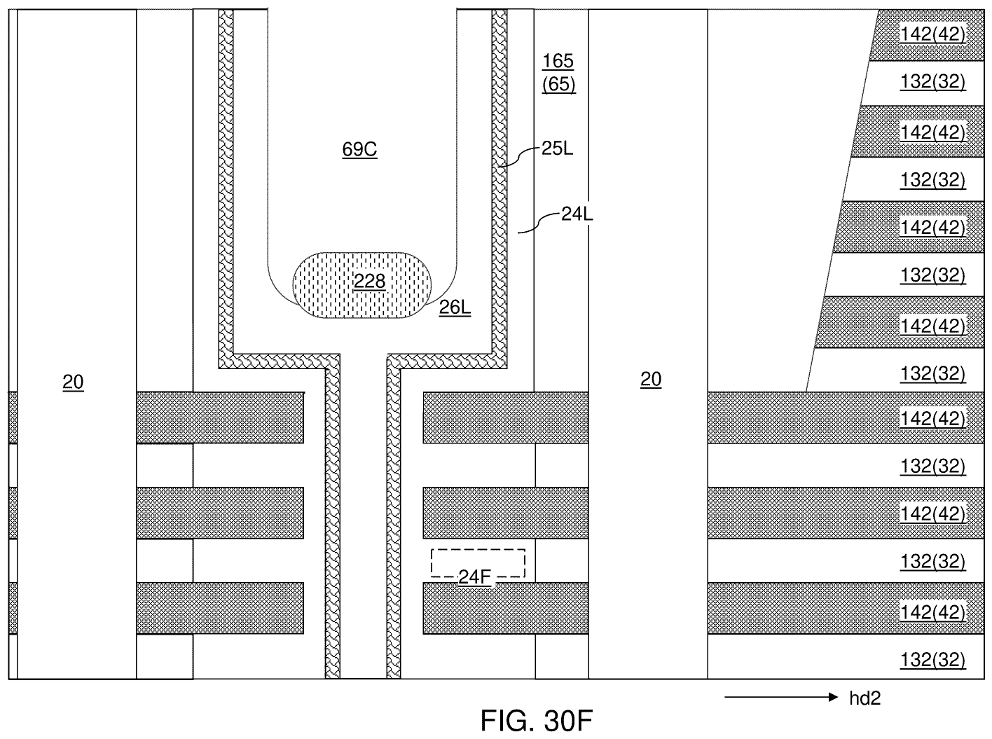

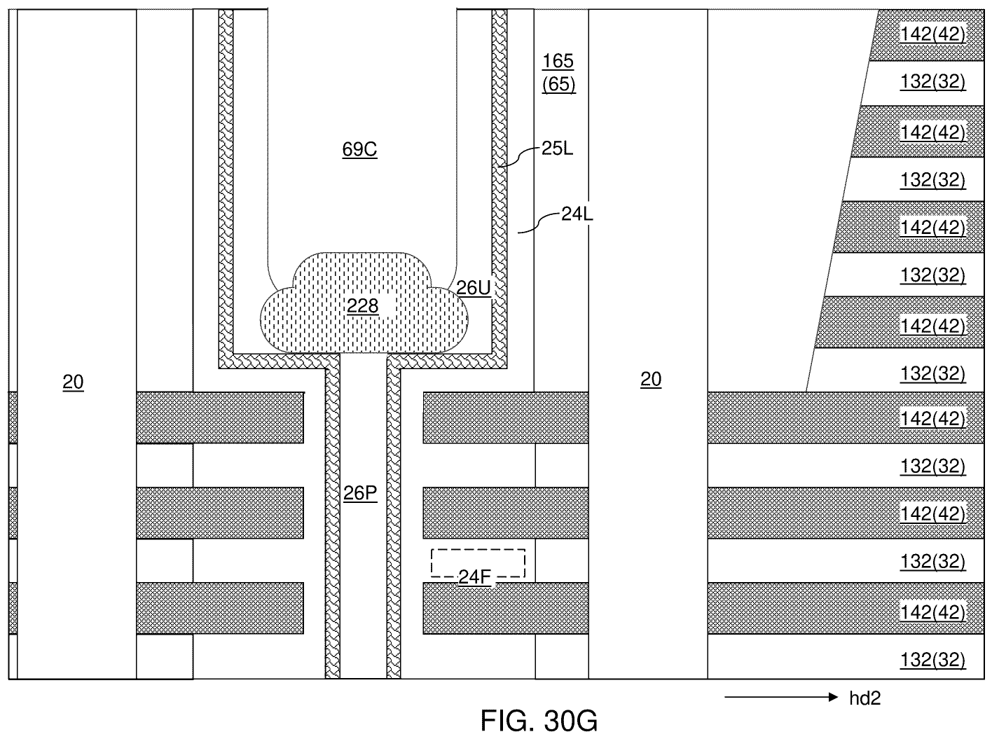

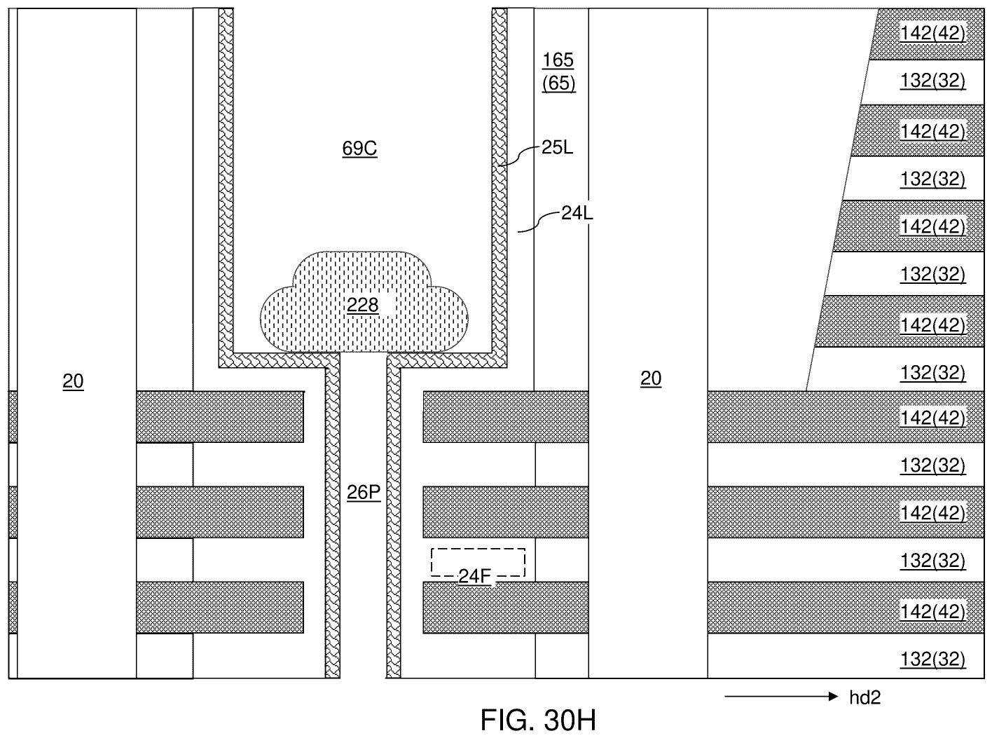

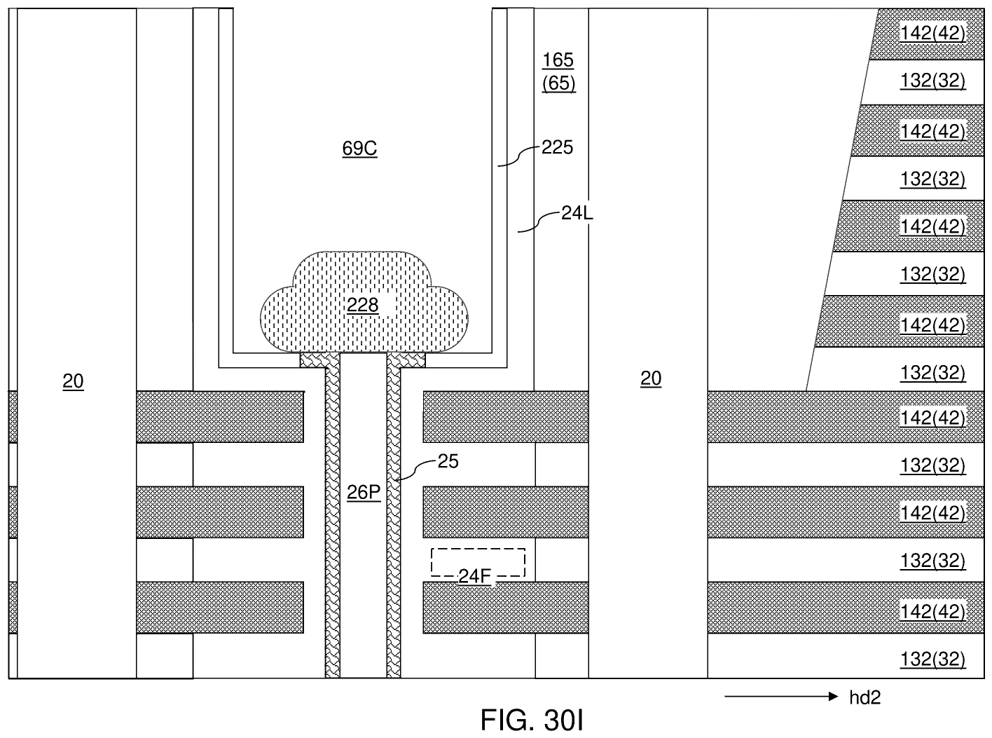

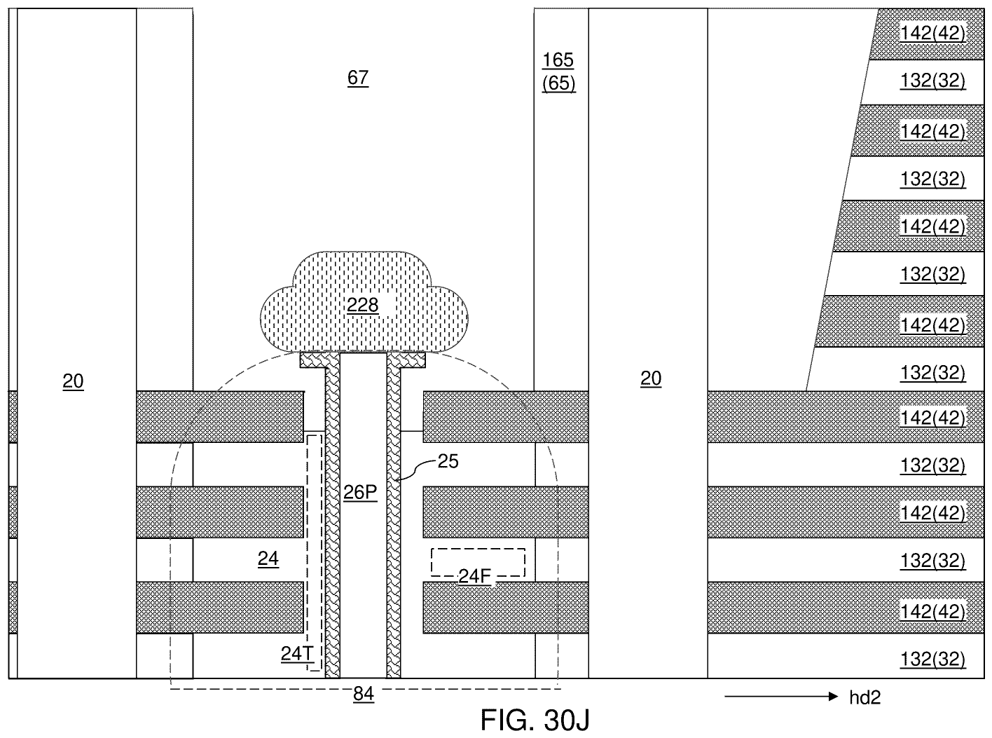

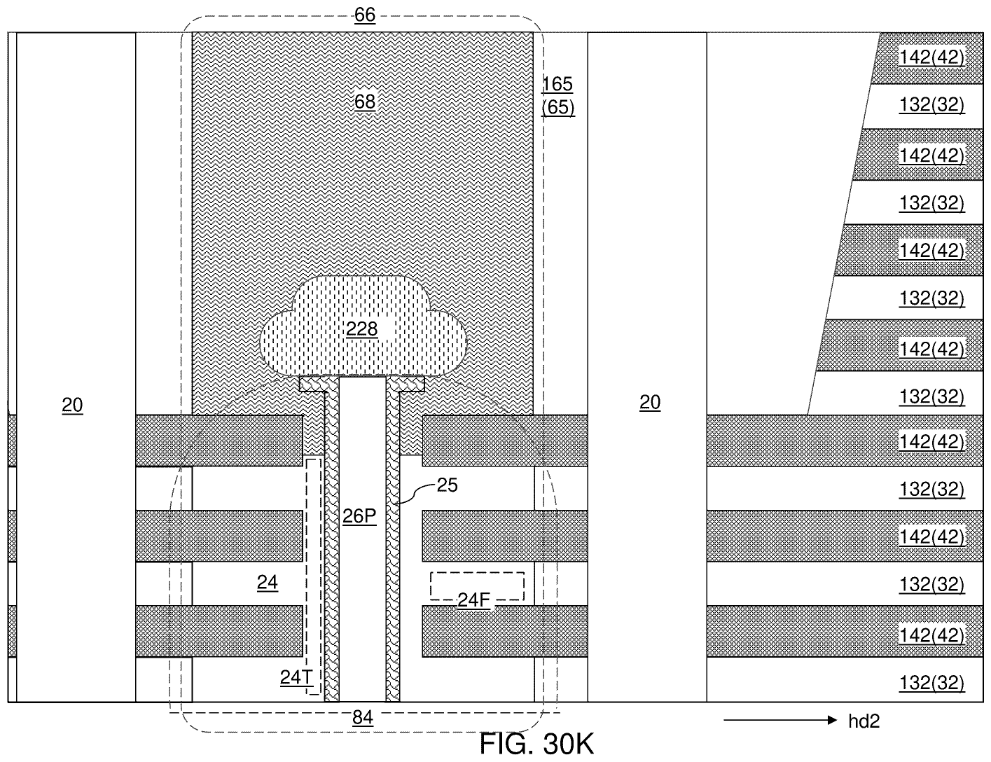

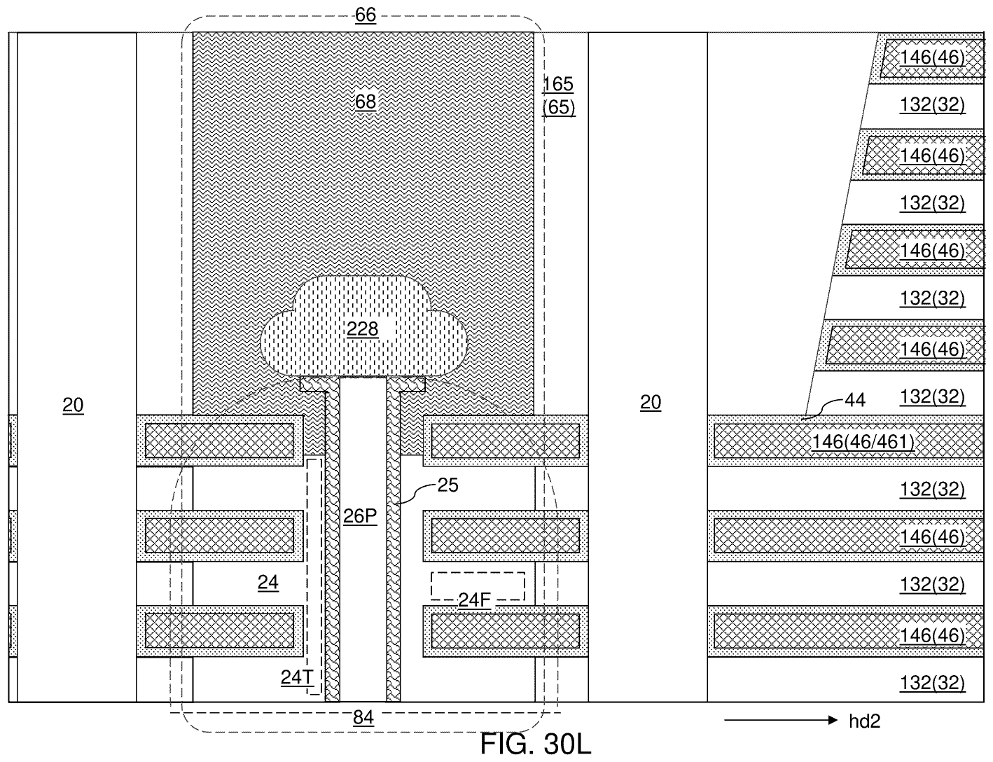

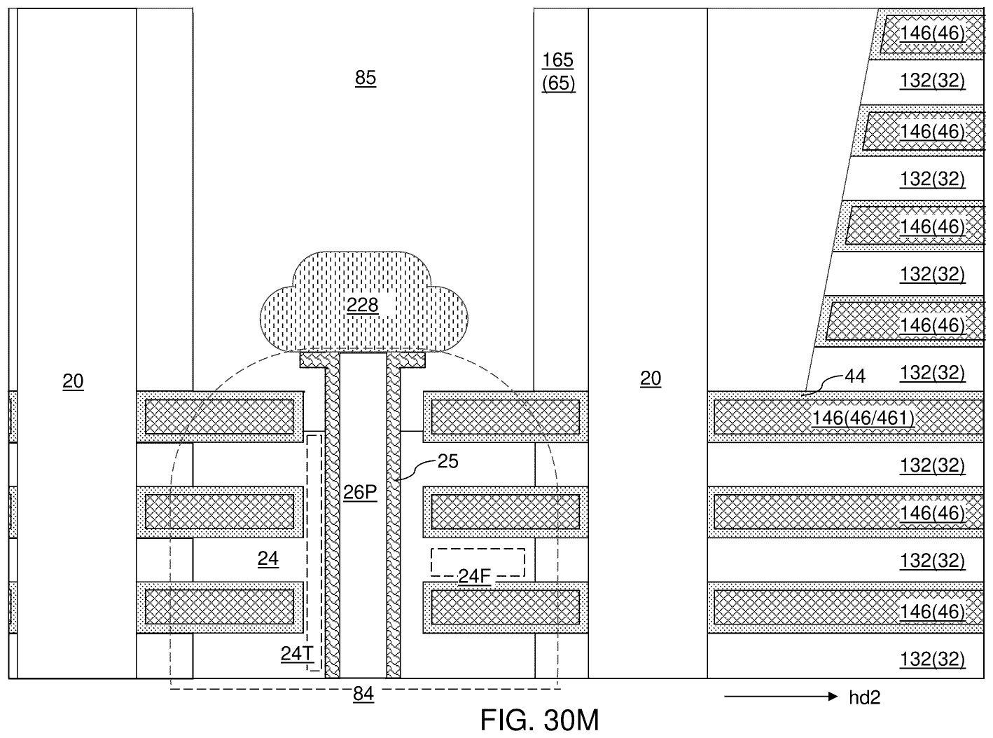

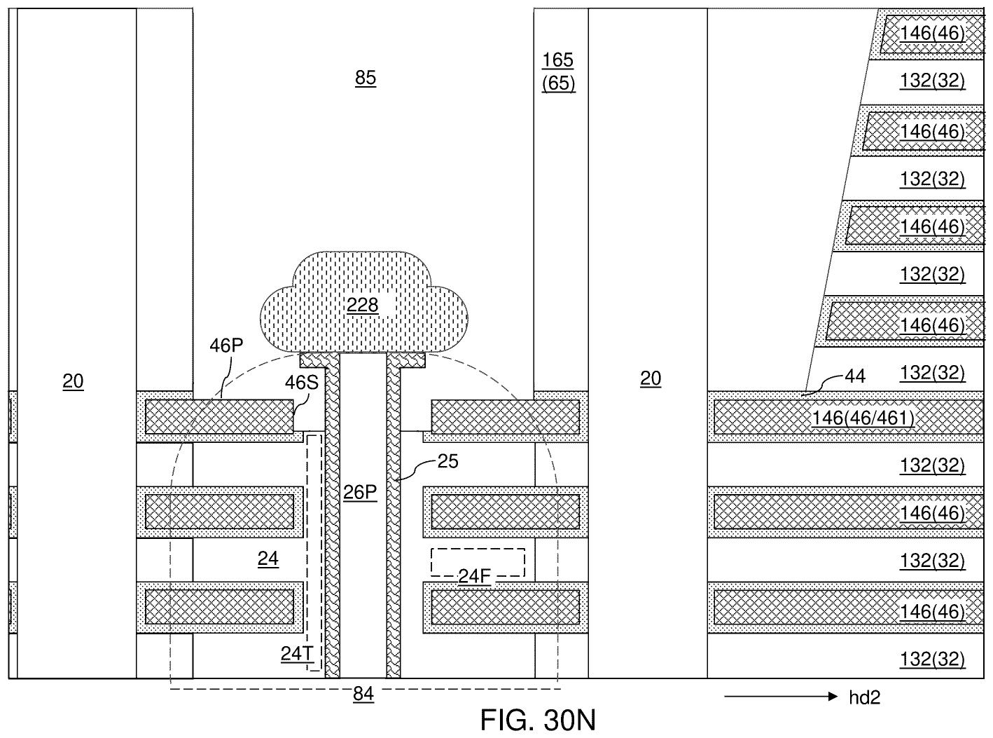

FIGS. 30A-30O are sequential vertical cross-sectional views of a region of a first configuration of the second exemplary structure during formation of a combination of a finned support assembly 84 and a layer contact via structure 86 according to the second embodiment of the present disclosure.

Referring to FIG. 30A, the first configuration of the second exemplary structure is shown after performing the processing steps described with reference to FIGS. 11A-11C. Contact via cavities 69 can be formed through at least one retro-stepped dielectric material portion 65 and an underlying vertically alternating sequence of insulating layers 32 and sacrificial material layers 42.

Referring to FIG. 30B, a first selective isotropic etch process can be performed to laterally recess surface portions of the insulating layers 32 and the retro-stepped dielectric material portions 65 around each contact via cavity 69. In an illustrative example, the insulating layers 32 and the retro-stepped dielectric material portions 65 may comprise a respective silicon oxide material (such as undoped silicate glass or a doped silicate glass), and the sacrificial material layers 42 may comprise silicon nitride. In this case, the first selective isotropic etch process may comprise a wet etch process employing dilute hydrofluoric acid. Annular fin cavities 69F are formed in volumes from which portions of the insulating layers 32 are removed during the first selective isotropic etch process. Each contact via cavity 69 can be laterally expanded by laterally recessing a respective cylindrical sidewall of a retro-stepped dielectric material portions 65. The duration of the first selective isotropic etch process can be selected such that the lateral recess distance of the first selective isotropic etch process for the insulating layers 32 is in a range from 100% to 600%, such as from 150% to 400%, of the thickness of each insulating layer 32.

After the first selective isotropic etch process, each contact via cavity 69 may comprise a main cavity portion 69M that is laterally surrounded by at least one retro-stepped dielectric material portion 65, having a respective cylindrical shape, and vertically extending from the horizontal plane including the top surface of the topmost retro-stepped dielectric material portion (such as a third-tier retro-stepped dielectric material portion 365) to a respective annular top surface segment of a sacrificial material layer 42. Further, each contact via cavity 69 may comprise a pillar cavity portion 69P having a shape of a cylinder and vertically extending from the horizontal plane including the respective annular top surface segment of the sacrificial material layer 42 to the substrate 9. In addition, each contact via cavity 69 may comprise at least one annular fin cavity 69F located at each level of the insulating layers 32 that laterally surrounds the pillar cavity portion 69P.

Referring to FIG. 30C, a dielectric material, such as undoped silicate glass or a doped silicate glass, can be conformally deposited in peripheral regions of the contact via cavities 69 to form a dielectric material layer 24L. The dielectric material layer 24L may be deposited by a conformal deposition process such as a chemical vapor deposition process. The thickness of the dielectric material layer 24L can be greater than one half of the height of each annular fin cavity 69F located at levels of the insulating layers 32 (which is the same as the thickness of each insulating layer 32). The thickness of the dielectric material layer 24L is less than the lateral dimension (such as a diameter) of the pillar cavity portion 69P of each contact via cavity 69. The dielectric material layer 24L can fill the volumes of the annular fin cavities 69F, and thus, a dielectric fin 24F having a shape of an annular plate can be formed within each annular fin cavity 69F.

A semiconductor liner layer 25L can be deposited by a conformal deposition process such as a chemical vapor deposition process. The semiconductor liner layer 25L comprises a semiconductor material such as amorphous silicon, polysilicon, or a compound semiconductor material. The thickness of the semiconductor liner layer 25L may be in a range from 5 nm to 60 nm, such as from 10 nm to 40 nm, although lesser and greater thicknesses may also be employed. The semiconductor liner layer 25L may comprise an intrinsic semiconductor material, and/or is not intentionally doped with electrical dopants (such as p-type dopants or n-type dopants). As such, the atomic concentration of electrical dopants in the semiconductor liner layer 25L may be in a range from 1.0×10¹⁰/cm³ to 1.0×10¹⁶/cm³, such as from 1.0×10¹²/cm³ to 1.0×10¹⁵/cm³.

Referring to FIG. 30D, a silicate glass material such as undoped silicate glass (i.e., silicon oxide) or a doped silicate glass can be conformally deposited to form a dielectric fill material layer 26L, which fills remaining volumes of the pillar cavity portions 69P of the contact via cavities 69 but leaves an unfilled cavity portion 69C of the main cavity portion 69M. Thus, the volumes of the annular fin cavities 69F and the pillar cavity portions 69P of the contact via cavities 69 can be filled with a combination of the dielectric material layer 24L, the semiconductor liner layer 25L, and the dielectric fill material layer 26L.

An optional implant barrier liner 227L may be optionally deposited over the dielectric fill material layer 26L. The optional implant barrier liner 227, if employed, may comprise a semiconductor material such as silicon, or a carbon-based material such as amorphous carbon. The thickness of the optional implant barrier liner 227L may be in a range from 10 nm to 30 nm, although lesser and greater thicknesses may also be employed.

Referring to FIG. 30E, at least one dopant species selected from nitrogen and carbon can be implanted along a downward vertical direction into a portion of the silicate glass material in the dielectric fill material layer 26L that underlies a cylindrical cavity 69C and overlies a horizontally-extending surface segment of the stepped surfaces of the vertically alternating sequences (32, 42). An implanted portion of the dielectric fill material layer 26L is converted into a doped silicate glass portion 228. The doped silicate glass portion 228 comprises at least one dopant species selected from carbon and nitrogen at an atomic percentage in a range from 1% to 25%, such as from 3% to 20%, and/or from 5% to 15%. In one embodiment, the doped silicate glass portion 228 may comprise carbon atoms at an atomic percentage in a range from 1% to 25%, such as from 3% to 20%, and/or from 5% to 15%. In one embodiment, the doped silicate glass portion 228 may comprise nitrogen atoms at an atomic percentage in a range from 1% to 25%, such as from 3% to 20%, and/or from 5% to 15%. In one embodiment, the doped silicate glass portion 228 may comprise a combination of carbon atoms and nitrogen atoms at a total atomic percentage in a range from 1% to 25%, such as from 3% to 20%, and/or from 5% to 15%. In other words, the doped silicate glass portion 228 comprises silicon oxynitride (SiON), silicon oxycarbide (SiOC) or silicon oxynitride carbide (SiONC).

Referring to FIG. 30F, the implant barrier liner 227L can be removed selective to the material of the dielectric fill material layer 26L. For example, if the implant barrier liner 227L comprises silicon, a wet etch process employing hot trimethyl-2 hydroxyethyl ammonium hydroxide (“hot TMY”) or tetramethyl ammonium hydroxide (TMAH) may be performed to remove the implant barrier liner 227L. If the implant barrier liner 227L comprises amorphous carbon, an ashing process may be performed to remove the implant barrier liner 227L.

A second selective isotropic etch process can be performed to remove an unimplanted portion of the silicate glass material of the dielectric fill material layer 26L selective to the doped silicate glass portion 228. The cavity 69C overlying the doped silicate glass portion 228 can be expanded by the second selective isotropic etch process. In one embodiment, the second selective isotropic etch process may comprise a wet etch process employing dilute hydrofluoric acid. In one embodiment, the duration of the second selective isotropic etch process can be selected such that the semiconductor liner layer 25L is covered by a remaining portion of the dielectric fill material layer 26L after the second selective isotropic etch process.

Referring to FIG. 30G, an additional implantation process (i.e., a second implantation process) can be performed to implant at least one dopant species selected from nitrogen and carbon. The at least one dopant species is implanted along a downward vertical direction into the doped silicate glass portion 228 and into a remaining portion of the silicate glass material in the dielectric fill material layer 26L that underlies the cavity 69C and overlies a horizontally-extending surface segment of the stepped surfaces of the vertically alternating sequences (32, 42). The additional implantation process converts an additional implanted portion of the dielectric fill material layer 26L into an additional portion of the doped silicate glass portion 228. Thus, the additional implantation process increases the volume of the doped silicate glass portion 228. In one embodiment, the doped silicate glass portion 228 comprises an upper region having a first lateral extent, and a lower region having a second lateral extent that is greater than the first lateral extent. In one embodiment, the bottom surface of the doped silicate glass portion 228 may contact an annular portion of the semiconductor liner layer 25L. The portion of the dielectric fill material layer 26L that underlies the doped silicate glass portion 228 is herein referred to as a cylindrical dielectric pillar 26P.

The doped silicate glass portion 228 comprises at least one dopant species selected from carbon and nitrogen at an atomic percentage in a range from 1% to 25%, such as from 3% to 20%, and/or from 5% to 15%. In one embodiment, the doped silicate glass portion 228 may comprise carbon atoms at an atomic percentage in a range from 1% to 25%, such as from 3% to 20%, and/or from 5% to 15%. In one embodiment, the doped silicate glass portion 228 may comprise nitrogen atoms at an atomic percentage in a range from 1% to 25%, such as from 3% to 20%, and/or from 5% to 15%. In one embodiment, the doped silicate glass portion 228 may comprise a combination of carbon atoms and nitrogen atoms at a total atomic percentage in a range from 1% to 25%, such as from 3% to 20%, and/or from 5% to 15%.

Referring to FIG. 30H, a third selective isotropic etch process can be performed to remove an unimplanted portion of the dielectric fill material layer 26L from above the horizontally-extending portion of the semiconductor liner layer 25L selective to the doped silicate glass portion 228. The cavity 69C overlying the doped silicate glass portion 228 can be expanded by the third selective isotropic etch process until the portion of the dielectric fill material layer 26L overlying the horizontally-extending portion of the semiconductor liner layer 25L is completely removed, and the cylindrical inner sidewall of a cylindrical portion of the semiconductor liner layer 25L is exposed. In one embodiment, the third selective isotropic etch process may comprise a wet etch process employing dilute hydrofluoric acid.

In an alternative embodiment, the depth of the ion implantation process employed at the processing steps of FIG. 30E can be increased such that the doped silicate glass portion 228 contacts the horizontally-extending portion of the semiconductor liner layer 25L. In this case, the second selective isotropic etch process can be temporally extended until the unimplanted portion of the silicate glass material of the dielectric fill material layer 26L is completely removed from above the horizontally-extending portion of the semiconductor liner layer 25L selective to the doped silicate glass portion 228. In this case, the processing steps described with reference to FIGS. 30G and 30H can be omitted.

Referring to FIG. 30I, an oxidation process can be performed to convert the physically-exposed portion of the semiconductor liner layer 25L into a semiconductor oxide liner layer 225, which may comprise silicon oxide. The remaining portion of the semiconductor liner layer 25L has a tubular configuration, and is herein referred to as a tubular semiconductor liner 25. The tubular semiconductor liner 25 laterally surrounds the cylindrical dielectric pillar 26P. The outer surface of the doped silicate glass portion 228 may also be oxidized to form a silicon oxide liner around the doped silicate glass portion 228.

Referring to FIG. 30J, an isotropic etch process can be performed to isotropically etch silicon oxide materials of the semiconductor oxide liner layer 225, an upper portion of the dielectric material layer 24L, and the oxide liner around the doped silicate glass portion 228 selective to the materials of the sacrificial material layers 42 and the doped silicate glass portion 228. For example, the isotropic etch process may comprise a wet etch process employing dilute hydrofluoric acid as an etchant. The semiconductor oxide liner layer 225, an upper portion of the dielectric material layer 24L, and oxide liner around the doped silicate glass portion 228 can be removed by the isotropic etch process. A remaining lower portion of the dielectric material layer 24L comprises a dielectric material portion, which is herein referred to as a finned dielectric pillar 24. Each finned dielectric pillar 24 comprises a tubular dielectric portion 24T and at least one dielectric fin 24F that laterally protrudes from the tubular dielectric portion 24T. The at least one dielectric fin 24F may comprise a plurality of dielectric fins 24F for some of the finned dielectric pillars 24.

A layer contact via cavity 67 is formed around each doped silicate glass portion 228. An annular surface segment of a top surface of a sacrificial material layer 42 can be physically exposed underneath each layer contact via cavity 67. A cylindrical sidewall surface segment of an opening in the sacrificial material layer 42 can also be optionally physically exposed underneath each layer contact via cavity 67. The assembly of all material portions that replaces materials of the insulating layers 32 and the sacrificial material layers 42 and underlies a layer contact via cavity 67 is herein referred to as a finned support assembly 84. The finned support assembly comprises a cylindrical dielectric pillar 26P, a tubular semiconductor liner 25 that laterally surrounds the cylindrical dielectric pillar 26P, and a finned dielectric pillar 24 laterally surrounding the tubular semiconductor liner 25 and comprising a tubular dielectric portion 24T and at least one dielectric fin 24F (which may be a plurality of dielectric fins 24F) that laterally protrudes from the tubular dielectric portion 24T.

Referring to FIG. 30K, a sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Referring to FIG. 30L, the processing steps described with reference to FIGS. 14-19C can be performed to form memory opening fill structures 58 and to replace the sacrificial material layers 42 with electrically conductive layers 46.

Referring to FIG. 30M, the processing steps described with reference to FIGS. 20A-21C can be performed to form lateral isolation trench fill structures 76 and connection via cavities, and to form layer contact via cavities 85 by removing the sacrificial contact via structures 68.

Referring to FIG. 30N, an isotropic etch process, such as a wet etch process, can be performed to remove physically exposed surface portions of the outer blocking dielectric layers 44. An annular planar top surface segment 46P and a cylindrical sidewall surface segment 46S of an electrically conductive layer 46 can be physically exposed underneath each layer contact via cavity 85.

Referring to FIG. 30O, at least one electrically conductive material, such as at least one metallic material can be deposited in the layer contact via cavities 85. The at least one metallic material may comprise a combination of a metallic barrier liner material (such as TiN, TaN, WN, and/or MoN) and a metallic fill material (such as W, Ru, Mo, Co, Cu, etc.). Excess portions of the at least one metallic material can be removed from above the horizontal plane including the top surface of the contact-level dielectric layer 80. Each remaining portion of the at least one metallic material that fills a respective layer contact via cavity 85 constitutes a layer contact via structure 86.

Each layer contact via structure 86 may comprise a tubular portion 86T contacting a surface segment of an outer sidewall of a tubular semiconductor liner 25 and contacting a cylindrical sidewall surface segment 46S of an opening in a respective first electrically conductive layer 461 of the electrically conductive layers 46.

During formation of the first configuration of the second exemplary structure, a contact assembly (84, 228, 86) comprising a finned support assembly 84, a doped silicate glass portion 228 overlying the finned support assembly 84, and the contact via structure 86 can be formed in a contact via cavity. The doped silicate glass portion 228 can be interposed between the finned support assembly 84 and the layer contact via structure 86. In one embodiment, each layer contact via structure 86 vertically extends through the retro-stepped dielectric material portion 65 and comprises a contoured bottom surface that includes an annular surface segment that contacts an annular top surface segment 46P of a respective first electrically conductive layer 461 of the electrically conductive layers 46. The finned support assembly 84 contacts central surface segments of the contoured bottom surface of the layer contact via structure 86. All surface segments of the doped silicate glass portion 228 that overlie a topmost surface of the finned support assembly 84 are in contact with surface segments of the layer contact via structure 86.

In one embodiment, the doped silicate glass portion 228 comprises at least one dopant species selected from carbon and nitrogen at an atomic percentage in a range from 1% to 25%. In one embodiment, the doped silicate glass portion 228 comprises a carbon-doped silicate glass (i.e., silicon oxycarbide). In another embodiment, the doped silicate glass portion 228 comprises a nitrogen-doped silicate glass (i.e., silicon oxynitride). In one embodiment, a maximum horizontal cross-sectional area of the doped silicate glass portion 228 is greater than an area of a topmost surface of the finned support assembly 84. In one embodiment, the doped silicate glass portion 228 comprises an upper region having a first lateral extent, and a lower region having a second lateral extent that is greater than the first lateral extent.

In one embodiment, the layer contact via structure 86 comprises tubular portion 86T having an outer cylindrical surface that contacts a cylindrical sidewall surface segment 46S of an opening through the first electrically conductive layer 461. In one embodiment, the tubular portion 86T of the layer contact via structure 86 contacts a cylindrical sidewall surface segment of the finned support assembly 84.

In one embodiment, the finned support assembly 84 comprises a dielectric material portion (such as a cylindrical dielectric pillar 26P) having a planar top surface that contacts a central bottom surface segment of the doped silicate glass portion 228, and a spacer liner (such as a tubular semiconductor liner 25) that laterally surrounds the dielectric material portion (such as a cylindrical dielectric pillar 26P) and contacting an annular bottom surface segment of the doped silicate glass portion 228. In one embodiment, the spacer liner (such as the tubular semiconductor liner 25) comprises an outer cylindrical surface segment that contacts a cylindrical sidewall surface segment 46S of the layer contact via structure 86. In one embodiment, the dielectric material portion comprises a cylindrical dielectric pillar 26P, and the finned support assembly 84 further comprises a finned dielectric pillar 24 that laterally surrounds the spacer liner (such as the tubular semiconductor liner 25) and comprises a tubular dielectric portion 24T in contact with the spacer liner (such as the tubular semiconductor liner 25) and a plurality of dielectric fins 24F that laterally protrude from the tubular dielectric portion 24T. In one embodiment, the plurality of dielectric fins 24F are located at levels of a subset of the insulating layers 32 that underlie the first electrically conductive layer 461. In one embodiment, the spacer liner (such as the tubular semiconductor liner 25) comprises a semiconductor material, such as amorphous silicon or polysilicon.

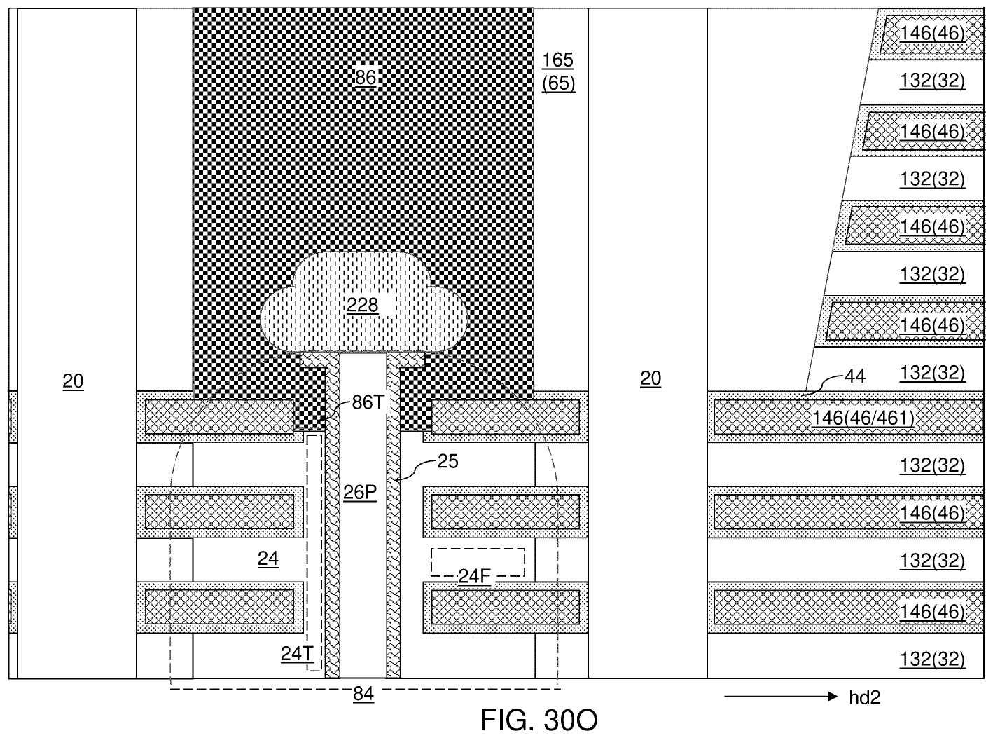

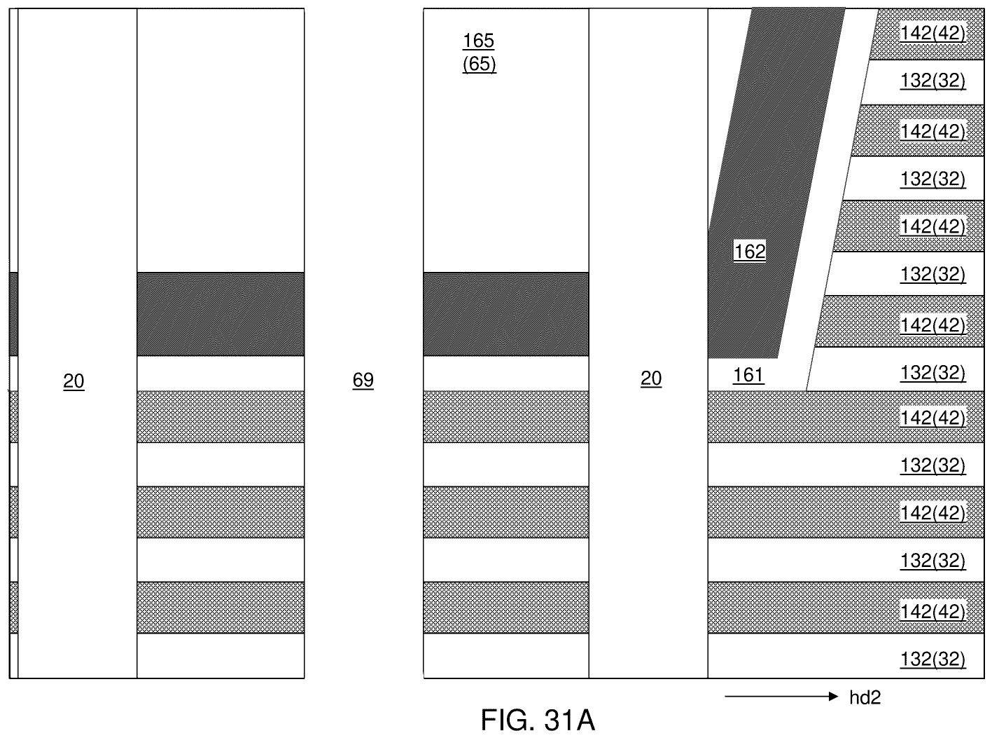

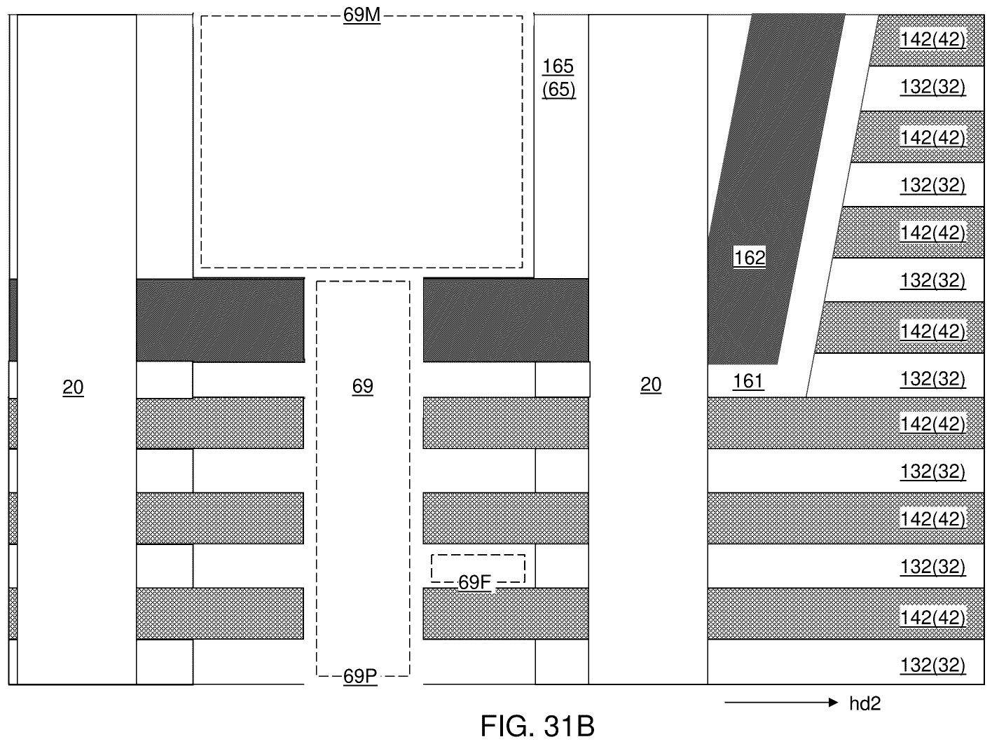

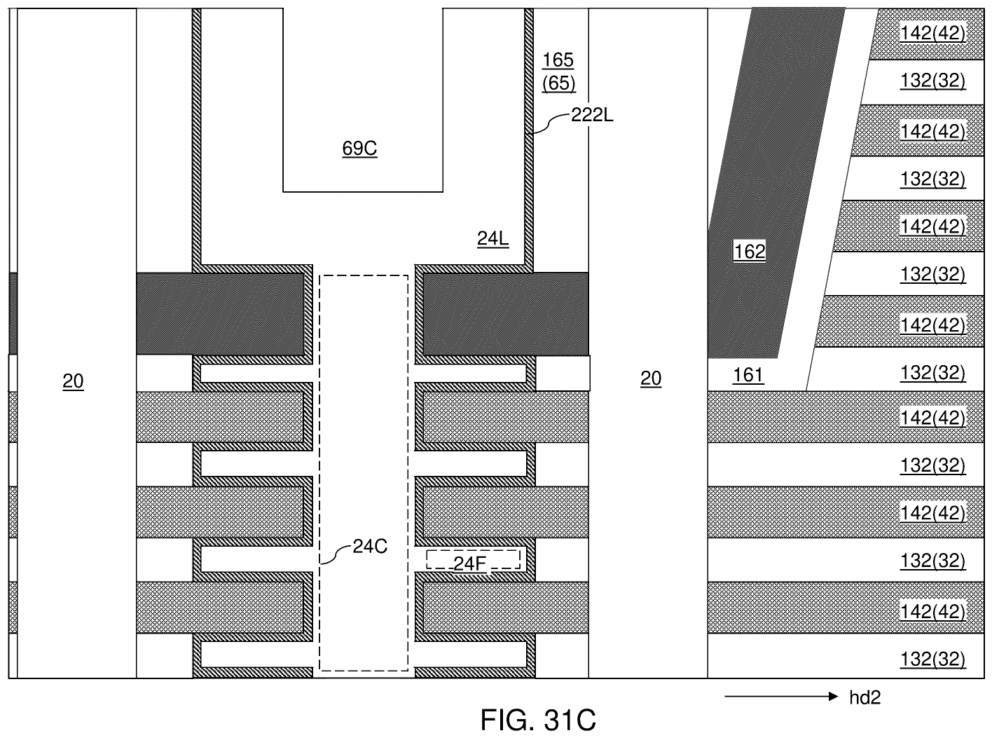

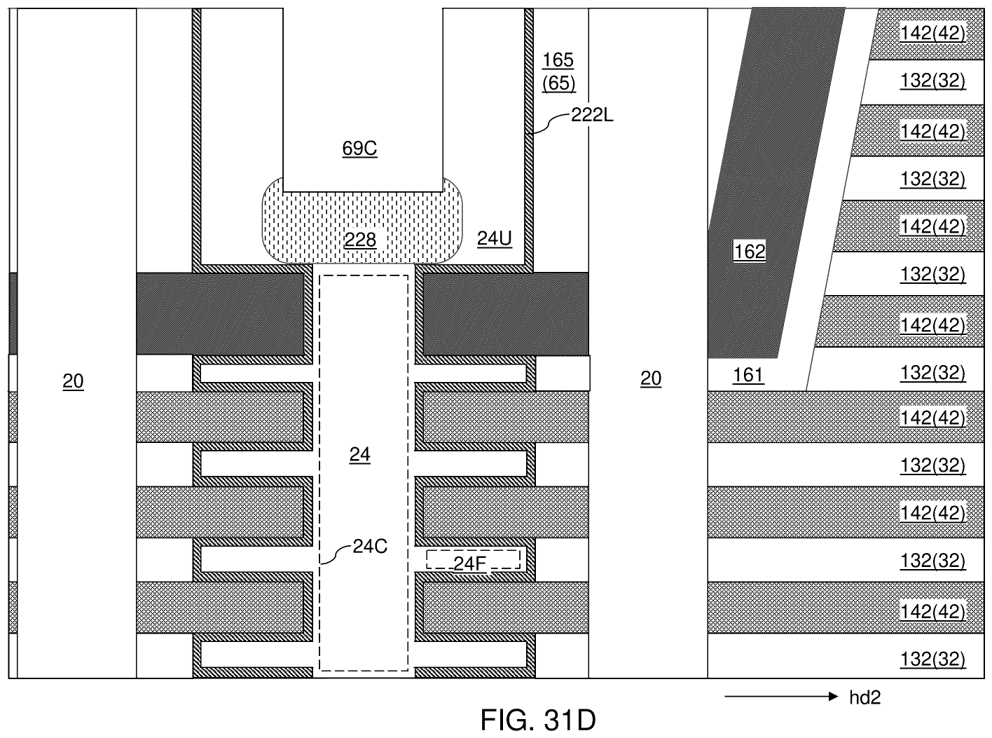

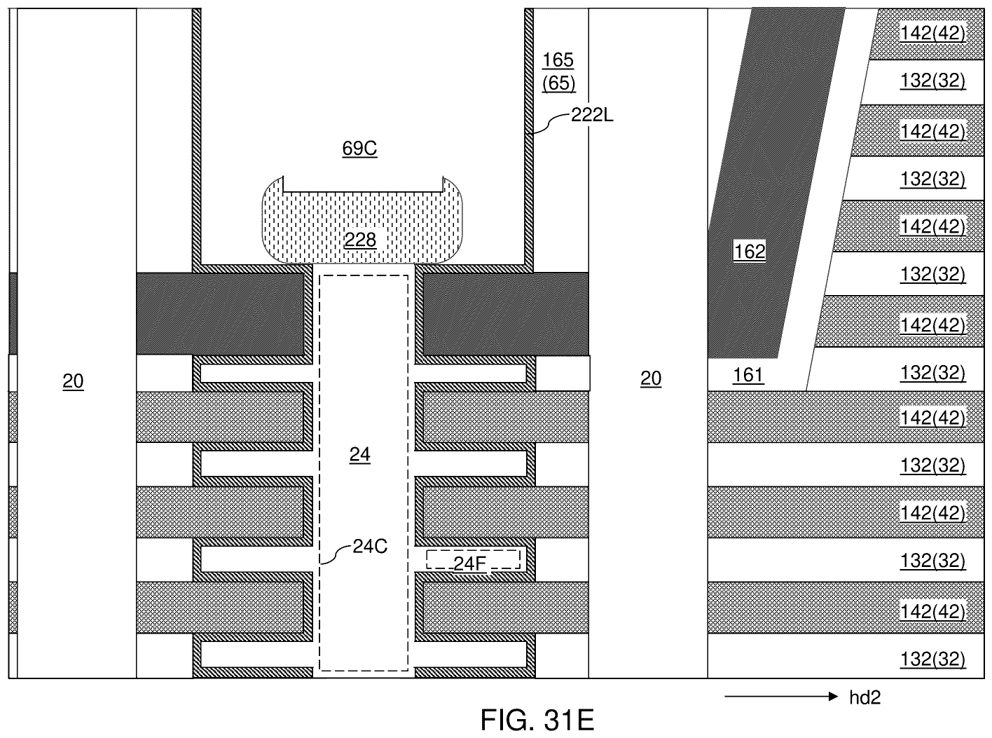

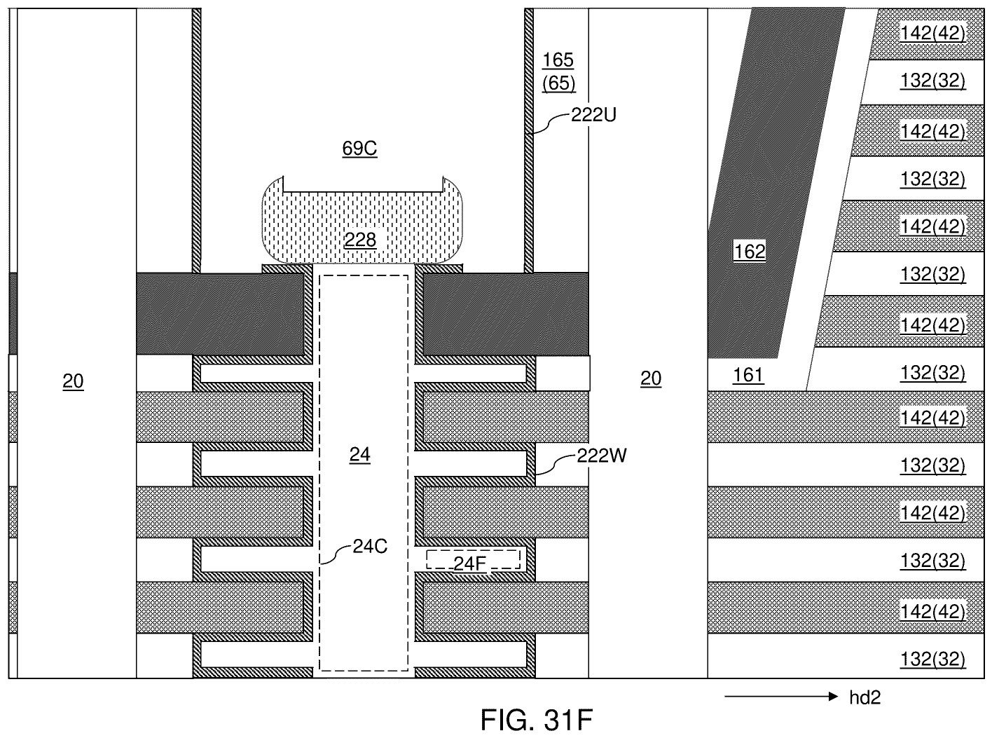

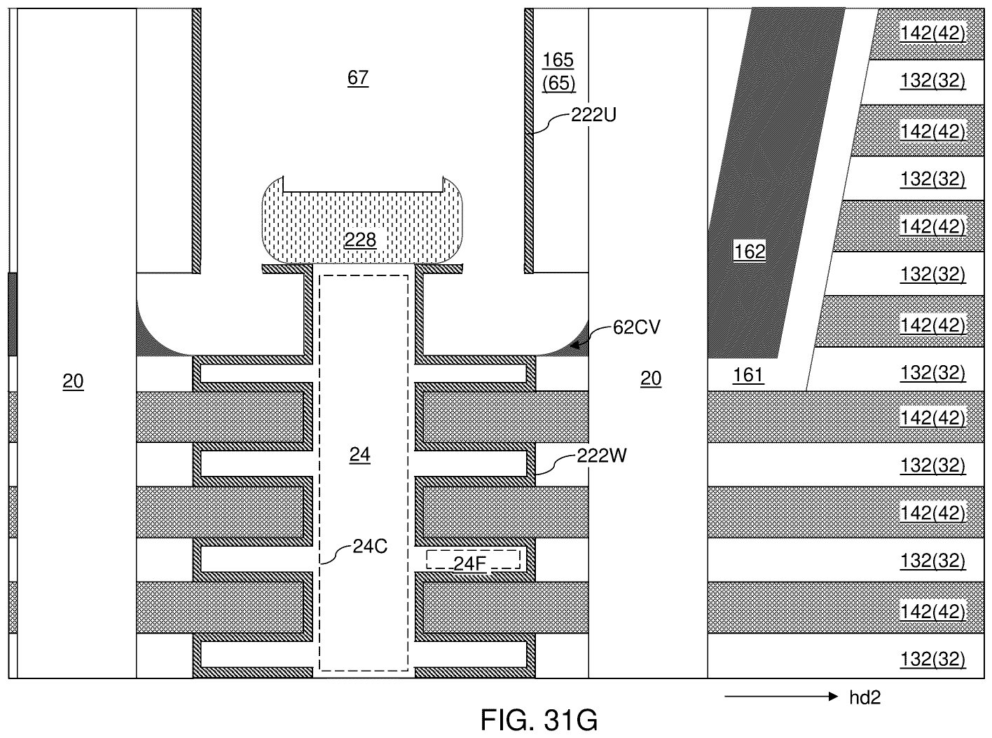

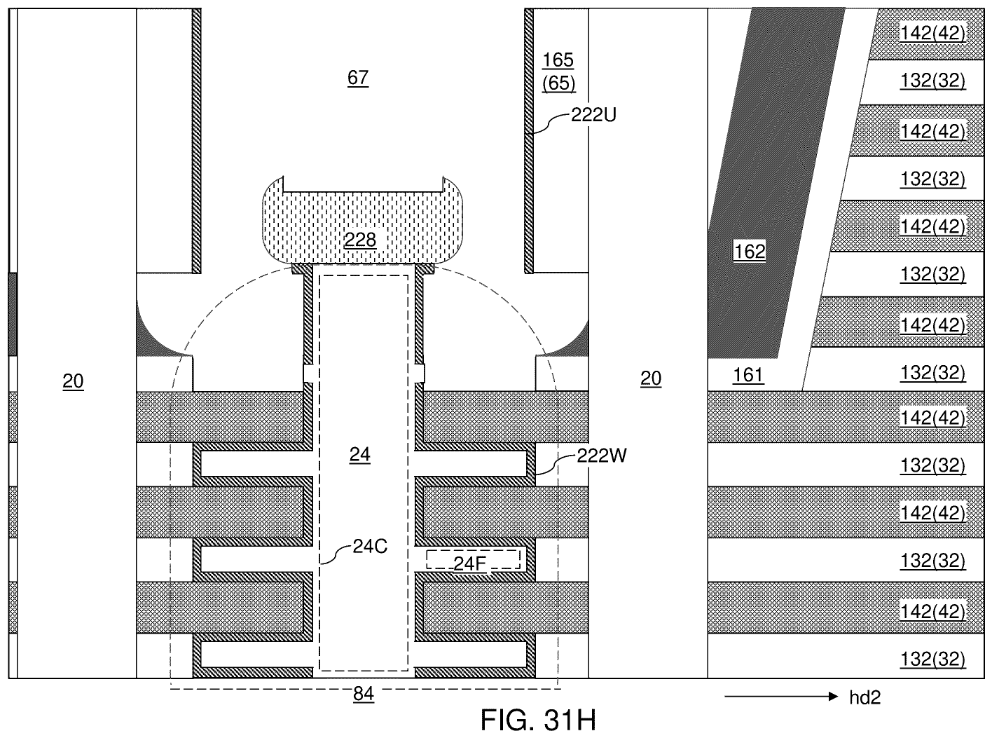

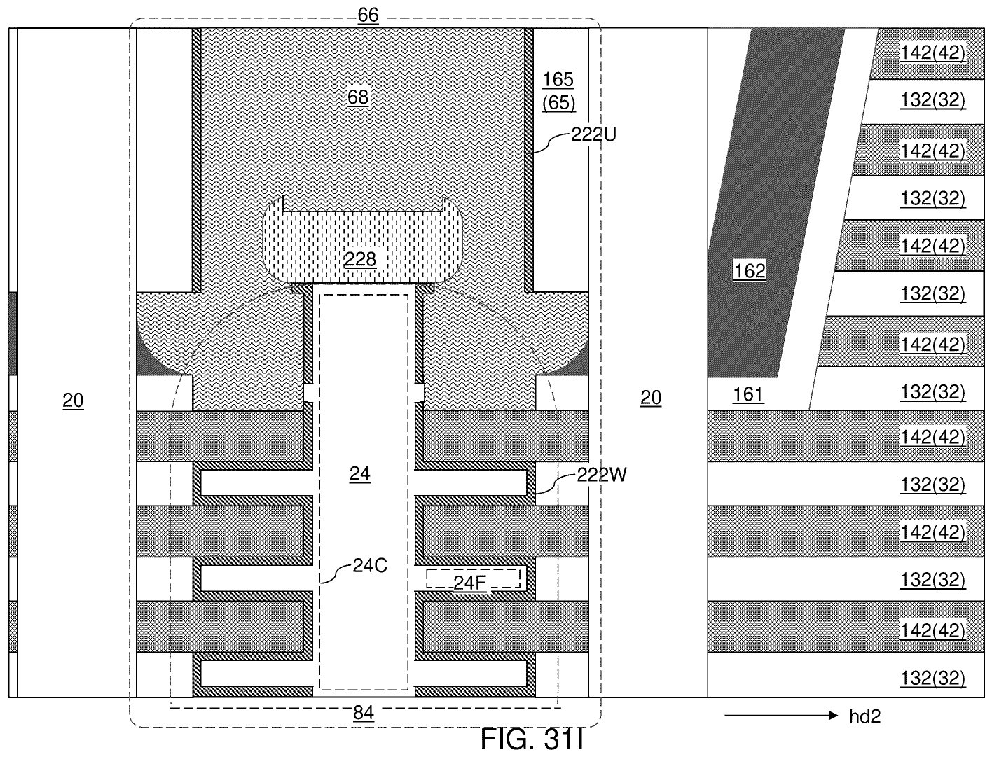

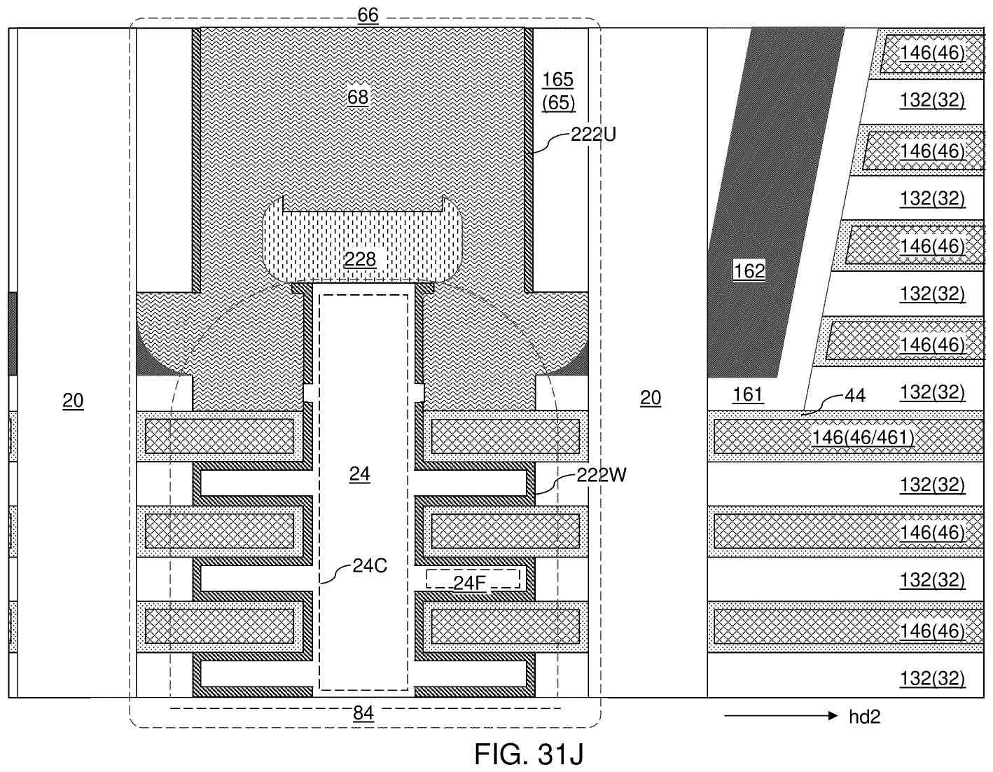

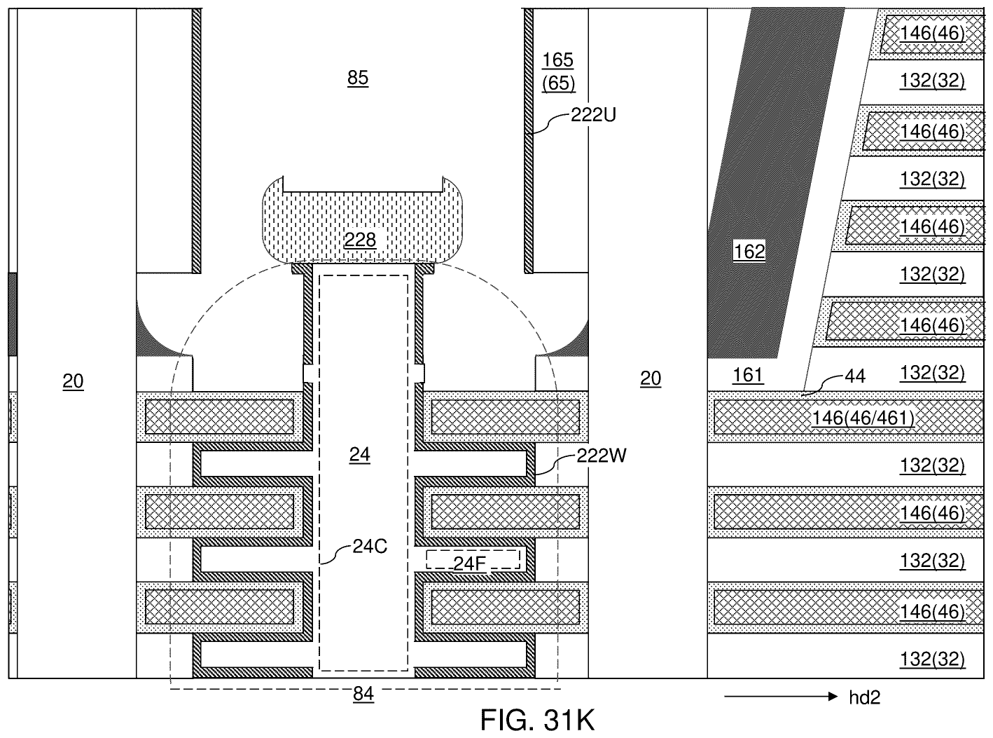

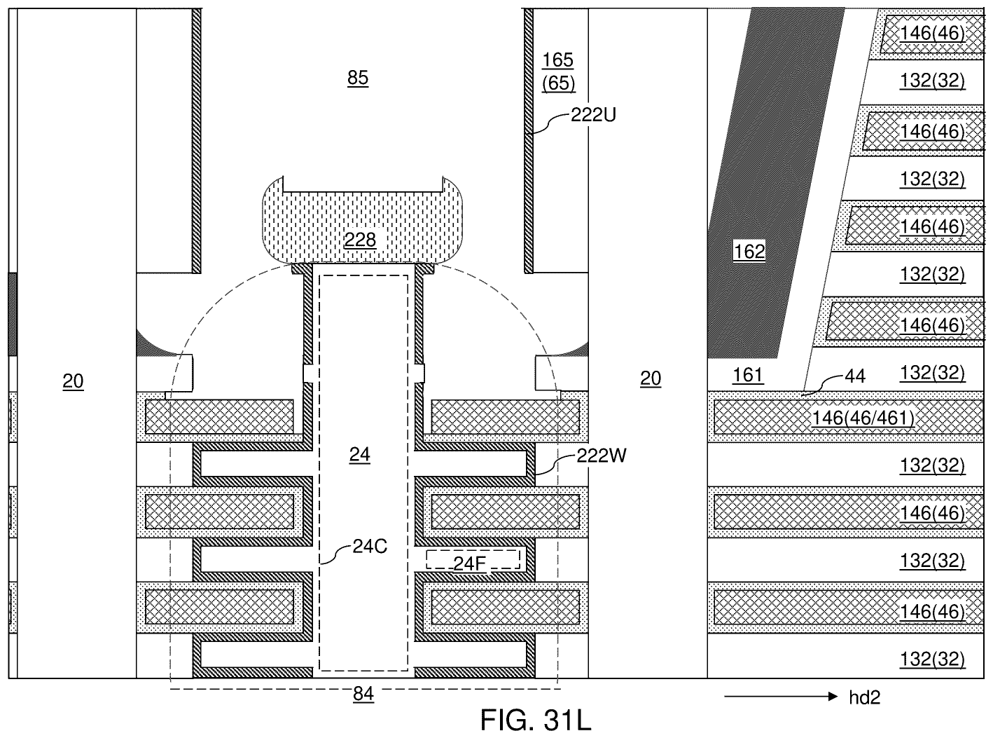

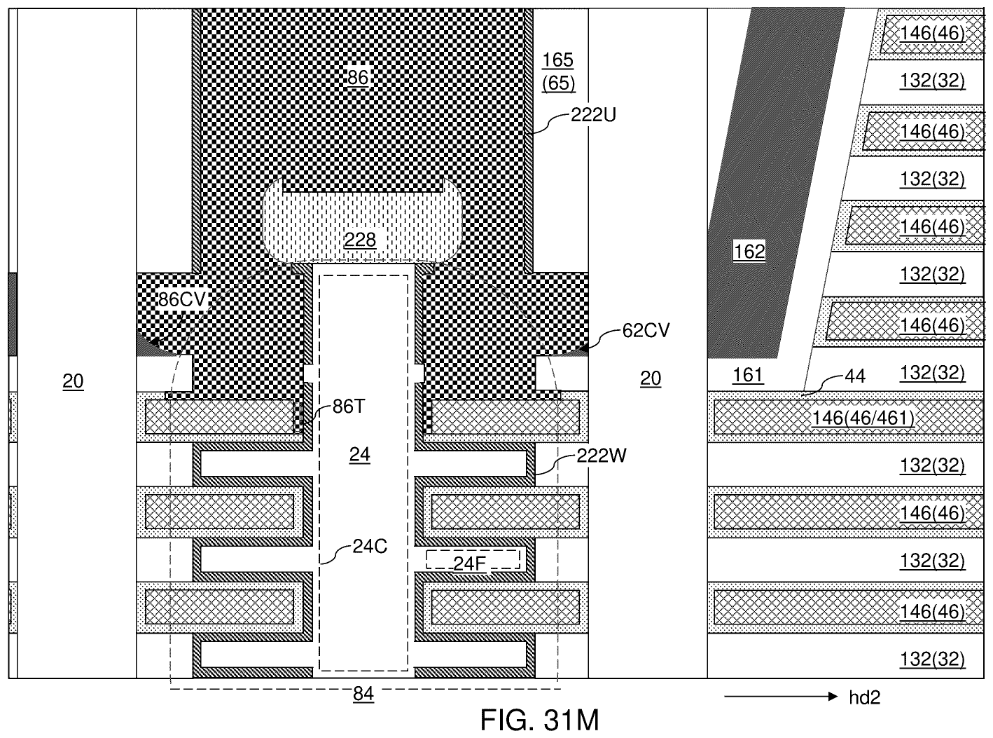

FIGS. 31A-31M are sequential vertical cross-sectional views of a region of a second configuration of the second exemplary structure during formation of a combination of a finned support assembly 84 and a layer contact via structure according to the second embodiment of the present disclosure.

Referring to FIG. 31A, the second configuration of the second exemplary structure may be the same as the first exemplary structure illustrated in FIGS. 11A-11C.

Referring to FIG. 31B, the processing steps described with reference to FIG. 12A can be performed. In this case, the second configuration of the second exemplary structure may be the same as the first exemplary structure illustrated in FIG. 12A.

Referring to FIG. 31C, a spacer liner layer 222L can be conformally deposited in the contact via cavity 69. In one embodiment, the spacer liner layer 222L may comprise a dielectric material that is resistant to a wet etch process employing dilute hydrofluoric acid. For example, the spacer liner layer 222L may comprise silicon oxycarbide. The atomic percentage of carbon in the silicon oxycarbide material of the spacer liner layer 222L may be in a range from 1% to 25%, such as from 3% to 20%, and/or from 5% to 15%. Alternatively, the spacer liner layer 222L may comprise a semiconductor material, such as amorphous silicon or polysilicon. In this case, the semiconductor material of the spacer liner layer 222L may be intrinsic or undoped (i.e., not intentionally doped) with an atomic concentration of electrical dopants less than 1.0×10¹⁵/cm³. The spacer liner layer 222L may be deposited by a conformal deposition process, such as a chemical vapor deposition process. The thickness of the spacer liner layer 222L may be in a range from 3 nm to 30 nm, such as from 6 nm to 20 nm, although lesser and greater thicknesses may also be employed.

A silicate glass dielectric material (such as undoped silicate glass or a doped silicate glass) can be conformally deposited in the contact via cavities 69 to form a dielectric material layer 24L. The dielectric material layer 24L may be deposited by a conformal deposition process such as a chemical vapor deposition process. The dielectric material layer 24L can fill the volumes of the annular fin cavities 69F, and thus, a dielectric fin 24F having a shape of an annular plate can be formed within each annular fin cavity 69F. The dielectric material layer 24L fills the pillar cavity portions 69P of the contact via cavities 69 without completely filling an upper portion of each contact via cavity 69 that is surrounded by a retro-stepped dielectric material portion 65. Thus, the volumes of the annular fin cavities 69F and the pillar cavity portions 69P of the contact via cavities 69 can be filled with the dielectric material layer 24L.

Referring to FIG. 31D, at least one dopant species selected from nitrogen and carbon can be implanted along a downward vertical direction into a portion of the silicate glass material in the dielectric material layer 24L that underlies a cylindrical cavity and overlies a horizontally-extending surface segment of the stepped surfaces of the vertically alternating sequences (32, 42). An implanted portion of the dielectric material layer 24L is converted into a doped silicate glass portion 228. The doped silicate glass portion 228 comprises at least one dopant species selected from carbon and nitrogen at an atomic percentage in a range from 1% to 25%, such as from 3% to 20%, and/or from 5% to 15%. In one embodiment, the doped silicate glass portion 228 may comprise carbon atoms at an atomic percentage in a range from 1% to 25%, such as from 3% to 20%, and/or from 5% to 15%. In one embodiment, the doped silicate glass portion 228 may comprise nitrogen atoms at an atomic percentage in a range from 1% to 25%, such as from 3% to 20%, and/or from 5% to 15%. In one embodiment, the doped silicate glass portion 228 may comprise a combination of carbon atoms and nitrogen atoms at a total atomic percentage in a range from 1% to 25%, such as from 3% to 20%, and/or from 5% to 15%.

The depth of the ion implantation process can be the same as, or greater than, the thickness of the horizontally-extending portion of the dielectric material layer 24L. An unimplanted portion of the dielectric material layer 24L that overlies a horizontally-extending portion of a silicon nitride buffer layer (162, 262, or 362) comprises an upper tubular dielectric liner 24U. An unimplanted portion of the dielectric material layer 24L that underlies the doped silicate glass portion 228 comprises a finned dielectric pillar 24 that includes a cylindrical dielectric portion 24C and a plurality of dielectric fins 24F that laterally protrudes from the cylindrical dielectric portion 24C.

Referring to FIG. 31E, a second selective isotropic etch process can be performed to remove an unimplanted portion of the silicate glass material of the upper tubular dielectric liner 24U selective to the doped silicate glass portion 228. The cavity 69C overlying the doped silicate glass portion 228 can be expanded by the second selective isotropic etch process. In one embodiment, the second selective isotropic etch process may comprise a wet etch process employing dilute hydrofluoric acid. In one embodiment, the duration of the second selective isotropic etch process can be selected such that the entirety of the upper tubular dielectric liner 24U is removed by the second selective isotropic etch process.

Referring to FIG. 31F, an anisotropic etch process can be performed to etch an horizontally-extending portion of the spacer liner layer 222L that is not covered by the doped silicate glass portion 228. An annular surface segment of a horizontal top surface of a silicon nitride buffer layer (162, 262, or 326) can be exposed underneath the cavity 69C located in each layer contact cavity 69. Remaining portions of the spacer liner layer 222L comprise a spacer liner 222W (which are also referred to as a lower spacer liner) that laterally surrounds the finned dielectric pillar 24, and an additional spacer liner 222U (which is also referred to as an upper spacer liner) having a tubular configuration and having a physically exposed inner sidewall.

Referring to FIG. 31G, a selective isotropic etch process can be performed to isotropically etch proximal portions of the silicon nitride buffer layer (162, 262, or 362) underneath the void around each doped silicate glass portion 228. For example, the selective isotropic etch process may comprise a wet etch process employing hot phosphoric acid. The duration of the selective isotropic etch process can be selected such that the etch distance of the selective isotropic etch process is greater than the thickness of the silicon nitride buffer layer (162, 262, or 362). An opening is formed through the silicon nitride buffer layer (162, 262, or 362) around, and underneath, each doped silicate glass portion 228. Each opening may comprise an annular concave surface segment of the silicon nitride buffer layer (162, 262, or 362). If the doped silicate glass portion 228 comprises silicon oxynitride, then its size may be reduced during the etch process. A sidewall of each opening 67 may comprise an annular concave surface segment 62CV of the silicon nitride buffer layer (162, 262, or 362).

Referring to FIG. 31H, an anisotropic etch process can be performed to etch horizontally exposed portions of the lower spacer liner 222W in the layer contact cavity 67 and the silicon oxide buffer layers (161, 261, 361). Generally, two horizontally-extending annular portions of the spacer liner layer 222L and an annular portion of a silicon oxide buffer layer (161, 261, 361) can be removed around and underneath each doped silicate glass portion 228. An annular surface segment of a top surface of a sacrificial material layer 42 can be physically exposed underneath each layer contact via cavity 67. In one embodiment, a cylindrical sidewall of a silicon oxide buffer layer (161, 261, or 361) can be physically exposed to each layer contact via cavity 67.

Referring to FIG. 31I, a sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material, such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Referring to FIG. 31J, the processing steps described with reference to FIGS. 14-19C can be performed to form memory opening fill structures 58 and to replace the sacrificial material layers 42 with electrically conductive layers 46.

Referring to FIG. 31K, the processing steps described with reference to FIGS. 20A-21C can be performed to form lateral isolation trench fill structures 76 and connection via cavities, and to form layer contact via cavities 85 by removing the sacrificial contact via structures 68.

Referring to FIG. 31L, an etch process such as a wet etch process can be performed to remove physically exposed surface portions of the outer blocking dielectric layers 44 (if present). An annular planar top surface segment and a cylindrical surface segment of an electrically conductive layer 46 can be physically exposed underneath each layer contact via cavity 85.

Referring to FIG. 31M, at least one electrically conductive material, such as a metallic material can be deposited in the layer contact via cavities 85. The at least one metallic material may comprise a combination of a metallic barrier liner material (such as TiN, TaN, WN, and/or MoN) and a metal fill material (such as W, Ru, Mo, Co, Cu, etc.). Excess portions of the at least one metallic material can be removed from above the horizontal plane including the top surface of the contact-level dielectric layer 80. Each remaining portion of the at least one metallic material that fills a respective layer contact via cavity 85 constitutes a layer contact via structure 86.

Each layer contact via structure 86 may comprise a tubular portion 86T contacting a surface segment of an outer sidewall of lower spacer liner 222W and contacting a cylindrical surface segment of an opening in a respective first electrically conductive layer 461 of the electrically conductive layers 46.

During formation of the second configuration of the second exemplary structure, a contact assembly (84, 228, 86) comprising a finned support assembly 84, a doped silicate glass portion 228 overlying the finned support assembly 84, and a sacrificial contact via structure 68 can be formed in a contact via cavity 85. The doped silicate glass portion 228 can be interposed between the finned support assembly 84 and the layer contact via structure 86. In one embodiment, each layer contact via structure 86 vertically extends through the retro-stepped dielectric material portion 65 and comprises a contoured bottom surface that includes an annular surface segment that contacts an annular top surface segment of a respective first electrically conductive layer 461 of the electrically conductive layers 46. The finned support assembly 84 contacts central surface segments of the contoured bottom surface.

In one embodiment, all surface segments of the doped silicate glass portion 228 that overlies a topmost surface of the finned support assembly 84 are in contact with surface segments of the layer contact via structure 86.

In one embodiment, the doped silicate glass portion 228 comprises at least one dopant species selected from carbon and nitrogen at an atomic percentage in a range from 1% to 25%. In one embodiment, the doped silicate glass portion 228 comprises a carbon-doped silicate glass (e.g., silicon oxycarbide). In one embodiment, the doped silicate glass portion 228 comprises a nitrogen-doped silicate glass (e.g., silicon oxynitride). In one embodiment, a maximum horizontal cross-sectional area of the doped silicate glass portion 228 is greater than an area of a topmost surface of the finned support assembly 84.

In one embodiment, the layer contact via structure 86 comprises tubular portion 86T having an outer cylindrical surface that contacts a cylindrical surface segment of an opening through the first electrically conductive layer 461. In one embodiment, the tubular portion 86T of the layer contact via structure 86 contacts a cylindrical surface segment of the finned support assembly 84.

In one embodiment, the finned support assembly 84 comprises a dielectric material portion (such as a finned dielectric pillar 24) having a planar top surface that contacts a central bottom surface segment of the doped silicate glass portion 228, and a spacer liner 222W that laterally surrounds the dielectric material portion (such as a finned dielectric pillar 24) and contacting an annular bottom surface segment of the doped silicate glass portion 228. In one embodiment, the spacer liner 222W comprises an outer cylindrical surface segment that contacts a cylindrical surface segment of the layer contact via structure 86. In one embodiment, the dielectric material portion comprises a finned dielectric pillar 24 that includes a cylindrical dielectric portion 24C and a plurality of dielectric fins 24F that laterally protrude from the cylindrical dielectric portion 24C. In one embodiment, the plurality of dielectric fins 24F are located at levels of a subset of the insulating layers 32 that underlie the first electrically conductive layer 461. In one embodiment, the spacer liner 222W comprises a plurality of laterally-protruding portions that embed the plurality of dielectric fins 24F. In one embodiment, the spacer liner 222W comprises a dielectric material, such as silicon oxycarbide, or a semiconductor material, such as polysilicon. In one embodiment, a layer stack of a silicon oxide buffer layer (161, 261, or 361) and a silicon nitride buffer layer (162, 262, or 362) may be interposed between an alternating stack (32, 46) and the retro-stepped dielectric material portion 65 in a staircase region.

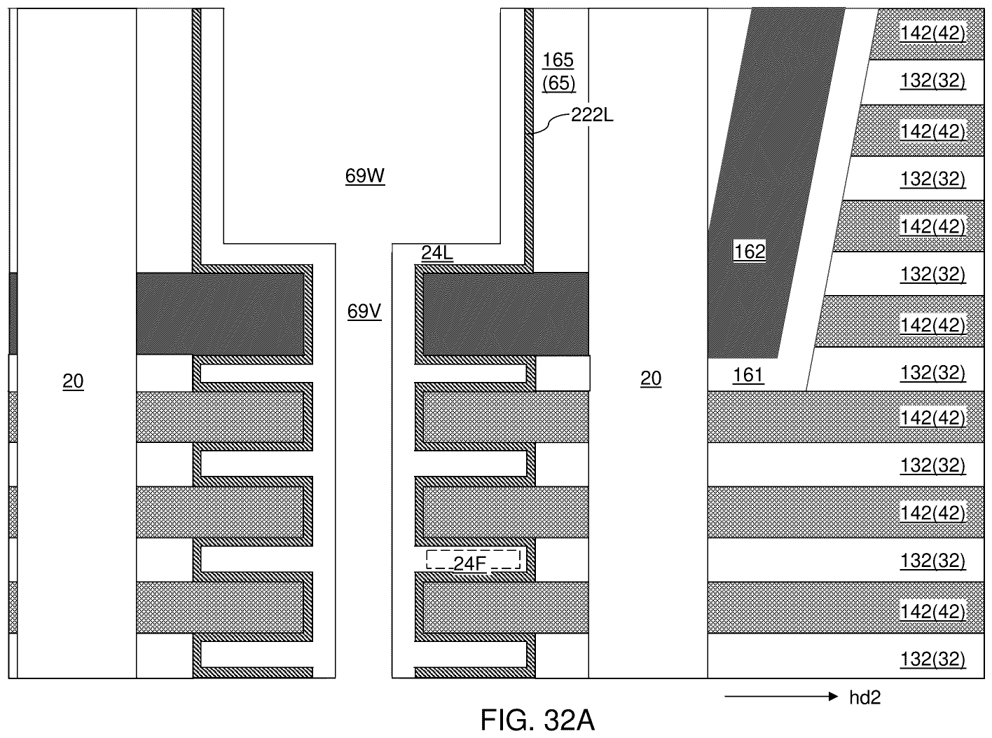

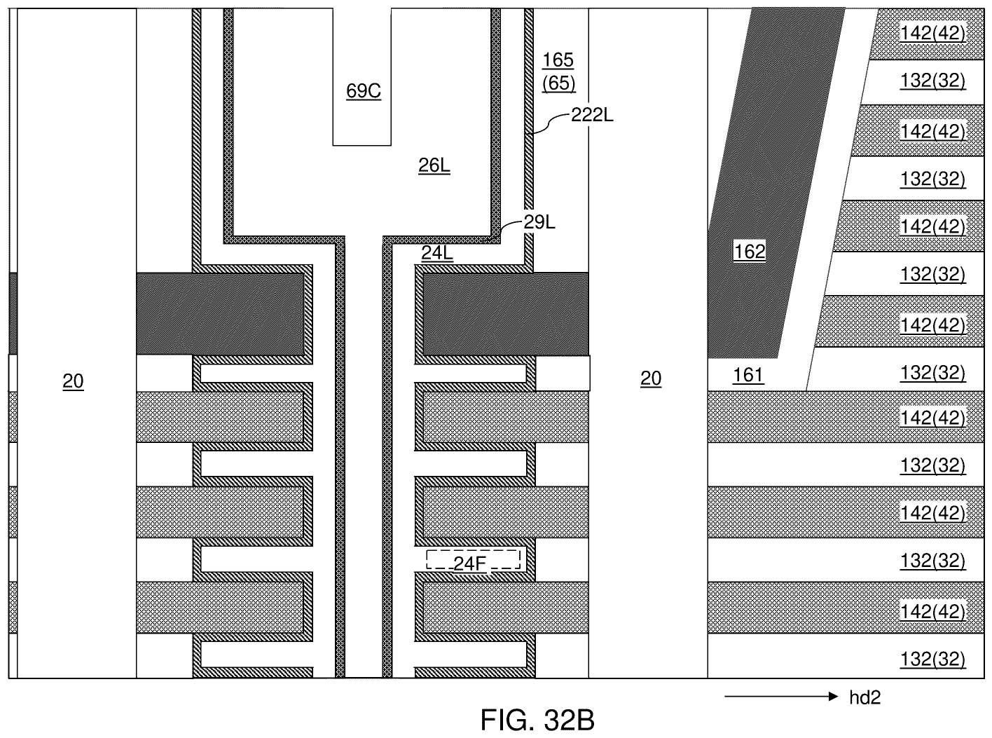

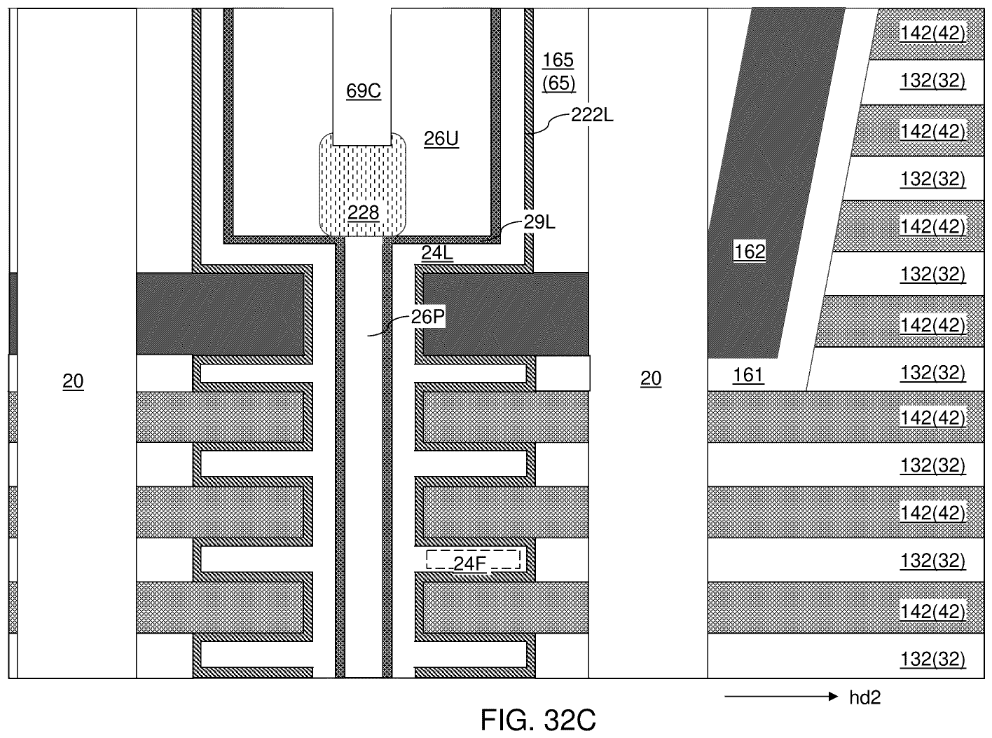

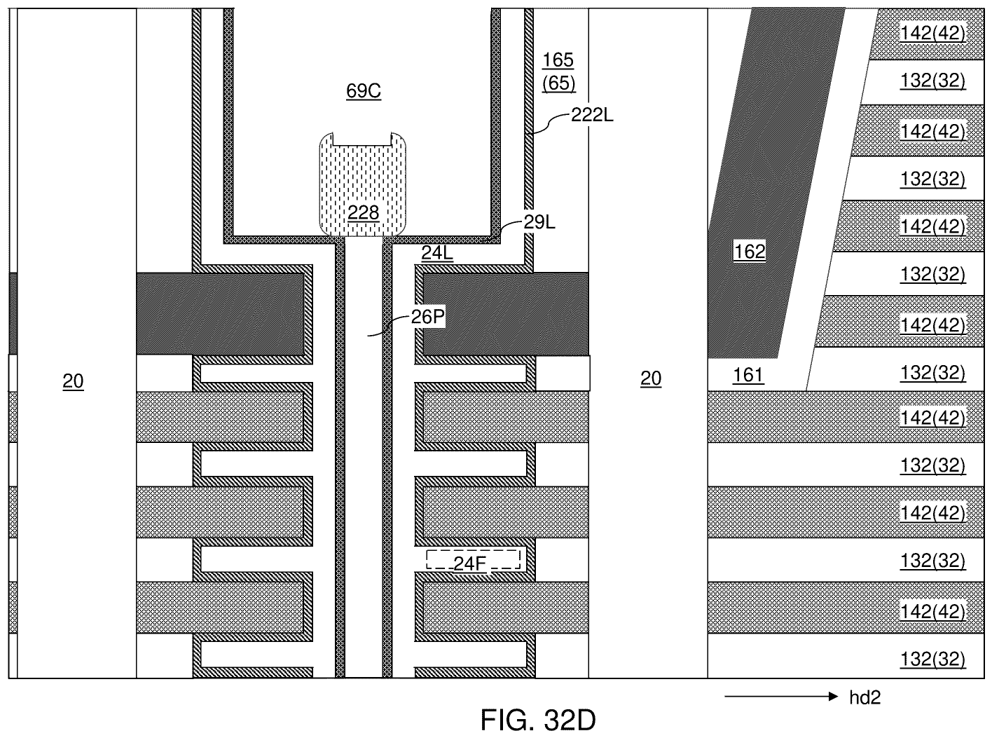

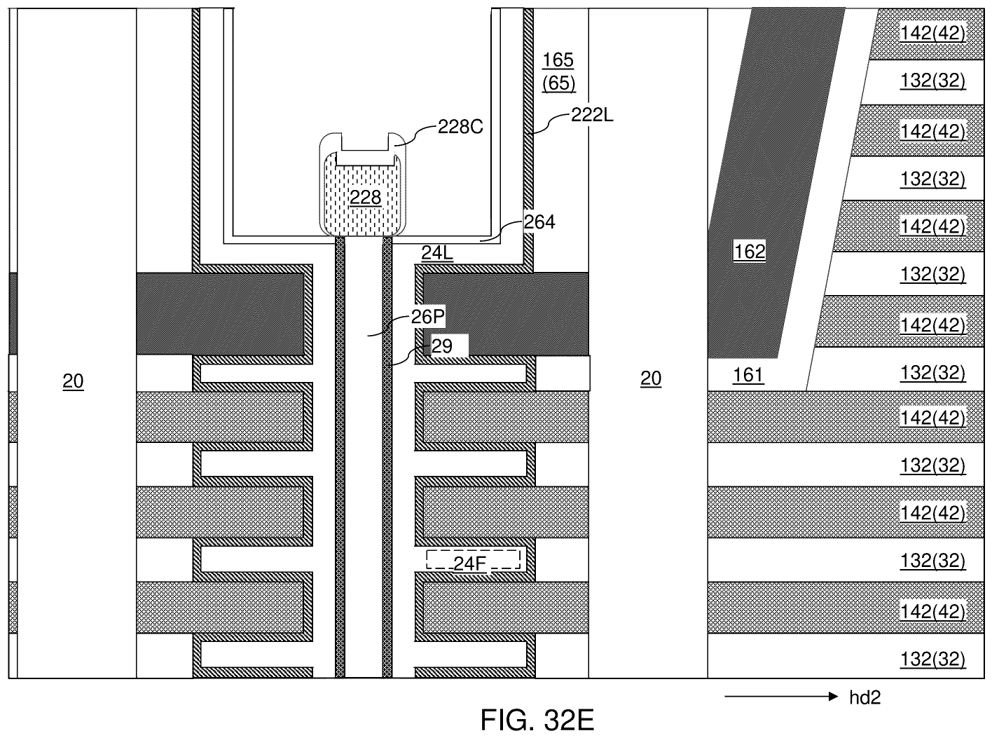

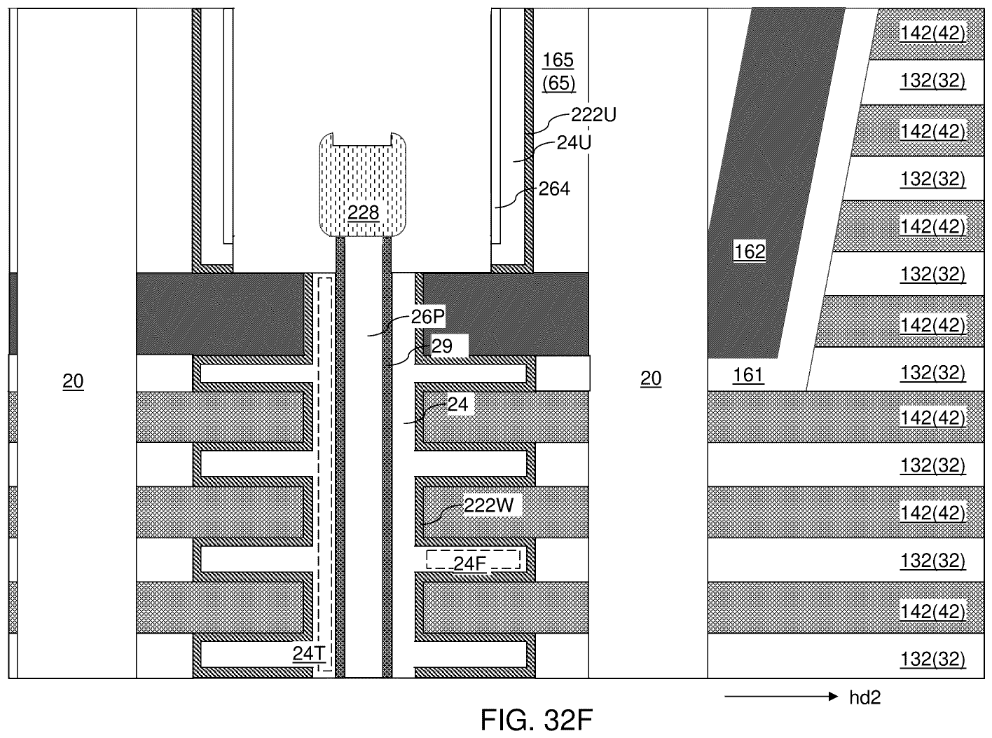

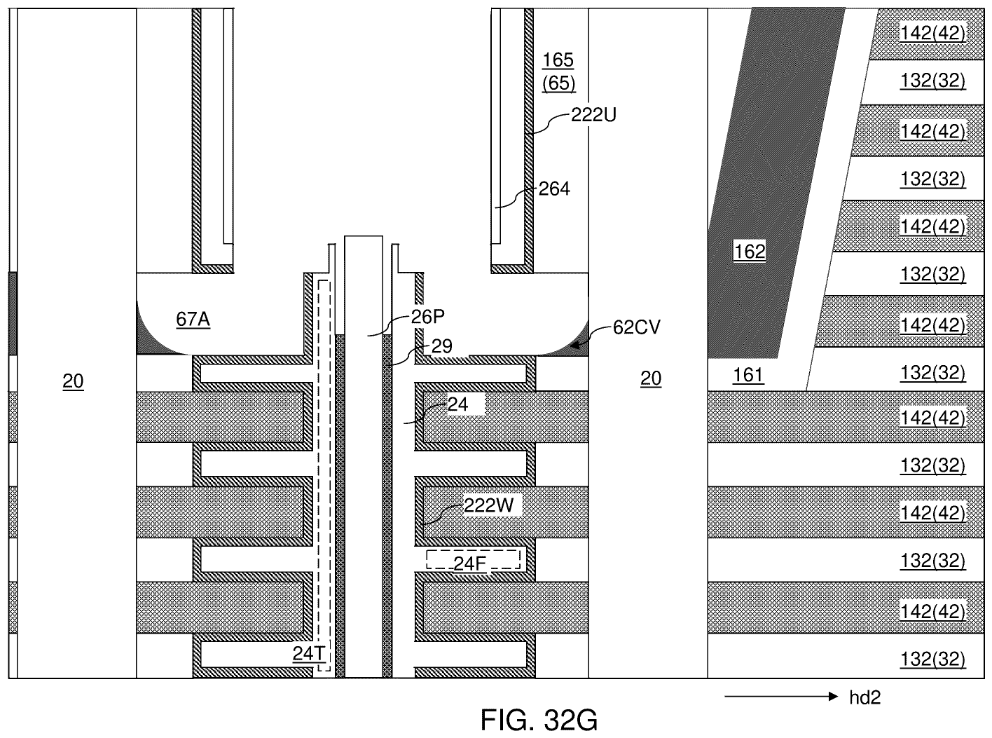

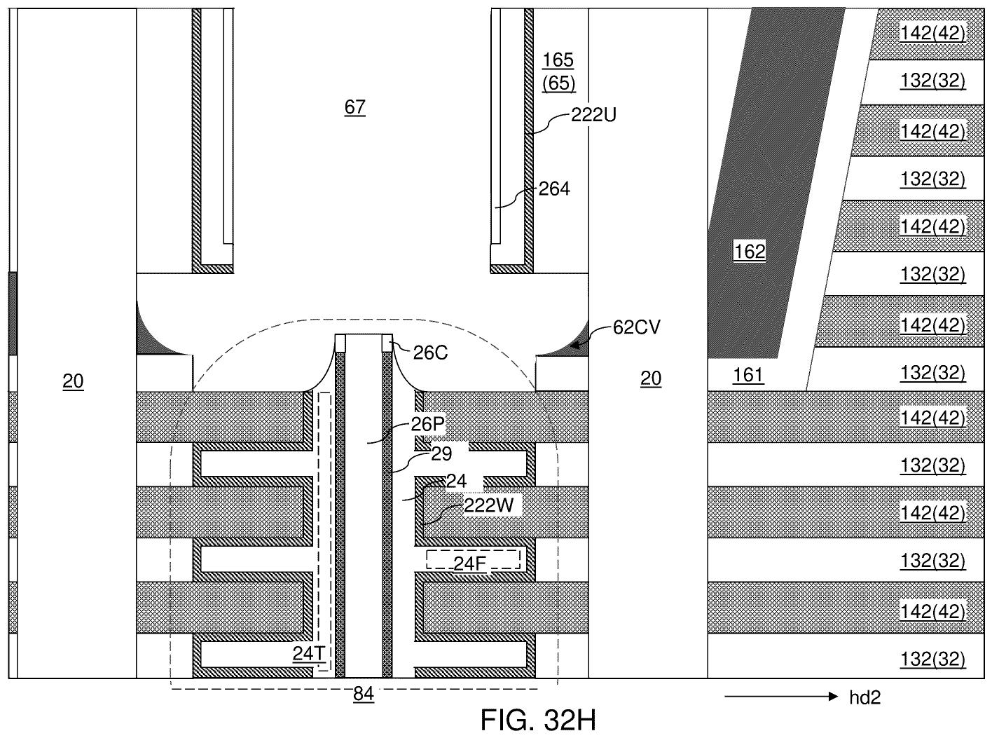

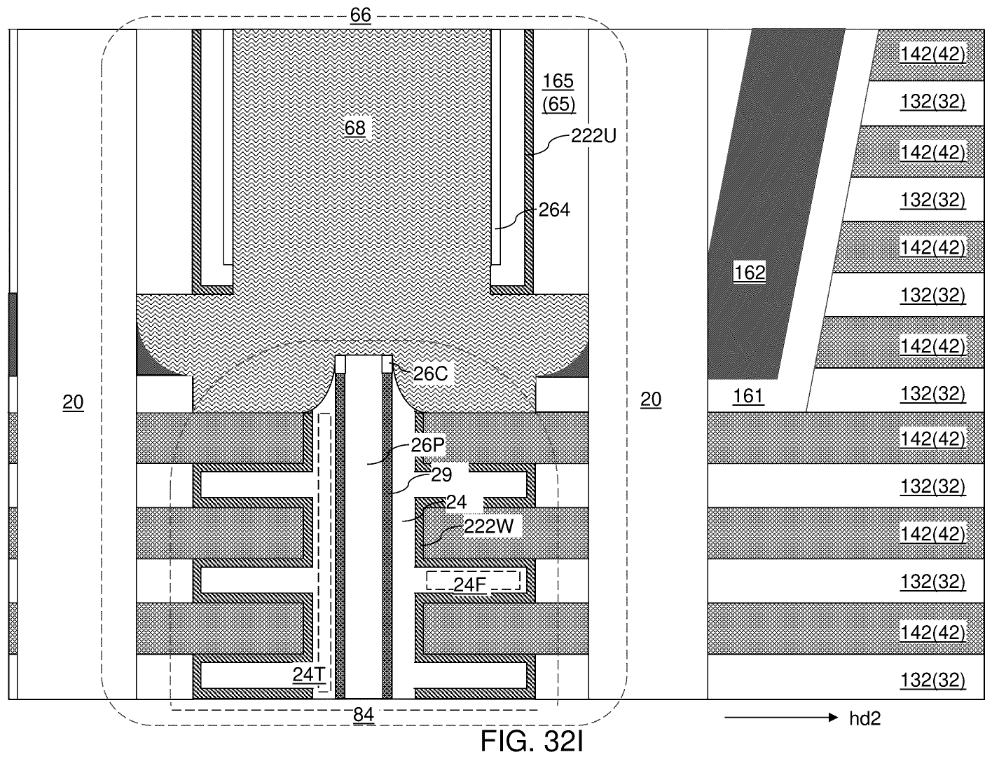

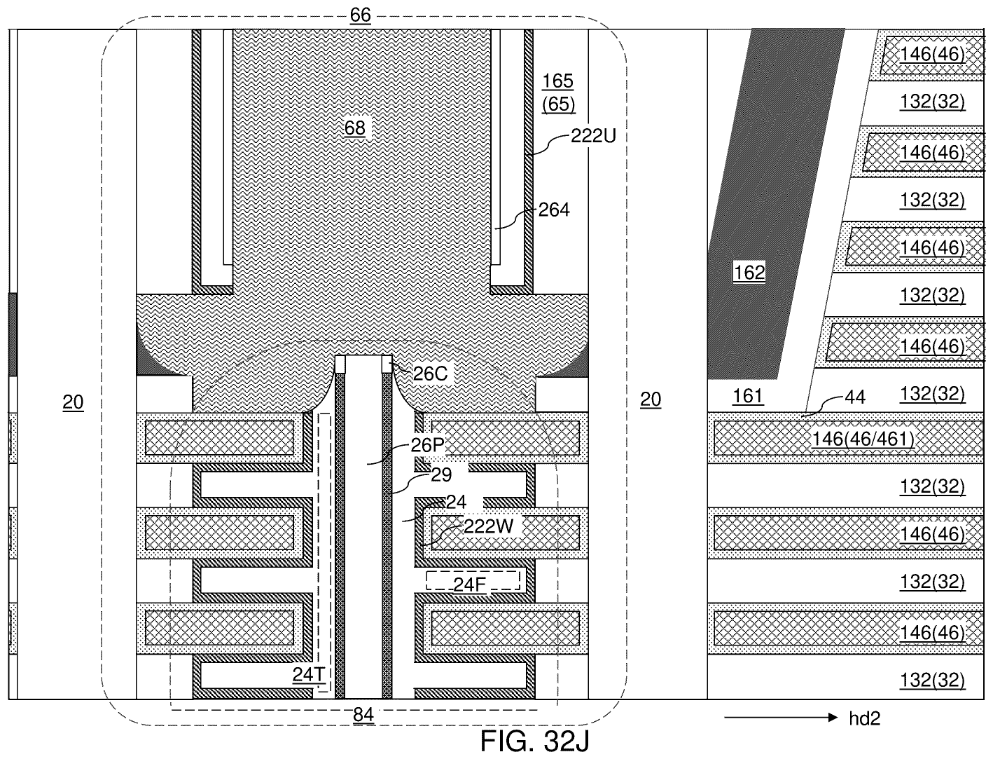

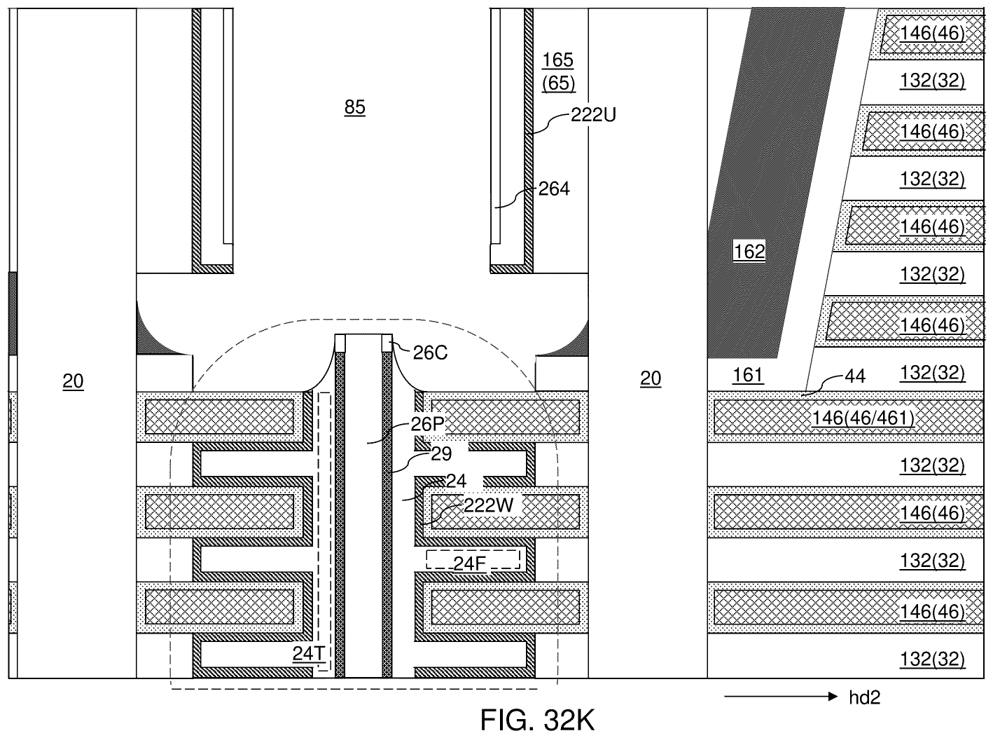

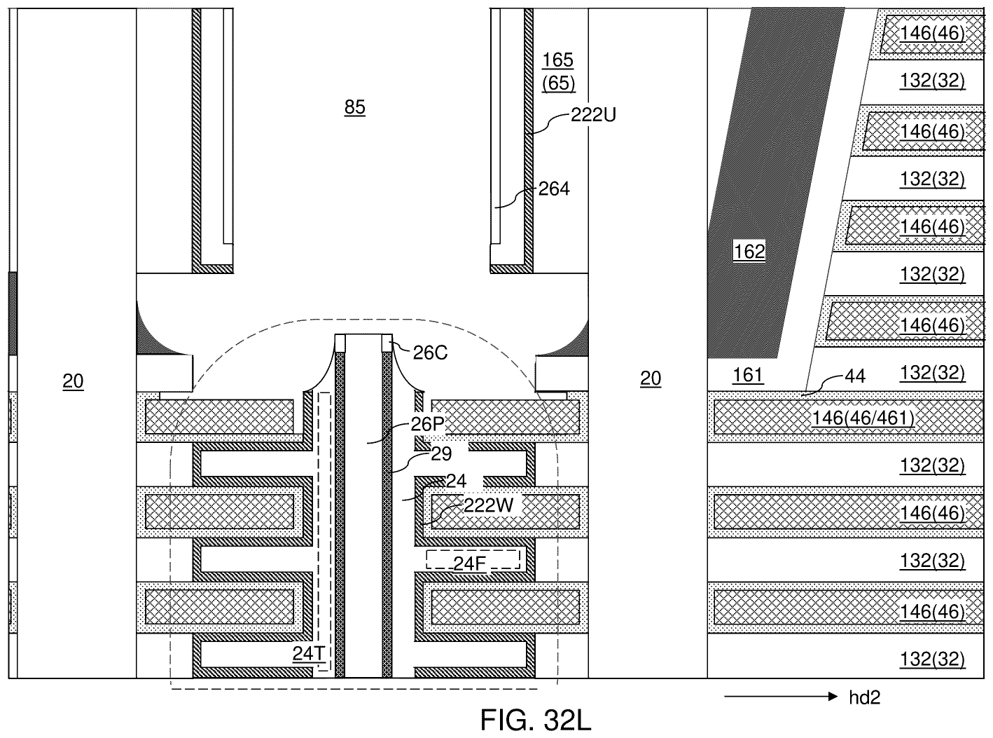

FIGS. 32A-32M are sequential vertical cross-sectional views of a region of a third configuration of the second exemplary structure during formation of a combination of a finned support assembly 84 and a layer contact via structure 86 according to the second embodiment of the present disclosure.

Referring to FIG. 32A, a third configuration of the second exemplary structure can be derived from the first configuration of the second exemplary structure illustrated in FIG. 30B by sequentially depositing the spacer liner layer 222L and the dielectric material layer 24L. The spacer liner layer 222L may have the same material composition and the same thickness and the spacer liner layer 222L described with reference to FIG. 31C. The dielectric material layer 24L comprises a silicate glass dielectric material (such as undoped silicate glass or a doped silicate glass). The dielectric material layer 24L may be deposited by a conformal deposition process such as a chemical vapor deposition process. The dielectric material layer 24L can fill the volumes of the annular fin cavities 69F, and thus, a dielectric fin 24F having a shape of an annular plate can be formed within each annular fin cavity 69F. The dielectric material layer 24L only partially fills the pillar cavity portions 69P of the contact via cavities 69. Thus, a lower cylindrical void 69V is present within a lower portion of each contact via cavity 69, and an upper cylindrical void 69W having a greater lateral extent than the lower cylindrical void is present in an upper portion of each contact via cavity.

Referring to FIG. 32B, an etch-stop dielectric liner layer 29L can be conformally deposited over the dielectric material layer 24L. In one embodiment, the etch-stop dielectric liner layer 29L comprises silicon nitride. The thickness of the etch-stop dielectric liner layer 29L may be in a range from 3 nm to 30 nm, although lesser and greater thicknesses may also be employed. A dielectric fill material, such as undoped silicate glass or a doped silicate glass, can be conformally deposited to form a dielectric fill material layer 26L. The dielectric fill material which fills remaining cylindrical voids 69V of the pillar cavity portions 69P of the contact via cavities 69. A cylindrical void (i.e., cavity) 69C is present in an upper portion of each contact via cavity after formation of the dielectric fill material layer 26L.

Referring to FIG. 32C, at least one dopant species selected from nitrogen and carbon can be implanted along a downward vertical direction into a portion of the silicate glass material in the dielectric fill material layer 26L that underlies the cylindrical void 69C and overlies a horizontally-extending surface segment of the stepped surfaces of the vertically alternating sequences (32, 42). An implanted portion of the dielectric fill material layer 26L is converted into the above described doped silicate glass portion 228.

The depth of the ion implantation process can be the same as or greater than the thickness of the horizontally-extending portion of the dielectric fill material layer 26L. An unimplanted portion of the dielectric fill material layer 26L that overlies a horizontally-extending portion of the etch-stop dielectric liner layer 29L comprises an upper tubular dielectric liner 26U. An unimplanted portion of the dielectric fill material layer 26L that underlies the doped silicate glass portion 228 comprises a cylindrical dielectric pillar 26P.

Referring to FIG. 32D, a selective isotropic etch process can be performed to remove an unimplanted portion of the silicate glass material of the upper tubular dielectric liner 26U selective to the doped silicate glass portion 228 and selective to the etch-stop dielectric liner layer 29L. The cavity 69C overlying the doped silicate glass portion 228 can be expanded by the selective isotropic etch process. In one embodiment, the selective isotropic etch process may comprise a wet etch process employing dilute hydrofluoric acid. In one embodiment, the duration of the selective isotropic etch process can be selected such that the entirety of the upper tubular dielectric liner 26U is removed by the second selective isotropic etch process.

Referring to FIG. 32E, an oxidation process can be performed to convert the physically exposed upper portion of the etch-stop dielectric liner layer 29L into a dielectric oxide liner 264. For example, if the etch-stop dielectric liner layer 29L comprises silicon nitride, the dielectric oxide liner 264 may comprise silicon oxide. A remaining tubular portion of the etch-stop dielectric liner layer 29L that underlies the doped silicate glass portion 228 comprises a spacer liner, which is herein referred to as a tubular etch-stop liner, or as a tubular dielectric liner 29. The outer portion of the doped silicate glass portion 228 may also be oxidized to form a silicon oxide rich cap liner 228C around the doped silicate glass portion 228.

Referring to FIG. 32F, an anisotropic etch process can be performed to remove an annular segment of the dielectric oxide liner 264 and an annular segment of the dielectric material layer 24L around each doped silicate glass portion 228. The silicon oxide rich cap liner 228C may also be removed during this etch process to reduce the size of the doped silicate glass portion 228. A remaining portion of the dielectric material layer 24L that overlies a silicon nitride buffer layer (162, 262, 362) comprises an upper tubular dielectric liner 24U. A remaining portion of the dielectric material layer 24L that underlies the doped silicate glass portion 228 comprises a finned dielectric pillar 24 laterally surrounding the tubular dielectric liner 29 and comprising a tubular dielectric portion 24T and a plurality of dielectric fins 24F that laterally protrudes from the tubular dielectric portion 24T. A remaining portion of the spacer liner layer 222L that underlies the doped silicate glass portion 228 comprises a spacer liner 222W, which is also referred to as a lower spacer liner. A remaining portion of the spacer liner layer 222L that overlies the silicon nitride buffer layer (162, 262, 362) comprises an additional spacer liner 222U, which is also referred to as an upper spacer liner.

Referring to FIG. 32G, a selective isotropic etch process can be performed to isotropically etch proximal portions of the silicon nitride buffer layer (162, 262, or 362) underneath the void around each doped silicate glass portion 228. For example, the selective isotropic etch process may comprise a wet etch process employing hot phosphoric acid. The duration of the selective isotropic etch process can be selected such that the etch distance of the selective isotropic etch process is greater than the thickness of the silicon nitride buffer layer (162, 262, or 362). An opening 67A is formed through the silicon nitride buffer layer (162, 262, or 362) around and underneath each doped silicate glass portion 228. A sidewall of each opening may comprise an annular concave surface segment 62CV of the silicon nitride buffer layer (162, 262, or 362).

Referring to FIG. 32H, an anisotropic etch process can be performed to etch the doped silicate glass portion 228 and portions of the spacer liner layer 222L and the silicon oxide buffer layers (161, 261, 361). The anisotropic etch process may comprise multiple anisotropic etch steps for sequentially etching the doped silicate glass portion 228 and portions of the spacer liner layer 222L and the silicon oxide buffer layers (161, 261, 361), or may comprise a single anisotropic etch step that indiscriminately etches the materials of the doped silicate glass portion 228 and portions of the spacer liner layer 222L and the silicon oxide buffer layers (161, 261, 361). Generally, two horizontally-extending annular portions of the spacer liner layer 222L, an annular portion of a silicon oxide buffer layer (161, 261, 361), and a doped silicate glass portion 228 can be removed underneath each void in the layer contact via cavity 67. An annular surface segment of a top surface of a sacrificial material layer 42 can be physically exposed underneath each layer contact via cavity 67. In one embodiment, a cylindrical sidewall of a silicon oxide buffer layer (161, 261, or 361) can be physically exposed to each layer contact via cavity 67.

If upper portions of the silicon tubular dielectric liners 29 are exposed to the contact via cavity 67, then they may be oxidized to form a silicon oxide cap 26C on the top of the silicon tubular dielectric liners 29. The oxidation may comprise a water vapor generation (WVG) oxidation which converts silicon nitride to silicon oxide. The oxidation step may be conducted prior to removing the horizontal portions of the lower spacer liner 222W to avoid oxidizing the upper surface of the sacrificial material layer 42 exposed in the contact via cavity 67.

Referring to FIG. 32I, a sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Referring to FIG. 32J, the processing steps described with reference to FIGS. 14-19C can be performed to form memory opening fill structures 58 and to replace the sacrificial material layers 42 with electrically conductive layers 46.

Referring to FIG. 32K, the processing steps described with reference to FIGS. 20A-21C can be performed to form lateral isolation trench fill structures 76 and connection via cavities, and to form layer contact via cavities 85 by removing the sacrificial contact via structures 68.

Referring to FIG. 32L, an isotropic etch process such as a wet etch process can be performed to remove physically exposed surface portions of the outer blocking dielectric layers 44 (if present). An annular planar top surface segment and a cylindrical surface segment of an electrically conductive layer 46 can be physically exposed underneath each layer contact via cavity 85.

Referring to FIG. 32M, at least one electrically conductive material, such as at least one metallic material can be deposited in the layer contact via cavities 85. The at least one metallic material may comprise a combination of a metallic barrier liner material (such as TiN, TaN, WN, and/or MoN) and a metal fill material (such as W, Ru, Mo, Co, Cu, etc.). Excess portions of the at least one metallic material can be removed from above the horizontal plane including the top surface of the contact-level dielectric layer 80. Each remaining portion of the at least one metallic material that fills a respective layer contact via cavity 85 constitutes a layer contact via structure 86.

Each layer contact via structure 86 may comprise a tubular portion 86T contacting a surface segment of an outer sidewall of a tubular semiconductor liner 25 and contacting a cylindrical surface segment of an opening in a respective first electrically conductive layer 461 among the electrically conductive layers 46.

The third configuration of the exemplary structure comprises: an alternating stack (32, 46) of insulating layers 32 and electrically conductive layers 46, wherein the alternating stack (32, 46) comprises a staircase region; a retro-stepped dielectric material portion 65 overlying the alternating stack (32, 46) in the staircase region; and a contact assembly (84, 86) comprising a layer contact via structure 86 and a finned support assembly 84, wherein the layer contact via structure 86 vertically extends through the retro-stepped dielectric material portion 65 and comprises a contoured bottom surface that includes an annular surface segment that contacts an annular top surface segment of a first electrically conductive layer 461 of the electrically conductive layers 46, and the finned support assembly 84 contacts central surface segments of the contoured bottom surface, wherein the finned support assembly 84 comprises a cylindrical dielectric pillar 26P, a spacer liner (25 or 222W) that laterally surrounds the cylindrical dielectric pillar 26P, and a finned dielectric pillar 24 that laterally surrounds the spacer liner (25 or 222W) and comprising a tubular dielectric portion 24T in contact with the spacer liner (25 or 222W) and a plurality of dielectric fins 24F that laterally protrude from the tubular dielectric portion 24T.

In one embodiment, the spacer liner (25 or 222W) comprises a tubular semiconductor liner 25 comprising a semiconductor material. In one embodiment, the spacer liner 222W comprises a tubular silicon nitride liner comprising silicon nitride. In one embodiment, a tubular dielectric liner 29 comprises a top surface contacting a first surface segment of the layer contact via structure 86; the spacer liner 222W contacts a second surface segment of the layer contact via structure 86; and the finned dielectric pillar 24 comprises a surface that contacts a third surface segment of the layer contact via structure 86.

In one embodiment, the layer contact via structure 86 comprises a tubular portion 86T having an inner cylindrical sidewall that contacts a cylindrical surface segment of the finned support assembly 84, and having an outer cylindrical sidewall that contacts a cylindrical surface segment of an opening in the first electrically conductive layer 461. In one embodiment, a layer stack including a silicon oxide buffer layer (161, 261, or 361) and a silicon nitride buffer layer (162, 262, or 362) is interposed between the alternating stack (32, 46) and the retro-stepped dielectric material portion 65 in the staircase region. In one embodiment shown in FIGS. 31M and 32M, the layer contact via structure 86 vertically extends through the layer stack; and the layer contact via structure 86 comprises an annular convex sidewall surface 86CV that contacts an annular concave sidewall surface 62CV of the silicon nitride buffer layer (162, 262, or 362).

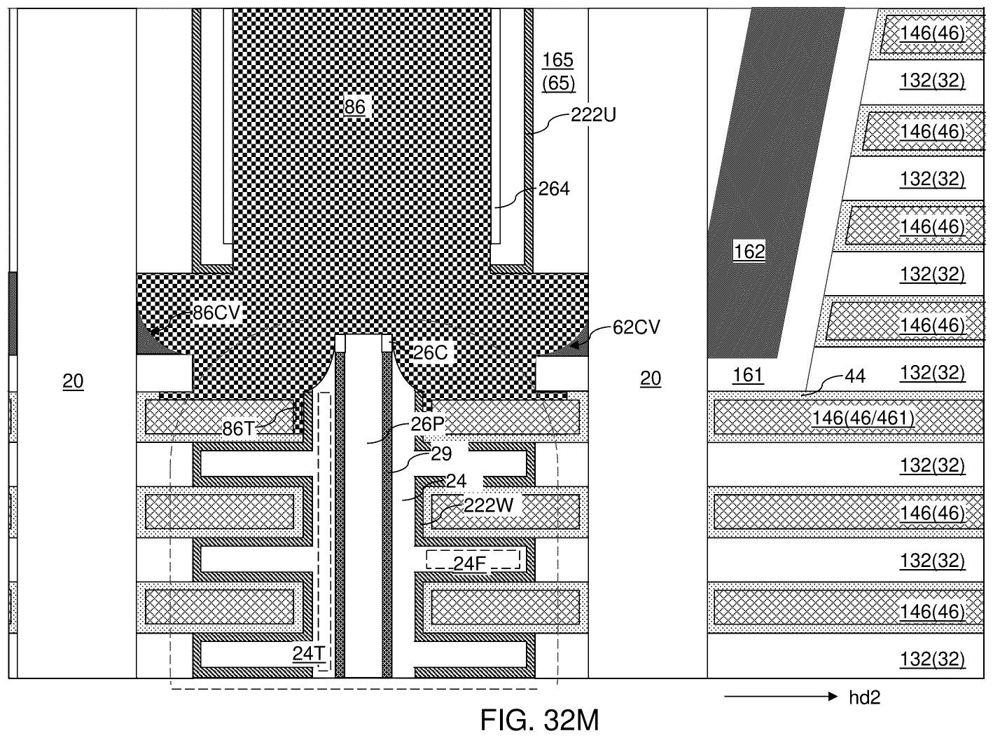

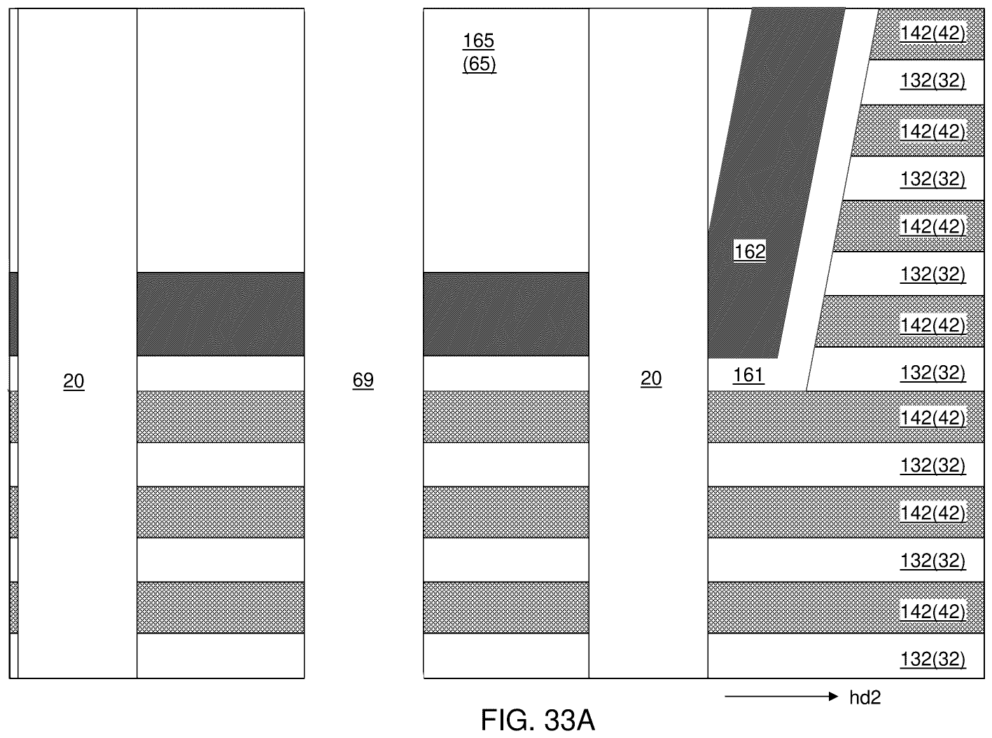

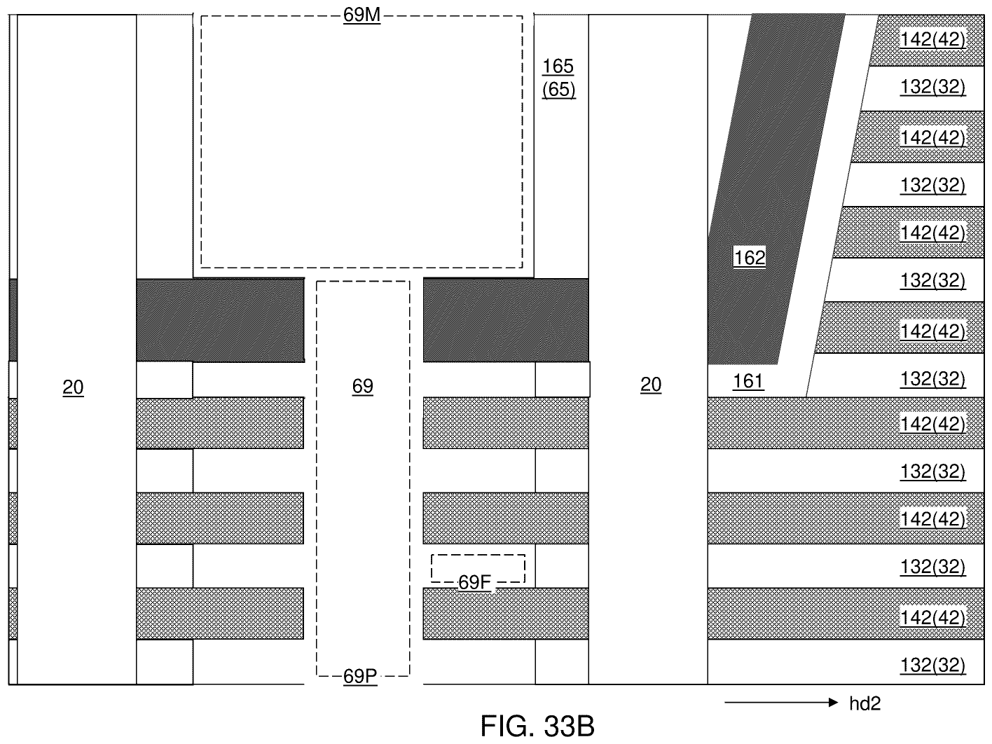

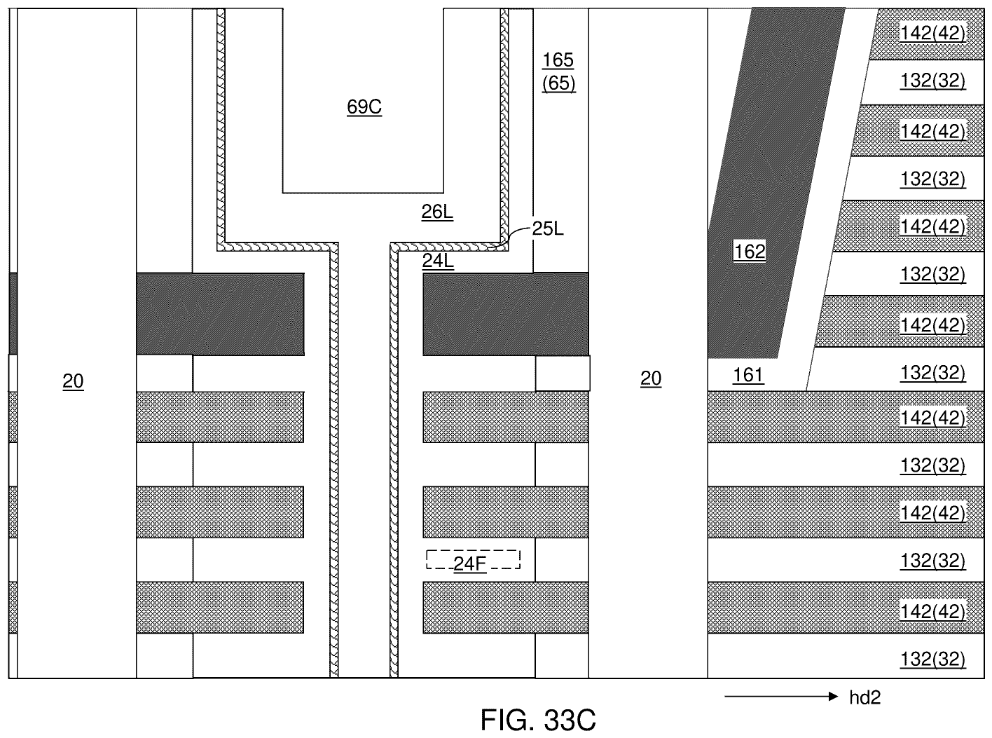

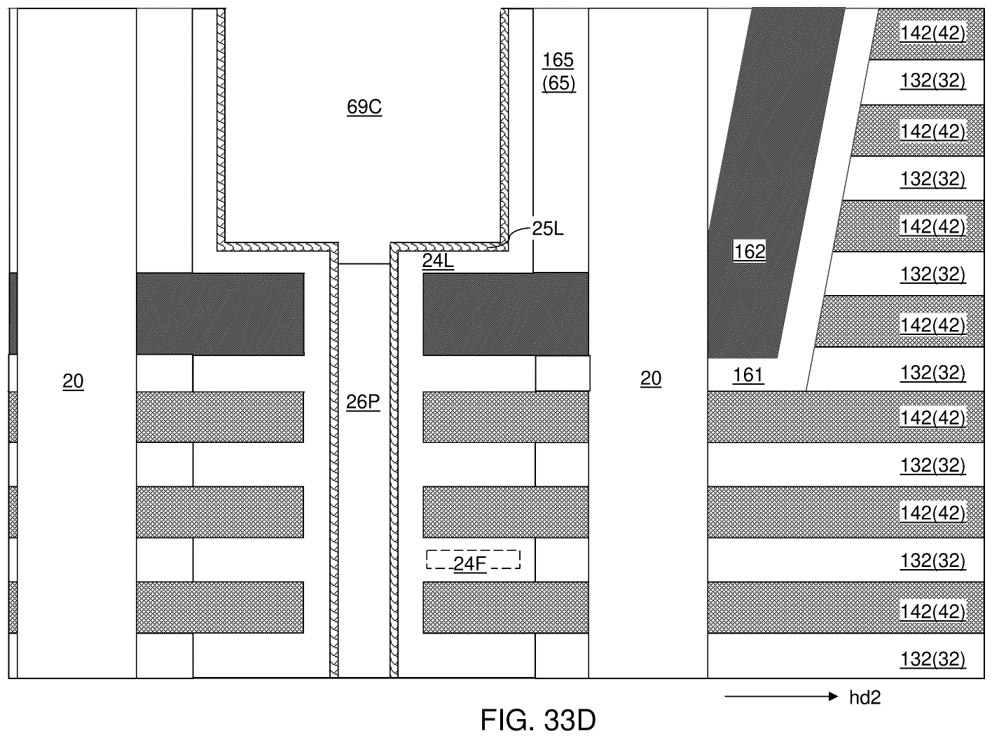

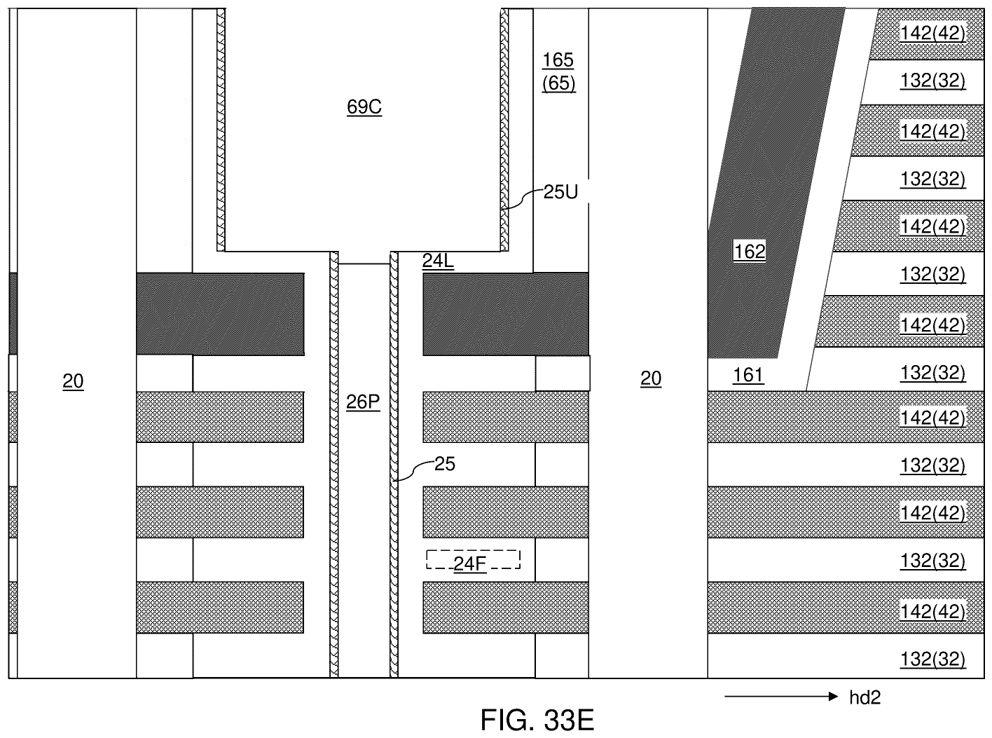

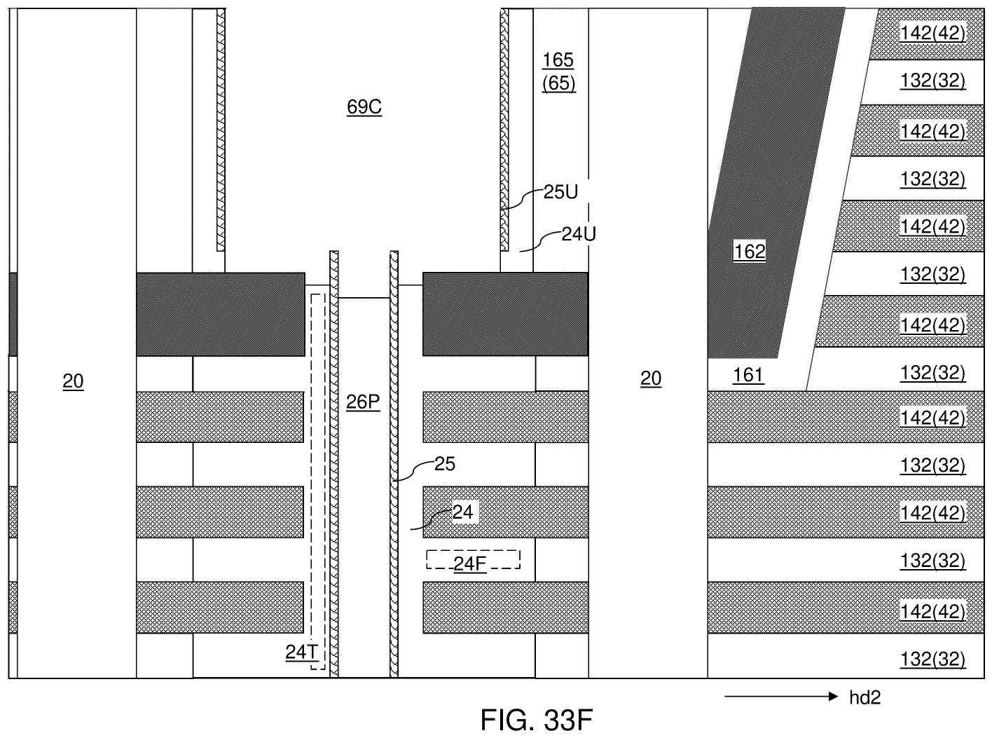

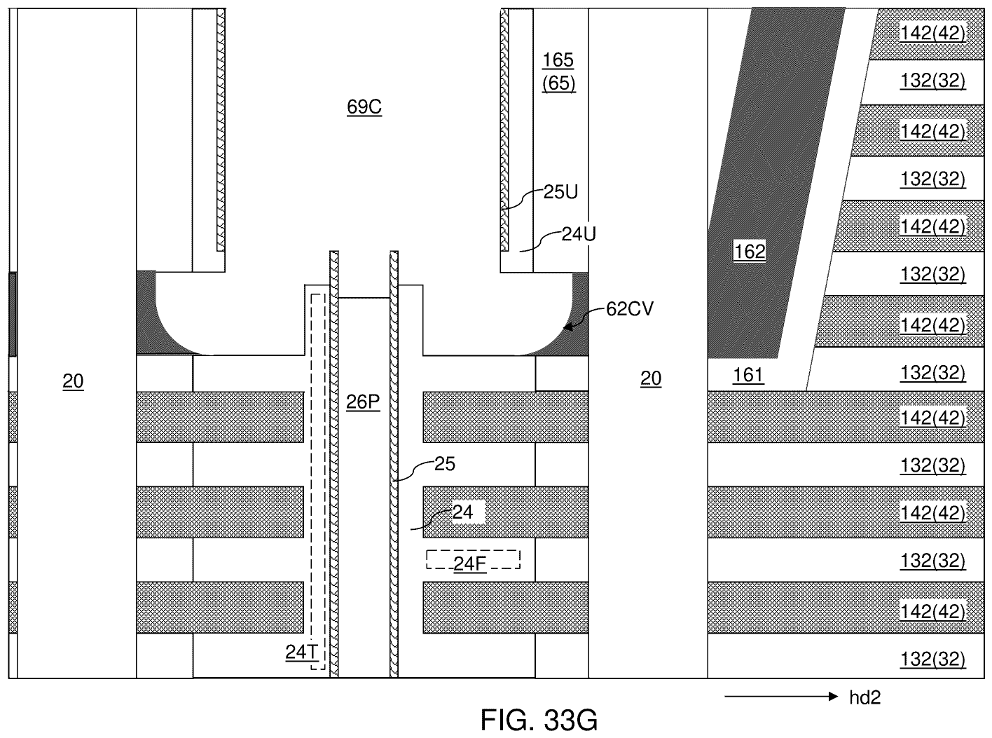

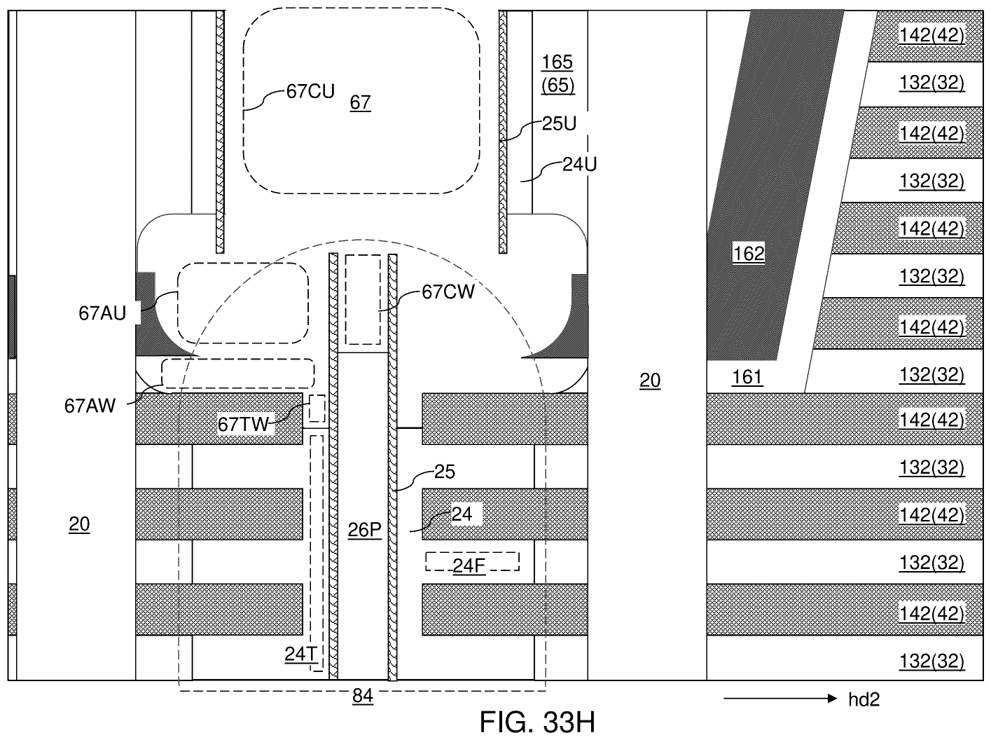

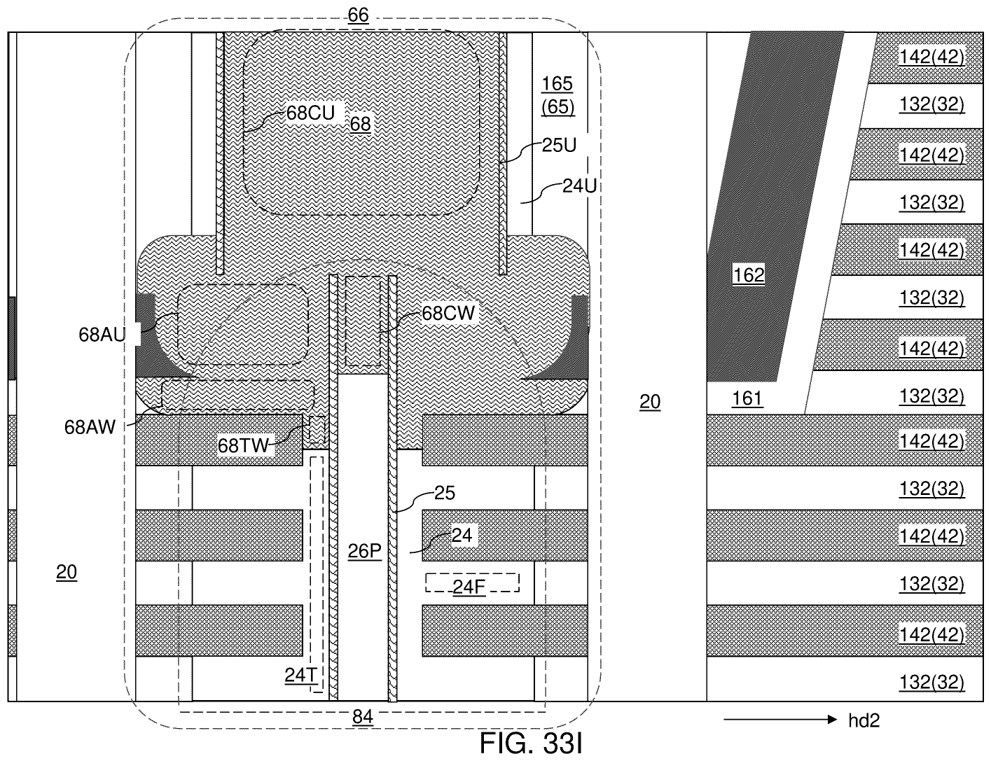

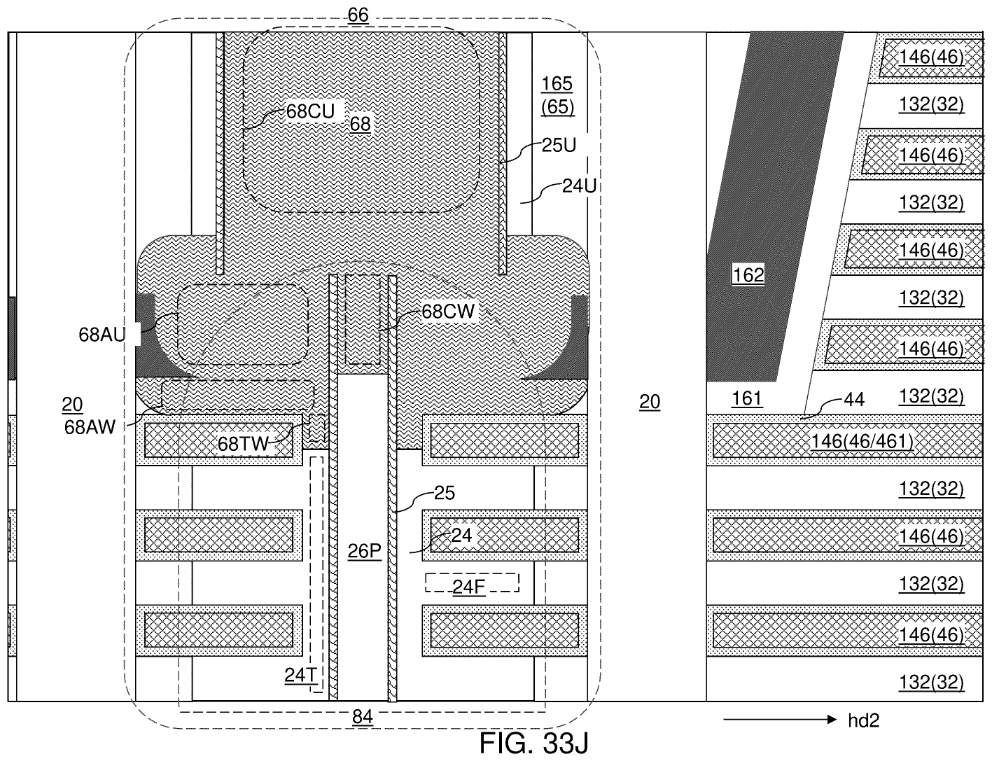

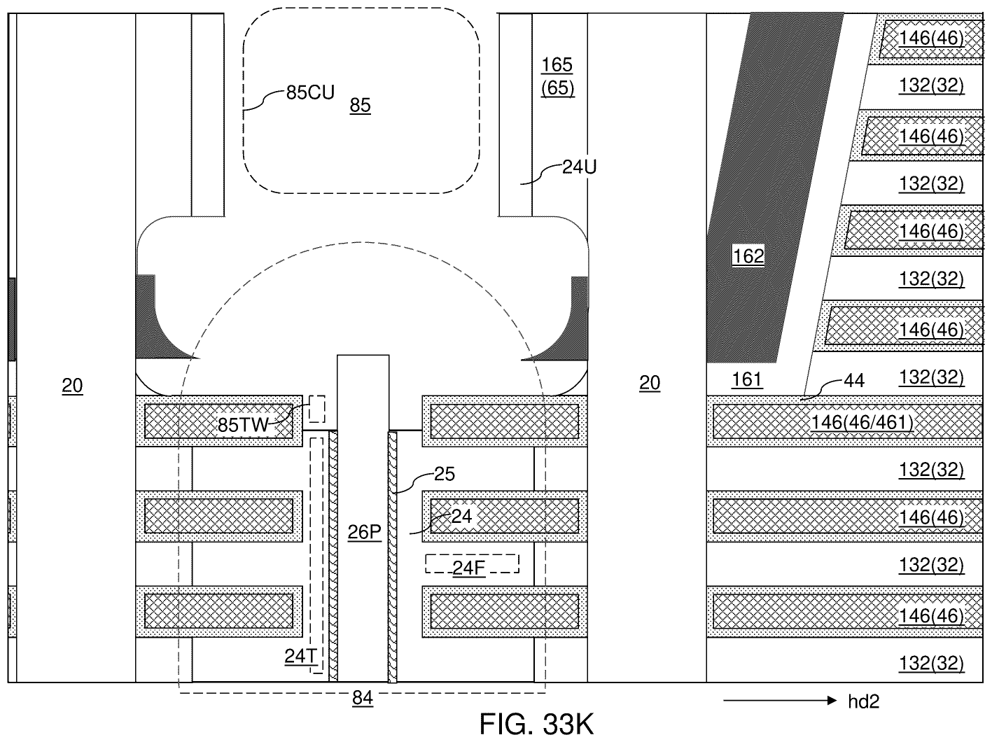

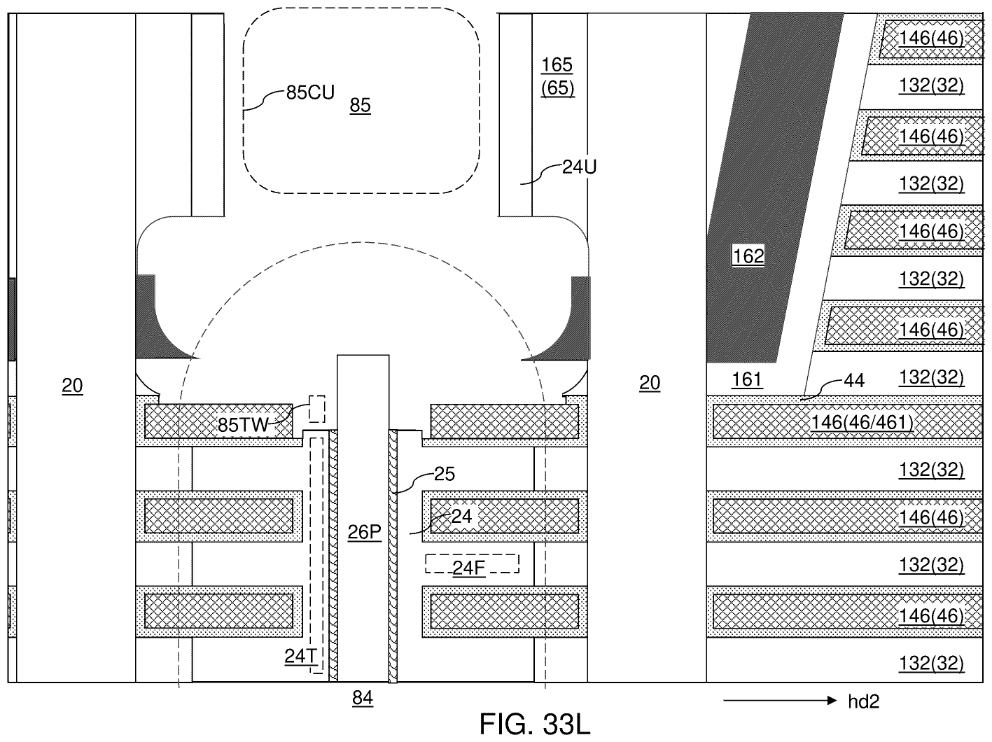

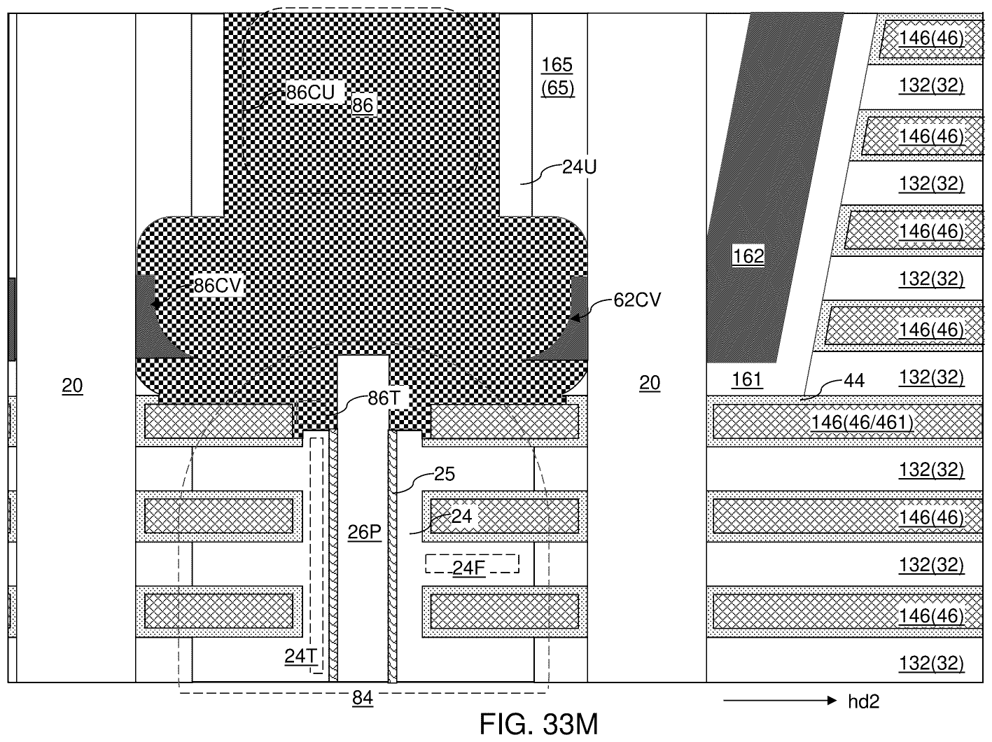

FIGS. 33A-33M are sequential vertical cross-sectional views of a region of a first configuration of a third exemplary structure during formation of a combination of a finned support assembly 84 and a layer contact via structure according to a third embodiment of the present disclosure.

Referring to FIG. 33A, the third exemplary structure may be the same as the first exemplary structure illustrated in FIGS. 11A-11C.

Referring to FIG. 33B, the processing steps described with reference to FIG. 12A can be performed. The third exemplary structure at the processing steps of FIG. 33B may be the same as the first exemplary structure at the processing steps of FIG. 12A.

Referring to FIG. 33C, a dielectric material layer 24L, a semiconductor liner layer 25L, and a dielectric fill material layer 26L can be sequentially deposited to fill the entire volume of each pillar cavity portion 69P and a peripheral region of an overlying portion of the contact via cavity. For example, the processing steps described within reference to FIGS. 12C and 12D may be performed to form the dielectric material layer 24L, the semiconductor liner layer 25L, and the dielectric fill material layer 26L.

Referring to FIG. 33D, a selective isotropic etch process can be performed to isotropically recess the material of the dielectric fill material layer 26L selective to the material of the semiconductor liner layer 25L. For example, a wet etch process employing dilute hydrofluoric acid can be performed to isotropically recess portions of the dielectric fill material layer 26L that overlies the silicon nitride buffer layer (162, 262, 362). The duration of the selective isotropic etch process can be selected such that surface segments of the semiconductor liner layer 25L are physically exposed above each annular interface between an annular bottom surface segment of the dielectric material layer 24L and an annular top surface segment of an underlying third-type perforated dielectric portion 23. Each remaining pillar-shaped dielectric material portion that is laterally surrounded by a tubular bottom portion of the semiconductor liner layer 25L comprises a cylindrical dielectric pillar 26P. Each cylindrical dielectric pillar 26P may have a cylindrical shape, and may have a respective top surface located at the level of a most proximal horizontally-extending portion of a silicon nitride buffer layer (162, 262, 362).

Referring to FIG. 33E, an anisotropic etch process can be performed to remove an annular horizontally-extending portion of the semiconductor liner layer 25L. Remaining portions of the semiconductor liner layer 25L include a tubular semiconductor liner 25 (which is also referred to as a lower tubular semiconductor liner) that laterally surrounds the cylindrical dielectric pillar 26P, and an additional tubular semiconductor liner 25U (which is also referred to as an upper tubular semiconductor liner).

Referring to FIG. 33F, another anisotropic etch process can be performed to remove an annular horizontally-extending portion of the dielectric material layer 24L. The dielectric material layer 24L can be divided into an upper tubular dielectric liner 24U that laterally surrounds the additional tubular semiconductor liner 25U (i.e., an upper tubular semiconductor liner), and a finned dielectric pillar 24 which comprises a tubular dielectric portion 24T and a plurality of dielectric fins 24F that laterally protrude from the tubular dielectric portion 24T. The finned dielectric pillar 24 surrounds the lower tubular semiconductor liner 25. An annular top surface segment of a silicon nitride barrier layer (162, 262, 362) can be physically exposed underneath a void within the contact via cavity.

Referring to FIG. 33G, a selective isotropic etch process can be performed to isotropically etch proximal portions of the silicon nitride buffer layer (162, 262, or 362) underneath the void in each contact via cavity 69C. For example, the selective isotropic etch process may comprise a wet etch process employing hot phosphoric acid. The duration of the selective isotropic etch process can be selected such that the etch distance of the selective isotropic etch process is greater than the thickness of the silicon nitride buffer layer (162, 262, or 362). An opening is formed through the silicon nitride buffer layer (162, 262, or 362) underneath each void in the contact via cavities. Each opening may comprise an annular concave surface segment 62CV of the silicon nitride buffer layer (162, 262, or 362).

Referring to FIG. 33H, an isotropic etch process can be performed to isotropically etch silicon oxide materials of the cylindrical dielectric pillar 26P, the finned dielectric pillar 24, the upper tubular dielectric liner 24U, and the retro-stepped dielectric material portions 65 selective to the semiconductor material of the tubular semiconductor liner 25 and the additional tubular semiconductor liner 25U and selective to the material of the silicon nitride buffer layer (162, 262, 362) and the sacrificial material layers 42. For example, the isotropic etch process may comprise a wet etch process employing dilute hydrofluoric acid as an etchant. A layer contact via cavity 67 is formed around each opening through a silicon nitride buffer layer (162, 262, 362). Each layer contact via cavity 67 may comprise an upper cylindrical cavity portion 67CU that is laterally surrounded by the additional tubular semiconductor liner 25U (i.e., an upper tubular semiconductor liner), a lower cylindrical cavity portion 67CW that is laterally surrounded by an upper segment of the tubular semiconductor liner 25, a tubular cavity portion 67TW that laterally surrounds a cylindrical segment of the tubular semiconductor liner 25, a lower annular cavity portion 67AW that is located between the silicon nitride buffer layer (162, 262, or 362) and a sacrificial material layer 42, and an upper annular cavity portion 67AU that is located between the silicon nitride buffer layer (162, 262, 362) and a contoured bottom surface segment of the retro-stepped dielectric material portion 65.

The assembly of all material portions that replaces materials of the insulating layers 32 and the sacrificial material layers 42 and underlies or located within an opening in a silicon nitride buffer layer (162, 262, 362) is herein referred to as a finned support assembly 84. The finned support assembly 84 comprises a cylindrical dielectric pillar 26P, a tubular semiconductor liner 25, and a finned dielectric pillar 24 laterally surrounding the tubular semiconductor liner 25 and comprising a tubular dielectric portion 24T and a plurality of dielectric fins 24F that laterally protrude from the tubular dielectric portion 24T.

Referring to FIG. 33I, a sacrificial via fill material can be deposited in the layer contact via cavities 67, and excess portions of the sacrificial via fill material can be removed from above the horizontal plane including the top surface of the topmost retro-stepped dielectric material portions 65 (such as the third-tier retro-stepped dielectric material portions 365). The sacrificial via fill material may comprise a semiconductor material such as amorphous silicon or polysilicon, or may comprise a carbon-based material such as amorphous carbon. Each remaining portion of the sacrificial via fill material that fills a layer contact via cavity 67 comprises a sacrificial contact via structure 68. Each stack of a finned support assembly 84 and a sacrificial contact via structure 68 constitutes an in-process contact assembly 66, which is subsequently modified to replace the sacrificial contact via structure 68 with a layer contact via structure.

Each sacrificial contact via structure 68 may comprise an upper cylindrical sacrificial material portion 68CU that is laterally surrounded by an upper tubular semiconductor oxide liner 28U, a lower cylindrical sacrificial material portion 68CW that is laterally surrounded by the tubular semiconductor liner 25, a tubular sacrificial material portion 68TW that laterally surrounds the tubular semiconductor liner 25, a lower annular sacrificial material portion 68AW that is located between the silicon nitride buffer layer (162, 262, or 362) and a sacrificial material layer 42, and an upper annular sacrificial material portion 68AU that is located between the silicon nitride buffer layer (162, 262, 362) and a contoured bottom surface segment of the retro-stepped dielectric material portion 65.

Referring to FIG. 33J, the processing steps described with reference to FIGS. 14-19C can be performed to form memory opening fill structures 58 and to replace the sacrificial material layers 42 with electrically conductive layers 46.

Referring to FIG. 33K, the processing steps described with reference to FIGS. 20A-21C can be performed to form lateral isolation trench fill structures 76 and connection via cavities, and to form layer contact via cavities 85 by removing the sacrificial contact via structures 68. The additional tubular semiconductor liners 25U and an upper cylindrical portion of each tubular semiconductor liner 25 may be collaterally removed during removal of the sacrificial contact via structure 68, if the sacrificial contact via structure 68 comprises the same semiconductor material (e.g., amorphous silicon) as the additional tubular semiconductor liners 25U. Each layer contact via cavity 85 may comprise an upper cylindrical cavity portion 85CU that is laterally surrounded by an upper tubular dielectric liner 24U and a tubular cavity portion 85TW that laterally surrounds an upper portion of a cylindrical dielectric pillar 26P.

Referring to FIG. 33L, an isotropic etch process such as a wet etch process can be performed to remove physically exposed surface portions of the outer blocking dielectric layers 44 (if present). An annular planar top surface segment and a cylindrical sidewall surface segment of an electrically conductive layer 46 can be physically exposed underneath each layer contact via cavity 85.

Referring to FIG. 33M, at least one electrically conductive material, such as at least one metallic material can be deposited in the layer contact via cavities 85. The at least one metallic material may comprise a combination of a metallic barrier liner material (such as TiN, TaN, WN, and/or MoN) and a metal fill material (such as W, Ru, Mo, Co, Cu, etc.). Excess portions of the at least one metallic material can be removed from above the horizontal plane including the top surface of the contact-level dielectric layer 80. Each remaining portion of the at least one metallic material that fills a respective layer contact via cavity 85 constitutes a layer contact via structure 86. Each layer contact via structure 86 may comprise a tubular portion 86T and an upper cylindrical portion 86CU.

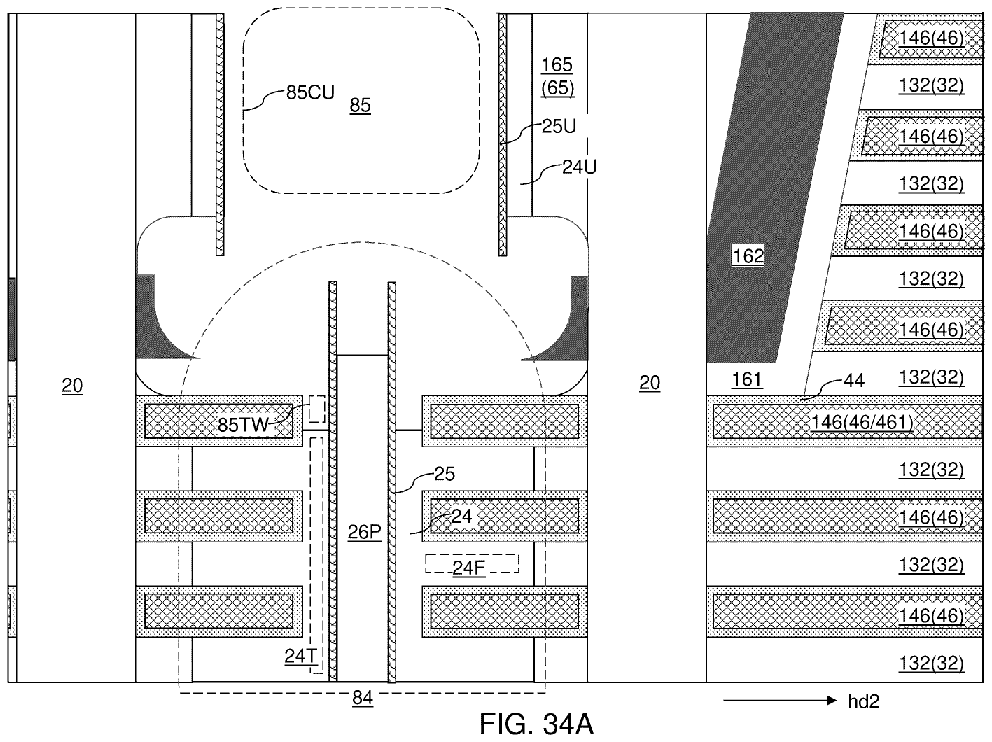

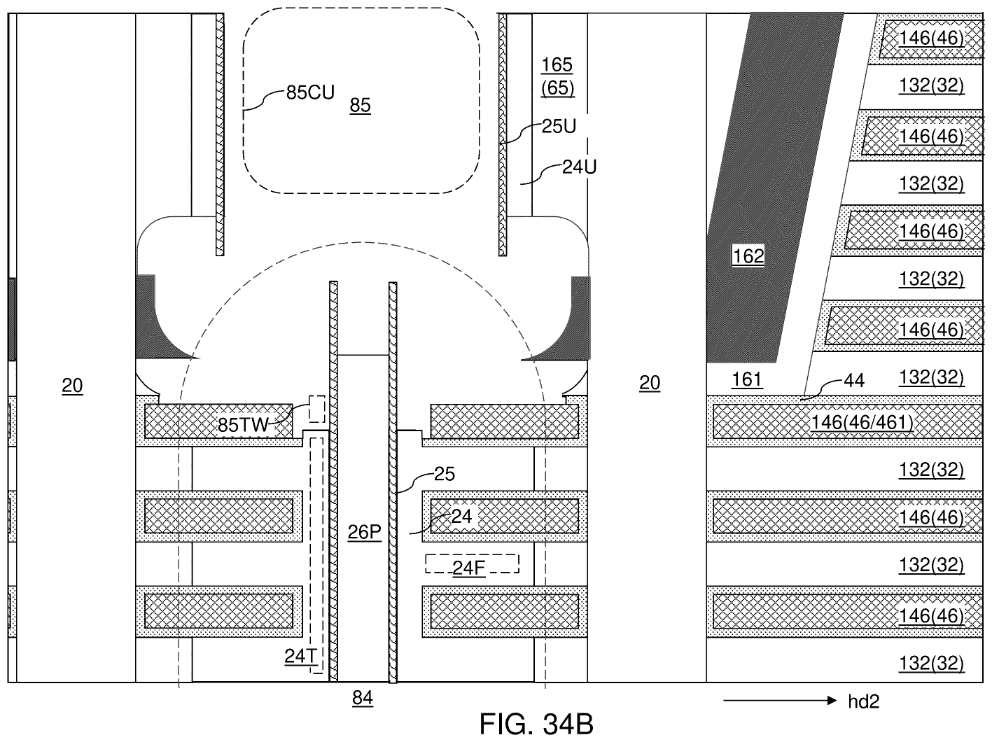

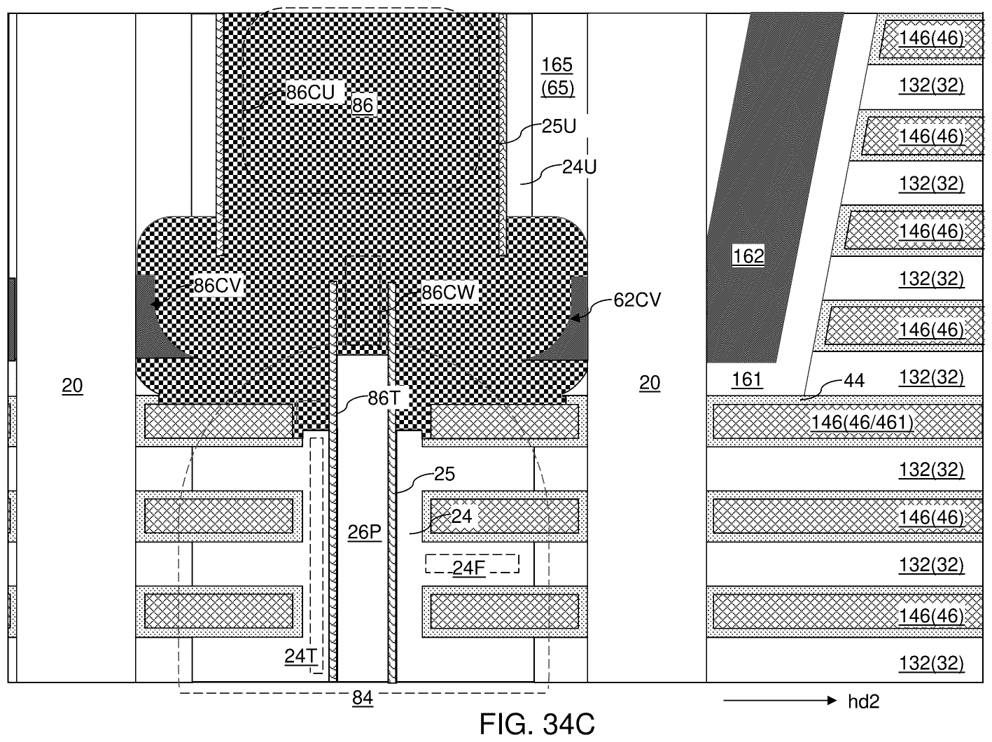

FIGS. 34A-34C are sequential vertical cross-sectional views of a region of a second configuration of a third exemplary structure during formation of a combination of a finned support assembly 84 and a layer contact via structure 86 according to the third embodiment of the present disclosure. In the second configuration, the sacrificial contact via structure 68 comprises a different material than the lower tubular semiconductor liner 25 and the upper tubular semiconductor liner 25U. For example, the sacrificial contact via structure 68 comprises a carbon material, such as amorphous carbon, and the lower tubular semiconductor liner 25 and the upper tubular semiconductor liner 25U comprise intrinsic amorphous silicon.

The structure of FIG. 34A may be derived from the structure of FIG. 33K after removal of the sacrificial contact via structure 68. In the second configuration, the sacrificial contact via structure 68 may be removed by ashing, and the lower tubular semiconductor liner 25 and the upper tubular semiconductor liner 25U remain unetched. Thus, the lower tubular semiconductor liner 25 protrudes into the layer contact via cavity 85 above the top surfaces of the cylindrical dielectric pillar 26P and the finned dielectric pillar 24. The upper tubular semiconductor liner 25U surrounds the upper cylindrical cavity portion 85CU. The upper tubular dielectric liner 24U surrounds the upper tubular semiconductor liner 25U.

The structure of FIG. 34B may be derived from the structure of FIG. 33L, except for the presence of the upper tubular semiconductor liner 25U, and the protrusion of the lower tubular semiconductor liner 25 into the layer contact via cavity 85 above the top surfaces of the cylindrical dielectric pillar 26P and the finned dielectric pillar 24.

The structure of FIG. 34C may be derived from the structure of FIG. 33M, except for the presence of the upper tubular semiconductor liner 25U which surrounds the upper cylindrical portion 86CU of the layer contact via structure 86. The layer contact via structure 86 also includes a lower cylindrical portion 86CW that is laterally surrounded by an upper segment of the lower tubular semiconductor liner 25 and has an outer sidewall surface segment which contacts an inner sidewall surface segment of the lower tubular semiconductor liner 25.

The third exemplary structure may comprise: an alternating stack (32, 46) of insulating layers 32 and electrically conductive layers 46, wherein the alternating stack (32, 46) comprises a staircase region; a retro-stepped dielectric material portion 65 overlying the alternating stack (32, 46) in the staircase region; and a contact assembly (84, 86) comprising a layer contact via structure 86 and a finned support assembly 84, wherein the layer contact via structure 86 vertically extends through the retro-stepped dielectric material portion 65 and comprises a contoured bottom surface that includes an annular horizontal surface segment that contacts an annular top surface segment of a first electrically conductive layer 461 of the electrically conductive layers 46, and the finned support assembly 84 contacts central surface segments of the contoured bottom surface.

In one embodiment, the finned support assembly 84 comprises a tubular semiconductor liner 25 having an outer cylindrical segment that contacts an annular surface segment of the contoured bottom surface of the layer contact via structure 86. In one embodiment, the finned support assembly 84 further comprises a cylindrical dielectric pillar 26P that is laterally surrounded by the tubular semiconductor liner 25. In the first configuration of FIG. 33M, the layer contact via structure 86 contacts a cylindrical surface segment of a sidewall of the cylindrical dielectric pillar 26P. In the second configuration of FIG. 34C, the tubular semiconductor liner 25 further comprises an inner cylindrical segment that contacts an outer surface segment of a lower cylindrical portion 86CW of the contoured bottom surface of the layer contact via structure 86.

In one embodiment, the finned support assembly 84 further comprises a finned dielectric pillar 24 that includes a tubular dielectric portion 24T in contact with a lower portion of a cylindrical outer sidewall of the tubular semiconductor liner 25 and further comprises a plurality of dielectric fins 24F that laterally protrude from the tubular dielectric portion 24T. In one embodiment, the plurality of dielectric fins 24F are located at levels of a subset of the insulating layers 32 that underlie the first electrically conductive layer 461.

In one embodiment, the contoured bottom surface further includes a cylindrical surface segment that contacts a cylindrical surface segment of an opening in the first electrically conductive layer 461. A layer stack including a silicon oxide buffer layer (161, 261, or 361) and a silicon nitride buffer layer (162, 262, or 362) can be interposed between the alternating stack (32, 46) and the retro-stepped dielectric material portion 65 in the staircase region. In one embodiment, the layer contact via structure 86 vertically extends through the layer stack; and the layer contact via structure 86 comprises an annular convex sidewall surface 86CV that contacts an annular concave sidewall surface 62CV of the silicon nitride buffer layer (162, 262, or 362).

In the first configuration of the third embodiment shown in FIG. 33M, an upper tubular dielectric liner 24U overlies the tubular semiconductor liner 25 and contacts a cylindrical sidewall of a portion of the layer contact via structure 86 that vertically extends through the retro-stepped dielectric material portion 65, and the upper tubular dielectric liner 24U is spaced from the first electrically conductive layer 461 by a laterally-bulging portion of the layer contact via structure 86.

In the second configuration of the third embodiment shown in FIG. 34C, an upper tubular dielectric liner 24U overlies the tubular semiconductor liner; and an additional tubular semiconductor liner 25U is surrounded by the upper tubular dielectric liner 24U and contacts a cylindrical sidewall of a portion of the layer contact via structure 86 that vertically extends through the retro-stepped dielectric material portion 65. The upper tubular dielectric liner 24U and the additional tubular semiconductor liner 25 are spaced from the first electrically conductive layer 461 by a laterally-bulging portion of the layer contact via structure 86.

Referring collectively to the third configuration of the second exemplary structure and the third exemplary structure, a device structure comprises: an alternating stack (32, 46) of insulating layers 32 and electrically conductive layers 46, wherein the alternating stack (32, 46) comprises a staircase region; a retro-stepped dielectric material portion 65 overlying the alternating stack (32, 46) in the staircase region; and a contact assembly (84, 86) comprising a layer contact via structure 86 and a finned support assembly 84, wherein the layer contact via structure 86 vertically extends through the retro-stepped dielectric material portion 65 and comprises a contoured bottom surface that includes an annular surface segment that contacts an annular top surface segment of a first electrically conductive layer 461 of the electrically conductive layers 46, and the finned support assembly 84 contacts central surface segments of the contoured bottom surface, wherein the finned support assembly 84 comprises a cylindrical dielectric pillar 26P, a spacer liner (25 or 222W) that laterally surrounds the cylindrical dielectric pillar 26P, and a finned dielectric pillar 24 that laterally surrounds the spacer liner (25 or 222W) and comprising a tubular dielectric portion 24T in contact with the spacer liner (25 or 222W) and a plurality of dielectric fins 24F that laterally protrude from the tubular dielectric portion 24T.

In the third embodiment, the spacer liner comprises a tubular semiconductor liner 25 comprising a semiconductor material. In the second embodiment, the spacer liner comprises a tubular silicon nitride liner 222W comprising silicon nitride. In one embodiment, the cylindrical dielectric pillar 26P comprises a top surface contacting a first surface segment of the layer contact via structure 86; the spacer liner (25 or 222W) contacts a second surface segment of the layer contact via structure 86; and the finned dielectric pillar 24 comprises a surface that contacts a third surface segment of the layer contact via structure 86.

In one embodiment, the layer contact via structure 86 comprises a tubular portion 86T having an inner cylindrical sidewall that contacts a cylindrical surface segment of the finned support assembly 84, and having an outer cylindrical sidewall that contacts a cylindrical surface segment of an opening in the first electrically conductive layer 461. In one embodiment, a layer stack including a silicon oxide buffer layer (161, 261, or 361) and a silicon nitride buffer layer (162, 262, or 362) can be interposed between the alternating stack (32, 46) and the retro-stepped dielectric material portion 65 in the staircase region. The layer contact via structure 86 vertically extends through the layer stack; and the layer contact via structure 86 comprises an annular convex sidewall surface that contacts an annular concave sidewall surface of the silicon nitride buffer layer (162, 262, or 362).

The various embodiments of the present disclosure provide layer contact via structures 86 that are self-aligned to a respective opening in a respective underlying first electrically conductive layer 461, and reduce the likelihood of a short circuit between the respective layer contact via structure 86 and a second electrically conductive layer 462 which is located below the first electrically conductive layer 461.

Although the foregoing refers to particular embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A device structure, comprising:
an alternating stack of insulating layers and electrically conductive layers, wherein the alternating stack comprises a staircase region;
a retro-stepped dielectric material portion overlying the alternating stack in the staircase region; and
a contact assembly comprising a layer contact via structure, a finned support assembly, and a doped silicate glass portion interposed between the finned support assembly and the layer contact via structure, wherein:
the layer contact via structure vertically extends through the retro-stepped dielectric material portion and comprises a contoured bottom surface that includes an annular surface segment that contacts an annular top surface segment of a first electrically conductive layer of the electrically conductive layers, and the finned support assembly contacts central surface segments of the contoured bottom surface of the layer contact via structure.

2. The device structure of claim 1, wherein the doped silicate glass portion comprises at least one dopant species selected from carbon and nitrogen.

3. The device structure of claim 1, wherein the doped silicate glass portion comprises a carbon-doped silicate glass containing carbon at an atomic percentage in a range from 1% to 25%.

4. The device structure of claim 1, wherein the doped silicate glass portion comprises a nitrogen-doped silicate glass containing nitrogen at an atomic percentage in a range from 1% to 25%.

5. The device structure of claim 1, wherein a maximum horizontal cross-sectional area of the doped silicate glass portion is greater than an area of a topmost surface of the finned support assembly.

6. The device structure of claim 1, wherein all surface segments of the doped silicate glass portion that overlie a topmost surface of the finned support assembly are in contact with surface segments of the layer contact via structure.

7. The device structure of claim 1, wherein the layer contact via structure comprises tubular portion having an outer cylindrical surface that contacts a cylindrical surface segment of an opening through the first electrically conductive layer, and wherein the tubular portion of the layer contact via structure contacts a cylindrical surface segment of the finned support assembly.

8. The device structure of claim 1, further comprising a memory opening fill structure vertically extending through the alternating stack, wherein the memory opening fill structure comprises a vertical semiconductor channel and a memory film.

9. The device structure of claim 1, wherein the finned support assembly comprises:
a dielectric material portion having a planar top surface that contacts a central bottom surface segment of the doped silicate glass portion; and
a spacer liner that laterally surrounds the dielectric material portion and contacting an annular bottom surface segment of the doped silicate glass portion.

10. The device structure of claim 9, wherein the spacer liner comprises an outer cylindrical surface segment that contacts a cylindrical surface segment of the layer contact via structure.

11. The device structure of claim 9, wherein:
the dielectric material portion comprises a cylindrical dielectric pillar; and
the finned support assembly further comprises a finned dielectric pillar that laterally surrounds the spacer liner and includes a tubular dielectric portion in contact with the spacer liner and a plurality of dielectric fins that laterally protrude from the tubular dielectric portion.

12. The device structure of claim 11, wherein the plurality of dielectric fins are located at levels of a subset of the insulating layers that underlie the first electrically conductive layer.

13. The device structure of claim 11, wherein the spacer liner comprises a semiconductor material or silicon oxycarbide.

14. The device structure of claim 9, wherein
the dielectric material portion comprises finned dielectric pillar that includes a cylindrical dielectric portion and a plurality of dielectric fins that laterally protrude from the cylindrical dielectric portion; and
the spacer liner comprises a plurality of laterally-protruding portions that embed the plurality of dielectric fins.

15. The device structure of claim 9, further comprising a layer stack including a silicon oxide buffer layer and a silicon nitride buffer layer and interposed between the alternating stack and the retro-stepped dielectric material portion in the staircase region, wherein:
the layer contact via structure vertically extends through the layer stack; and
the layer contact via structure comprises an annular convex sidewall surface that contacts an annular concave sidewall surface of the silicon nitride buffer layer.

16. A method of forming a device structure, comprising:
forming an alternating stack of insulating layers and sacrificial material layers over a substrate;
forming stepped surfaces by patterning the alternating stack;
forming a retro-stepped dielectric material portion overlying the stepped surfaces;
forming a contact via cavity through the retro-stepped dielectric material portion and the alternating stack;
forming a combination of a finned support assembly, a doped silicate glass portion overlying the finned support assembly, and a sacrificial contact via structure in the contact via cavity;
replacing the sacrificial material layers with electrically conductive layers; and
replacing the sacrificial contact via structure with a layer contact via structure that directly contacts an annular surface segment of a first electrically conductive layer of the electrically conductive layers.

17. The method of claim 16, further comprising laterally recessing surface portions of the insulating layers and the retro-stepped dielectric material portion around the contact via cavity by performing a selective isotropic etch process, wherein annular fin cavities are formed in volumes from which portions of the insulating layers are removed, and an upper portion of the contact via cavity is laterally expanded at a level of the retro-stepped dielectric material portion.

18. The method of claim 17, further comprising:
depositing at least one fill material that includes a silicate glass material in the contact via cavity, wherein portions of the contact via cavity laterally surrounded by the alternating stack are filled with the at least one fill material, and wherein a cylindrical cavity is present within the upper portion of the contact via cavity; and
implanting at least one dopant species selected from nitrogen and carbon into a portion of the silicate glass material that underlies the cylindrical cavity and overlies the alternating stack to form the doped silicate glass portion.

19. The method of claim 18, further comprising removing an unimplanted portion of the silicate glass material selective to the doped silicate glass portion.

20. The method of claim 18, further comprising:
forming a layer stack including a silicon oxide buffer layer and a silicon nitride buffer layer over the stepped surfaces, wherein the retro-stepped dielectric material portion is formed over the layer stack, and wherein the contact via cavity is formed through the layer stack;
performing an etch processes that etches the layer stack selective to the doped silicate glass portion; and
performing at least one additional etch process that physically exposes an annular top surface segment of one of the sacrificial material layers.
